(19) United States
(12) Patent Application Publication
(10) Pub. No.: US 2025/0176425 A1
(43) Pub. Date: May 29, 2025

(54) ELECTROACTIVE COMPOUNDS AND ELECTROLUMINESCENT DEVICE COMPRISING THE SAME

(71) Applicant: DUPONT ELECTRONICS, INC., WILMINGTON, DE (US)

(72) Inventors: YUNLONG ZOU, WILMINGTON, DE (US); DENIS KONDAKOV, WILMINGTON, DE (US); HJALTI SKULASON, WILMINGTON, DE (US); VIACHESLAV V. DIEV, WILMINGTON, DE (US); NORMAN HERRON, WILMINGTON, DE (US)

(21) Appl. No.: 18/901,522

(22) Filed: Sep. 30, 2024

Related U.S. Application Data
(60) Provisional application No. 63/602,770, filed on Nov. 27, 2023.

(51) Int. Cl. H10K 85/60; C09K 11/02; H10K 50/12; H10K 85/40

(52) U.S. Cl. CPC H10K 85/633; C09K 11/02; H10K 50/12; H10K 85/40; H10K 85/615; H10K 85/622; H10K 85/6574

(57) ABSTRACT

There is provided a composition comprising a mixture of a first compound and a second compound which can be processed into thin film(s) for use in organic electronic devices. Devices with layers comprising these films exhibit enhanced efficiency and other operational characteristics.

### BACKGROUND INFORMATION

### Field of the Disclosure

This disclosure relates in general to aryl amine compounds and their use in electronic devices.

### Description of the Related Art

Organic electronic devices that emit light, such as light-emitting diodes that make up displays, are present in many different kinds of electronic equipment. In all such devices, an organic active layer is positioned between two electrical contact layers. At least one of the electrical contact layers is light transmitting so that light can pass through the electrical contact layer. The organic active layer emits light through the light-transmitting electrical contact layer upon application of electricity across the electrical contact layers.

Such organic light emitting (OLED) devices have become a mainstream display technology in recent years. The most common blue host materials used in commercial OLED devices are anthracene-based molecules, some of which incorporate oxygen atoms. These oxygen-containing molecules typically have a dipole moment close to or above 1 Debye, and many form polarized layers with the negative end of the macroscopic dipole pointing towards the substrate when vapor deposited. The manifestation of spontaneous orientation polarization (SOP) in OLED devices was first reported in 2000, when Berleb et al. (Organic Electronics 2000, 1 (1) 41-47) observed an injection of holes at negative voltage that was linearly dependent on thickness of Alq₃ layer and interpreted these observations in terms of interfacial charge inherently present at NPB|Alq3 interface. In 2002 Ito et al. (J. Appl. Phys. 2002, 92 (12), 7306) discovered that the similarly thickness-dependent potential (termed giant surface potential—GSP) was present on the surface of vacuum-deposited Alq₃ films and proposed that the spontaneous preferential orientation of Alq₃ molecule results in formation of a macroscopic dipole and bulk polarization. Later, it was discovered that SOP in OLED devices can lead to charge accumulation at interfaces and affect device operation (see, for example, Kondakov et al., J. Appl. Phys. 2002, 93 (2) 1108). In state-of-the art blue fluorescent OLED, polarization in the emissive layer (EML) causes charge accumulation at both HTL/EML and ETL/EML interfaces before the device turns on. Such an increase in charge density, especially at the EML/ETL interface, facilitates charge injection and reduces device operating voltage. When compared with a device using non-polarized host material (purely aromatic hydrocarbon anthracene derivatives), the voltage reduction can be more than 0.5 V at 1000 nits, resulting in improved power efficiency. Additionally, lower blue pixel operating voltage has benefits in terms of reducing lateral leakage and preventing color shift at low luminance in high resolution OLED displays (see, for example, Diethelm et al., J. Info. Disp. 2018, 19, 1). However, devices with polarized EML typically show lower efficiency, especially at low luminance, presumably due to additional quenching of excitons caused by larger density of holes in the vicinity of recombination zone. Considering all the benefits of using polarized EML in fluorescent blue devices, there is an ongoing need to identify a way to recover device efficiency without eliminating the SOP in EML.

### SUMMARY

There is provided a composition comprising a mixture of a first aryl amine compound and a second aryl amine compound, a thin film comprising a first aryl amine compound and a second aryl amine compound, and an organic electronic device comprising an electron blocking layer comprising one or more aryl amine compounds.

### BRIEF DESCRIPTION OF THE DRAWINGS

Embodiments are illustrated in the accompanying figures to improve understanding of concepts as presented herein.

FIG. 1 includes an illustration of one example of an organic electronic device including the layer structure described herein.

FIG. 2 includes an illustration of another example of an organic electronic device including the layer structure described herein.

FIG. 3 includes an illustration of another example of an organic electronic device including the layer structure described herein.

FIG. 4 includes an illustration of relative OLED device efficiency as a function of the SOP of the electron blocking layer (EBL) for the devices described herein.

Skilled artisans appreciate that objects in the figures are illustrated for simplicity and clarity and have not necessarily been drawn to scale. For example, the dimensions of some of the objects in the figures may be exaggerated relative to other objects to help to improve understanding of the associated embodiments.

The foregoing general description and the following detailed description are exemplary and explanatory only and are not restrictive of the invention, as defined in the appended claims.

### DETAILED DESCRIPTION

Many aspects and embodiments are described herein and are merely exemplary and not limiting. After reading this specification, skilled artisans appreciate that other aspects and embodiments are possible without departing from the scope of the invention.

Other features and benefits of any one or more of the embodiments will be apparent from the following detailed description, and from the claims. The detailed description first addresses Definitions and Clarification of Terms followed by Mixtures of Aryl Amine Compounds; Thin Films; Organic Electronic Device; and finally, Examples.

### 1. Definitions and Clarification of Terms

Before addressing details of embodiments described below, some terms are defined or clarified.

As used throughout this specification, the following abbreviations shall have the following meanings, unless the context clearly indicates otherwise: ° C.=degree Celsius; g=gram; nm=nanometer, μm=micron=micrometer; mm=millimeter; sec.=second; and min.=minutes. All amounts are percent by weight (“Weight %” or “wt. %”) and all ratios are molar ratios, unless otherwise noted. All numerical ranges are inclusive and combinable in any order, except where it is clear that such numerical ranges are constrained to add up to 100%. Unless otherwise noted all polymer and oligomer molecular weights are weight average molecular weights (‘Mw”) with unit of g/mol or Dalton and are determined using gel permeation chromatography compared to polystyrene standards.

The articles “a”, “an” and “the” refer to the singular and the plural, unless the context clearly indicates otherwise. As used herein, the term “and/or” includes any and all combinations of one or more of the associated items.

As used in herein, R, R^{a}, R^{b}, R′, R″ and any other variables are generic designations and may be the same as or different from those defined in the formulas.

As used herein, the term “adjacent” as it refers to substituent groups refers to groups that are bonded to carbons that are joined together with a single or multiple bond. Exemplary adjacent R groups are shown below:

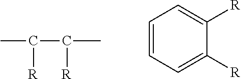

The term “alkoxy” is intended to mean the group RO—, where R is an alkyl group.

The term “alkyl” is intended to mean a group derived from an aliphatic hydrocarbon and includes a linear, a branched, or a cyclic group. A group “derived from” a compound, indicates the radical formed by removal of one or more H or D.

In some embodiments, an alkyl has from 1-20 carbon atoms.

The term “aromatic compound” is intended to mean an organic compound comprising at least one unsaturated cyclic group having 4n+2 delocalized pi electrons.

The term “aryl” is intended to mean a group derived from an aromatic hydrocarbon having one or more points of attachment. The term includes groups which have a single ring and those which have multiple rings which can be joined by a single bond or fused together. Carbocyclic aryl groups have only carbon in the ring structures. Heteroaryl groups have at least one heteroatom in a ring structure.

The term “aryl amine” or “aryl amine group” is intended to mean a specific type of heteroaryl group wherein the heteroatom is an amino nitrogen (N) that is directly bonded to one or more aromatic rings or aryl groups.

The term “alkylaryl” is intended to mean an aryl group having one or more alkyl substituents.

The term “aryloxy” is intended to mean the group RO—, where R is an aryl group.

The term “charge transport,” when referring to a layer, material, member, or structure is intended to mean such layer, material, member, or structure that facilitates migration of such charge through the thickness of such layer, material, member, or structure with relative efficiency and small loss of charge. Hole transport materials facilitate positive charge; electron transport materials facilitate negative charge. Although light-emitting materials may also have some charge transport properties, the term “charge transport layer, material, member, or structure” is not intended to include a layer, material, member, or structure whose primary function is light emission.

The term “core structure” as it refers to compounds is intended to mean a specific group of atoms bonded together in a specific partial structure.

The term “deuterated” is intended to mean that at least one hydrogen (“H”) has been replaced by deuterium (“D”). The term “deuterated analog” refers to an analog of a compound or group having the same structure but in which one or more available hydrogens have been replaced with deuterium. In a deuterated compound or deuterated analog, the deuterium is present in at least 100 times the natural abundance level. The term “% deuterated” or “% deuteration” is intended to mean the ratio of deuterons to the sum of protons plus deuterons, expressed as a percentage.

The term “dipole moment” or “p” is intended to mean a measure of the separation of positive and negative electrical charges within a molecule or system. It is a measure of the resulting overall polarity and can be expressed in units of debye (D).

The term “dopant” is intended to mean a material, within a layer including a host material, that changes the electronic characteristic(s) or the targeted wavelength(s) of radiation emission, reception, or filtering of the layer compared to the electronic characteristic(s) or the wavelength(s) of radiation emission, reception, or filtering of the layer in the absence of such material.

The term “germyl” refers to the group R₃Ge—, where R is the same or different at each occurrence and is H, D, C1-20 alkyl, deuterated alkyl, fluoroalkyl, aryl, or deuterated aryl.

The term “glass transition temperature,” or “T_{g}” is intended to mean the temperature at which an amorphous material undergoes a reversible change from a relatively-brittle glassy state into a viscous or rubbery state upon heating.

The prefix “hetero” indicates that one or more carbon atoms have been replaced with a different atom. In some embodiments, the different atom is N, O, or S.

The term “host material” is intended to mean a material, usually in the form of a layer, to which a dopant may be added. The host material may or may not have electronic characteristic(s) or the ability to emit, receive, or filter radiation.

The terms “luminescent material”, “emissive material” and “emitter” are intended to mean a material that emits light when activated by an applied voltage (such as in a light-emitting diode or light-emitting electrochemical cell). The term “blue luminescent material” is intended to mean a material capable of emitting radiation that has an emission maximum at a wavelength in a range of approximately 445-490 nm.

The term “layer” is used interchangeably with the term “film” and refers to a coating covering a desired area. The term is not limited by size. The area can be as large as an entire device or as small as a specific functional area such as the actual visual display, or as small as a single sub-pixel. Layers and films can be formed by any conventional deposition technique, including vapor deposition, liquid deposition (continuous and discontinuous techniques), and thermal transfer. Continuous deposition techniques, include but are not limited to, spin coating, gravure coating, curtain coating, dip coating, slot-die coating, spray coating, and continuous nozzle coating or printing. Discontinuous deposition techniques include, but are not limited to, ink jet printing, gravure printing, and screen printing.

The term “N-heterocycle” or “N-heteroaryl” refers to a heteroaromatic compound or group having at least one nitrogen in an aromatic ring.

The term “N,O,S-heterocycle” or “N,O,S-heteroaryl” refers to a heteroaromatic compound or group having at least one heteroatom in an aromatic ring, where the heteroatom is N, O, or S. The N,O,S-heterocycle may have more than one type of heteroatom.

The term “organic electronic device” or sometimes just “electronic device” is intended to mean a device including one or more organic semiconductor layers or materials.

The term “photoactive” refers to a material or layer that emits light when activated by an applied voltage (such as in a light emitting diode or chemical cell) or responds to radiant energy and generates a signal with or without an applied bias voltage (such as in a photodetector or a photovoltaic cell). The photoactive material or layer is sometimes referred to as the emissive layer. The photoactive layer is abbreviated herein as “EML” and may also be referred to as the “emissive layer.”

The term “electron blocking” refers to an optional material or layer that is between the HTL and EML which can function to manipulate positive and/or negative charges so as to improve the performance characteristics of an organic electronic device.

The term “siloxane” refers to the group R₃SiO(R₂Si)—, where R is the same or different at each occurrence and is H, D, C1-20 alkyl, deuterated alkyl, fluoroalkyl, aryl, or deuterated aryl. In some embodiments, one or more carbons in an R alkyl group are replaced with Si.

The term “siloxy” refers to the group R₃SiO—, where R is the same or different at each occurrence and is H, D, C1-20 alkyl, deuterated alkyl, fluoroalkyl, aryl, or deuterated aryl.

The term “silyl” refers to the group R₃Si—, where R is the same or different at each occurrence and is H, D, C1-20 alkyl, deuterated alkyl, fluoroalkyl, aryl, or deuterated aryl. In some embodiments, one or more carbons in an R alkyl group are replaced with Si.

The term “spontaneous orientation polarization,” which can be abbreviated “SOP,” refers to a phenomenon which can develop when molecules exhibiting a non-zero dipole moment adopt a preferred relative orientation when evaporated to form films. Specific chemical functionalities present in certain film-forming molecules can cause the vapor-deposited films to exhibit a net polarization that can be measured, for example, in units of mV/nm. This phenomenon is not observed when nonpolar molecules are evaporated to form films or when polar molecules are evaporated with random orientation. SOP values are defined as positive when the associated polarization is directed towards the substrate and negative when the associated polarization is directed away from the substrate.

All groups may be unsubstituted or substituted. The substituent groups are discussed below. In a structure where a substituent bond passes through one or more rings as shown below,

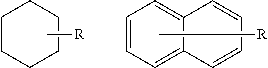

it is meant that the substituent R may be bonded at any available position on the one or more rings.

In any of the formulas or combination of formulas below, any subscript, such as a-h, k, p, q, r, s, a1, b1, and k1, that is present more than one time, may be the same or different at each occurrence.

In this specification, unless explicitly stated otherwise or indicated to the contrary by the context of usage, where an embodiment of the subject matter hereof is stated or described as comprising, including, containing, having, being composed of or being constituted by or of certain features or elements, one or more features or elements in addition to those explicitly stated or described may be present in the embodiment. An alternative embodiment of the disclosed subject matter hereof, is described as consisting essentially of certain features or elements, in which embodiment features or elements that would materially alter the principle of operation or the distinguishing characteristics of the embodiment are not present therein. A further alternative embodiment of the described subject matter hereof is described as consisting of certain features or elements, in which embodiment, or in insubstantial variations thereof, only the features or elements specifically stated or described are present.

Also, use of “a” or “an” are employed to describe elements and components described herein. This is done merely for convenience and to give a general sense of the scope of the invention. This description should be read to include one or at least one and the singular also includes the plural unless it is obvious that it is meant otherwise.

Group numbers corresponding to columns within the Periodic Table of the elements use the “New Notation” convention as seen in the CRC Handbook of Chemistry and Physics, 81^{st} Edition (2000-2001).

Unless otherwise defined, all technical and scientific terms used herein have the same meaning as commonly understood by one of ordinary skill in the art to which this invention belongs. Although methods and materials similar or equivalent to those described herein can be used in the practice or testing of embodiments of the present invention, suitable methods and materials are described below. In addition, the materials, methods, and examples are illustrative only and not intended to be limiting.

To the extent not described herein, many details regarding specific materials, processing acts, and circuits are conventional and may be found in textbooks and other sources within the organic light-emitting diode display, photodetector, photovoltaic cell, and semiconductive member arts.

In this specification, unless explicitly stated otherwise or indicated to the contrary by the context of usage, where an embodiment of the subject matter hereof is stated or described as comprising, including, containing, having, being composed of, or being constituted by or of certain features or elements, one or more features or elements in addition to those explicitly stated or described may be present in the embodiment. An alternative embodiment of the disclosed subject matter hereof is described as consisting essentially of certain features or elements in which embodiment features or elements that would materially alter the principle of operation or the distinguishing characteristics of the embodiment are not present therein. A further alternative embodiment of the described subject matter hereof is described as consisting of certain features or elements in which embodiment, or in insubstantial variations thereof, only the features or elements specifically stated or described are present.

Unless otherwise defined, all technical and scientific terms used herein have the same meaning as commonly understood by one of ordinary skill in the art to which this disclosure belongs. Although methods and materials similar or equivalent to those described herein can be used in the practice or testing of embodiments of the present disclosure, suitable methods and materials are described below. In addition, the materials, methods, and examples are illustrative only and not intended to be limiting.

### 2. Polarized Aryl Amine Compounds and Mixtures Thereof

There is provided herein a composition comprising a mixture of a first compound and a second compound; wherein the first compound has a different chemical structure than the second compound; wherein the first compound and the second compound have molecular weights between 300 and 1000; wherein the first compound and the second compound have glass transition temperatures (T_{g}'s) greater than 105° C.; wherein the first compound and the second compound each comprise one or more aryl amine groups; wherein the first compound has a concentration C1 in the mixture; wherein the second compound has a concentration C2 in the mixture; wherein C1 is between 1 wt. % and 99 wt. %; and C2 is between 1 wt. % and 99 wt. %.

In some non-limiting embodiments of the composition comprising a mixture of a first compound and a second compound disclosed herein, the first compound and the second compound have molecular weights between 100 and 3000, in some non-limiting embodiments between 200 and 2000, in some non-limiting embodiments between 300 and 1000, in some non-limiting embodiments between 400 and 900, in some non-limiting embodiments between 500 and 800, and in some non-limiting embodiments between 600 and 700.

Since the first compound and the second compound have different chemical structures, non-limiting embodiments of the composition disclosed herein will generally have first compounds and second compounds with molecular weights that are different from one another. One having ordinary skill in the art will recognize that embodiments wherein the first compound and second compound have identical molecular weights are possible in select circumstances.

In some non-limiting embodiments of the composition comprising a mixture of a first compound and a second compound disclosed herein, the first compound and the second compound have glass transition temperatures (Tg's) greater than 90° C., in some non-limiting embodiments greater than 95° C., in some non-limiting embodiments greater than 100° C., in some non-limiting embodiments greater than 105° C., in some non-limiting embodiments greater than 110° C., in some non-limiting embodiments greater than 115° C., in some non-limiting embodiments greater than 120° C., in some non-limiting embodiments greater than 125° C., in some non-limiting embodiments greater than 130° C., in some non-limiting embodiments greater than 135° C., in some non-limiting embodiments greater than 140° C., in some non-limiting embodiments greater than 145° C., in some non-limiting embodiments greater than 150° C., in some non-limiting embodiments greater than 155° C., in some non-limiting embodiments greater than 160° C., in some non-limiting embodiments greater than 165° C., in some non-limiting embodiments greater than 170° C., in some non-limiting embodiments greater than 180° C., in some non-limiting embodiments greater than 190° C., and in some non-limiting embodiments greater than 200° C.

Since the first compound and the second compound have different chemical structures, non-limiting embodiments of the composition disclosed herein will generally have first compounds and second compounds with glass transition temperatures (T_{g}'s) that are different from one another. One having ordinary skill in the art will recognize that embodiments wherein the first compound and second compound have identical glass transition temperatures (T_{g}'s) are possible in select circumstances.

In some non-limiting embodiments of the composition comprising a mixture of a first compound and a second compound disclosed herein, the first compound comprises one aryl amine group, in some non-limiting embodiments two aryl amine groups, in some non-limiting embodiments three aryl amine groups, in some non-limiting embodiments four aryl amine groups, and in some non-limiting embodiments 5 or more aryl amine groups.

In some non-limiting embodiments of the composition comprising a mixture of a first compound and a second compound disclosed herein, the second compound comprises one aryl amine group, in some non-limiting embodiments two aryl amine groups, in some non-limiting embodiments three aryl amine groups, in some non-limiting embodiments four aryl amine groups, and in some non-limiting embodiments 5 or more aryl amine groups.

In some non-limiting embodiments of the composition comprising a mixture of a first compound and a second compound disclosed herein, the first compound has a dipole moment μ1 and a concentration C1 wherein C1 is between 1 wt. % and 99 wt. %, in some non-limiting embodiments between 10 wt. % and 90 wt. %, in some non-limiting embodiments between 20 wt. % and 80 wt. %, in some non-limiting embodiments between 30 wt. % and 70 wt. %, and in some non-limiting embodiments between 40 wt. % and 60 wt. %.

In some non-limiting embodiments of the composition comprising a mixture of a first compound and a second compound disclosed herein, the second compound has a dipole moment μ2 and a concentration C2 wherein C2 is between 1 wt. % and 99 wt. %, in some non-limiting embodiments between 10 wt. % and 90 wt. %, in some non-limiting embodiments between 20 wt. % and 80 wt. %, in some non-limiting embodiments between 30 wt. % and 70 wt. %, and in some non-limiting embodiments between 40 wt. % and 60 wt. %.

In some non-limiting embodiments of the composition comprising a mixture of a first compound and a second compound disclosed herein, the first compound has a dipole moment μ1 wherein μ1 is greater than 0.1 D, in some nonlimiting embodiments greater than 0.2 D, in some non-limiting embodiments greater than 0.3 D, in some non-limiting embodiments greater than 0.4 D, in some non-limiting embodiments greater than 0.5 D, in some non-limiting embodiments greater than 0.6 D, in some non-limiting embodiments greater than 0.7 D, and in some non-limiting embodiments greater than 0.8 D.

In some non-limiting embodiments of the composition comprising a mixture of a first compound and a second compound disclosed herein, the second compound has a dipole moment μ2 wherein μ2 greater than 0.1 D, in some nonlimiting embodiments greater than 0.2 D, in some non-limiting embodiments greater than 0.3 D, in some non-limiting embodiments greater than 0.4 D, in some non-limiting embodiments greater than 0.5 D, in some non-limiting embodiments greater than 0.6 D, in some non-limiting embodiments greater than 0.7 D, and in some non-limiting embodiments greater than 0.8 D.

In some non-limiting embodiments of the composition comprising a mixture of a first compound and a second compound disclosed herein, the first compound and/or the second compound have a chemical structure given by Formula 1:

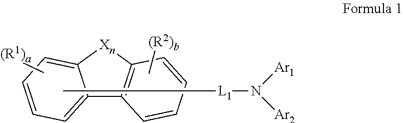

wherein
X represents —O—, —S—, —Si(R′)(R″)—, —N(R)—, —C(R′)(R″)—, —Se—, or (R′)(R″)C-C(R′″)(R″″);
R, R′, and R″ each independently represent a substituted or unsubstituted (C1-C30)alkyl, a substituted or unsubstituted (C6-C30)aryl, or a substituted or unsubstituted (3- to 30-membered)heteroaryl, -L2-N—(Ar₃)(Ar₄) or -L3-N(Ar₅)-L₄-N—(Ar₆)(Ar₇); or R′ and R″ may be linked to each other to form a ring(s), and R′ and R″ may be the same or different;
Ar₁-Ar₇ each independently represent hydrogen, deuterium, a substituted or unsubstituted (C1-C30)alkyl, a substituted or unsubstituted (C6-C30)aryl, a substituted or unsubstituted (3- to 30-membered) heteroaryl, a substituted or unsubstituted mono- or di-(C1-C30) alkylamino, a substituted or unsubstituted mono- or di-(C6-C30)arylamino, or a substituted or unsubstituted (C1-C30)alkyl(C6-C30)arylamino, where if a plurality of Ar₁-Ar₇ is present, each of adjacent Ar₁-Ar₇ may be the same or different; wherein
if Ar₁-Ar₇ each independently represent a substituted or unsubstituted (C6-C30)aryl, or a substituted or unsubstituted (3- to 30-membered)heteroaryl, adjacent Ar₁-Ar₇ may be linked to each other via a single bond to form a ring(s);
L₁-L₄ represent a single bond, a substituted or unsubstituted (C6-C30)arylene, or a substituted or unsubstituted (3- to 30-membered)heteroarylene;
R¹ and R² each independently represent hydrogen, deuterium, a halogen, a cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted mono- or di-(C1-C30)alkylamino, a substituted or unsubstituted mono- or di-(C6-C30)arylamino, or a substituted or unsubstituted (C1-C30)alkyl(C6-C30)arylamino, where if a plurality of R¹ and/or R² is present, each may be the same or different at each occurrence, and where adjacent R¹ and/or R² groups or R¹ and/or R² groups on adjacent rings can be joined together to form a 5- or 6-membered cycloaliphatic ring, carbocyclic aromatic ring, heteroaromatic ring, or a substituted derivative thereof;
a and b each independently represent an integer between 0 and 4, with the proviso that the maximum value for a or b is 3 when the bond to L₁ attaches to the ring bearing R¹ or R², respectively; and
n represents 1 or 2.

In some non-limiting embodiments of Formula 1, the compound or compounds have molecular weights, T_{g}'s, and dipole moments as disclosed above herein.

In some non-limiting embodiments of Formula 1, X═—O—.

In some non-limiting embodiments of Formula 1, X═—S—.

In some non-limiting embodiments of Formula 1, X═—Si(R′)(R″)—.

In some non-limiting embodiments of Formula 1, X═—N(R)—.

In some non-limiting embodiments of Formula 1, X═C(R′)(R″)—.

In some non-limiting embodiments of Formula 1, X═—Se—.

In some non-limiting embodiments of Formula 1, R, R′, and R″ each independently represent a substituted or unsubstituted (C1-C30)alkyl, a substituted or unsubstituted (C6-C30)aryl, or a substituted or unsubstituted (3- to 30-membered)heteroaryl, -L₂-N—(Ar₃)(Ar₄) or -L₃-N(Ar₅)-L₄-N—(Ar₆)(Ar₇) wherein L₂, L₃, and L₄ are linking groups with embodiments the same as those disclosed for L₁ herein; or R′ and R″ may be linked to each other to form a ring(s), and R′ and R″ may be the same or different.

In some embodiments of Formula 1, the compound is deuterated. In some non-limiting embodiments, the compound is at least 10% deuterated; in some non-limiting embodiments, at least 20% deuterated; in some non-limiting embodiments, at least 30% deuterated; in some non-limiting embodiments, at least 40% deuterated; in some non-limiting embodiments, at least 50% deuterated; in some non-limiting embodiments, at least 60% deuterated; in some non-limiting embodiments, at least 70% deuterated; in some non-limiting embodiments, at least 80% deuterated; in some non-limiting embodiments, at least 90% deuterated; in some non-limiting embodiments, 100% deuterated.

In some non-limiting embodiments of Formula 1, deuteration is present on one or more of Ar₁, Ar₂, R¹, and R².

In some non-limiting embodiments of Formula 1, Ar is selected from the group consisting of hydrocarbon aryl groups, heteroaryl groups, and substituted derivatives thereof, wherein substituted derivatives have only substituents selected from the group consisting of D, alkyl, silyl, germyl, deuterated alkyl, deuterated silyl, and deuterated germyl, and no other substituents.

In some non-limiting embodiments of Formula 1, Ar is an unsubstituted hydrocarbon aryl.

In some non-limiting embodiments of Formula 1, Ar is a hydrocarbon aryl or deuterated analog thereof having 6-30 ring carbons; in some embodiments 6-18 ring carbons.

In some non-limiting embodiments of Formula 1, Ar is a substituted hydrocarbon aryl, where the substituent is selected from the group consisting of D, alkyl, silyl, germyl, hydrocarbon aryl, heteroaryl, deuterated alkyl, deuterated silyl, deuterated germyl, deuterated hydrocarbon aryl, and deuterated heteroaryl. In some embodiments, the heteroaryl has heteroatoms selected from the group consisting of O, S, and Se.

In some non-limiting embodiments of Formula 1, Ar is selected from the group consisting of phenyl, biphenyl, terphenyl, 1-naphthyl, 2-naphthyl, anthracenyl, fluorenyl, phenanthryl, deuterated analogs thereof, and derivatives thereof having one or more substituents selected from the group consisting of D, alkyl, silyl, germyl, hydrocarbon aryl, heteroaryl, deuterated alkyl, deuterated silyl, deuterated germyl, deuterated hydrocarbon aryl, and deuterated heteroaryl. In some non-limiting embodiments, the heteroaryl has heteroatoms selected from the group consisting of O, S, and Se.

In some non-limiting embodiments of Formula 1, Ar₁ is selected from the group consisting of phenyl, biphenyl, terphenyl, 1-naphthyl, 2-naphthyl, anthracenyl, fluorenyl, phenanthryl, and derivatives thereof having one or more substituents selected from the group consisting of D, alkyl, silyl, germyl, deuterated alkyl, deuterated silyl, and deuterated germyl.

In some non-limiting embodiments of Formula 1, Ar is selected from the group consisting of phenyl, biphenyl, naphthyl and substituted derivatives thereof.

In some non-limiting embodiments of Formula 1, Ar is an unsubstituted heteroaryl.

In some non-limiting embodiments of Formula 1, Ar is a heteroaryl or deuterated analog thereof having 3-30 ring carbons; in some non-limiting embodiments 3-18 ring carbons.

In some non-limiting embodiments of Formula 1, Ar is a substituted heteroaryl, where the substituent is selected from the group consisting of D, alkyl, silyl, germyl, deuterated alkyl, deuterated silyl, and deuterated germyl.

In some non-limiting embodiments of Formula 1, Ar is selected from the group consisting of heteroaryl and deuterated heteroaryl, where the heteroaryl has at least one ring atom which is selected from the group consisting of O and S.

In some non-limiting embodiments of Formula 1, Ar is an O-heteroaryl having at least one ring atom that is O.

In some non-limiting embodiments, the O-heteroaryl is derived from a compound selected from the group consisting of furan, benzofuran, isobenzofuran, dibenzofuran, and substituted derivatives thereof.

In some non-limiting embodiments of Formula 1, Ar is present and is an S-heteroaryl having at least one ring atom which is S.

In some non-limiting embodiments, the S-heteroaryl is derived from a compound selected form the group consisting of thiophene, benzothiophene, isobenzothiophene, dibenzothiophene, and substituted derivatives thereof.

All the embodiments for Ar disclosed herein apply equally to Ar₂.

In some non-limiting embodiments of Formula 1, Ar₁═Ar₂.

In some non-limiting embodiments of Formula 1, Ar₁≠Ar₂.

In some non-limiting embodiments of Formula 1, L₁ is a single bond.

In some non-limiting embodiments of Formula 1, L₁ is a substituted or unsubstituted (C6-C30)arylene given by Formula a:

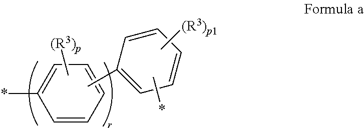

wherein R³ is the same or different at each occurrence and is selected from the group consisting of D, alkyl, aryloxy, heteroaryl, alkoxy, siloxy, silyl, germyl, deuterated alkyl, deuterated aryloxy, deuterated heteroaryl, deuterated alkoxy, deuterated siloxane, deuterated silyl, deuterated germyl, and wherein adjacent R³ groups can be joined together to form a fused ring. In some non-limiting embodiments, p is the same or different at each occurrence and is an integer from 0-4. In some non-limiting embodiments, μ1 is the same or different at each occurrence and is an integer from 0-4. In some non-limiting embodiments, r is an integer from 0-5.

In some non-limiting embodiments of Formula 1, L₁ is a substituted or unsubstituted (3- to 30-membered) heteroarylene group that is derived from the corresponding heteroaryl groups selected from pyrrole, pyridine, pyrimidine, carbazole, imidazole, benzimidazole, imidazolobenzimidazole, triazole, benzotriazole, triazolopyridine, indolocarbazole, phenanthroline, quinoline, isoquinoline, quinoxaline, indole, indoloindole, substituted derivatives thereof, and deuterated analogs thereof.

In some non-limiting embodiments of Formula 1, R¹ and R² each independently represent hydrogen, deuterium, a halogen, a cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted mono- or di-(C1-C30)alkylamino, a substituted or unsubstituted mono- or di-(C6-C30)arylamino, or a substituted or unsubstituted (C1-C30)alkyl(C6-C30)arylamino, where if a plurality of R¹ and/or R² is present, each may be the same or different at each occurrence.

In some non-limiting embodiments of Formula 1, a=0. In some non-limiting embodiments, a=1. In some non-limiting embodiments, a=2. In some non-limiting embodiments, a=3. In some non-limiting embodiments, a=4.

In some non-limiting embodiments of Formula 1, b=0. In some non-limiting embodiments, b=1. In some non-limiting embodiments, b=2. In some non-limiting embodiments, b=3. In some non-limiting embodiments, a=b.

In some non-limiting embodiments of Formula 1, n=1. In some non-limiting embodiments, n=2. In embodiments with n=1, the bridging group comprising Y is a 5-membered ring. In embodiments with n=2, the bridging group comprising the Y's is a 6-membered ring. In some non-limiting embodiments with n=2, both Y's are given by C(R′)(R″)— wherein R′ and R″ are as defined herein. In some non-limiting embodiments with n=2, one Y is given by C(R′)(R″)— wherein R′ and R″ are as defined herein and the other Y is selected from the group consisting of —O—, —S—, —Si—, —N(R)—, and —Se— wherein R is as defined herein.

In some non-limiting embodiments of Formula 1, X is Si(CH₃)₂, R¹ and R² are H, L₁ is phenylene, Ar is phenyl, Ar₂ is terphenyl, a and b are 4, and n is 1.

In some non-limiting embodiments of Formula 1, X is —C(R′)(R″)—, R′ and R″ are methyl, R¹ and R² are H, L₁ is phenylene, Ar is phenyl, Ar₂ is 1-phenyltriphenyl, a and b are 4, and n is 2. In some non-limiting embodiments of Formula 1, X is —C(R′)(R″)—, R′ and R″ are methyl, R¹ and R² are H, L₁ is phenylene, Ar is phenyl, Ar₂ is 2-phenyltriphenyl, a and b are 4, and n is 2. Regarding the selection of a specific compound having Formula 1 for use in a particular OLED device, there are a number of considerations of potential importance. Significant dipole moment of individual molecules is a necessary, but not sufficient, condition. Molecular shape, specific short-range interactions, and processing conditions used also seem to be important factors affecting SOP; but it is currently not possible to predict even the direction of polarization by simulating only a single molecule. The basic design principle for a polarized aryl amine compound like those having Formula 1 as disclosed herein is therefore to include at least one electron deficient or sufficient functional groups like heteroatom or alkyl containing condensed polycyclic organic matter in the molecular structure. In order to choose molecular structures that have higher likelihood to show strong SOP in the preferred direction, one having skill in the art can use molecular dynamics simulations of vacuum deposition process.

Examples of compounds having Formula 1 include, but are not limited to, the compounds shown below.

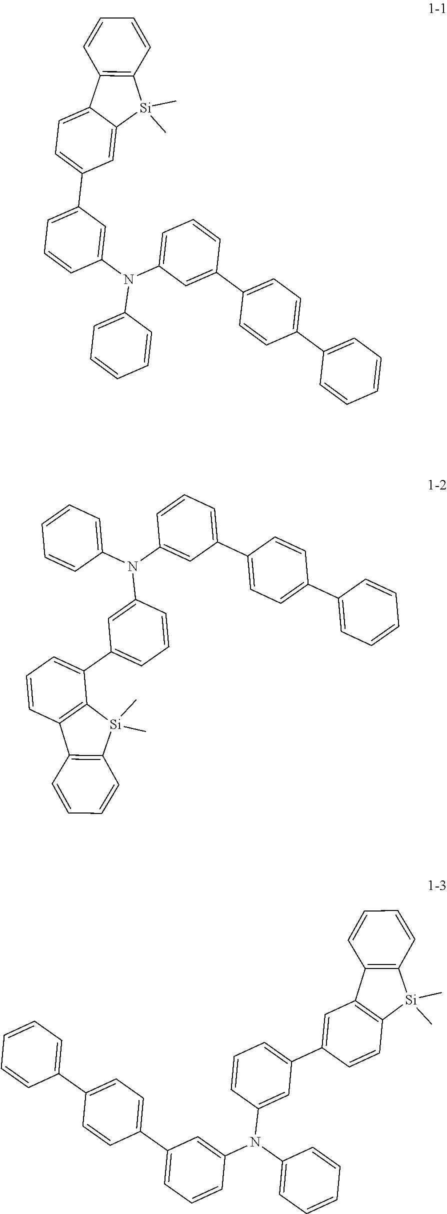 [SMILES: C[Si]1(C)c2ccccc2-c2ccc(-c3cccc(N(c4ccccc4)c4cccc(-c5ccc(-c6ccccc6)cc5)c4)c3)cc21 ; C[Si]1(C)c2ccccc2-c2cccc(-c3cccc(N(c4ccccc4)c4cccc(-c5ccc(-c6ccccc6)cc5)c4)c3)c21 ; C[Si]1(C)c2ccccc2-c2cc(-c3cccc(N(c4ccccc4)c4cccc(-c5ccc(-c6ccccc6)cc5)c4)c3)ccc21]

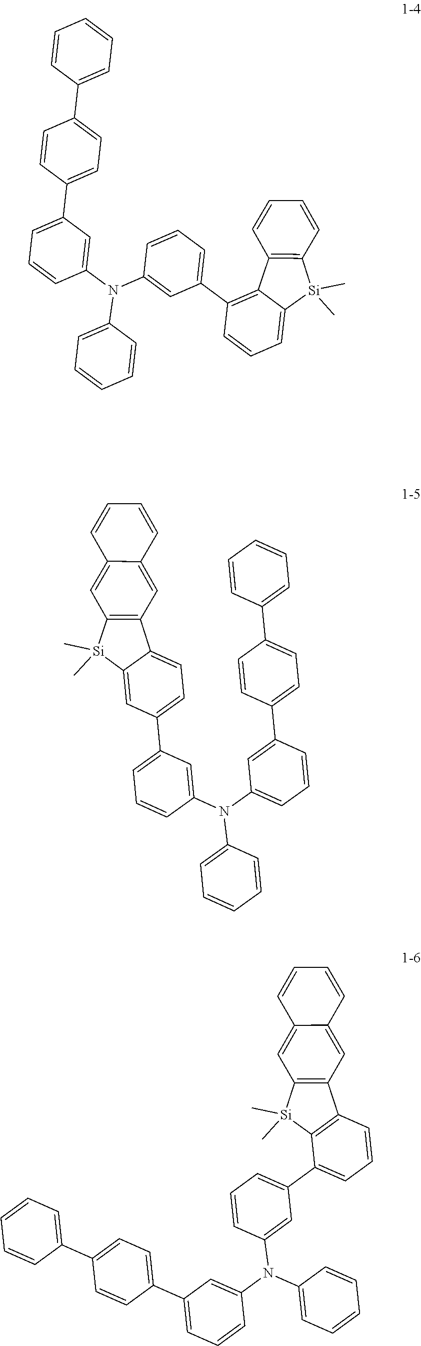

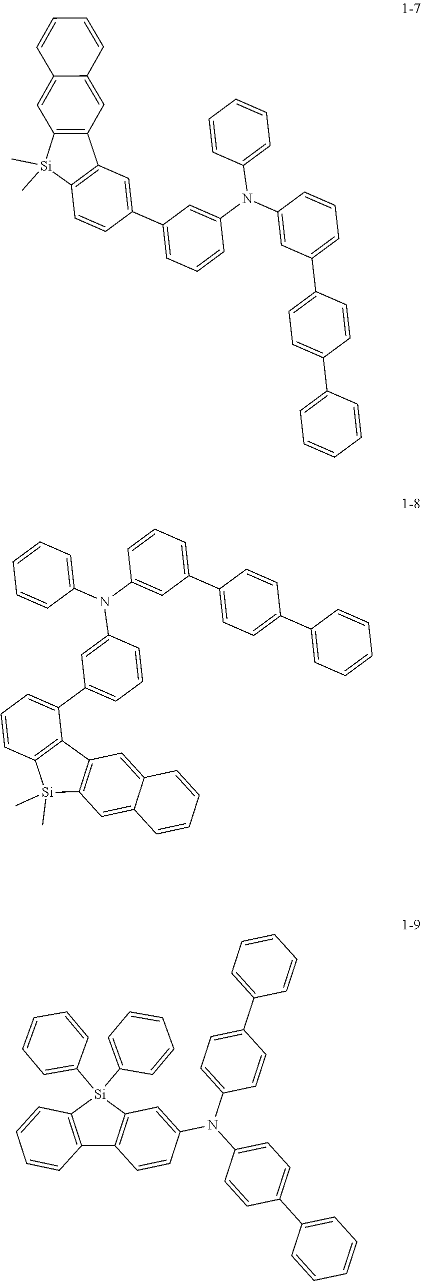 [SMILES: C[Si]1(C)c2ccc(-c3cccc(N(c4ccccc4)c4cccc(-c5ccc(-c6ccccc6)cc5)c4)c3)cc2-c2cc3ccccc3cc21 ; C[Si]1(C)c2cc3ccccc3cc2-c2c(-c3cccc(N(c4ccccc4)c4cccc(-c5ccc(-c6ccccc6)cc5)c4)c3)cccc21 ; c1ccc(-c2ccc(N(c3ccc(-c4ccccc4)cc3)c3ccc4c(c3)[Si](c3ccccc3)(c3ccccc3)c3ccccc3-4)cc2)cc1]

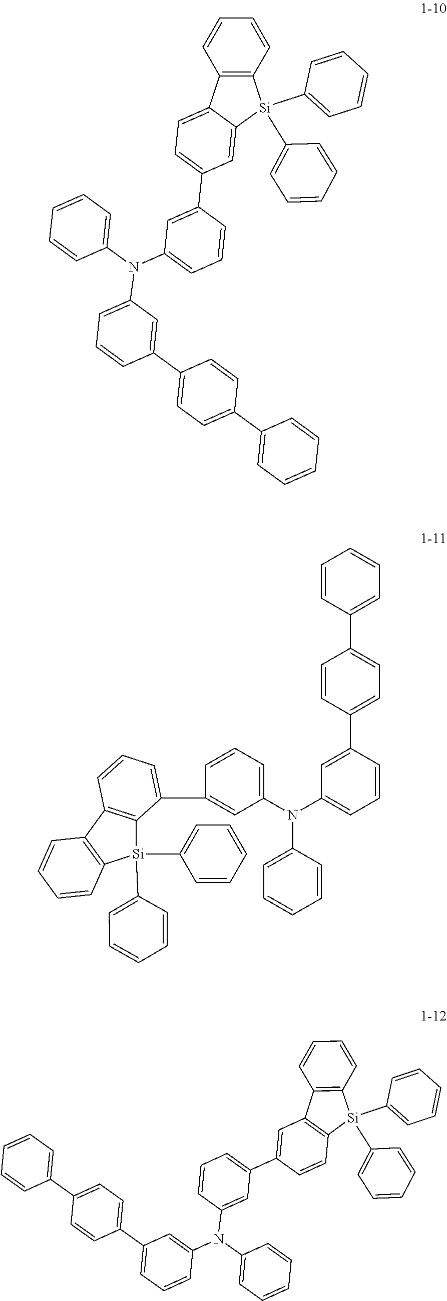 [SMILES: c1ccc(-c2ccc(-c3cccc(N(c4ccccc4)c4cccc(-c5ccc6c(c5)[Si](c5ccccc5)(c5ccccc5)c5ccccc5-6)c4)c3)cc2)cc1 ; c1ccc(-c2ccc(-c3cccc(N(c4ccccc4)c4cccc(-c5cccc6c5[Si](c5ccccc5)(c5ccccc5)c5ccccc5-6)c4)c3)cc2)cc1 ; c1ccc(-c2ccc(-c3cccc(N(c4ccccc4)c4cccc(-c5ccc6c(c5)-c5ccccc5[Si]6(c5ccccc5)c5ccccc5)c4)c3)cc2)cc1]

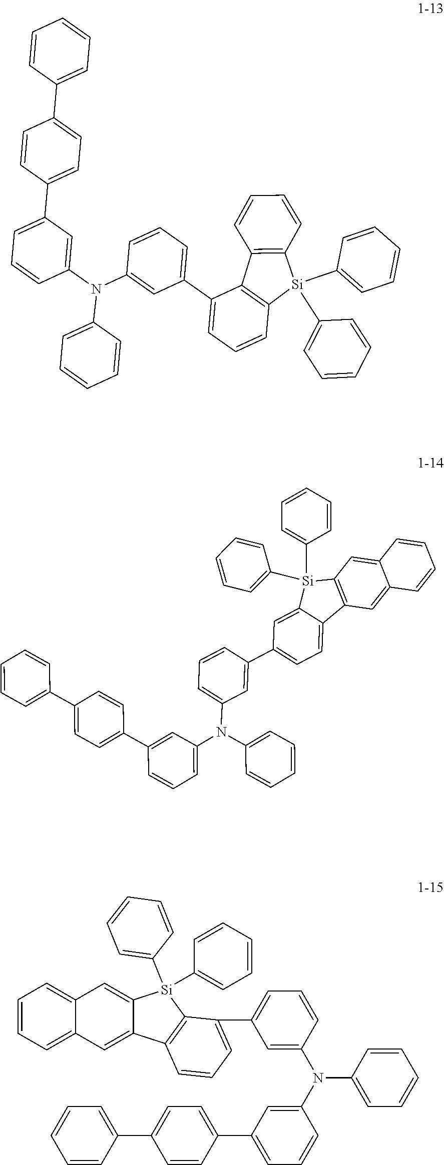 [SMILES: c1ccc(-c2ccc(-c3cccc(N(c4ccccc4)c4cccc(-c5cccc6c5-c5ccccc5[Si]6(c5ccccc5)c5ccccc5)c4)c3)cc2)cc1 ; c1ccc(-c2ccc(-c3cccc(N(c4ccccc4)c4cccc(-c5ccc6c(c5)[Si](c5ccccc5)(c5ccccc5)c5cc7ccccc7cc5-6)c4)c3)cc2)cc1 ; c1ccc(-c2ccc(-c3cccc(N(c4ccccc4)c4cccc(-c5cccc6c5[Si](c5ccccc5)(c5ccccc5)c5cc7ccccc7cc5-6)c4)c3)cc2)cc1]

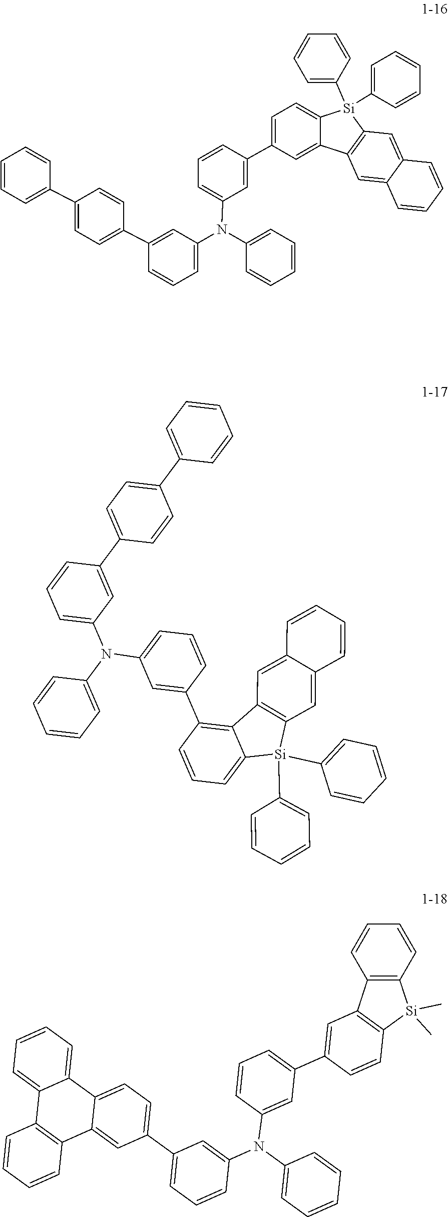 [SMILES: c1ccc(-c2ccc(-c3cccc(N(c4ccccc4)c4cccc(-c5ccc6c(c5)-c5cc7ccccc7cc5[Si]6(c5ccccc5)c5ccccc5)c4)c3)cc2)cc1 ; c1ccc(-c2ccc(-c3cccc(N(c4ccccc4)c4cccc(-c5cccc6c5-c5cc7ccccc7cc5[Si]6(c5ccccc5)c5ccccc5)c4)c3)cc2)cc1 ; C[Si]1(C)c2ccccc2-c2cc(-c3cccc(N(c4ccccc4)c4cccc(-c5ccc6c7ccccc7c7ccccc7c6c5)c4)c3)ccc21]

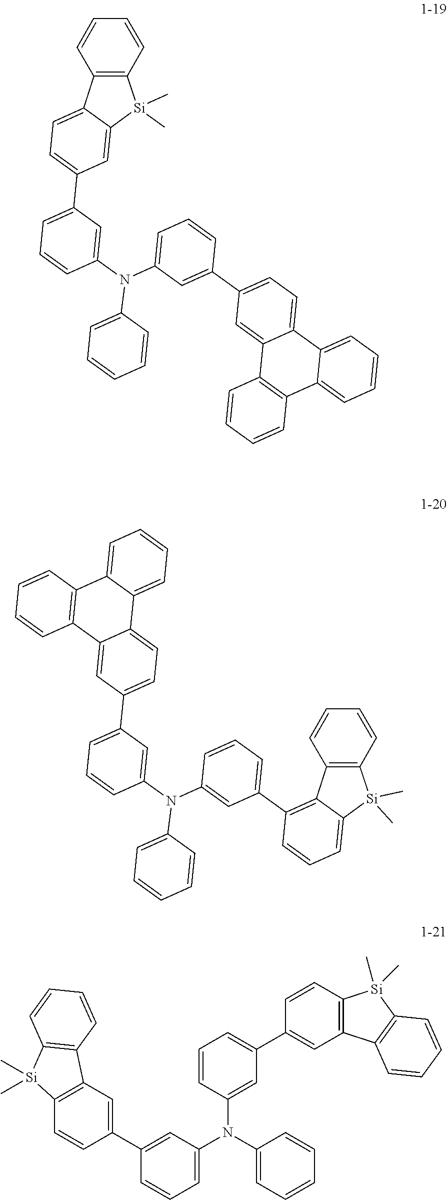

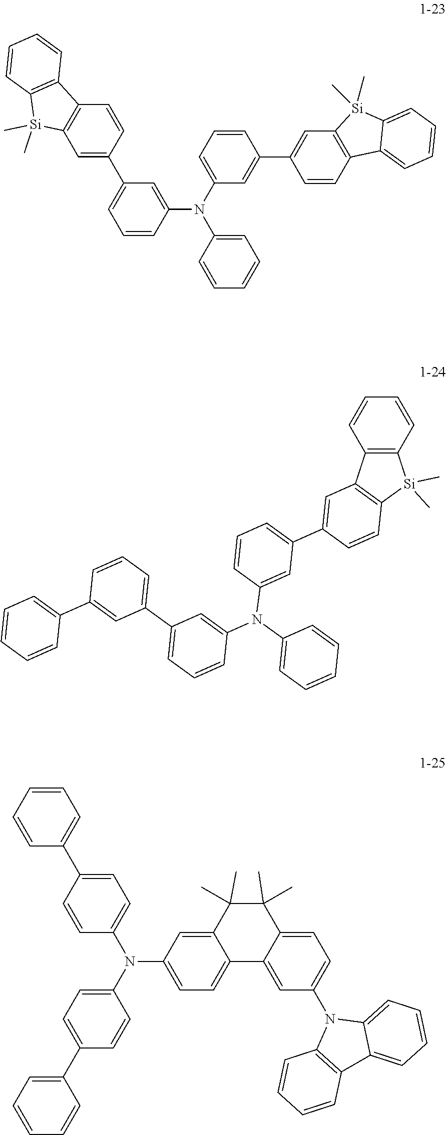 [SMILES: C[Si]1(C)c2ccccc2-c2ccc(-c3cccc(N(c4ccccc4)c4cccc(-c5ccc6c(c5)[Si](C)(C)c5ccccc5-6)c4)c3)cc21 ; C[Si]1(C)c2ccccc2-c2cc(-c3cccc(N(c4ccccc4)c4cccc(-c5cccc(-c6ccccc6)c5)c4)c3)ccc21 ; CC1(C)c2ccc(-n3c4ccccc4c4ccccc43)cc2-c2ccc(N(c3ccc(-c4ccccc4)cc3)c3ccc(-c4ccccc4)cc3)cc2C1(C)C]

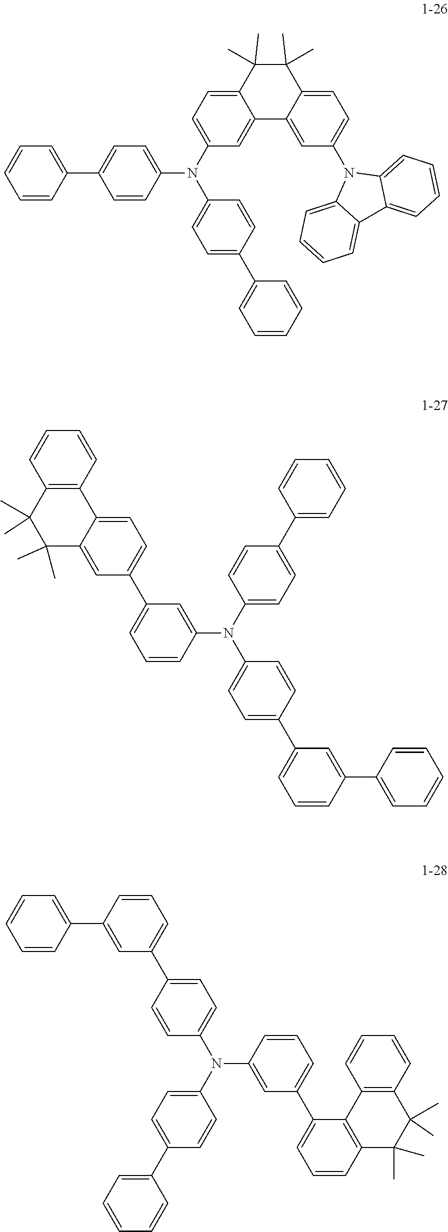 [SMILES: CC1(C)c2ccc(N(c3ccc(-c4ccccc4)cc3)c3ccc(-c4ccccc4)cc3)cc2-c2cc(-n3c4ccccc4c4ccccc43)ccc2C1(C)C ; CC1(C)c2ccccc2-c2ccc(-c3cccc(N(c4ccc(-c5ccccc5)cc4)c4ccc(-c5cccc(-c6ccccc6)c5)cc4)c3)cc2C1(C)C ; CC1(C)c2ccccc2-c2c(-c3cccc(N(c4ccc(-c5ccccc5)cc4)c4ccc(-c5cccc(-c6ccccc6)c5)cc4)c3)cccc2C1(C)C]

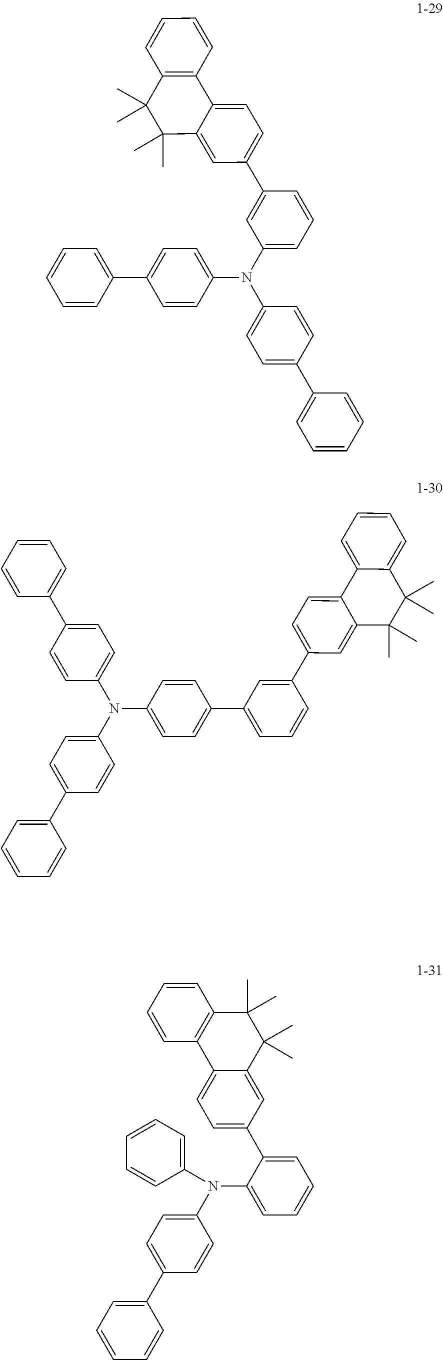 [SMILES: CC1(C)c2ccccc2-c2ccc(-c3cccc(N(c4ccc(-c5ccccc5)cc4)c4ccc(-c5ccccc5)cc4)c3)cc2C1(C)C ; CC1(C)c2ccccc2-c2ccc(-c3cccc(-c4ccc(N(c5ccc(-c6ccccc6)cc5)c5ccc(-c6ccccc6)cc5)cc4)c3)cc2C1(C)C ; CC1(C)c2ccccc2-c2ccc(-c3ccccc3N(c3ccccc3)c3ccc(-c4ccccc4)cc3)cc2C1(C)C]

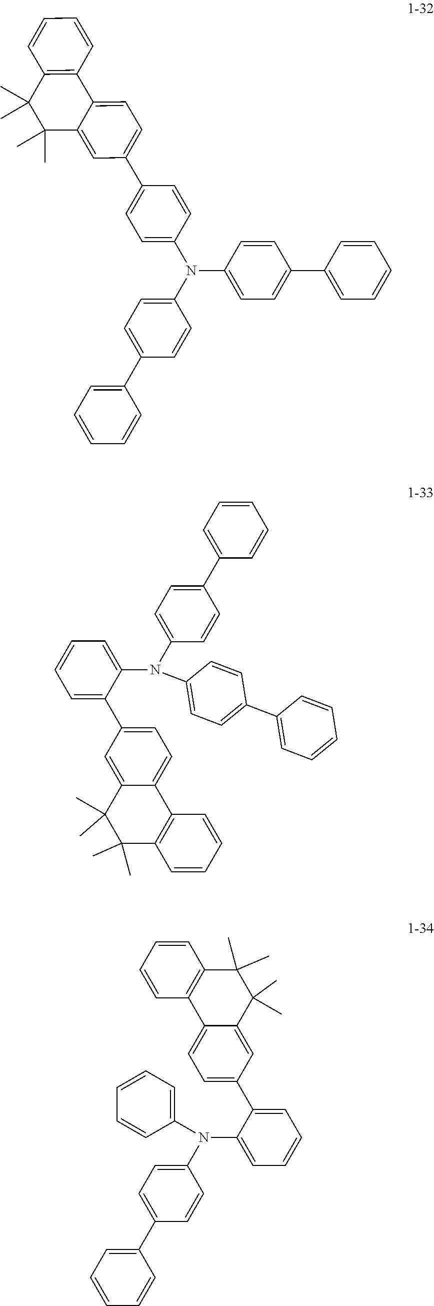 [SMILES: CC1(C)c2ccccc2-c2ccc(-c3ccc(N(c4ccc(-c5ccccc5)cc4)c4ccc(-c5ccccc5)cc4)cc3)cc2C1(C)C ; CC1(C)c2ccccc2-c2ccc(-c3ccccc3N(c3ccc(-c4ccccc4)cc3)c3ccc(-c4ccccc4)cc3)cc2C1(C)C ; CC1(C)c2ccccc2-c2ccc(-c3ccccc3N(c3ccccc3)c3ccc(-c4ccccc4)cc3)cc2C1(C)C]

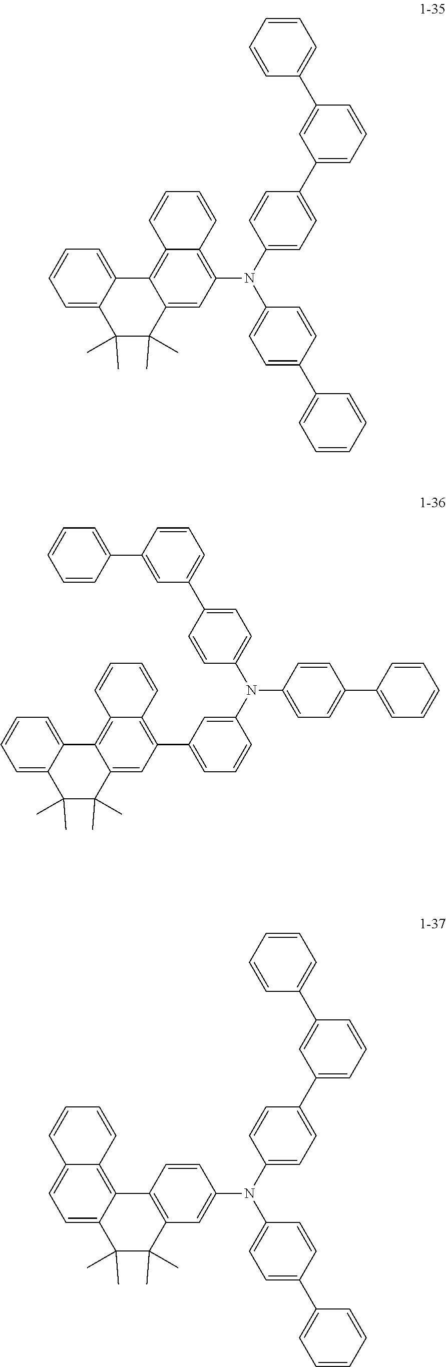 [SMILES: CC1(C)c2ccccc2-c2c(cc(N(c3ccc(-c4ccccc4)cc3)c3ccc(-c4cccc(-c5ccccc5)c4)cc3)c3ccccc23)C1(C)C ; CC1(C)c2ccccc2-c2c(cc(-c3cccc(N(c4ccc(-c5ccccc5)cc4)c4ccc(-c5cccc(-c6ccccc6)c5)cc4)c3)c3ccccc23)C1(C)C ; CC1(C)c2cc(N(c3ccc(-c4ccccc4)cc3)c3ccc(-c4cccc(-c5ccccc5)c4)cc3)ccc2-c2c(ccc3ccccc23)C1(C)C]

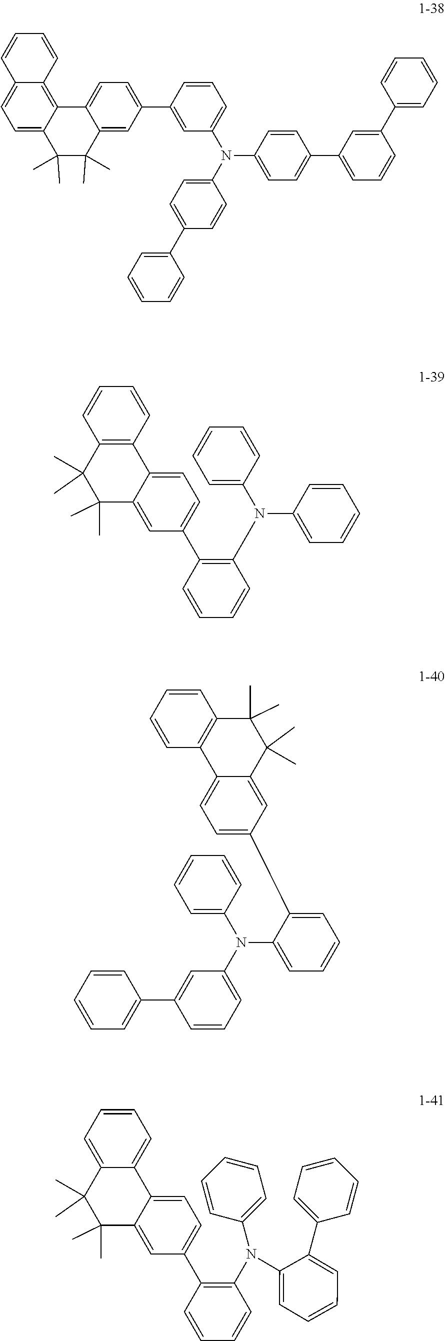 [SMILES: CC1(C)c2cc(-c3cccc(N(c4ccc(-c5ccccc5)cc4)c4ccc(-c5cccc(-c6ccccc6)c5)cc4)c3)ccc2-c2c(ccc3ccccc23)C1(C)C ; CC1(C)c2ccccc2-c2ccc(-c3ccccc3N(c3ccccc3)c3ccccc3)cc2C1(C)C ; CC1(C)c2ccccc2-c2ccc(-c3ccccc3N(c3ccccc3)c3cccc(-c4ccccc4)c3)cc2C1(C)C ; CC1(C)c2ccccc2-c2ccc(-c3ccccc3N(c3ccccc3)c3ccccc3-c3ccccc3)cc2C1(C)C]

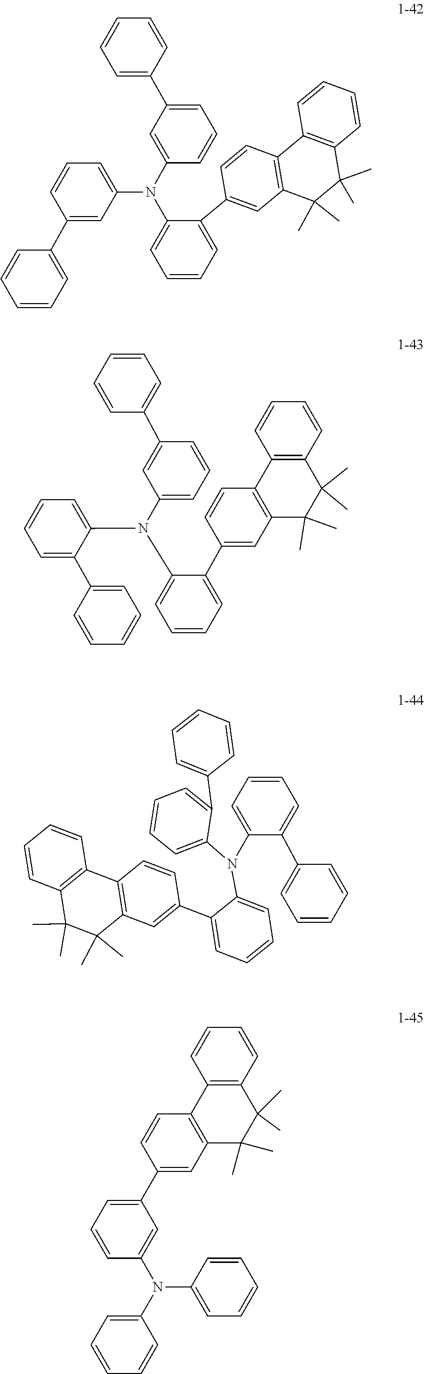 [SMILES: CC1(C)c2ccccc2-c2ccc(-c3ccccc3N(c3cccc(-c4ccccc4)c3)c3cccc(-c4ccccc4)c3)cc2C1(C)C ; CC1(C)c2ccccc2-c2ccc(-c3ccccc3N(c3cccc(-c4ccccc4)c3)c3ccccc3-c3ccccc3)cc2C1(C)C ; CC1(C)c2ccccc2-c2ccc(-c3ccccc3N(c3ccccc3-c3ccccc3)c3ccccc3-c3ccccc3)cc2C1(C)C ; CC1(C)c2ccccc2-c2ccc(-c3cccc(N(c4ccccc4)c4ccccc4)c3)cc2C1(C)C]

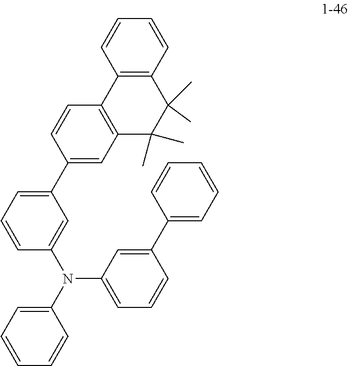 [SMILES: CC1(C)c2ccccc2-c2ccc(-c3cccc(N(c4ccccc4)c4cccc(-c5ccccc5)c4)c3)cc2C1(C)C]

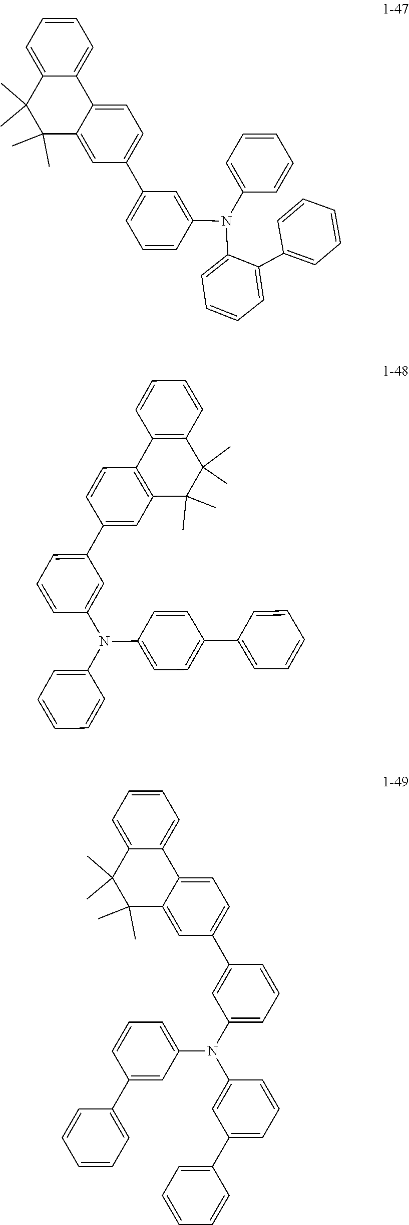 [SMILES: CC1(C)c2ccccc2-c2ccc(-c3cccc(N(c4ccccc4)c4ccccc4-c4ccccc4)c3)cc2C1(C)C ; CC1(C)c2ccccc2-c2ccc(-c3cccc(N(c4ccccc4)c4ccc(-c5ccccc5)cc4)c3)cc2C1(C)C ; CC1(C)c2ccccc2-c2ccc(-c3cccc(N(c4cccc(-c5ccccc5)c4)c4cccc(-c5ccccc5)c4)c3)cc2C1(C)C]

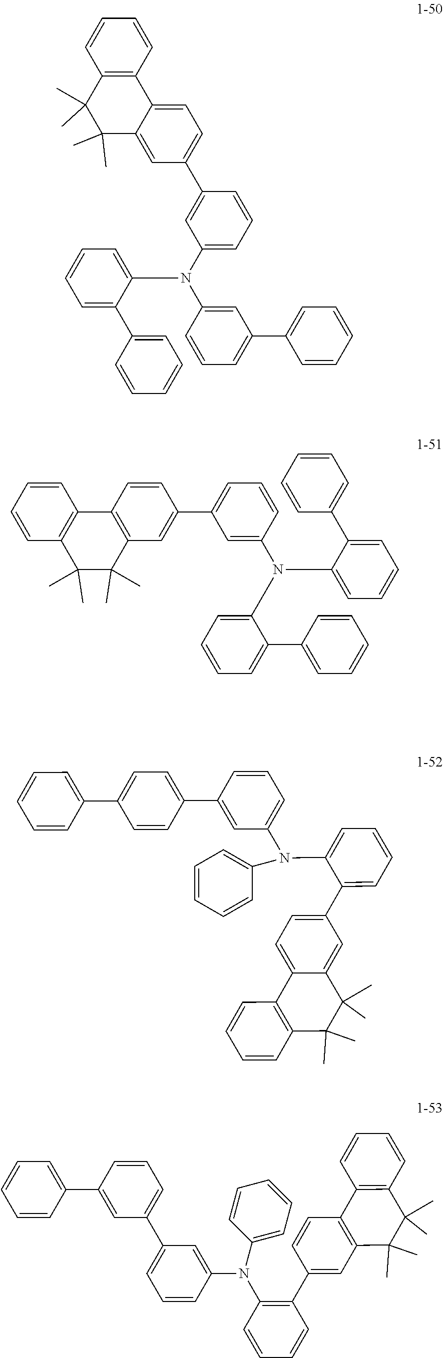 [SMILES: CC1(C)c2ccccc2-c2ccc(-c3cccc(N(c4cccc(-c5ccccc5)c4)c4ccccc4-c4ccccc4)c3)cc2C1(C)C ; CC1(C)c2ccccc2-c2ccc(-c3cccc(N(c4ccccc4-c4ccccc4)c4ccccc4-c4ccccc4)c3)cc2C1(C)C ; CC1(C)c2ccccc2-c2ccc(-c3ccccc3N(c3ccccc3)c3cccc(-c4ccc(-c5ccccc5)cc4)c3)cc2C1(C)C ; CC1(C)c2ccccc2-c2ccc(-c3ccccc3N(c3ccccc3)c3cccc(-c4cccc(-c5ccccc5)c4)c3)cc2C1(C)C]

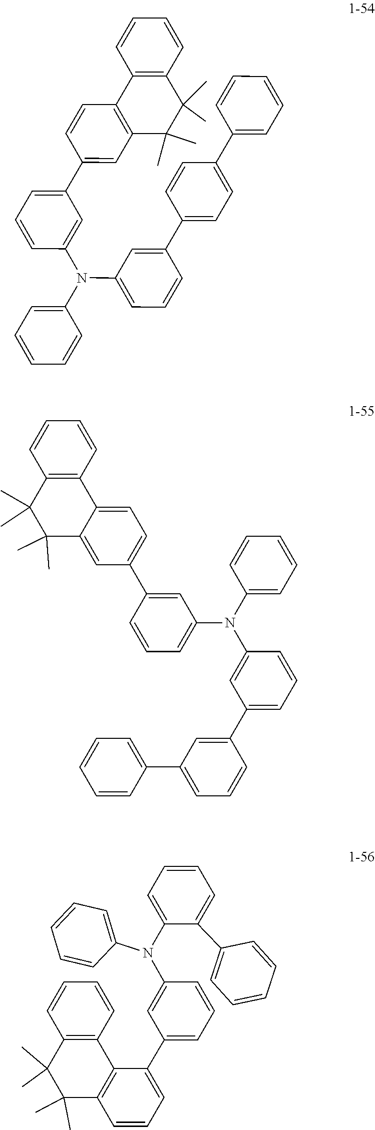 [SMILES: CC1(C)c2ccccc2-c2ccc(-c3cccc(N(c4ccccc4)c4cccc(-c5ccc(-c6ccccc6)cc5)c4)c3)cc2C1(C)C ; CC1(C)c2ccccc2-c2ccc(-c3cccc(N(c4ccccc4)c4cccc(-c5cccc(-c6ccccc6)c5)c4)c3)cc2C1(C)C ; CC1(C)c2ccccc2-c2c(-c3cccc(N(c4ccccc4)c4ccccc4-c4ccccc4)c3)cccc2C1(C)C]

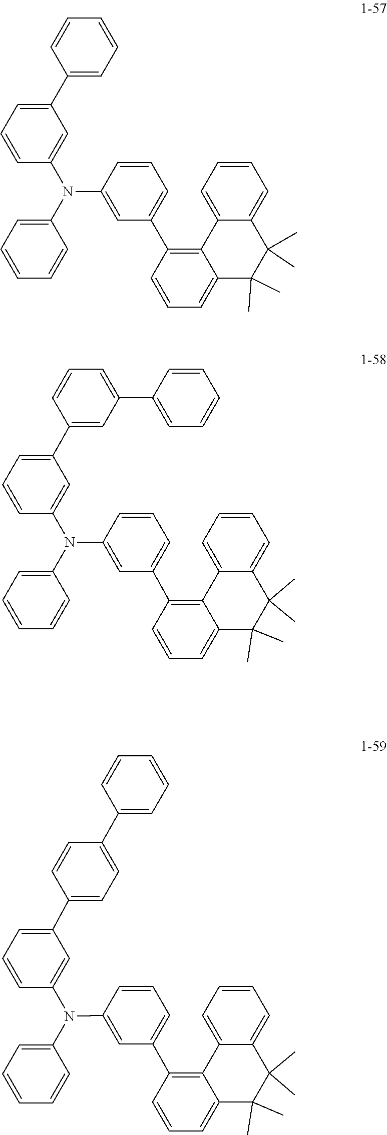 [SMILES: CC1(C)c2ccccc2-c2c(-c3cccc(N(c4ccccc4)c4cccc(-c5ccccc5)c4)c3)cccc2C1(C)C ; CC1(C)c2ccccc2-c2c(-c3cccc(N(c4ccccc4)c4cccc(-c5cccc(-c6ccccc6)c5)c4)c3)cccc2C1(C)C ; CC1(C)c2ccccc2-c2c(-c3cccc(N(c4ccccc4)c4cccc(-c5ccc(-c6ccccc6)cc5)c4)c3)cccc2C1(C)C]

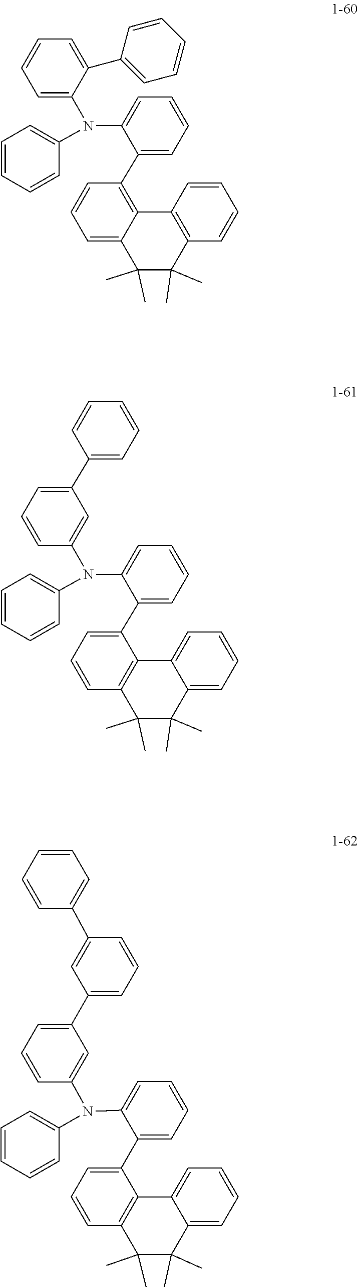 [SMILES: CC1(C)c2ccccc2-c2c(-c3ccccc3N(c3ccccc3)c3ccccc3-c3ccccc3)cccc2C1(C)C ; CC1(C)c2ccccc2-c2c(-c3ccccc3N(c3ccccc3)c3cccc(-c4ccccc4)c3)cccc2C1(C)C ; CC1(C)c2ccccc2-c2c(-c3ccccc3N(c3ccccc3)c3cccc(-c4cccc(-c5ccccc5)c4)c3)cccc2C1(C)C]

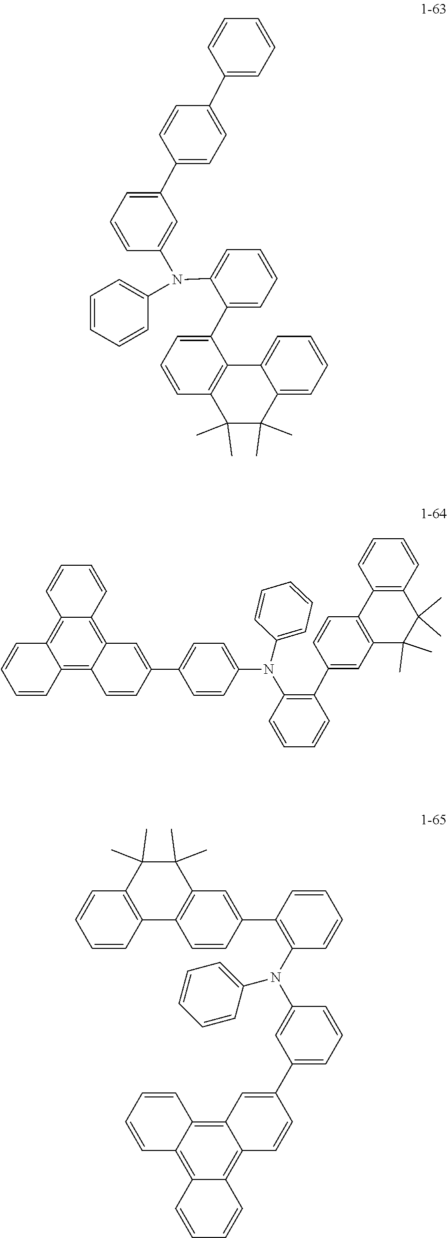 [SMILES: CC1(C)c2ccccc2-c2c(-c3ccccc3N(c3ccccc3)c3cccc(-c4ccc(-c5ccccc5)cc4)c3)cccc2C1(C)C ; CC1(C)c2ccccc2-c2ccc(-c3ccccc3N(c3ccccc3)c3ccc(-c4ccc5c6ccccc6c6ccccc6c5c4)cc3)cc2C1(C)C ; CC1(C)c2ccccc2-c2ccc(-c3ccccc3N(c3ccccc3)c3cccc(-c4ccc5c6ccccc6c6ccccc6c5c4)c3)cc2C1(C)C]

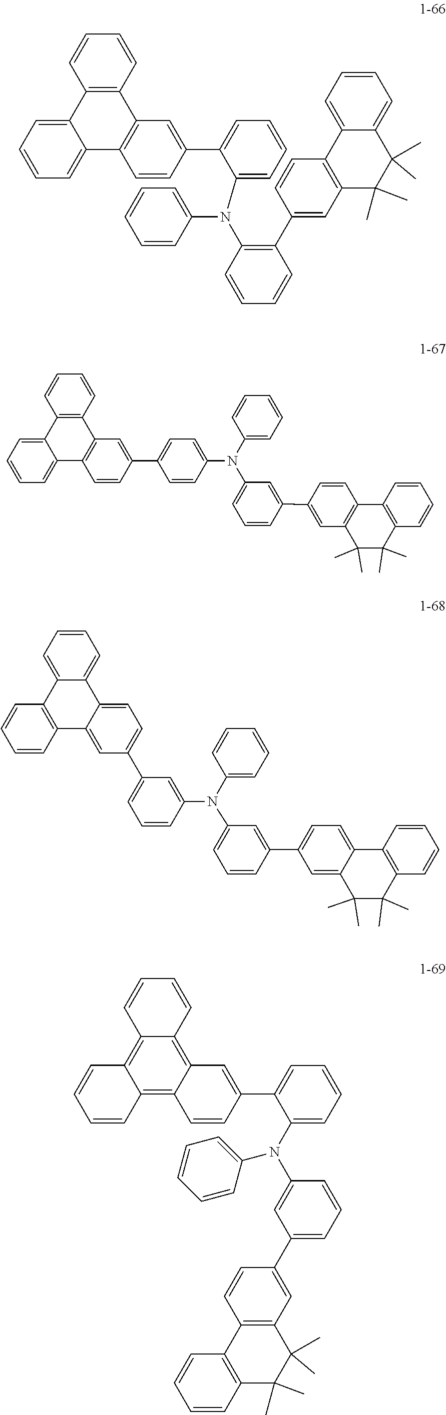 [SMILES: CC1(C)c2ccccc2-c2ccc(-c3ccccc3N(c3ccccc3)c3ccccc3-c3ccc4c5ccccc5c5ccccc5c4c3)cc2C1(C)C ; CC1(C)c2ccccc2-c2ccc(-c3cccc(N(c4ccccc4)c4ccc(-c5ccc6c7ccccc7c7ccccc7c6c5)cc4)c3)cc2C1(C)C ; CC1(C)c2ccccc2-c2ccc(-c3cccc(N(c4ccccc4)c4cccc(-c5ccc6c7ccccc7c7ccccc7c6c5)c4)c3)cc2C1(C)C ; CC1(C)c2ccccc2-c2ccc(-c3cccc(N(c4ccccc4)c4ccccc4-c4ccc5c6ccccc6c6ccccc6c5c4)c3)cc2C1(C)C]

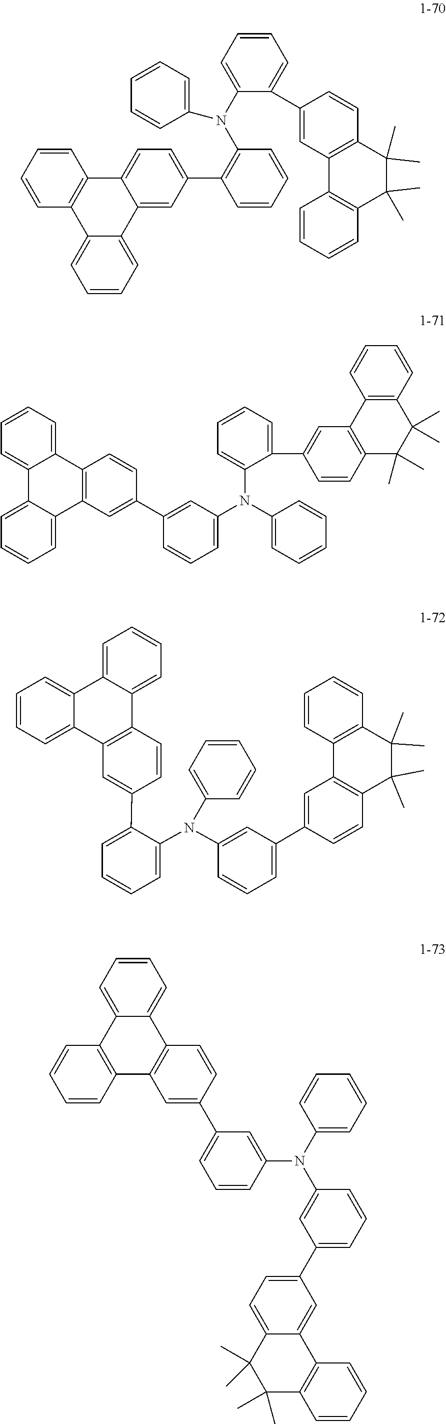 [SMILES: CC1(C)c2ccccc2-c2cc(-c3ccccc3N(c3ccccc3)c3ccccc3-c3ccc4c5ccccc5c5ccccc5c4c3)ccc2C1(C)C ; CC1(C)c2ccccc2-c2cc(-c3ccccc3N(c3ccccc3)c3cccc(-c4ccc5c6ccccc6c6ccccc6c5c4)c3)ccc2C1(C)C ; CC1(C)c2ccccc2-c2cc(-c3cccc(N(c4ccccc4)c4ccccc4-c4ccc5c6ccccc6c6ccccc6c5c4)c3)ccc2C1(C)C ; CC1(C)c2ccccc2-c2cc(-c3cccc(N(c4ccccc4)c4cccc(-c5ccc6c7ccccc7c7ccccc7c6c5)c4)c3)ccc2C1(C)C]

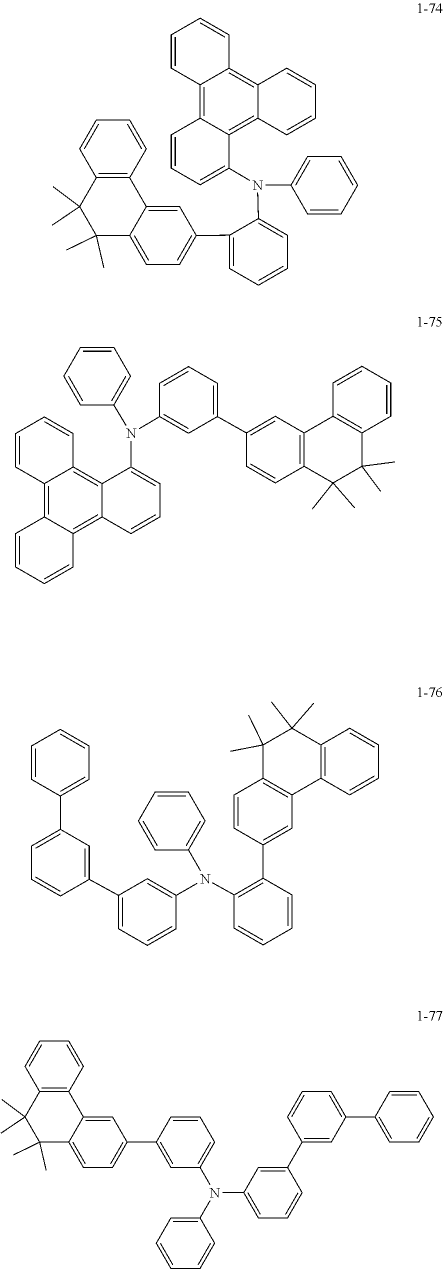

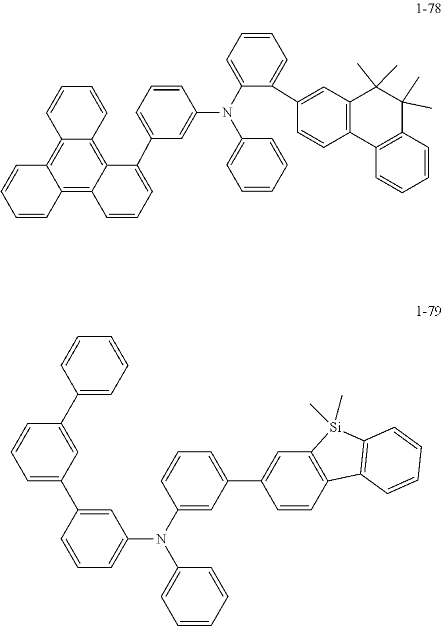 [SMILES: CC1(C)c2ccccc2-c2ccc(-c3ccccc3N(c3ccccc3)c3cccc(-c4cccc5c6ccccc6c6ccccc6c45)c3)cc2C1(C)C ; C[Si]1(C)c2ccccc2-c2ccc(-c3cccc(N(c4ccccc4)c4cccc(-c5cccc(-c6ccccc6)c5)c4)c3)cc21]

In some non-limiting embodiments of the composition comprising a mixture of a first compound and a second compound disclosed herein, the first compound and/or the second compound have a chemical structure given by Formula 2:

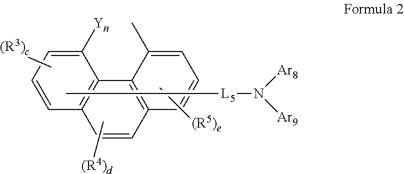

wherein
Y is the same or different at each occurrence and represents —O—, —S—, —Si(R′)(R″)—, —N(R)—, C(R′)(R″)—, —Se—, or (R′)(R″)C-C(R′″)(R″″);
R, R′, and R″ each independently represent a substituted or unsubstituted (C1-C30)alkyl, a substituted or unsubstituted (C6-C30)aryl, or a substituted or unsubstituted (3- to 30-membered)heteroaryl, -L₂-N—(Ar₃)(Ar₄) or -L₃-N(Ar₅)-L₄-N—(Ar₆)(Ar₇); or R′ and R″ may be linked to each other to form a ring(s), and R′ and R″ may be the same or different;
Ar₃-Ar₉ each independently represent hydrogen, deuterium, a substituted or unsubstituted (C1-C30)alkyl, a substituted or unsubstituted (C6-C30)aryl, a substituted or unsubstituted (3- to 30-membered) heteroaryl, a substituted or unsubstituted mono- or di-(C1-C30) alkylamino, a substituted or unsubstituted mono- or di-(C6-C30)arylamino, or a substituted or unsubstituted (C1-C30)alkyl(C6-C30)arylamino, where if a plurality of Ar₃-Ar₉ is present, each of Ar₃-Ar₉ may be the same or different; wherein
if Ar₃-Ar₉ each independently represent a substituted or unsubstituted (C6-C30)aryl, or a substituted or unsubstituted (3- to 30-membered)heteroaryl, adjacent Ar₃-Ar₉ may be linked to each other via a single bond to form a ring(s);
L₂-L₅ represent a single bond, a substituted or unsubstituted (C6-C30)arylene, or a substituted or unsubstituted (3- to 30-membered)heteroarylene;
R³-R⁵ each independently represent hydrogen, deuterium, a halogen, a cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted mono- or di-(C1-C30)alkylamino, a substituted or unsubstituted mono- or di-(C6-C30)arylamino, or a substituted or unsubstituted (C1-C30)alkyl(C6-C30)arylamino, where if a plurality of R³-R⁵ is present, each may be the same or different at each occurrence; and where adjacent R³ and/or R⁴ and/or R⁵ groups or R³ and/or R⁴ and/or R⁵ groups on adjacent rings can be joined together to form a 5- or 6-membered cycloaliphatic ring, carbocyclic aromatic ring, heteroaromatic ring, or a substituted derivative thereof;
c and e each independently represent an integer between 0 and 3, with the proviso that the maximum value for c or e is 2 when the bond to L₅ attaches to the ring bearing R³ or R⁵, respectively. d represents an integer between 0 and 2, with the proviso that the maximum value for d is 1 when the bond to L₅ attaches to the ring bearing R⁴; and
n represents 1 or 2.

In some non-limiting embodiments of Formula 2, the compound or compounds have molecular weights, T_{g}'s, and dipole moments as disclosed above herein.

In some non-limiting embodiments of Formula 2, Y═—O—.

In some non-limiting embodiments of Formula 2, Y═—S—.

In some non-limiting embodiments of Formula 2, Y═—Si(R′)(R″)—.

In some non-limiting embodiments of Formula 2, Y═—N(R)—.

In some non-limiting embodiments of Formula 2, Y═C(R′)(R″)—.

In some non-limiting embodiments of Formula 2, Y═—Se—.

In some non-limiting embodiments of Formula 2, R, R′, and R″ each independently represent a substituted or unsubstituted (C1-C30)alkyl, a substituted or unsubstituted (C6-C30)aryl, or a substituted or unsubstituted (3- to 30-membered)heteroaryl, -L₂-N—(Ar₃)(Ar₄) or -L₃-N(Ar₅)-L₄-N—(Ar₆)(Ar₇) wherein L₂, L₃, and L₄ are linking groups with embodiments the same as those disclosed for L₅ herein; or R′ and R″ may be linked to each other to form a ring(s), and R′ and R″ may be the same or different.

In some embodiments of Formula 2, the compound is deuterated. In some non-limiting embodiments, the compound is at least 10% deuterated; in some non-limiting embodiments, at least 20% deuterated; in some non-limiting embodiments, at least 30% deuterated; in some non-limiting embodiments, at least 40% deuterated; in some non-limiting embodiments, at least 50% deuterated; in some non-limiting embodiments, at least 60% deuterated; in some non-limiting embodiments, at least 70% deuterated; in some non-limiting embodiments, at least 80% deuterated; in some non-limiting embodiments, at least 90% deuterated; in some non-limiting embodiments, 100% deuterated.

In some non-limiting embodiments of Formula 2, deuteration is present on one or more of Ar₈, Ar₉, and R³-R⁵.

In some non-limiting embodiments of Formula 2, Ar₈ is selected from the group consisting of hydrocarbon aryl groups, heteroaryl groups, and substituted derivatives thereof, wherein substituted derivatives have only substituents selected from the group consisting of D, alkyl, silyl, germyl, deuterated alkyl, deuterated silyl, and deuterated germyl, and no other substituents.

In some non-limiting embodiments of Formula 2, Ar₈ is an unsubstituted hydrocarbon aryl.

In some non-limiting embodiments of Formula 2, Ar₈ is a hydrocarbon aryl or deuterated analog thereof having 6-30 ring carbons; in some embodiments 6-18 ring carbons.

In some non-limiting embodiments of Formula 2, Ar₈ is a substituted hydrocarbon aryl, where the substituent is selected from the group consisting of D, alkyl, silyl, germyl, hydrocarbon aryl, heteroaryl, deuterated alkyl, deuterated silyl, deuterated germyl, deuterated hydrocarbon aryl, and deuterated heteroaryl. In some embodiments, the heteroaryl has heteroatoms selected from the group consisting of O, S, and Se.

In some non-limiting embodiments of Formula 2, Ar₈ is selected from the group consisting of phenyl, biphenyl, terphenyl, 1-naphthyl, 2-naphthyl, anthracenyl, fluorenyl, phenanthryl, deuterated analogs thereof, and derivatives thereof having one or more substituents selected from the group consisting of D, alkyl, silyl, germyl, hydrocarbon aryl, heteroaryl, deuterated alkyl, deuterated silyl, deuterated germyl, deuterated hydrocarbon aryl, and deuterated heteroaryl. In some non-limiting embodiments, the heteroaryl has heteroatoms selected from the group consisting of O, S, and Se.

In some non-limiting embodiments of Formula 2, Ar₈ is selected from the group consisting of phenyl, biphenyl, terphenyl, 1-naphthyl, 2-naphthyl, anthracenyl, fluorenyl, phenanthryl, and derivatives thereof having one or more substituents selected from the group consisting of D, alkyl, silyl, germyl, deuterated alkyl, deuterated silyl, and deuterated germyl.

In some non-limiting embodiments of Formula 2, Ar₈ is selected from the group consisting of phenyl, biphenyl, naphthyl and substituted derivatives thereof.

In some non-limiting embodiments of Formula 2, Ar₈ is an unsubstituted heteroaryl.

In some non-limiting embodiments of Formula 2, Ar₈ is a heteroaryl or deuterated analog thereof having 3-30 ring carbons; in some non-limiting embodiments 3-18 ring carbons.

In some non-limiting embodiments of Formula 2, Ar₈ is a substituted heteroaryl, where the substituent is selected from the group consisting of D, alkyl, silyl, germyl, deuterated alkyl, deuterated silyl, and deuterated germyl.

In some non-limiting embodiments of Formula 2, Ar₈ is selected from the group consisting of heteroaryl and deuterated heteroaryl, where the heteroaryl has at least one ring atom which is selected from the group consisting of O and S.

In some non-limiting embodiments of Formula 2, Ar₈ is an O-heteroaryl having at least one ring atom that is O.

In some non-limiting embodiments, the O-heteroaryl is derived from a compound selected from the group consisting of furan, benzofuran, isobenzofuran, dibenzofuran, and substituted derivatives thereof.

In some non-limiting embodiments of Formula 2, Ar₈ is present and is an S-heteroaryl having at least one ring atom which is S.

In some non-limiting embodiments, the S-heteroaryl is derived from a compound selected form the group consisting of thiophene, benzothiophene, isobenzothiophene, dibenzothiophene, and substituted derivatives thereof.

All the embodiments for Ar₈ disclosed herein apply equally to Ar₉.

In some non-limiting embodiments of Formula 2, Ar₈═Ar₉.

In some non-limiting embodiments of Formula 2, Ar₈≠Ar₉.

In some non-limiting embodiments of Formula 2, L₅ is a single bond.

In some non-limiting embodiments of Formula 2, L₅ is a substituted or unsubstituted (C6-C30)arylene given by Formula a:

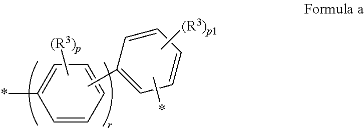

wherein R³ is the same or different at each occurrence and is selected from the group consisting of D, alkyl, aryloxy, heteroaryl, alkoxy, siloxy, silyl, germyl, deuterated alkyl, deuterated aryloxy, deuterated heteroaryl, deuterated alkoxy, deuterated siloxane, deuterated silyl, deuterated germyl, and wherein adjacent R³ groups can be joined together to form a fused ring. In some non-limiting embodiments, p is the same or different at each occurrence and is an integer from 0-4. In some non-limiting embodiments, p1 is the same or different at each occurrence and is an integer from 0-4. In some non-limiting embodiments, r is an integer from 0-5.

In some non-limiting embodiments of Formula 2, L₅ is a substituted or unsubstituted (3- to 30-membered) heteroarylene group that is derived from the corresponding heteroaryl groups selected from pyrrole, pyridine, pyrimidine, carbazole, imidazole, benzimidazole, imidazolobenzimidazole, triazole, benzotriazole, triazolopyridine, indolocarbazole, phenanthroline, quinoline, isoquinoline, quinoxaline, indole, indoloindole, substituted derivatives thereof, and deuterated analogs thereof.

In some non-limiting embodiments of Formula 2, R³-R⁵ each independently represent hydrogen, deuterium, a halogen, a cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted mono- or di-(C1-C30)alkylamino, a substituted or unsubstituted mono- or di-(C6-C30)arylamino, or a substituted or unsubstituted (C1-C30)alkyl(C6-C30)arylamino, where if a plurality of R³-R⁵ is present, each may be the same or different at each occurrence.

In some non-limiting embodiments of Formula 2, c=0. In some non-limiting embodiments, c=1. In some non-limiting embodiments, c=2. In some non-limiting embodiments, c=3.

In some non-limiting embodiments of Formula 2, d=0. In some non-limiting embodiments, d=1. In some non-limiting embodiments, d=2.

In some non-limiting embodiments of Formula 2, e=0. In some non-limiting embodiments, e=1. In some non-limiting embodiments, e=2. In some non-limiting embodiments, e=3.

In some non-limiting embodiments of Formula 2, n=1. In some non-limiting embodiments, n=2. In embodiments with n=1, the bridging group comprising Y is a 5-membered ring. In embodiments with n=2, the bridging group comprising the Y's is a 6-membered ring. In some non-limiting embodiments with n=2, both Y's are given by C(R′)(R″)— wherein R′ and R″ are as defined herein. In some non-limiting embodiments with n=2, one Y is given by C(R′)(R″)— wherein R′ and R″ are as defined herein and the other Y is selected from the group consisting of —O—, —S—, —Si—, —N(R)—, and —Se— wherein R is as defined herein.

In some non-limiting embodiments of Formula 2, Y is C(R′)(R″), R′ and R″ are methyl, R³-R⁵ are H, L⁵ is phenylene, Ar⁸ is phenyl, Ar⁹ is terphenyl, n is 1, c and e are 3, and d is 1.

In some non-limiting embodiments of Formula 2, Y is C(R′)(R″), R′ and R″ are methyl, R³-R⁵ are H, L⁵ is phenylene, Ar⁸ is phenyl, Ar⁹ is 2-triphenylene, n is 1, c and e are 3, and d is 1.

Considerations for the selection of a particular compound having Formula 2 for use in an OLED device are the same as those discussed above in the context of one or more compounds having Formula 1.

Examples of compounds having Formula 2 include, but are not limited to, the compounds shown below.

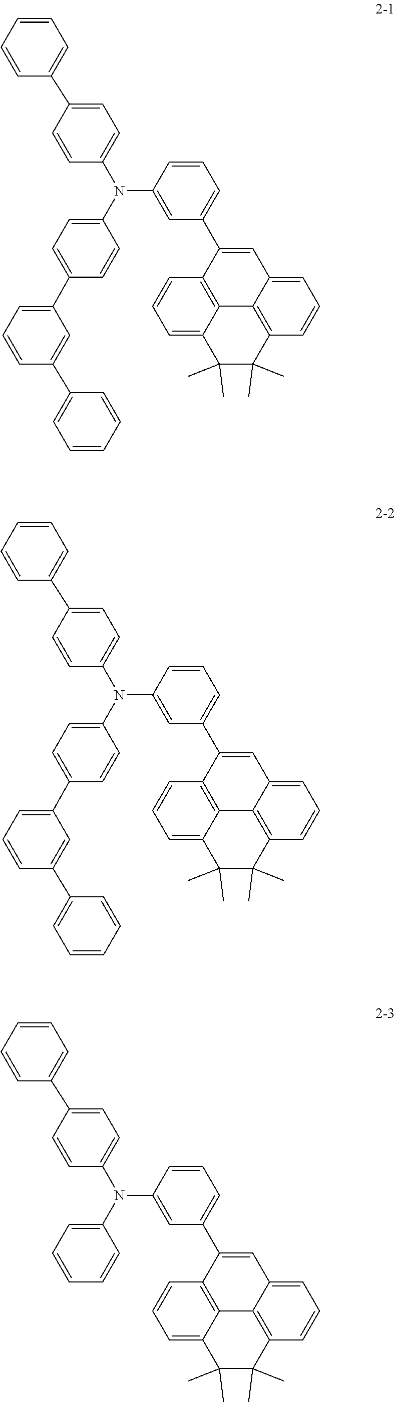 [SMILES: CC1(C)c2cccc3cc(-c4cccc(N(c5ccc(-c6ccccc6)cc5)c5ccc(-c6cccc(-c7ccccc7)c6)cc5)c4)c4cccc(c4c23)C1(C)C ; CC1(C)c2cccc3cc(-c4cccc(N(c5ccc(-c6ccccc6)cc5)c5ccc(-c6cccc(-c7ccccc7)c6)cc5)c4)c4cccc(c4c23)C1(C)C ; CC1(C)c2cccc3cc(-c4cccc(N(c5ccccc5)c5ccc(-c6ccccc6)cc5)c4)c4cccc(c4c23)C1(C)C]

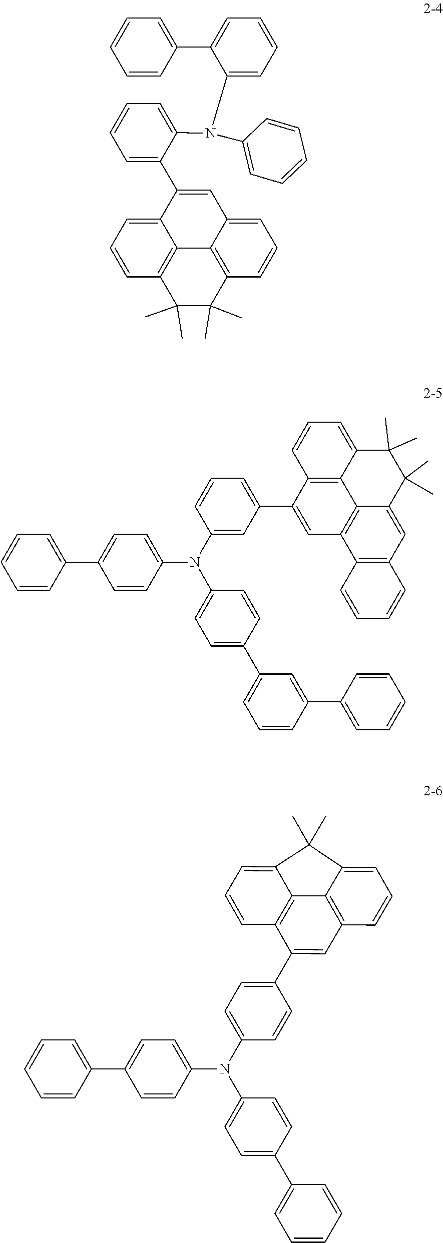 [SMILES: CC1(C)c2cccc3cc(-c4ccccc4N(c4ccccc4)c4ccccc4-c4ccccc4)c4cccc(c4c23)C1(C)C ; CC1(C)c2cccc3c(-c4cccc(N(c5ccc(-c6ccccc6)cc5)c5ccc(-c6cccc(-c7ccccc7)c6)cc5)c4)cc4c5ccccc5cc(c4c23)C1(C)C ; CC1(C)c2cccc3cc(-c4ccc(N(c5ccc(-c6ccccc6)cc5)c5ccc(-c6ccccc6)cc5)cc4)c4cccc1c4c23]

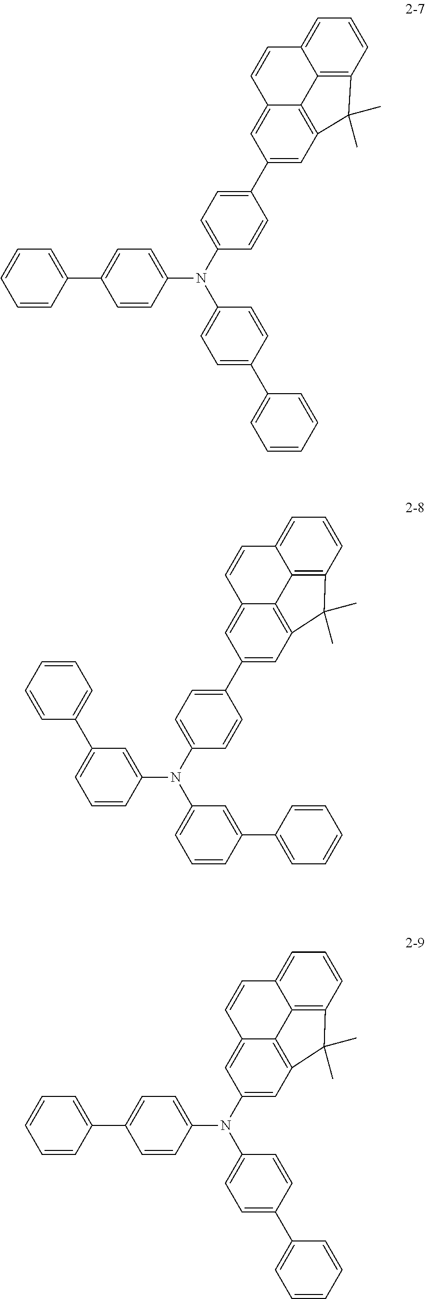 [SMILES: CC1(C)c2cccc3ccc4cc(-c5ccc(N(c6ccc(-c7ccccc7)cc6)c6ccc(-c7ccccc7)cc6)cc5)cc1c4c23 ; CC1(C)c2cccc3ccc4cc(-c5ccc(N(c6cccc(-c7ccccc7)c6)c6cccc(-c7ccccc7)c6)cc5)cc1c4c23 ; CC1(C)c2cccc3ccc4cc(N(c5ccc(-c6ccccc6)cc5)c5ccc(-c6ccccc6)cc5)cc1c4c23]

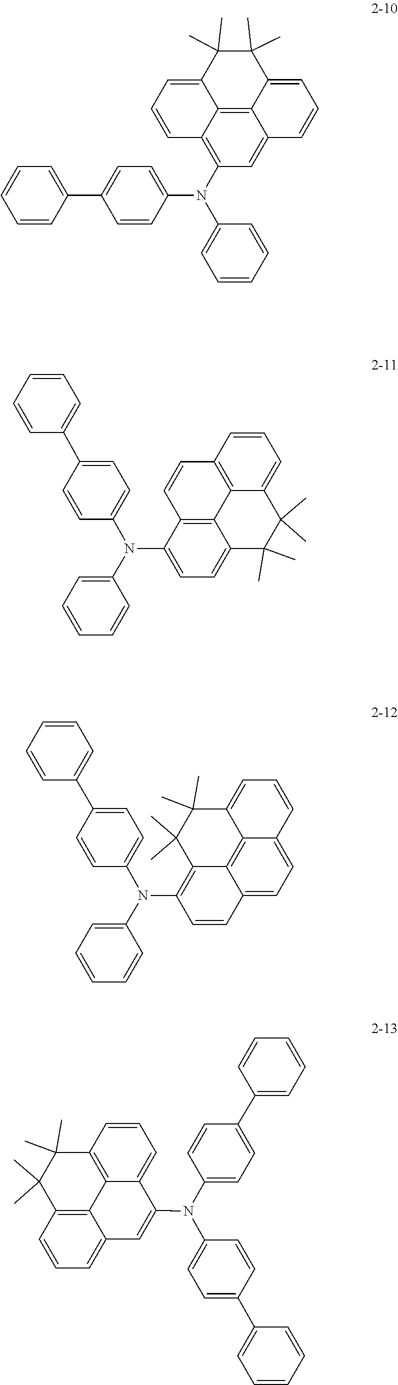

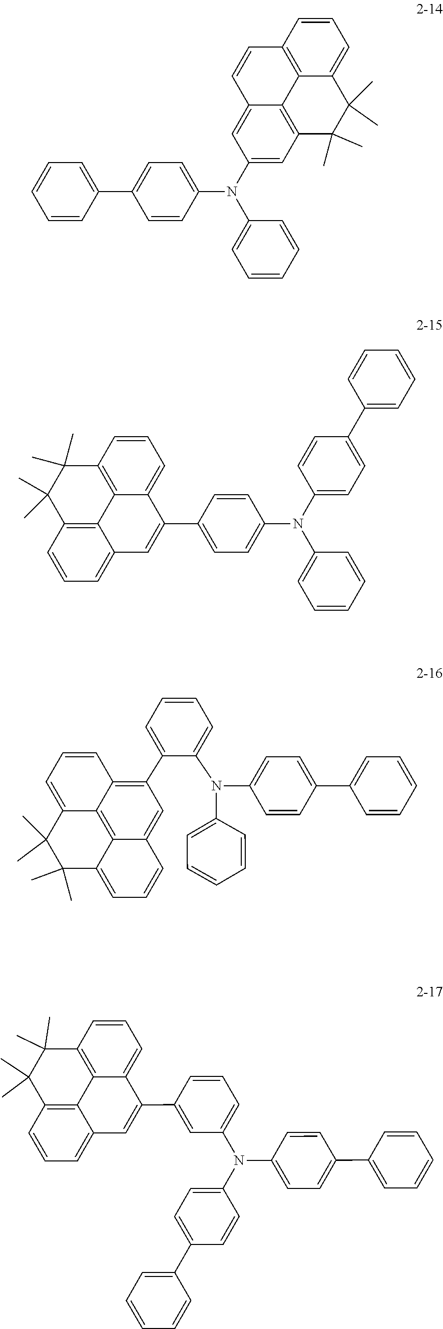

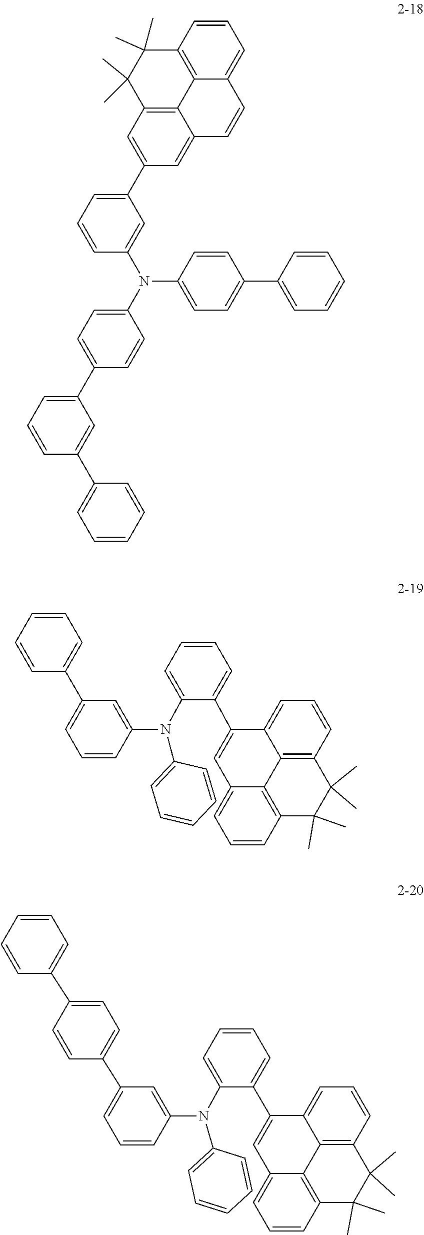 [SMILES: CC1(C)c2cccc3ccc4cc(-c5cccc(N(c6ccc(-c7ccccc7)cc6)c6ccc(-c7cccc(-c8ccccc8)c7)cc6)c5)cc(c4c23)C1(C)C ; CC1(C)c2cccc3cc(-c4ccccc4N(c4ccccc4)c4cccc(-c5ccccc5)c4)c4cccc(c4c23)C1(C)C ; CC1(C)c2cccc3cc(-c4ccccc4N(c4ccccc4)c4cccc(-c5ccc(-c6ccccc6)cc5)c4)c4cccc(c4c23)C1(C)C]

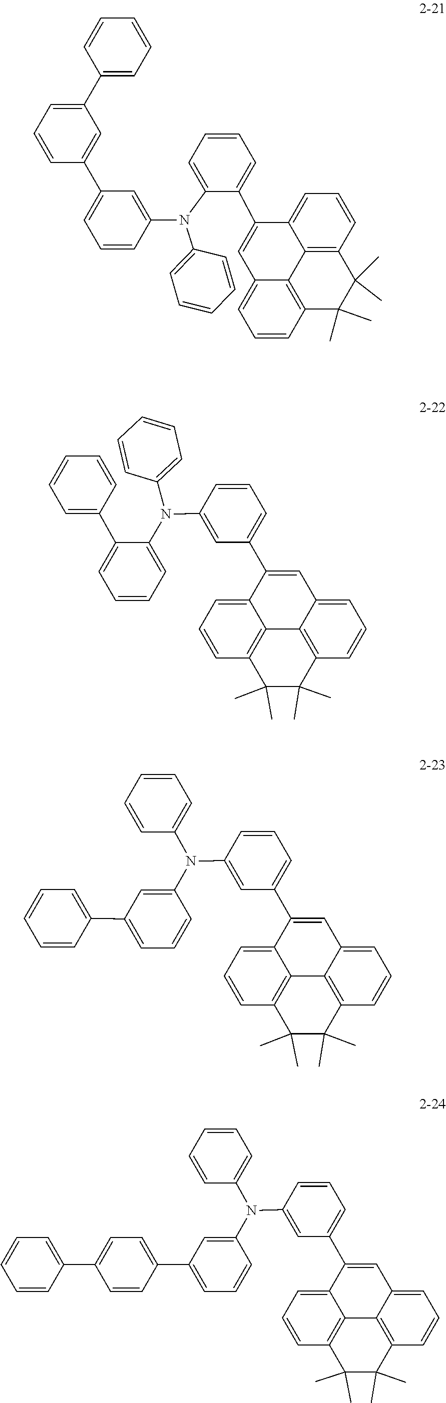 [SMILES: CC1(C)c2cccc3cc(-c4ccccc4N(c4ccccc4)c4cccc(-c5cccc(-c6ccccc6)c5)c4)c4cccc(c4c23)C1(C)C ; CC1(C)c2cccc3cc(-c4cccc(N(c5ccccc5)c5ccccc5-c5ccccc5)c4)c4cccc(c4c23)C1(C)C ; CC1(C)c2cccc3cc(-c4cccc(N(c5ccccc5)c5cccc(-c6ccccc6)c5)c4)c4cccc(c4c23)C1(C)C ; CC1(C)c2cccc3cc(-c4cccc(N(c5ccccc5)c5cccc(-c6ccc(-c7ccccc7)cc6)c5)c4)c4cccc(c4c23)C1(C)C]

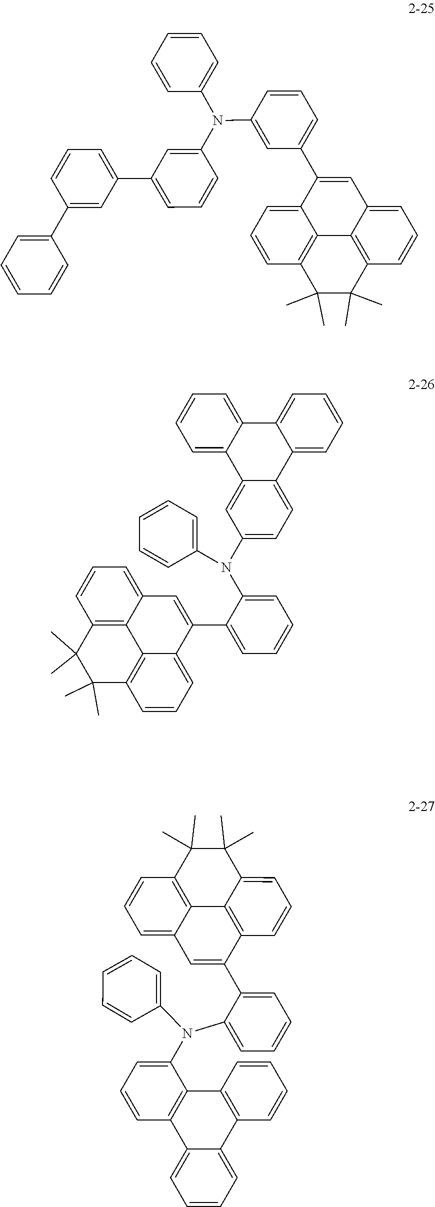 [SMILES: CC1(C)c2cccc3cc(-c4cccc(N(c5ccccc5)c5cccc(-c6cccc(-c7ccccc7)c6)c5)c4)c4cccc(c4c23)C1(C)C ; CC1(C)c2cccc3cc(-c4ccccc4N(c4ccccc4)c4ccc5c6ccccc6c6ccccc6c5c4)c4cccc(c4c23)C1(C)C ; CC1(C)c2cccc3cc(-c4ccccc4N(c4ccccc4)c4cccc5c6ccccc6c6ccccc6c45)c4cccc(c4c23)C1(C)C]

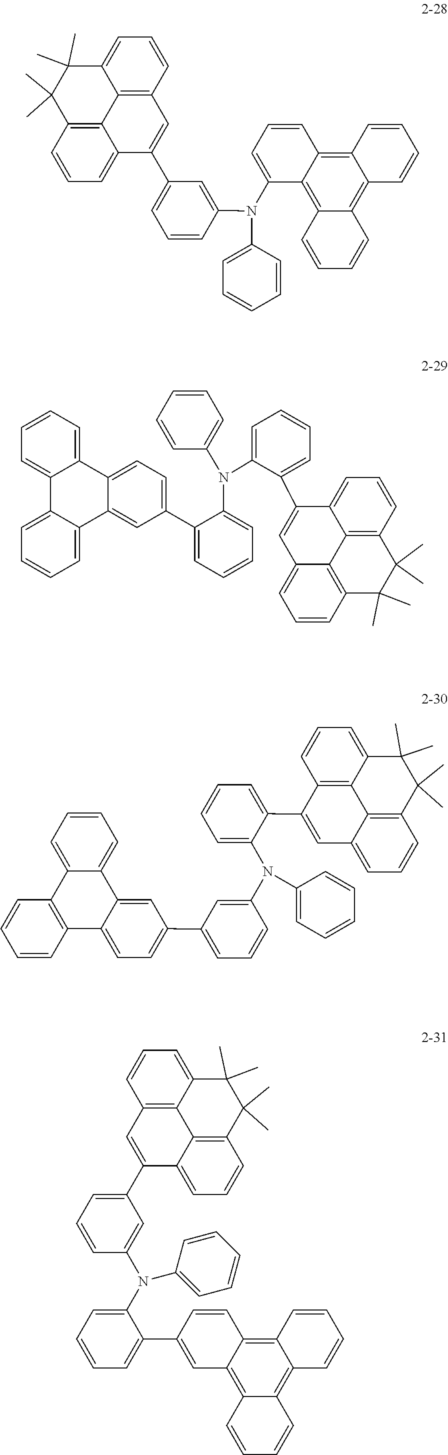 [SMILES: CC1(C)c2cccc3cc(-c4cccc(N(c5ccccc5)c5cccc6c7ccccc7c7ccccc7c56)c4)c4cccc(c4c23)C1(C)C ; CC1(C)c2cccc3cc(-c4ccccc4N(c4ccccc4)c4ccccc4-c4ccc5c6ccccc6c6ccccc6c5c4)c4cccc(c4c23)C1(C)C ; CC1(C)c2cccc3cc(-c4ccccc4N(c4ccccc4)c4cccc(-c5ccc6c7ccccc7c7ccccc7c6c5)c4)c4cccc(c4c23)C1(C)C ; CC1(C)c2cccc3cc(-c4cccc(N(c5ccccc5)c5ccccc5-c5ccc6c7ccccc7c7ccccc7c6c5)c4)c4cccc(c4c23)C1(C)C]

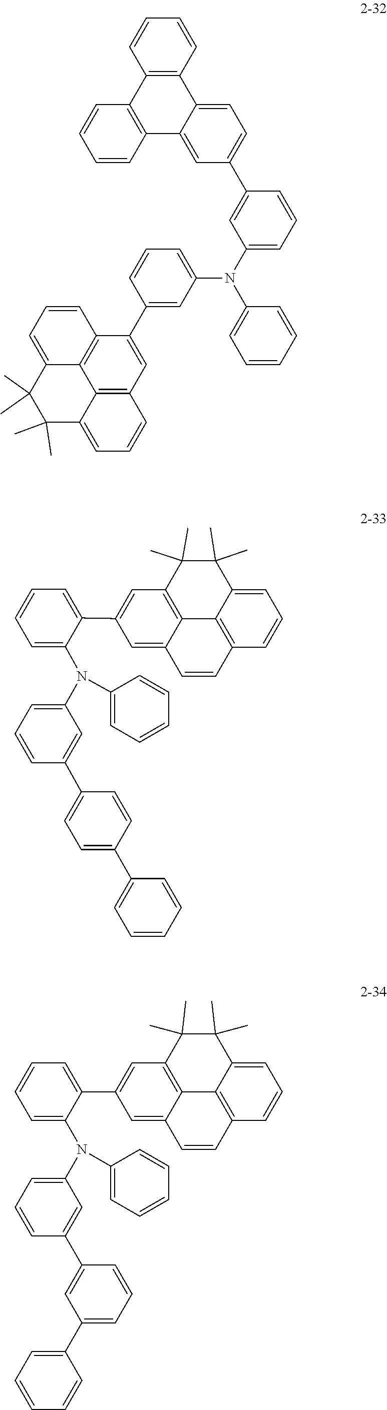 [SMILES: CC1(C)c2cccc3cc(-c4cccc(N(c5ccccc5)c5cccc(-c6ccc7c8ccccc8c8ccccc8c7c6)c5)c4)c4cccc(c4c23)C1(C)C ; CC1(C)c2cccc3ccc4cc(-c5ccccc5N(c5ccccc5)c5cccc(-c6ccc(-c7ccccc7)cc6)c5)cc(c4c23)C1(C)C ; CC1(C)c2cccc3ccc4cc(-c5ccccc5N(c5ccccc5)c5cccc(-c6cccc(-c7ccccc7)c6)c5)cc(c4c23)C1(C)C]

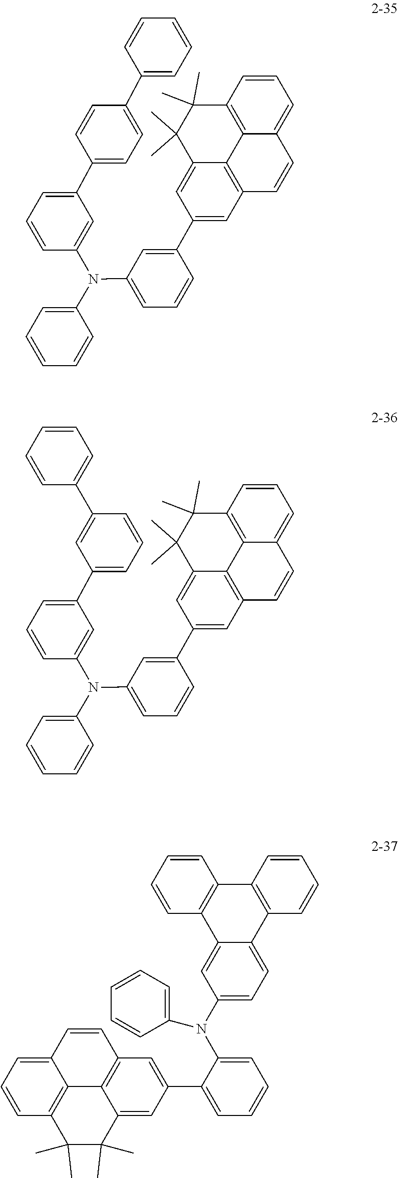 [SMILES: CC1(C)c2cccc3ccc4cc(-c5cccc(N(c6ccccc6)c6cccc(-c7ccc(-c8ccccc8)cc7)c6)c5)cc(c4c23)C1(C)C ; CC1(C)c2cccc3ccc4cc(-c5cccc(N(c6ccccc6)c6cccc(-c7cccc(-c8ccccc8)c7)c6)c5)cc(c4c23)C1(C)C ; CC1(C)c2cccc3ccc4cc(-c5ccccc5N(c5ccccc5)c5ccc6c7ccccc7c7ccccc7c6c5)cc(c4c23)C1(C)C]

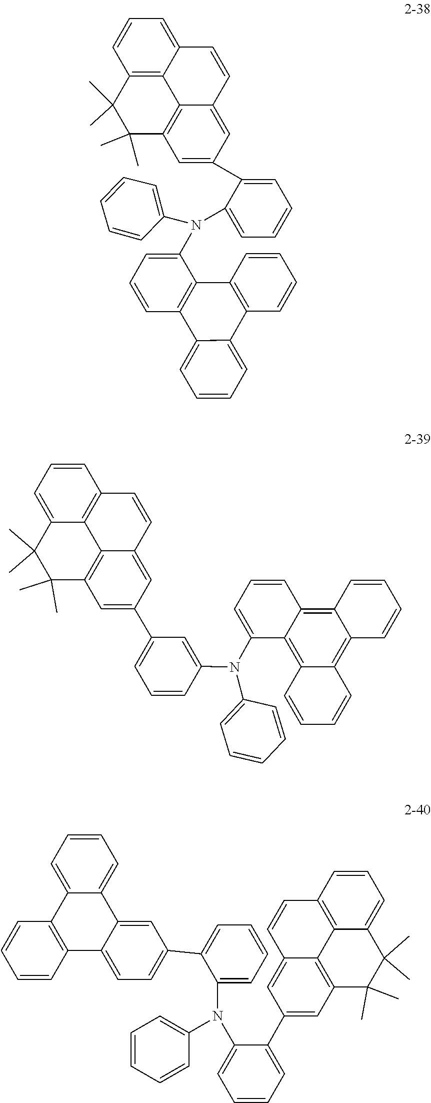 [SMILES: CC1(C)c2cccc3ccc4cc(-c5ccccc5N(c5ccccc5)c5cccc6c7ccccc7c7ccccc7c56)cc(c4c23)C1(C)C ; CC1(C)c2cccc3ccc4cc(-c5cccc(N(c6ccccc6)c6cccc7c8ccccc8c8ccccc8c67)c5)cc(c4c23)C1(C)C ; CC1(C)c2cccc3ccc4cc(-c5ccccc5N(c5ccccc5)c5ccccc5-c5ccc6c7ccccc7c7ccccc7c6c5)cc(c4c23)C1(C)C]

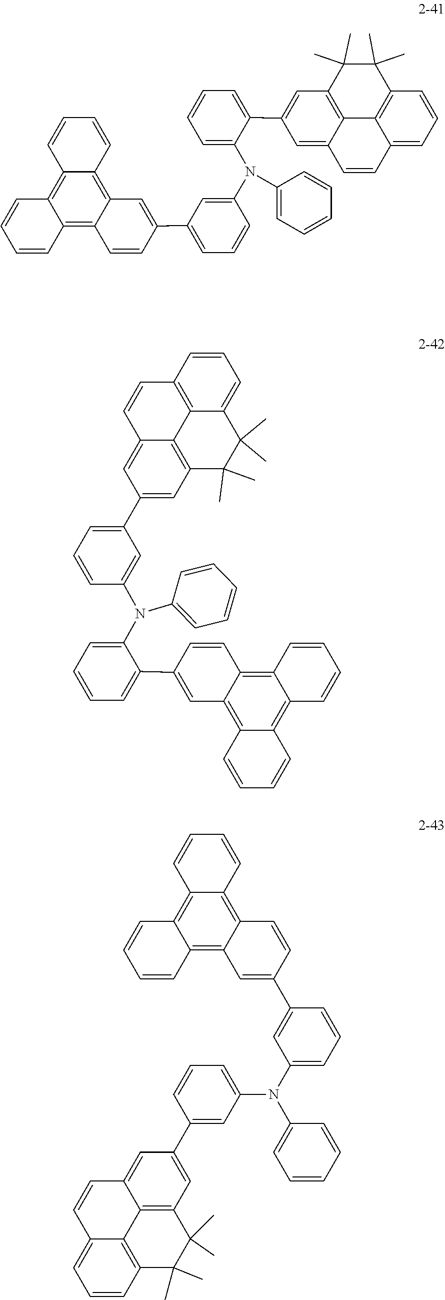 [SMILES: CC1(C)c2cccc3ccc4cc(-c5ccccc5N(c5ccccc5)c5cccc(-c6ccc7c8ccccc8c8ccccc8c7c6)c5)cc(c4c23)C1(C)C ; CC1(C)c2cccc3ccc4cc(-c5cccc(N(c6ccccc6)c6ccccc6-c6ccc7c8ccccc8c8ccccc8c7c6)c5)cc(c4c23)C1(C)C ; CC1(C)c2cccc3ccc4cc(-c5cccc(N(c6ccccc6)c6cccc(-c7ccc8c9ccccc9c9ccccc9c8c7)c6)c5)cc(c4c23)C1(C)C]

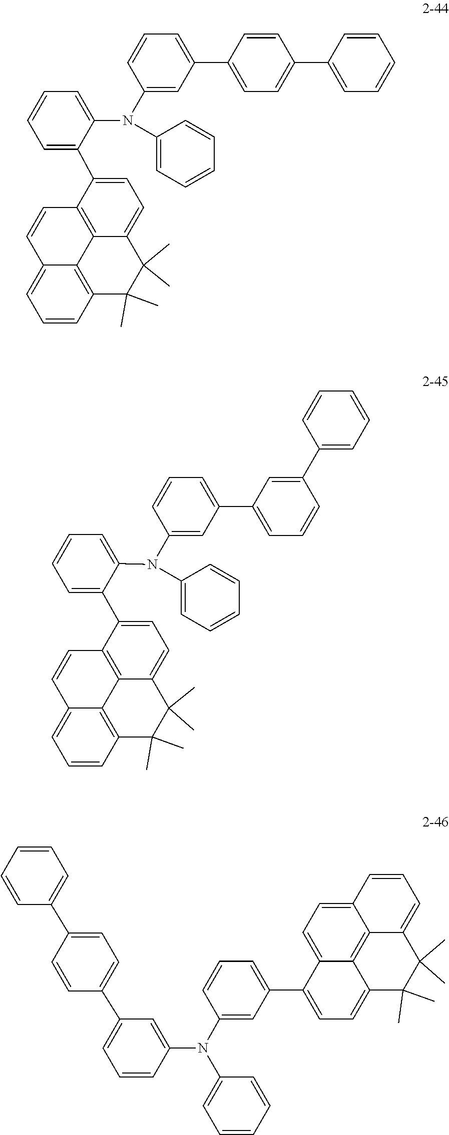 [SMILES: CC1(C)c2cccc3ccc4c(-c5ccccc5N(c5ccccc5)c5cccc(-c6ccc(-c7ccccc7)cc6)c5)ccc(c4c23)C1(C)C ; CC1(C)c2cccc3ccc4c(-c5ccccc5N(c5ccccc5)c5cccc(-c6cccc(-c7ccccc7)c6)c5)ccc(c4c23)C1(C)C ; CC1(C)c2cccc3ccc4c(-c5cccc(N(c6ccccc6)c6cccc(-c7ccc(-c8ccccc8)cc7)c6)c5)ccc(c4c23)C1(C)C]

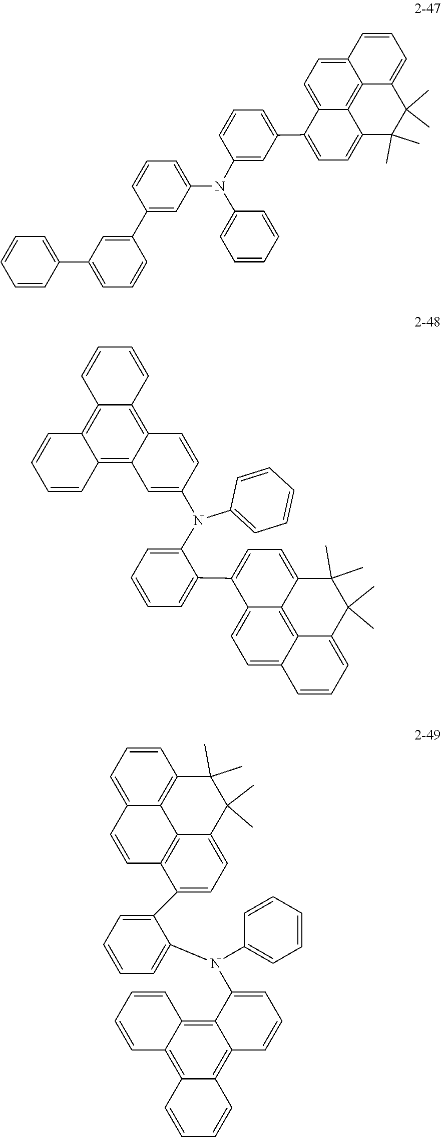 [SMILES: CC1(C)c2cccc3ccc4c(-c5cccc(N(c6ccccc6)c6cccc(-c7cccc(-c8ccccc8)c7)c6)c5)ccc(c4c23)C1(C)C ; CC1(C)c2cccc3ccc4c(-c5ccccc5N(c5ccccc5)c5ccc6c7ccccc7c7ccccc7c6c5)ccc(c4c23)C1(C)C ; CC1(C)c2cccc3ccc4c(-c5ccccc5N(c5ccccc5)c5cccc6c7ccccc7c7ccccc7c56)ccc(c4c23)C1(C)C]

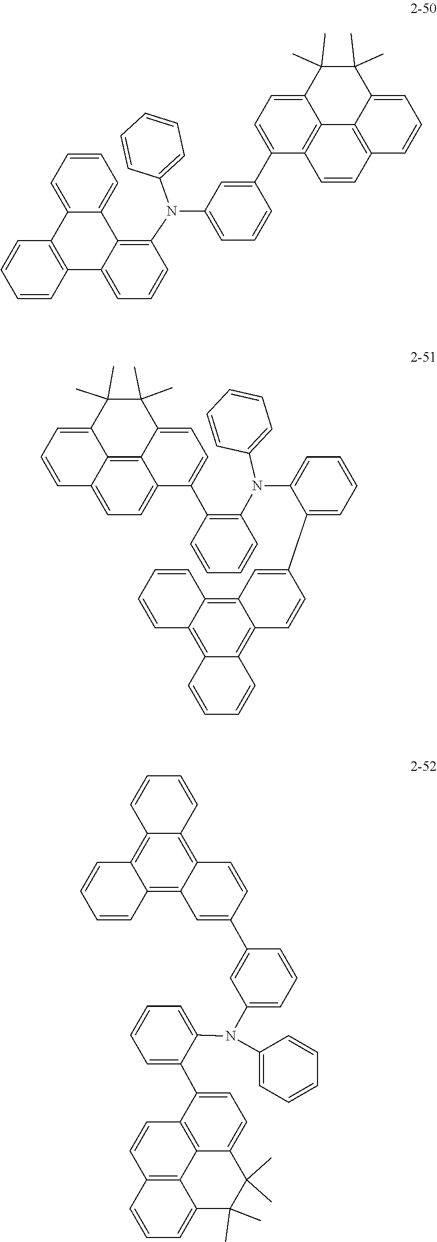 [SMILES: CC1(C)c2cccc3ccc4c(-c5cccc(N(c6ccccc6)c6cccc7c8ccccc8c8ccccc8c67)c5)ccc(c4c23)C1(C)C ; CC1(C)c2cccc3ccc4c(-c5ccccc5N(c5ccccc5)c5ccccc5-c5ccc6c7ccccc7c7ccccc7c6c5)ccc(c4c23)C1(C)C ; CC1(C)c2cccc3ccc4c(-c5ccccc5N(c5ccccc5)c5cccc(-c6ccc7c8ccccc8c8ccccc8c7c6)c5)ccc(c4c23)C1(C)C]

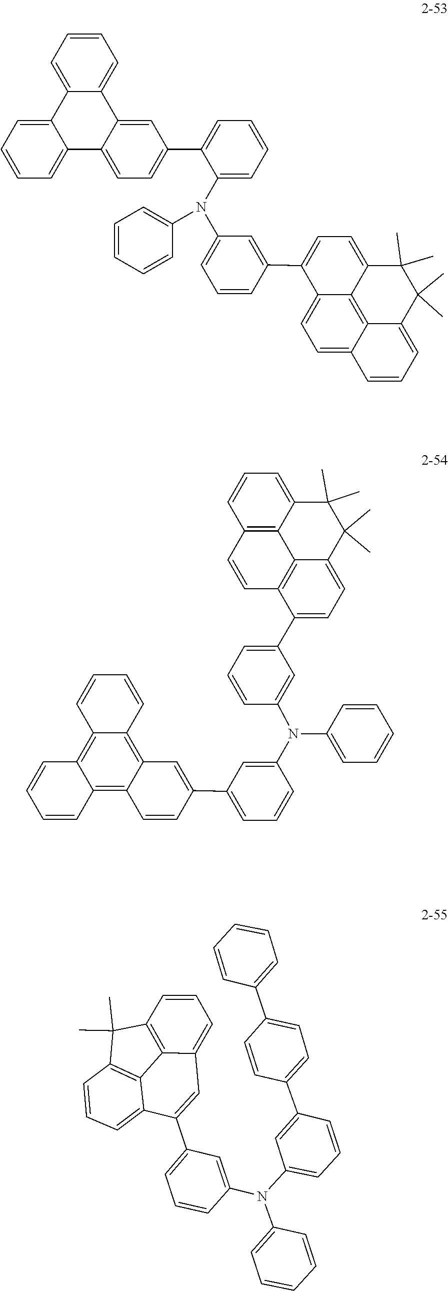

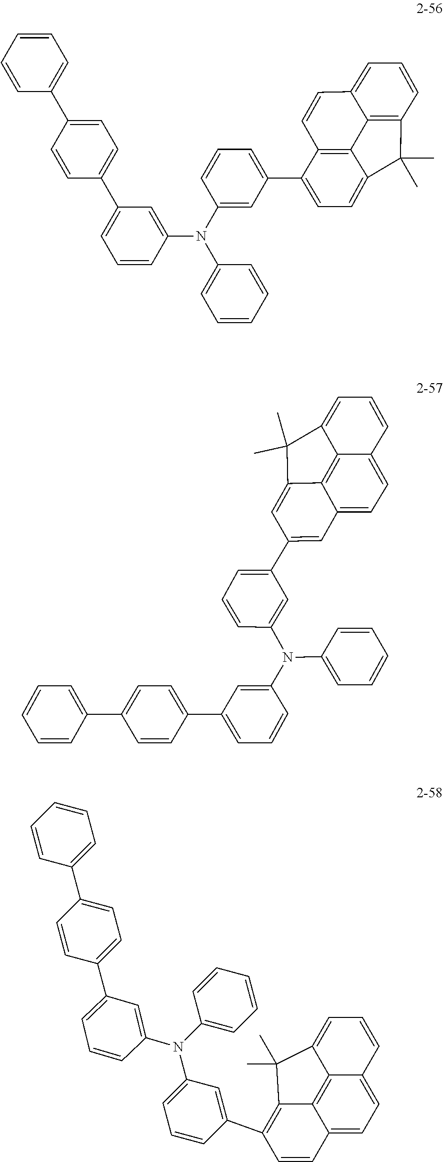 [SMILES: CC1(C)c2cccc3ccc4c(-c5cccc(N(c6ccccc6)c6cccc(-c7ccc(-c8ccccc8)cc7)c6)c5)ccc1c4c23 ; CC1(C)c2cccc3ccc4cc(-c5cccc(N(c6ccccc6)c6cccc(-c7ccc(-c8ccccc8)cc7)c6)c5)cc1c4c23 ; CC1(C)c2cccc3ccc4ccc(-c5cccc(N(c6ccccc6)c6cccc(-c7ccc(-c8ccccc8)cc7)c6)c5)c1c4c23]

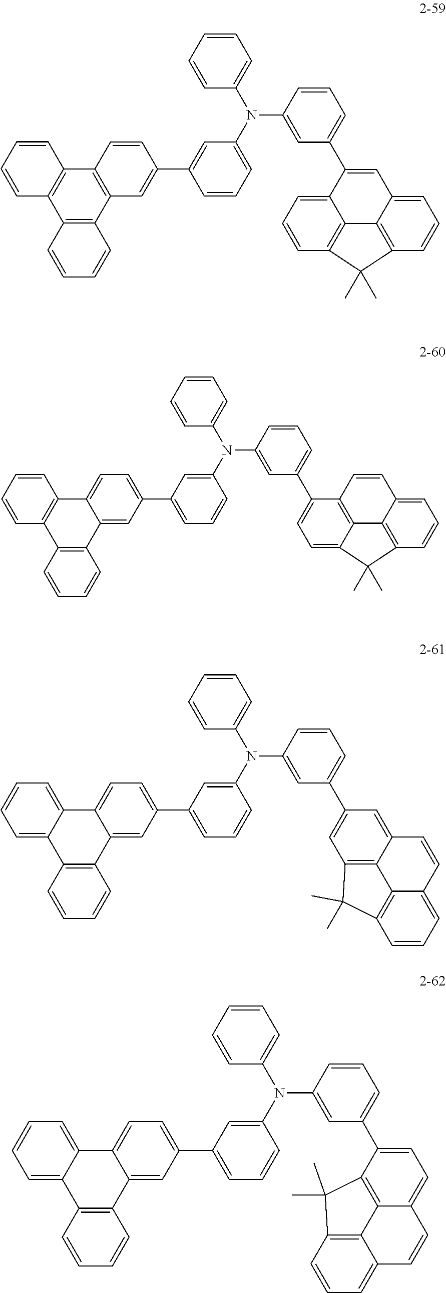 [SMILES: CC1(C)c2cccc3cc(-c4cccc(N(c5ccccc5)c5cccc(-c6ccc7c8ccccc8c8ccccc8c7c6)c5)c4)c4cccc1c4c23 ; CC1(C)c2cccc3ccc4c(-c5cccc(N(c6ccccc6)c6cccc(-c7ccc8c9ccccc9c9ccccc9c8c7)c6)c5)ccc1c4c23 ; CC1(C)c2cccc3ccc4cc(-c5cccc(N(c6ccccc6)c6cccc(-c7ccc8c9ccccc9c9ccccc9c8c7)c6)c5)cc1c4c23 ; CC1(C)c2cccc3ccc4ccc(-c5cccc(N(c6ccccc6)c6cccc(-c7ccc8c9ccccc9c9ccccc9c8c7)c6)c5)c1c4c23]

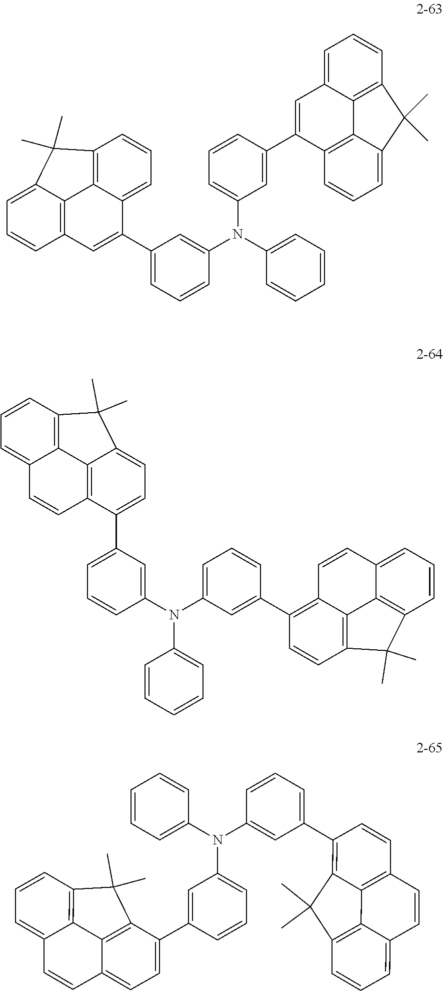 [SMILES: CC1(C)c2cccc3cc(-c4cccc(N(c5ccccc5)c5cccc(-c6cc7cccc8c7c7c(cccc67)C8(C)C)c5)c4)c4cccc1c4c23 ; CC1(C)c2cccc3ccc4c(-c5cccc(N(c6ccccc6)c6cccc(-c7ccc8c9c7ccc7cccc(c79)C8(C)C)c6)c5)ccc1c4c23 ; CC1(C)c2cccc3ccc4ccc(-c5cccc(N(c6ccccc6)c6cccc(-c7ccc8ccc9cccc%10c9c8c7C%10(C)C)c6)c5)c1c4c23]

In some non-limiting embodiments of the composition comprising a mixture of a first compound and a second compound disclosed herein, the first compound and/or the second compound have a chemical structure given by Formula 3:

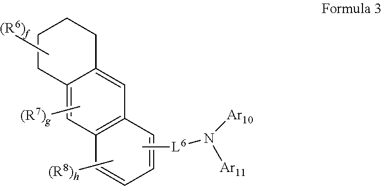

wherein
Ar₁₀-Ar₁₁ each independently represent hydrogen, deuterium, a substituted or unsubstituted (C1-C30)alkyl, a substituted or unsubstituted (C6-C30)aryl, a substituted or unsubstituted (3- to 30-membered) heteroaryl, a substituted or unsubstituted mono- or di-(C1-C30) alkylamino, a substituted or unsubstituted mono- or di-(C6-C30)arylamino, or a substituted or unsubstituted (C1-C30)alkyl(C6-C30)arylamino, where if a plurality of Ar₃-Ar₉ is present, each of Ar₁₀-Ar₁₁ may be the same or different; wherein
if Ar₁₀-Aᵣ₁₁ each independently represent a substituted or unsubstituted (C6-C30)aryl, or a substituted or unsubstituted (3- to 30-membered)heteroaryl, adjacent Ar₃-Ar₉ may be linked to each other via a single bond to form a ring(s);
L₆ represent a single bond, a substituted or unsubstituted (C6-C30)arylene, or a substituted or unsubstituted (3- to 30-membered)heteroarylene; R⁶, R⁷ and R⁸ each independently represent hydrogen, deuterium, a halogen, a cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted mono- or di-(C1-C30)alkylamino, a substituted or unsubstituted mono- or di-(C6-C30)arylamino, or a substituted or unsubstituted (C1-C30)alkyl(C6-C30)arylamino, where if a plurality of R⁶,R⁷ and/or R⁸ is present, each may be the same or different at each occurrence; and where adjacent R⁶ and/or R⁷ and/or R⁸ groups or R⁶ and/or R⁷ and/or R⁸ groups on adjacent rings can be joined together to form a 5- or 6-membered cycloaliphatic ring, carbocyclic aromatic ring, heteroaromatic ring, or a substituted derivative thereof;
f represents an integer between 0 and 8, g represents an integer between 0 and 2, and h represents an integer between 0 and 4 with the proviso that the maximum value for g is 1 and the maximum value for h is 3 when the bond to L₆ attaches to the ring bearing R⁷ or R⁸, respectively.

In some non-limiting embodiments of Formula 3, the compound or compounds have molecular weights, T_{g}'s, and dipole moments as disclosed above herein.

In some embodiments of Formula 3, the compound is deuterated. In some non-limiting embodiments, the compound is at least 10% deuterated; in some non-limiting embodiments, at least 20% deuterated; in some non-limiting embodiments, at least 30% deuterated; in some non-limiting embodiments, at least 40% deuterated; in some non-limiting embodiments, at least 50% deuterated; in some non-limiting embodiments, at least 60% deuterated; in some non-limiting embodiments, at least 70% deuterated; in some non-limiting embodiments, at least 80% deuterated; in some non-limiting embodiments, at least 90% deuterated; in some non-limiting embodiments, 100% deuterated.

In some non-limiting embodiments of Formula 3, deuteration is present on one or more of Ar₁₀, Ar₁₁, and R⁶-R⁸.

In some non-limiting embodiments of Formula 3, Ar₁₀ is selected from the group consisting of hydrocarbon aryl groups, heteroaryl groups, and substituted derivatives thereof, wherein substituted derivatives have only substituents selected from the group consisting of D, alkyl, silyl, germyl, deuterated alkyl, deuterated silyl, and deuterated germyl, and no other substituents.

In some non-limiting embodiments of Formula 3, Ar₁₀ is an unsubstituted hydrocarbon aryl.

In some non-limiting embodiments of Formula 3, Ar₁₀ is a hydrocarbon aryl or deuterated analog thereof having 6-30 ring carbons; in some embodiments 6-18 ring carbons.

In some non-limiting embodiments of Formula 3, Ar₁₀ is a substituted hydrocarbon aryl, where the substituent is selected from the group consisting of D, alkyl, silyl, germyl, hydrocarbon aryl, heteroaryl, deuterated alkyl, deuterated silyl, deuterated germyl, deuterated hydrocarbon aryl, and deuterated heteroaryl. In some embodiments, the heteroaryl has heteroatoms selected from the group consisting of O, S, and Se.

In some non-limiting embodiments of Formula 3, Ar₁₀ is selected from the group consisting of phenyl, biphenyl, terphenyl, 1-naphthyl, 2-naphthyl, anthracenyl, fluorenyl, phenanthryl, deuterated analogs thereof, and derivatives thereof having one or more substituents selected from the group consisting of D, alkyl, silyl, germyl, hydrocarbon aryl, heteroaryl, deuterated alkyl, deuterated silyl, deuterated germyl, deuterated hydrocarbon aryl, and deuterated heteroaryl. In some non-limiting embodiments, the heteroaryl has heteroatoms selected from the group consisting of O, S, and Se.

In some non-limiting embodiments of Formula 3, Ar₁₀ is selected from the group consisting of phenyl, biphenyl, terphenyl, 1-naphthyl, 2-naphthyl, anthracenyl, fluorenyl, phenanthryl, and derivatives thereof having one or more substituents selected from the group consisting of D, alkyl, silyl, germyl, deuterated alkyl, deuterated silyl, and deuterated germyl.

In some non-limiting embodiments of Formula 3, Ar₁₀ is selected from the group consisting of phenyl, biphenyl, naphthyl and substituted derivatives thereof.

In some non-limiting embodiments of Formula 3, Ar₁₀ is an unsubstituted heteroaryl.

In some non-limiting embodiments of Formula 3, Ar₁₀ is a heteroaryl or deuterated analog thereof having 3-30 ring carbons; in some non-limiting embodiments 3-18 ring carbons.

In some non-limiting embodiments of Formula 3, Ar₁₀ is a substituted heteroaryl, where the substituent is selected from the group consisting of D, alkyl, silyl, germyl, deuterated alkyl, deuterated silyl, and deuterated germyl.

In some non-limiting embodiments of Formula 3, Ar₁₀ is selected from the group consisting of heteroaryl and deuterated heteroaryl, where the heteroaryl has at least one ring atom which is selected from the group consisting of O and S.

In some non-limiting embodiments of Formula 3, Ar₁₀ is an O-heteroaryl having at least one ring atom that is O.

In some non-limiting embodiments, the O-heteroaryl is derived from a compound selected from the group consisting of furan, benzofuran, isobenzofuran, dibenzofuran, and substituted derivatives thereof.

In some non-limiting embodiments of Formula 3, Ar₁₀ is present and is an S-heteroaryl having at least one ring atom which is S.

In some non-limiting embodiments, the S-heteroaryl is derived from a compound selected form the group consisting of thiophene, benzothiophene, isobenzothiophene, dibenzothiophene, and substituted derivatives thereof.

All the embodiments for Ar₁₀ disclosed herein apply equally to Ar₁₁.

In some non-limiting embodiments of Formula 3, Ar₁₀═Ar₁₁.

In some non-limiting embodiments of Formula 3, Ar₁₀≠Ar₁₁.

In some non-limiting embodiments of Formula 3, L₆ is a single bond.

In some non-limiting embodiments of Formula 3, L₆ is a substituted or unsubstituted (C6-C30)arylene given by Formula a:

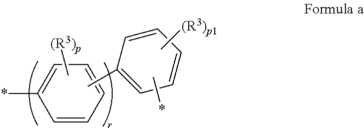

wherein R³ is the same or different at each occurrence and is selected from the group consisting of D, alkyl, aryloxy, heteroaryl, alkoxy, siloxy, silyl, germyl, deuterated alkyl, deuterated aryloxy, deuterated heteroaryl, deuterated alkoxy, deuterated siloxane, deuterated silyl, deuterated germyl, and wherein adjacent R³ groups can be joined together to form a fused ring. In some non-limiting embodiments, p is the same or different at each occurrence and is an integer from 0-4. In some non-limiting embodiments, p1 is the same or different at each occurrence and is an integer from 0-4. In some non-limiting embodiments, r is an integer from 0-5.

In some non-limiting embodiments of Formula 3, L₆ is a substituted or unsubstituted (3- to 30-membered) heteroarylene group that is derived from the corresponding heteroaryl groups selected from pyrrole, pyridine, pyrimidine, carbazole, imidazole, benzimidazole, imidazolobenzimidazole, triazole, benzotriazole, triazolopyridine, indolocarbazole, phenanthroline, quinoline, isoquinoline, quinoxaline, indole, indoloindole, substituted derivatives thereof, and deuterated analogs thereof.

In some non-limiting embodiments of Formula 3, R⁶-R⁸ each independently represent hydrogen, deuterium, a halogen, a cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted mono- or di-(C1-C30)alkylamino, a substituted or unsubstituted mono- or di-(C6-C30)arylamino, or a substituted or unsubstituted (C1-C30)alkyl(C6-C30)arylamino, where if a plurality of R⁶-R⁸ is present, each may be the same or different at each occurrence.

In some non-limiting embodiments of Formula 3, f=0. In some non-limiting embodiments, f=1. In some non-limiting embodiments, f=2. In some non-limiting embodiments, f=3. In some non-limiting embodiments, f=4. In some non-limiting embodiments, f=5. In some non-limiting embodiments, f=6. In some non-limiting embodiments, f=7. In some non-limiting embodiments, f=8.

In some non-limiting embodiments of Formula 3, g=0. In some non-limiting embodiments, g=1. In some non-limiting embodiments, g=2.

In some non-limiting embodiments of Formula 3, h=0. In some non-limiting embodiments, h=1. In some non-limiting embodiments, h=2. In some non-limiting embodiments, h=3. In some non-limiting embodiments, h=4.

Considerations for the selection of a particular compound having Formula 3 for use in an OLED device are the same as those discussed above in the context of one or more compounds having Formula 1 and/or Formula 2.

Examples of compounds having Formula 3 include, but are not limited to, the compounds shown below.

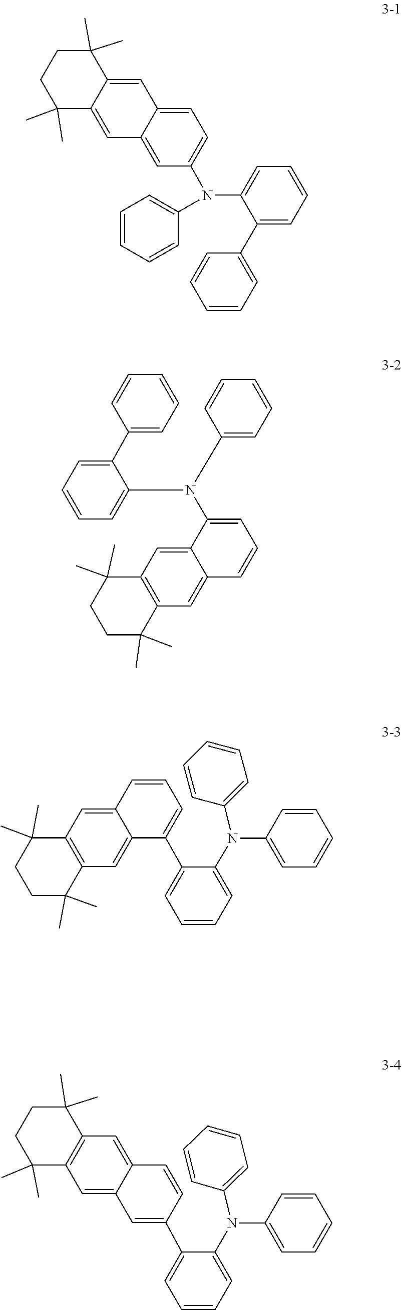 [SMILES: CC1(C)CCC(C)(C)c2cc3cc(N(c4ccccc4)c4ccccc4-c4ccccc4)ccc3cc21 ; CC1(C)CCC(C)(C)c2cc3c(N(c4ccccc4)c4ccccc4-c4ccccc4)cccc3cc21 ; CC1(C)CCC(C)(C)c2cc3c(-c4ccccc4N(c4ccccc4)c4ccccc4)cccc3cc21 ; CC1(C)CCC(C)(C)c2cc3cc(-c4ccccc4N(c4ccccc4)c4ccccc4)ccc3cc21]

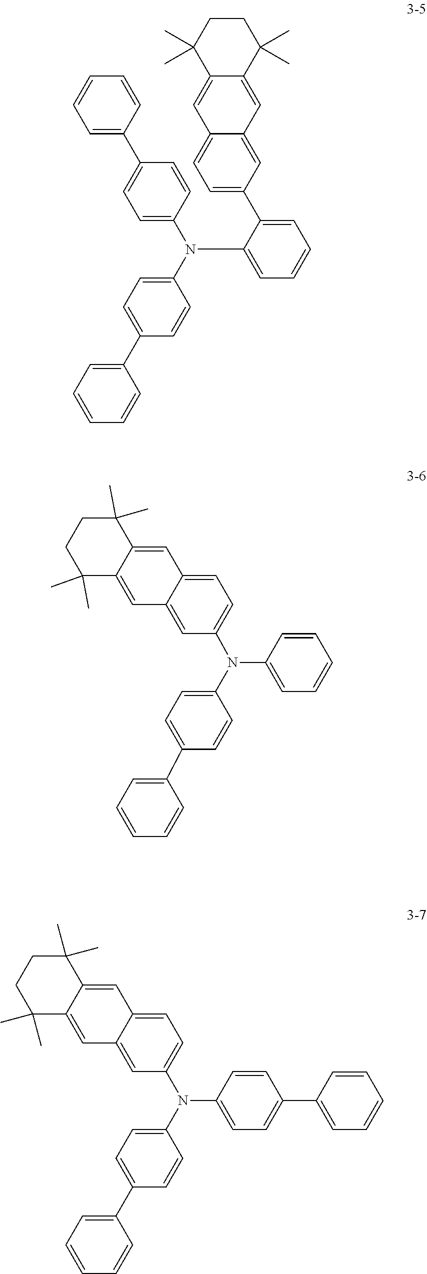 [SMILES: CC1(C)CCC(C)(C)c2cc3cc(-c4ccccc4N(c4ccc(-c5ccccc5)cc4)c4ccc(-c5ccccc5)cc4)ccc3cc21 ; CC1(C)CCC(C)(C)c2cc3cc(N(c4ccccc4)c4ccc(-c5ccccc5)cc4)ccc3cc21 ; CC1(C)CCC(C)(C)c2cc3cc(N(c4ccc(-c5ccccc5)cc4)c4ccc(-c5ccccc5)cc4)ccc3cc21]

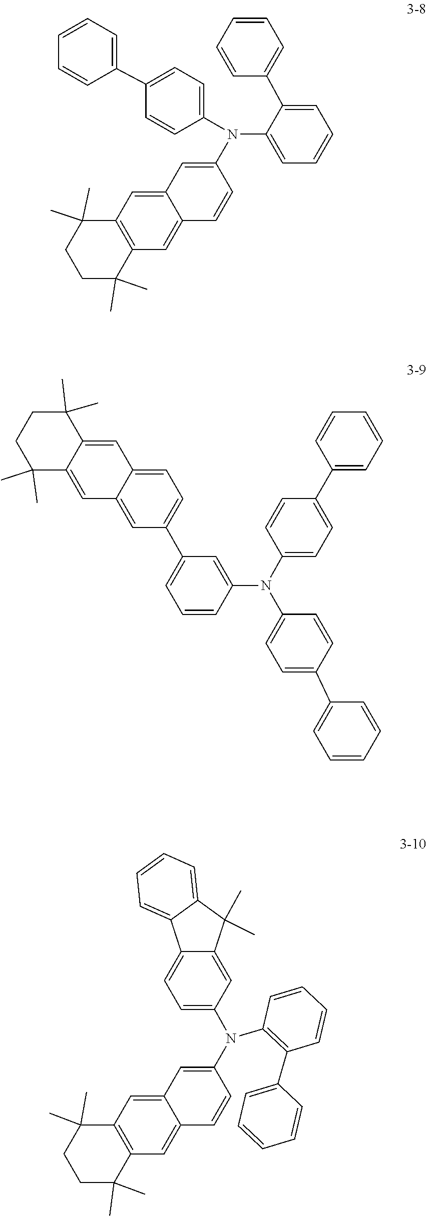 [SMILES: CC1(C)CCC(C)(C)c2cc3cc(N(c4ccc(-c5ccccc5)cc4)c4ccccc4-c4ccccc4)ccc3cc21 ; CC1(C)CCC(C)(C)c2cc3cc(-c4cccc(N(c5ccc(-c6ccccc6)cc5)c5ccc(-c6ccccc6)cc5)c4)ccc3cc21 ; CC1(C)CCC(C)(C)c2cc3cc(N(c4ccc5c(c4)C(C)(C)c4ccccc4-5)c4ccccc4-c4ccccc4)ccc3cc21]

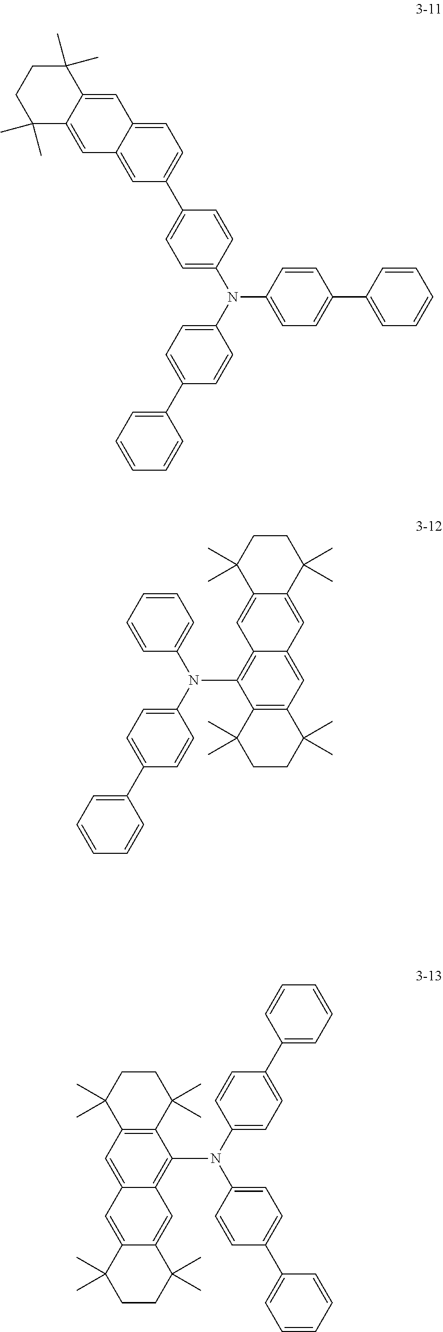 [SMILES: CC1(C)CCC(C)(C)c2cc3cc(-c4ccc(N(c5ccc(-c6ccccc6)cc5)c5ccc(-c6ccccc6)cc5)cc4)ccc3cc21 ; CC1(C)CCC(C)(C)c2cc3c(N(c4ccccc4)c4ccc(-c5ccccc5)cc4)c4c(cc3cc21)C(C)(C)CCC4(C)C ; CC1(C)CCC(C)(C)c2cc3c(N(c4ccc(-c5ccccc5)cc4)c4ccc(-c5ccccc5)cc4)c4c(cc3cc21)C(C)(C)CCC4(C)C]

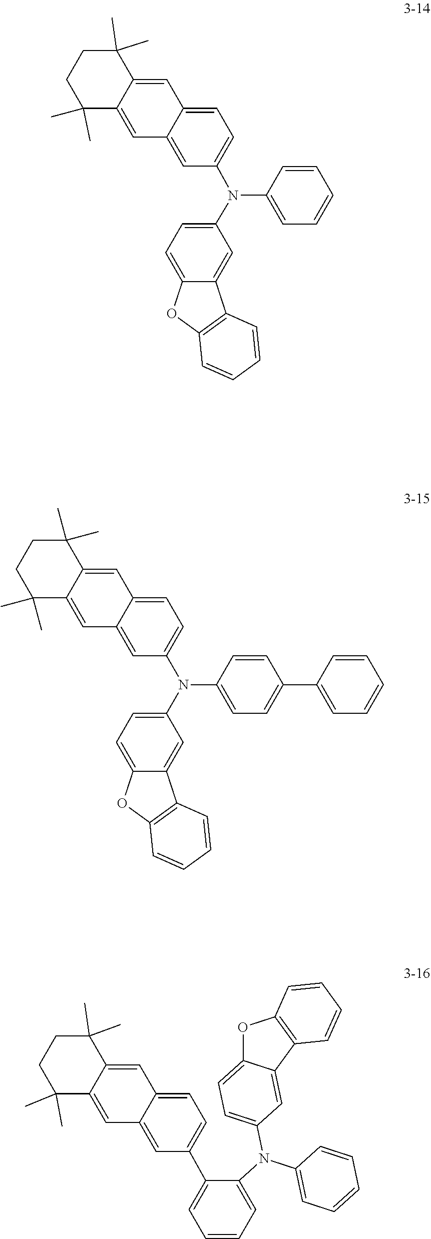 [SMILES: CC1(C)CCC(C)(C)c2cc3cc(N(c4ccccc4)c4ccc5oc6ccccc6c5c4)ccc3cc21 ; CC1(C)CCC(C)(C)c2cc3cc(N(c4ccc(-c5ccccc5)cc4)c4ccc5oc6ccccc6c5c4)ccc3cc21 ; CC1(C)CCC(C)(C)c2cc3cc(-c4ccccc4N(c4ccccc4)c4ccc5oc6ccccc6c5c4)ccc3cc21]

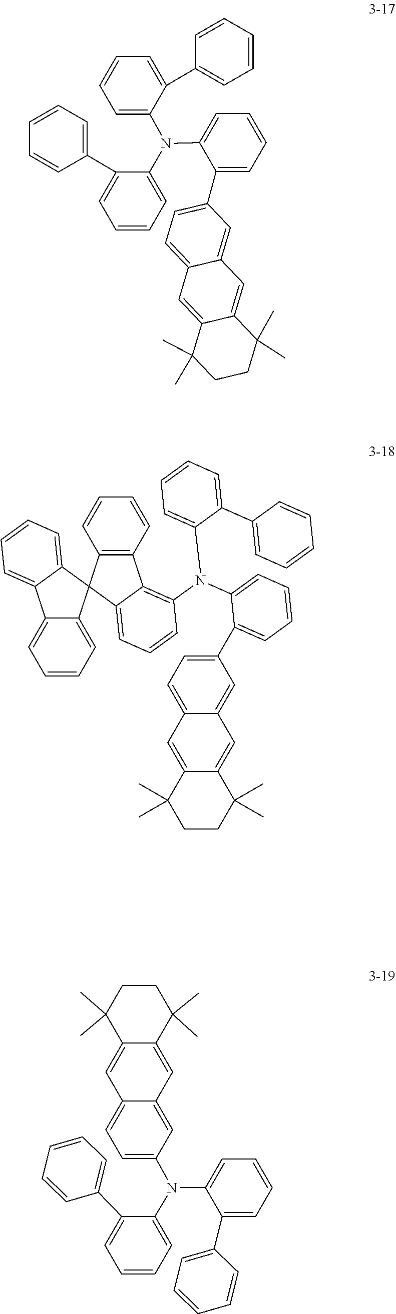 [SMILES: CC1(C)CCC(C)(C)c2cc3cc(-c4ccccc4N(c4ccccc4-c4ccccc4)c4ccccc4-c4ccccc4)ccc3cc21 ; CC1(C)CCC(C)(C)c2cc3cc(-c4ccccc4N(c4ccccc4-c4ccccc4)c4cccc5c4-c4ccccc4C54c5ccccc5-c5ccccc54)ccc3cc21 ; CC1(C)CCC(C)(C)c2cc3cc(N(c4ccccc4-c4ccccc4)c4ccccc4-c4ccccc4)ccc3cc21]

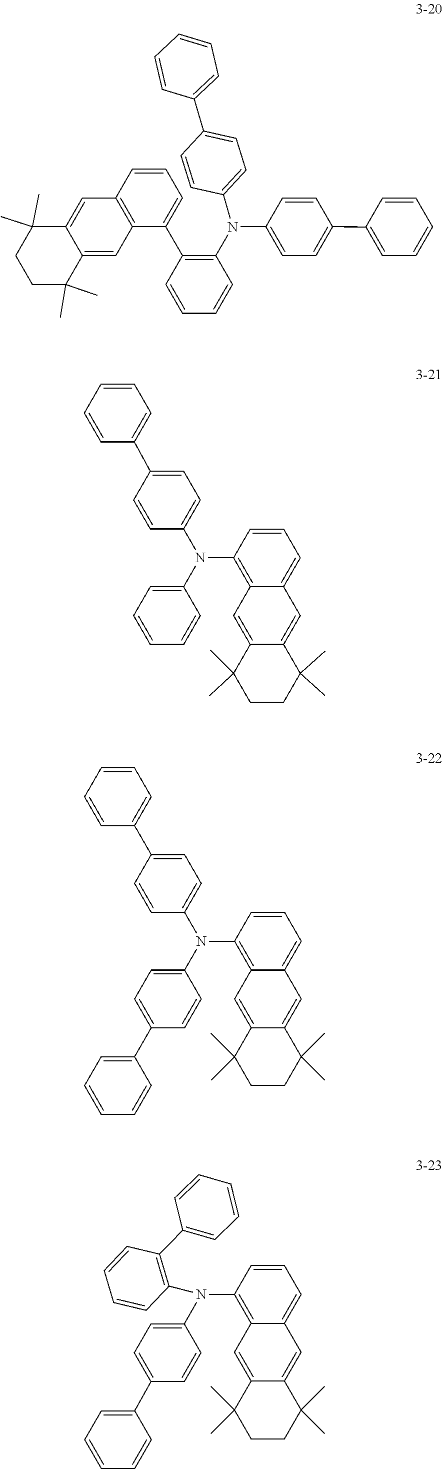 [SMILES: CC1(C)CCC(C)(C)c2cc3c(-c4ccccc4N(c4ccc(-c5ccccc5)cc4)c4ccc(-c5ccccc5)cc4)cccc3cc21 ; CC1(C)CCC(C)(C)c2cc3c(N(c4ccccc4)c4ccc(-c5ccccc5)cc4)cccc3cc21 ; CC1(C)CCC(C)(C)c2cc3c(N(c4ccc(-c5ccccc5)cc4)c4ccc(-c5ccccc5)cc4)cccc3cc21 ; CC1(C)CCC(C)(C)c2cc3c(N(c4ccc(-c5ccccc5)cc4)c4ccccc4-c4ccccc4)cccc3cc21]

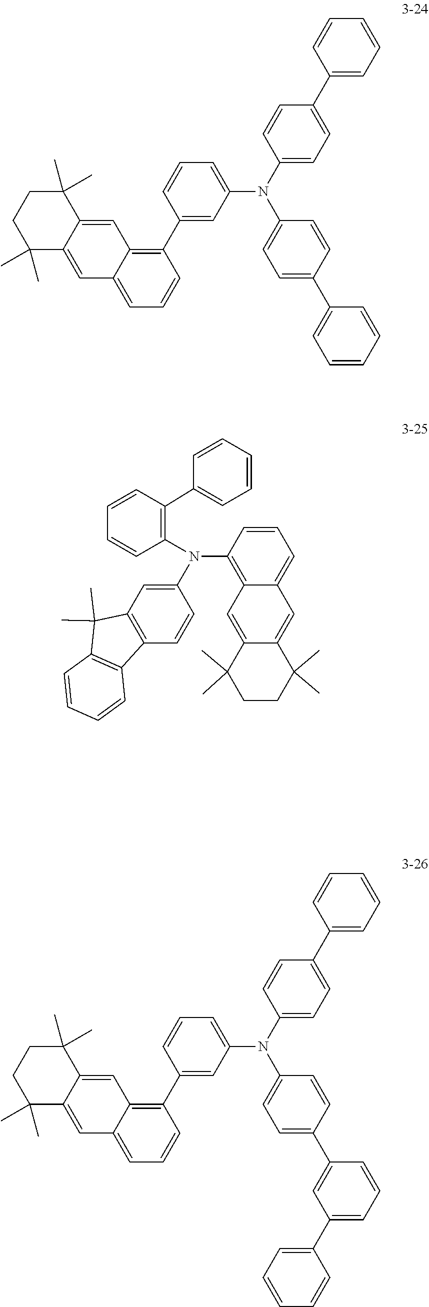

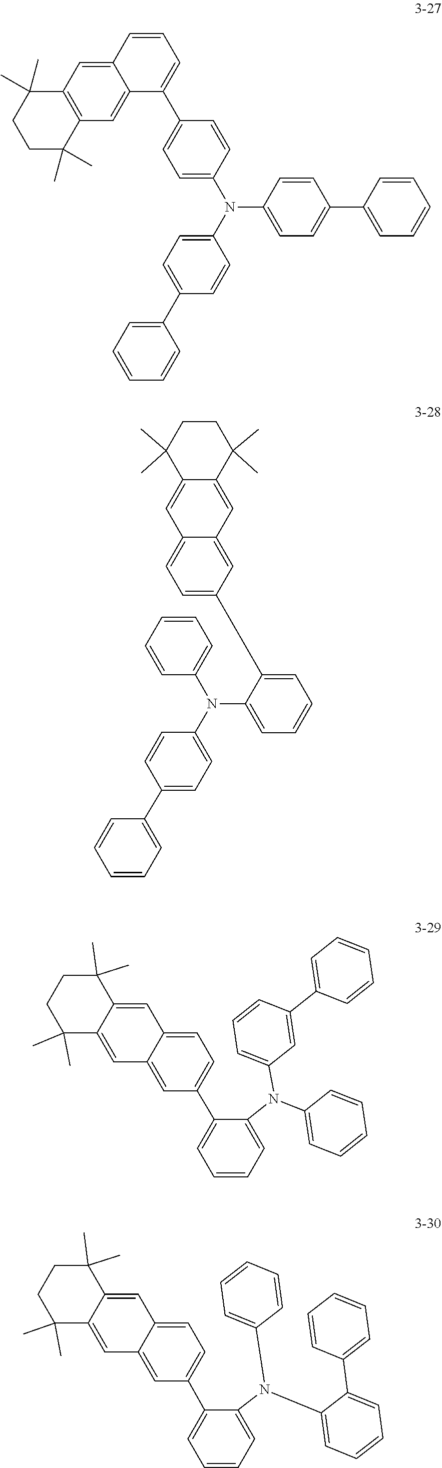

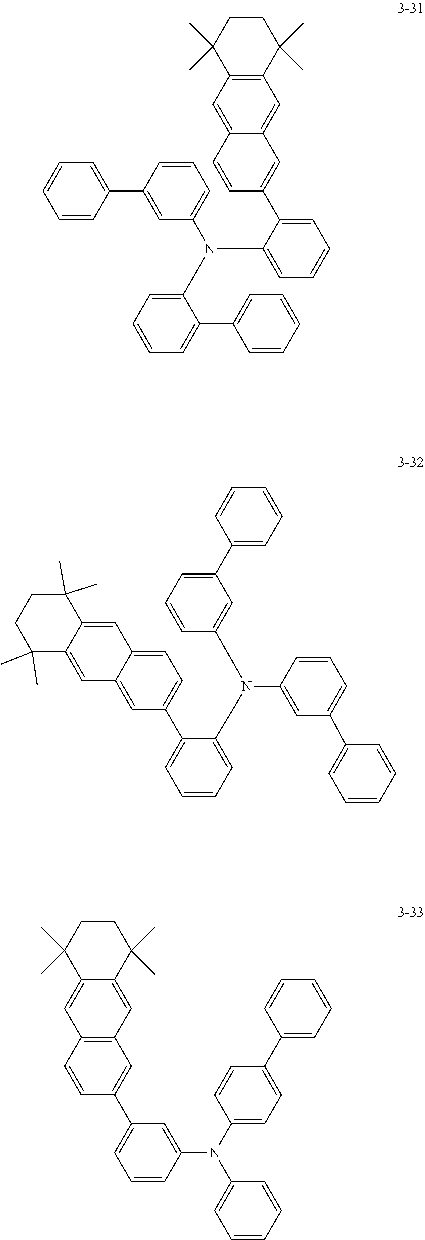 [SMILES: CC1(C)CCC(C)(C)c2cc3cc(-c4ccccc4N(c4cccc(-c5ccccc5)c4)c4ccccc4-c4ccccc4)ccc3cc21 ; CC1(C)CCC(C)(C)c2cc3cc(-c4ccccc4N(c4cccc(-c5ccccc5)c4)c4cccc(-c5ccccc5)c4)ccc3cc21 ; CC1(C)CCC(C)(C)c2cc3cc(-c4cccc(N(c5ccccc5)c5ccc(-c6ccccc6)cc5)c4)ccc3cc21]

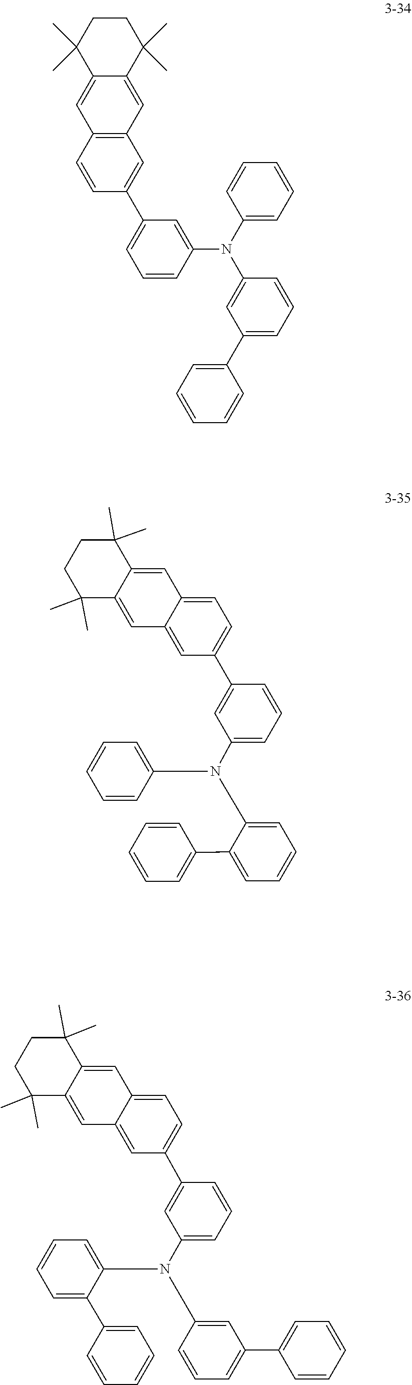 [SMILES: CC1(C)CCC(C)(C)c2cc3cc(-c4cccc(N(c5ccccc5)c5cccc(-c6ccccc6)c5)c4)ccc3cc21 ; CC1(C)CCC(C)(C)c2cc3cc(-c4cccc(N(c5ccccc5)c5ccccc5-c5ccccc5)c4)ccc3cc21 ; CC1(C)CCC(C)(C)c2cc3cc(-c4cccc(N(c5cccc(-c6ccccc6)c5)c5ccccc5-c5ccccc5)c4)ccc3cc21]

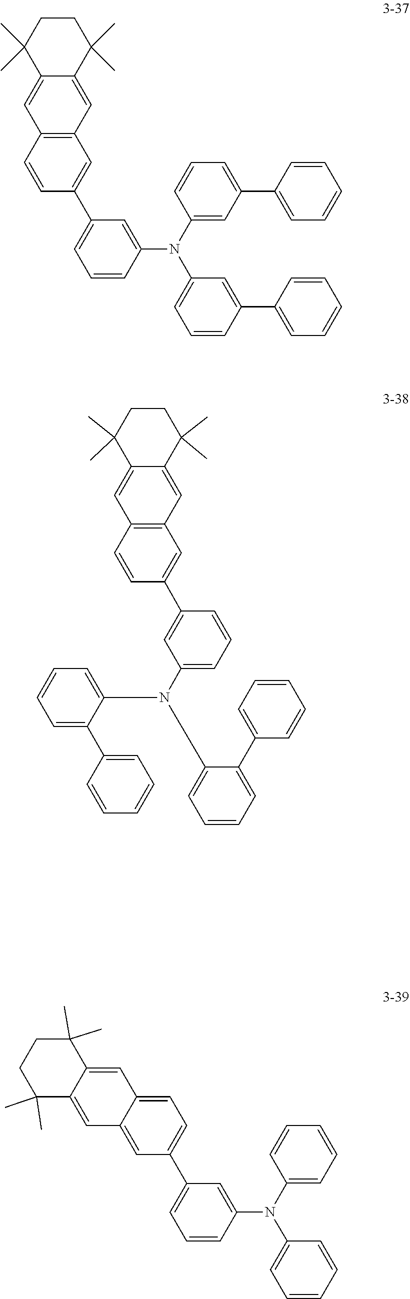 [SMILES: CC1(C)CCC(C)(C)c2cc3cc(-c4cccc(N(c5cccc(-c6ccccc6)c5)c5cccc(-c6ccccc6)c5)c4)ccc3cc21 ; CC1(C)CCC(C)(C)c2cc3cc(-c4cccc(N(c5ccccc5-c5ccccc5)c5ccccc5-c5ccccc5)c4)ccc3cc21 ; CC1(C)CCC(C)(C)c2cc3cc(-c4cccc(N(c5ccccc5)c5ccccc5)c4)ccc3cc21]

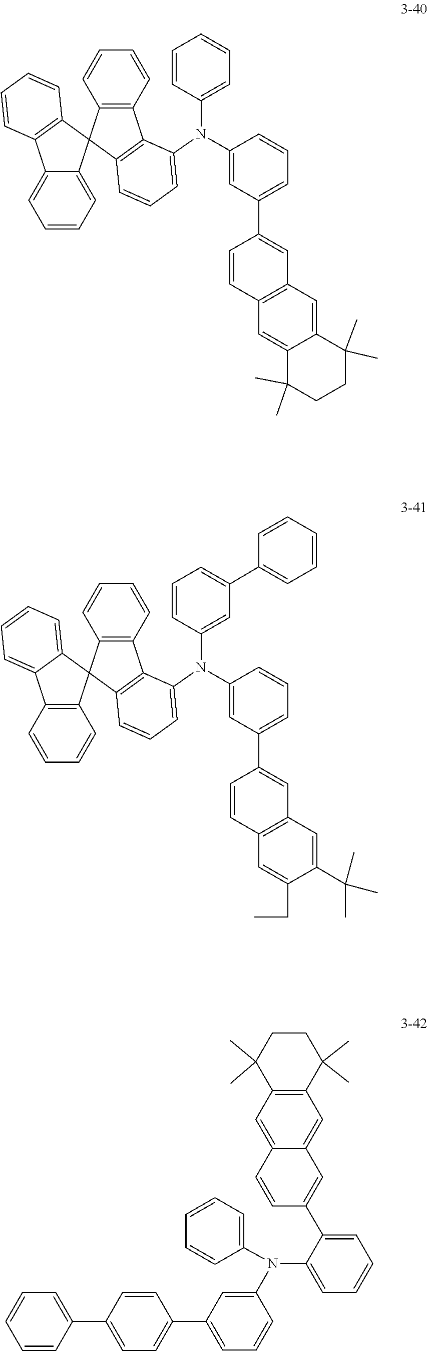 [SMILES: CC1(C)CCC(C)(C)c2cc3cc(-c4cccc(N(c5ccccc5)c5cccc6c5-c5ccccc5C65c6ccccc6-c6ccccc65)c4)ccc3cc21 ; CCc1cc2ccc(-c3cccc(N(c4cccc(-c5ccccc5)c4)c4cccc5c4-c4ccccc4C54c5ccccc5-c5ccccc54)c3)cc2cc1C(C)(C)C ; CC1(C)CCC(C)(C)c2cc3cc(-c4ccccc4N(c4ccccc4)c4cccc(-c5ccc(-c6ccccc6)cc5)c4)ccc3cc21]

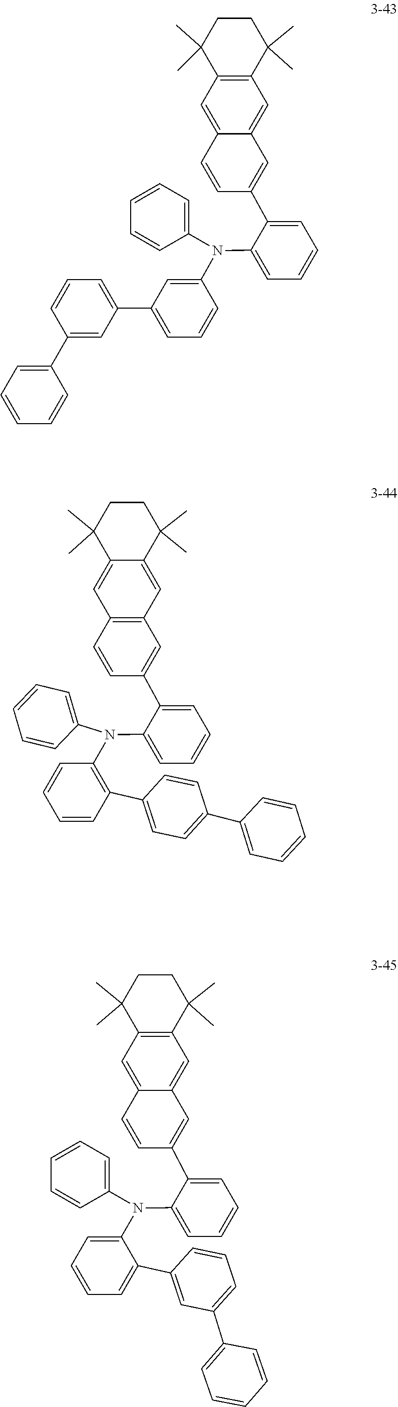 [SMILES: CC1(C)CCC(C)(C)c2cc3cc(-c4ccccc4N(c4ccccc4)c4cccc(-c5cccc(-c6ccccc6)c5)c4)ccc3cc21 ; CC1(C)CCC(C)(C)c2cc3cc(-c4ccccc4N(c4ccccc4)c4ccccc4-c4ccc(-c5ccccc5)cc4)ccc3cc21 ; CC1(C)CCC(C)(C)c2cc3cc(-c4ccccc4N(c4ccccc4)c4ccccc4-c4cccc(-c5ccccc5)c4)ccc3cc21]

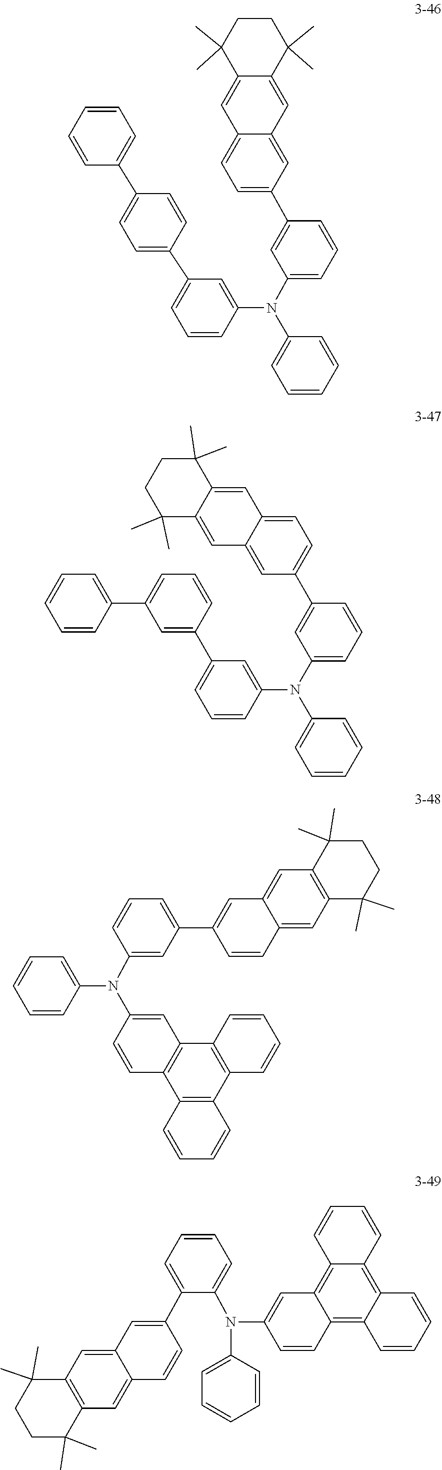

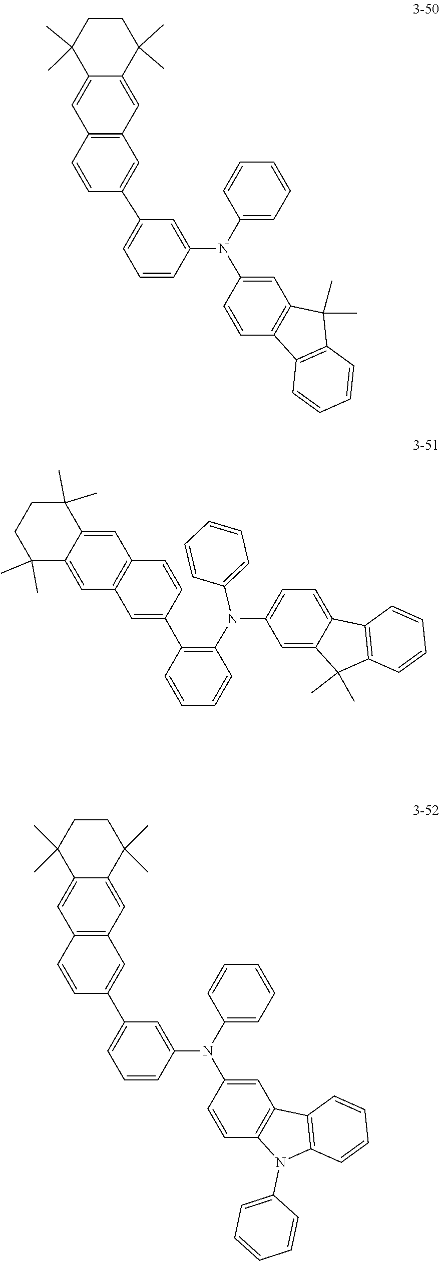

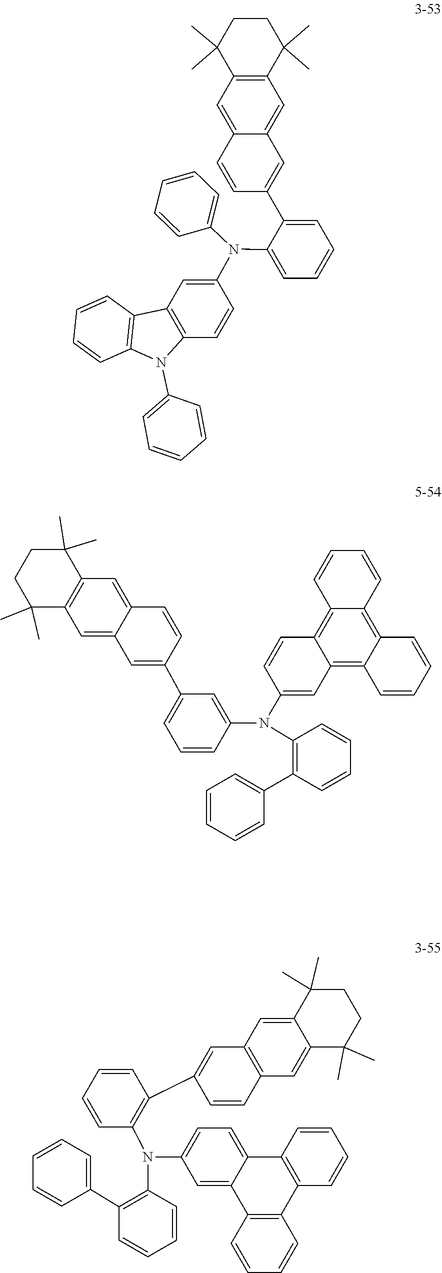 [SMILES: CC1(C)CCC(C)(C)c2cc3cc(-c4ccccc4N(c4ccccc4)c4ccc5c(c4)c4ccccc4n5-c4ccccc4)ccc3cc21 ; CC1(C)CCC(C)(C)c2cc3cc(-c4cccc(N(c5ccc6c7ccccc7c7ccccc7c6c5)c5ccccc5-c5ccccc5)c4)ccc3cc21 ; CC1(C)CCC(C)(C)c2cc3cc(-c4ccccc4N(c4ccc5c6ccccc6c6ccccc6c5c4)c4ccccc4-c4ccccc4)ccc3cc21]

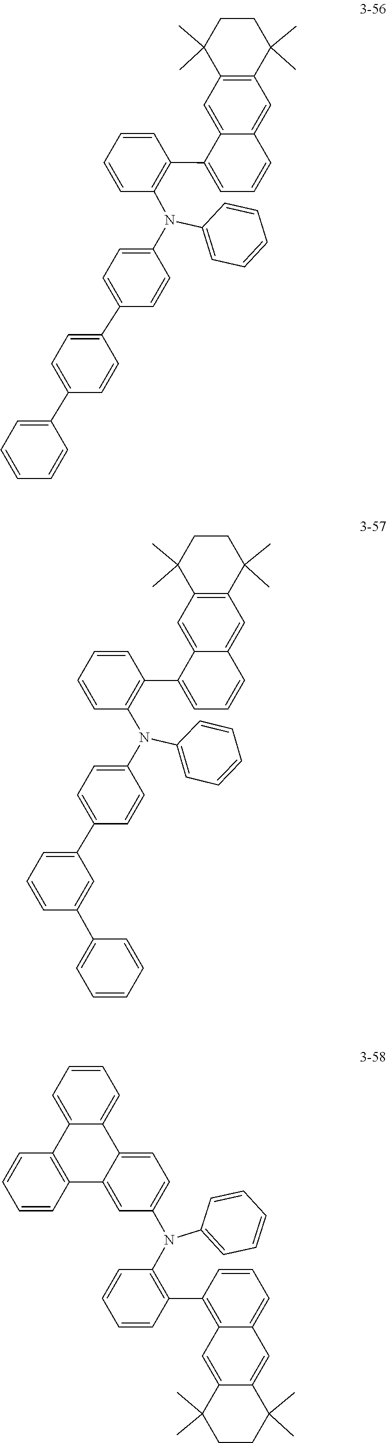 [SMILES: CC1(C)CCC(C)(C)c2cc3c(-c4ccccc4N(c4ccccc4)c4ccc(-c5ccc(-c6ccccc6)cc5)cc4)cccc3cc21 ; CC1(C)CCC(C)(C)c2cc3c(-c4ccccc4N(c4ccccc4)c4ccc(-c5cccc(-c6ccccc6)c5)cc4)cccc3cc21 ; CC1(C)CCC(C)(C)c2cc3c(-c4ccccc4N(c4ccccc4)c4ccc5c6ccccc6c6ccccc6c5c4)cccc3cc21]

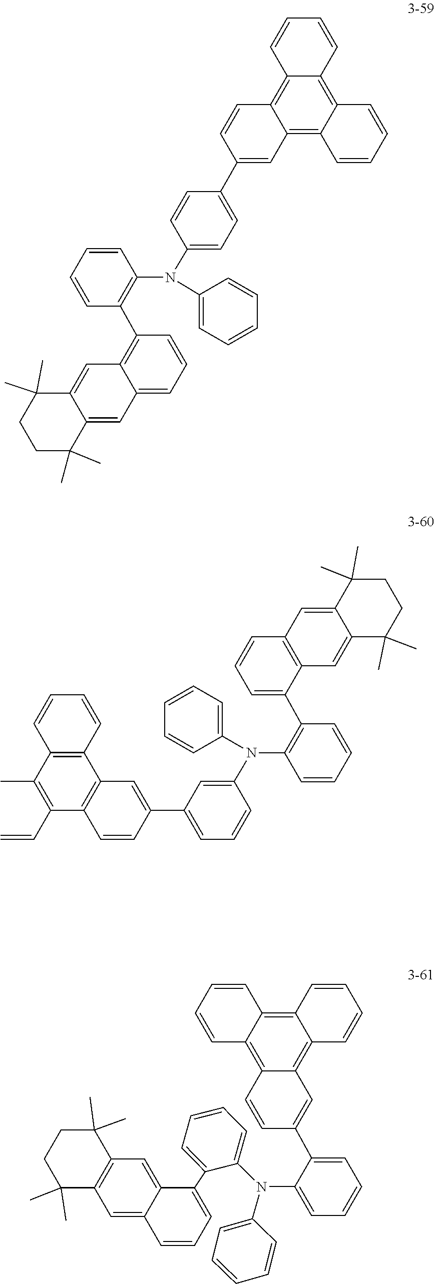

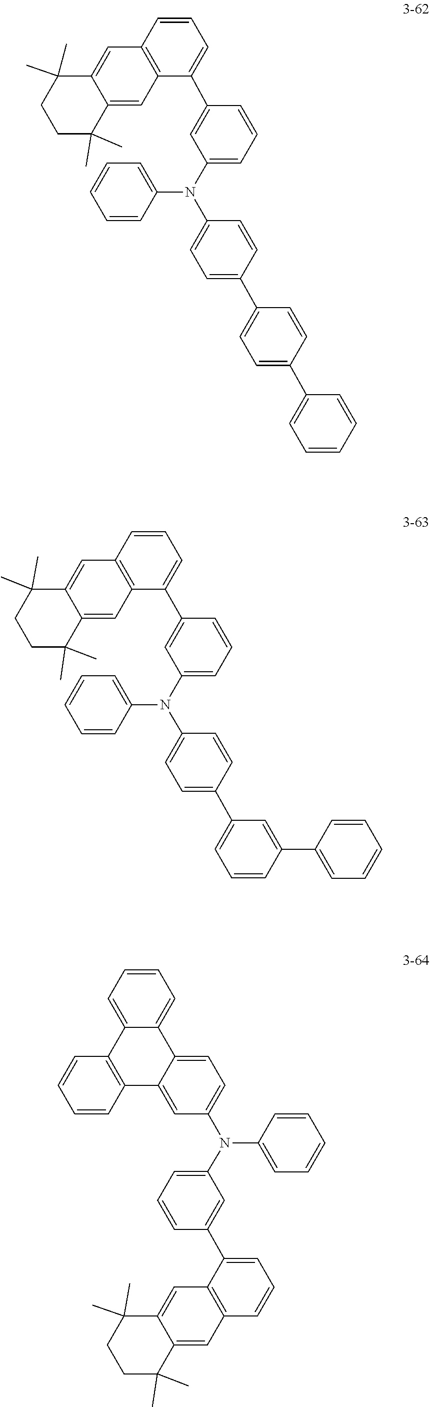 [SMILES: CC1(C)CCC(C)(C)c2cc3c(-c4cccc(N(c5ccccc5)c5ccc(-c6ccc(-c7ccccc7)cc6)cc5)c4)cccc3cc21 ; CC1(C)CCC(C)(C)c2cc3c(-c4cccc(N(c5ccccc5)c5ccc(-c6cccc(-c7ccccc7)c6)cc5)c4)cccc3cc21 ; CC1(C)CCC(C)(C)c2cc3c(-c4cccc(N(c5ccccc5)c5ccc6c7ccccc7c7ccccc7c6c5)c4)cccc3cc21]

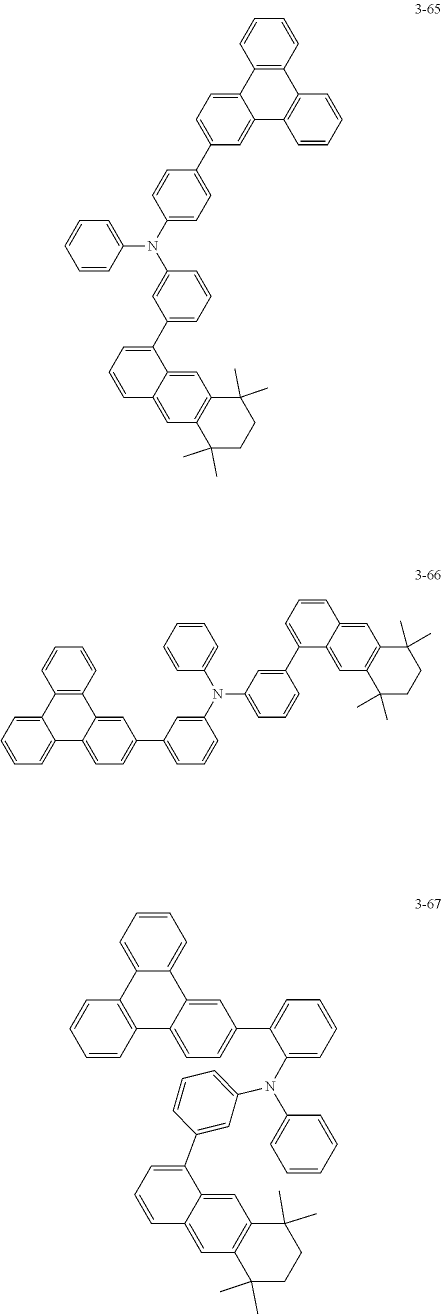 [SMILES: CC1(C)CCC(C)(C)c2cc3c(-c4cccc(N(c5ccccc5)c5ccc(-c6ccc7c8ccccc8c8ccccc8c7c6)cc5)c4)cccc3cc21 ; CC1(C)CCC(C)(C)c2cc3c(-c4cccc(N(c5ccccc5)c5cccc(-c6ccc7c8ccccc8c8ccccc8c7c6)c5)c4)cccc3cc21 ; CC1(C)CCC(C)(C)c2cc3c(-c4cccc(N(c5ccccc5)c5ccccc5-c5ccc6c7ccccc7c7ccccc7c6c5)c4)cccc3cc21]

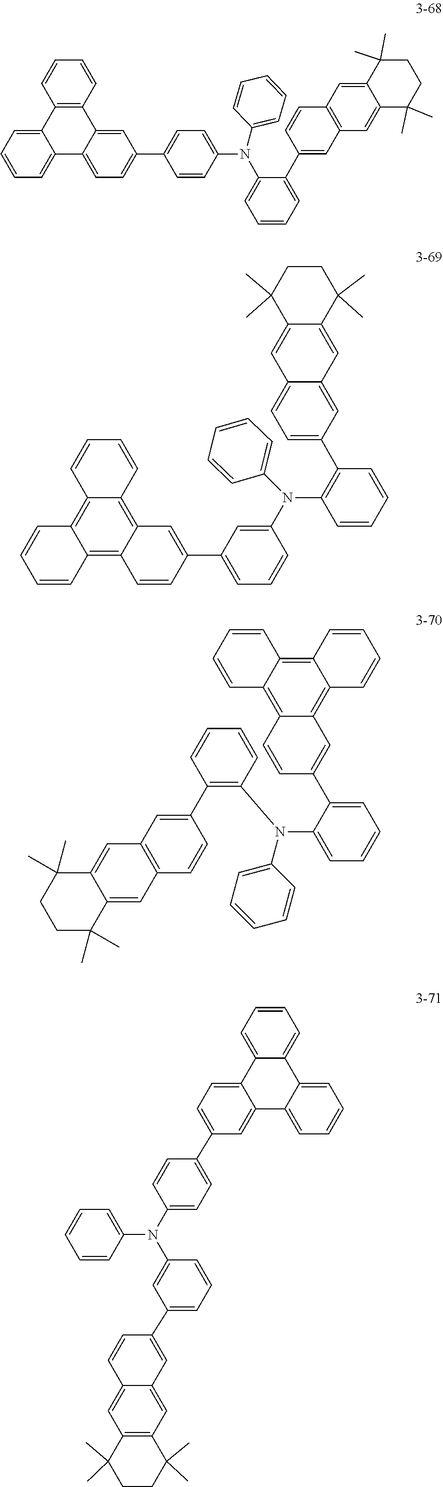

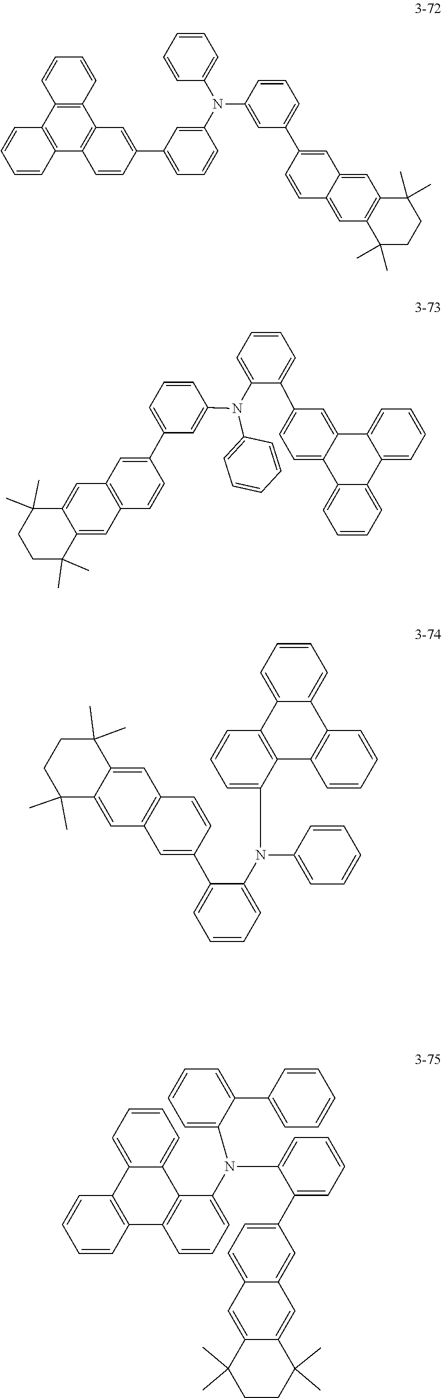

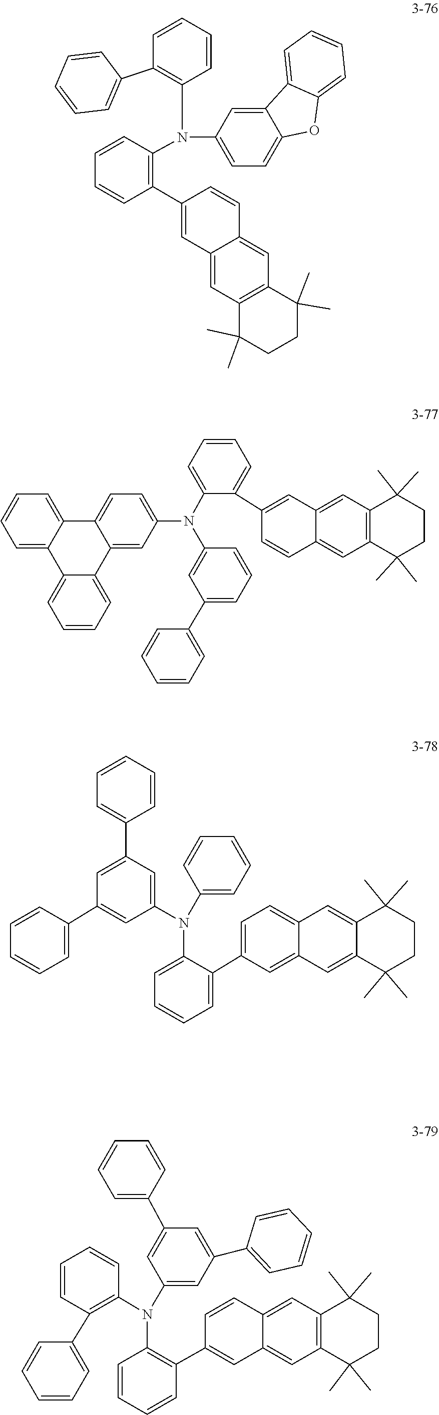 [SMILES: CC1(C)CCC(C)(C)c2cc3cc(-c4ccccc4N(c4ccc5oc6ccccc6c5c4)c4ccccc4-c4ccccc4)ccc3cc21 ; CC1(C)CCC(C)(C)c2cc3cc(-c4ccccc4N(c4cccc(-c5ccccc5)c4)c4ccc5c6ccccc6c6ccccc6c5c4)ccc3cc21 ; CC1(C)CCC(C)(C)c2cc3cc(-c4ccccc4N(c4ccccc4)c4cc(-c5ccccc5)cc(-c5ccccc5)c4)ccc3cc21 ; CC1(C)CCC(C)(C)c2cc3cc(-c4ccccc4N(c4cc(-c5ccccc5)cc(-c5ccccc5)c4)c4ccccc4-c4ccccc4)ccc3cc21]

Despite the relatively-early discovery of SOP, its mechanism is still not fully understood. Significant dipole moment of individual molecules is a necessary, but not sufficient condition. Shape of the molecule, specific short-range interactions, and processing conditions seem to be important factors affecting SOP; but it is currently not possible to predict even the direction of polarization by simulating only a single molecule.

The basic design principle for polarized aryl amine compounds is to include at least one electron deficient or sufficient functional groups like heteroatom- or alkyl-containing condensed polycyclic organic matter in the molecular structure. In order to choose molecular structures that have a higher likelihood of showing strong SOP in the preferred direction, one can use molecular dynamics simulations of vacuum deposition process.

In some non-limiting embodiments of the composition comprising a mixture of a first compound and a second compound disclosed herein, the first compound and the second compound both have a chemical structure given by Formula 1, in some non-limiting embodiments both have a chemical structure given by Formula 2, in some non-limiting embodiments both have a chemical structure given by Formula 3, and in some non-limiting embodiments the first and second compounds are combinations of Formula 1 and Formula 2, Formula 1 and Formula 3, or Formula 2 and Formula 3.

### 3. Thin Films

There is further provided herein a thin film comprising a mixture of a first compound and a second compound; wherein the first compound has a different chemical structure than the second compound; wherein the first compound and the second compound have molecular weights between 300 and 1000; wherein the first compound and the second compound have glass transition temperatures greater than 105° C.; wherein the first compound and the second compound each comprise one or more aryl amine groups; wherein a thin film formed from the first compound has a spontaneous orientation polarization SOP-1; wherein a thin film formed from the second compound has a spontaneous orientation polarization SOP-2; and the absolute value of the difference between SOP-1 and SOP-2 is greater than or equal to 10 mV/nm.

Specific embodiments for the first compound and second compounds, and mixtures of the compounds, are the same as those disclosed above herein.

In some non-limiting embodiments, a thin film formed from the first compound has a spontaneous orientation polarization SOP-1 between −50 mV/nm and +150 mV/nm, in some non-limiting embodiments between −40 mV/nm and +140 mV/nm, in some non-limiting embodiments between −30 mV/nm and +130 mV/nm, in some non-limiting embodiments between −20 mV/nm and +120 mV/nm, in some non-limiting embodiments between −10 mV/nm and +110 mV/nm, in some non-limiting embodiments between 0 mV/nm and 100 mV/nm, in some non-limiting embodiments between 10 mV/nm and 80 mV/nm, and in some non-limiting embodiments between 20 mV/nm and 60 mV/nm.

In some non-limiting embodiments, a thin film formed from the second compound has a spontaneous orientation polarization SOP-2 between −50 mV/nm and +150 mV/nm, in some non-limiting embodiments between −40 mV/nm and +140 mV/nm, in some non-limiting embodiments between −30 mV/nm and +130 mV/nm, in some non-limiting embodiments between −20 mV/nm and +120 mV/nm, in some non-limiting embodiments between −10 mV/nm and +110 mV/nm, in some non-limiting embodiments between 0 mV/nm and 100 mV/nm, in some non-limiting embodiments between 10 mV/nm and 80 mV/nm, and in some non-limiting embodiments between 20 mV/nm and 60 mV/nm.

In some non-limiting embodiments, the absolute value of the difference between SOP-1 and SOP-2 is greater than or equal to 2 mV/nm, in some non-limiting embodiments greater than or equal to 4 mV/nm, in some non-limiting embodiments greater than or equal to 6 mV/nm, in some non-limiting embodiments greater than or equal to 8 mV/nm, in some non-limiting embodiments greater than or equal to 10 mV/nm, in some non-limiting embodiments greater than or equal to 12 mV/nm, in some non-limiting embodiments greater than or equal to 14 mV/nm, in some non-limiting embodiments greater than or equal to 16 mV/nm, in some non-limiting embodiments greater than or equal to 18 mV/nm, in some non-limiting embodiments greater than or equal to 20 mV/nm, in some non-limiting embodiments greater than or equal to 25 mV/nm, in some non-limiting embodiments greater than or equal to 30 mV/nm, in some non-limiting embodiments greater than or equal to 35 mV/nm, and in some non-limiting embodiments greater than or equal to 40 mV/nm.

In some non-limiting embodiments of the thin films disclosed herein, the thin films have a thickness between 1 nm and 200 nm, in some non-limiting embodiments between 2 nm and 100 nm, in some non-limiting embodiments between 4 nm and 50 nm, in some non-limiting embodiments between 5 nm and 20 nm.

The methods by which the thin film may be generated are not limited and would generally be known by one having skill in the art. In some non-limiting embodiments; dry film-forming methods such as vacuum deposition, sputtering, plasma, ion plating methods, etc., or wet film-forming methods such as ink jet printing, nozzle printing, slot coating, spin coating, dip coating, flow coating methods, etc., can be used. When using a wet film-forming method, a thin film is formed by dissolving or dispersing the mixture in a suitable solvent, such as ethanol, chloroform, tetrahydrofuran, dioxane, etc. The solvents are not particularly limited as long as the mixture is soluble or dispersible in the solvents, which do not cause any problems in forming the targeted thin film.

### 4. Organic Electronic Device

There is further provided herein an organic electronic device comprising two or more layers wherein the first of the two or more layers is an emissive layer comprising one or more organic host compounds and one or more dopant compounds; wherein the second of the two or more layers is an electron blocking layer comprising a mixture of a first compound and a second compound; wherein the first compound has a different chemical structure than the second compound; wherein the first compound and the second compound each comprise one or more aryl amine groups; wherein a thin film formed from the first compound has a spontaneous orientation polarization SOP-1; wherein a thin film formed from the second compound has a spontaneous orientation polarization SOP-2; wherein the absolute value of the difference between SOP-1 and SOP-2 is greater than or equal to 10 mV/nm; such that the emissive layer has a spontaneous orientation polarization SOP-EML, the electron blocking layer has a spontaneous orientation polarization SOP-EBL; and the absolute value of the difference between SOP-EML and SOP-EBL is less than or equal to 25 mV/nm.

Organic electronic devices that may benefit from having one or more layers comprising the compounds and layers described herein include, but are not limited to, (1) devices that convert electrical energy into radiation (e.g., a light-emitting diode, light emitting diode display, diode laser, or lighting panel), (2) devices that detect a signal using an electronic process (e.g., a photodetector, a photoconductive cell, a photoresistor, a photoswitch, a phototransistor, a phototube, an infrared (“IR”) detector, or a biosensors), (3) devices that convert radiation into electrical energy (e.g., a photovoltaic device or solar cell), (4) devices that convert light of one wavelength to light of a longer wavelength, (e.g., a down-converting phosphor device); (5) devices that include one or more electronic components that include one or more organic semiconductor layers (e.g., a transistor or diode), or any combination of devices in items (1) through (5).

In some non-limiting embodiments, the organic electronic device includes two or more layers wherein the first of the two or more layers is an emissive layer comprising one or more organic host compounds and one or more dopant compounds, and wherein the second of the two or more layers is an electron blocking layer comprising a mixture of a first compound and a second compound as disclosed herein.

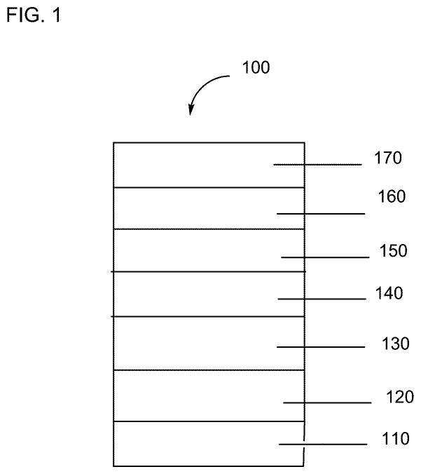

One illustration of an organic electronic device structure is shown in FIG. 1. The device 100 has a first electrical contact layer, an anode layer 110 and a second electrical contact layer, a cathode layer 170, and a photoactive layer (“EML”) 150 between them. Adjacent to the anode is a hole injection layer (“HIL”) 120. Adjacent to the hole injection layer is a hole transport layer (“HTL”) 130, comprising a hole transport material. Adjacent to the hole transport layer is the electron blocking layer (“EBL”) 140, comprising a mixture of a first compound and a second compound as disclosed herein. Adjacent to the cathode may be an electron transport layer (“ETL”) 160, comprising an electron transport material. As an option, devices may use one or more additional hole injection or hole transport layers (not shown) next to the anode 110 and/or one or more additional electron injection layer (“EIL”) or electron transport layer (not shown) next to the cathode 170. As a further option, devices may have an anti-quenching layer (not shown) between the photoactive layer 150 and the electron transport layer 160.

Layers 120 through 160, and any additional layers between them, are individually and collectively referred to as the active layers. In some non-limiting embodiments, the photoactive layer is pixelated. In such a device, layer 150 would be divided into pixel or subpixel units which are repeated over the layer. Each of the pixel or subpixel units represents a different color. In some embodiments, the subpixel units are for red, green, and blue. In some non-limiting embodiments, three subpixel units are used. In some non-limiting embodiments, more than three subpixel units may be used.

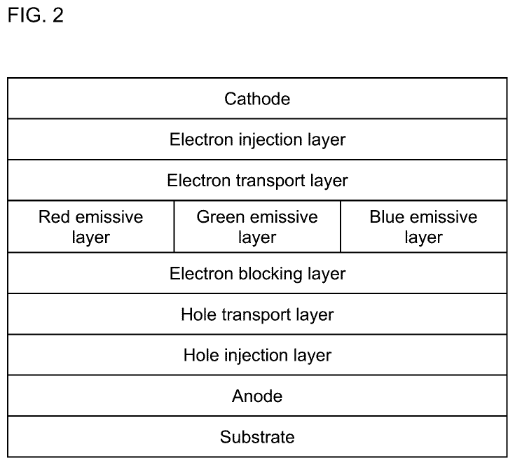

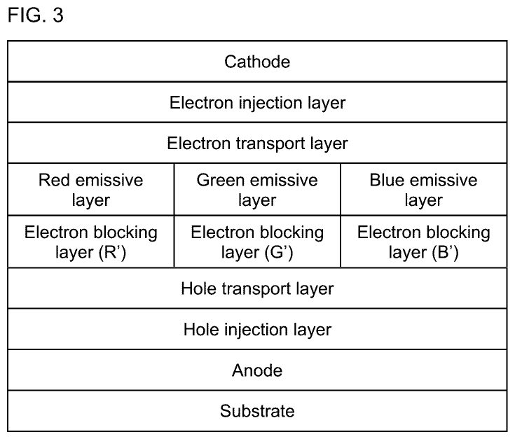

In some non-limiting embodiments, the electron blocking layer is common among red, green, and blue pixels as illustrated in FIG. 2. In some non-limiting embodiments, each subpixel has a unique electron blocking layer as illustrated in FIG. 3.

In some non-limiting embodiments, the different layers have the following range of thicknesses: anode 110, 50-500 nm, in some non-limiting embodiments, 100-200 nm; hole injection layer 120, 5-200 nm, in some non-limiting embodiments, 20-100 nm; hole transport layer 130, 5-200 nm, in some non-limiting embodiments, 20-100 nm; electron blocking layer 140, 5-50 nm, in some non-limiting embodiments 5-25 nm, photoactive layer 150, 1-200 nm, in some non-limiting embodiments, 10-100 nm; electron transport layer 160, 5-200 nm, in some non-limiting embodiments, 10-100 nm; cathode 170, 10-500 nm, in some non-limiting embodiments, 15-100 nm. The location of the electron-hole recombination zone in the device, and thus the emission spectrum of the device, can be affected by the relative thickness of each layer. The desired ratio of layer thicknesses will depend on the exact nature of the materials used.

In some non-limiting embodiments, the mixture of a first compound and second compound as disclosed herein are useful in the electron blocking layer of an organic electronic device. Non-limiting embodiments of the first compound and second compound are the same as those disclosed elsewhere herein.

a. Photoactive Layer

In some non-limiting embodiments, the photoactive layer includes one or more organic host compounds and one or more dopant compounds. In some non-limiting embodiments, the photoactive layer includes only host and dopant compounds. In some non-limiting embodiments, minor amounts of other materials are present so long as they do not significantly change the function of the layer.

Dopants are well known and broadly disclosed in the patent literature and technical journals. Exemplary dopants include, but are not limited to, anthracenes, benzanthracenes, benz[de]anthracenes, chrysenes, pyrenes, triphenylenes, benzofluorenes, other polycyclic aromatics, and analogs having one or more heteroatoms. Exemplary dopants also include, but are not limited to, benzofurans, dibenzofurans, carbazoles, benzocarbazoles, carbazolocarbazoles, and azaborines. In some embodiments, the dopants have one or more diarylamino substituents. Dopants have been disclosed in, for example, U.S. Pat. Nos. 7,816,017, 8,465,848, 9,112,157, US 2006/0127698, US 2010/0032658, US 2018/0069182, US 2019/0058124, CA 3107010, EP 3109253, WO 2019003615, and WO 2019035268.

Further, in some non-limiting embodiments, dopants are selected from metalated complex compounds of iridium (Ir), osmium (Os), copper (Cu), and platinum (Pt). In some non-limiting embodiments, dopants are selected from ortho-metallated complex compounds of iridium (Ir), osmium (Os), copper (Cu), and platinum (Pt).

Host materials are also well known and broadly disclosed in the patent literature and technical journals. Exemplary hosts include, but are not limited to anthracenes, chrysenes, pyrenes, phenanthrenes, triphenylenes, phenanthrolines, naphthalenes, triazines, quinolines, isoquinolines, quinoxalines, phenylpyridines, benzodifurans, metal quinolinate complexes, indolocarbazoles, substituted derivatives thereof, and combinations thereof. A number of these host materials comprise one or more heteroatoms—either in the backbone of the host compound molecular structure or as the result of incorporation of heteroatom-containing substituents. In such circumstances, the host materials exhibit a net dipole moment.

A non-limiting collection of such host materials includes:

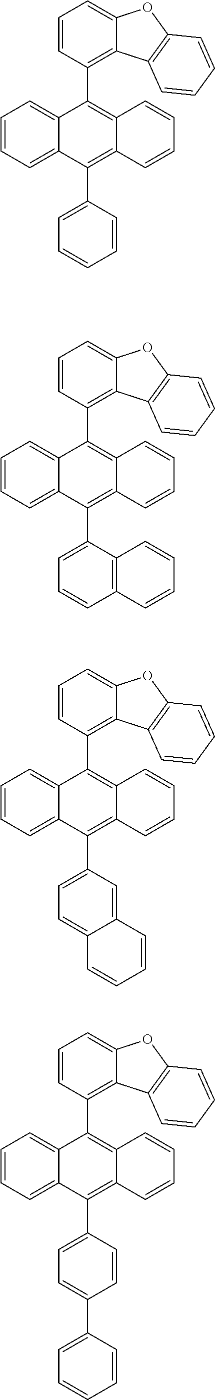 [SMILES: c1ccc(-c2c3ccccc3c(-c3cccc4oc5ccccc5c34)c3ccccc23)cc1 ; c1ccc2c(-c3c4ccccc4c(-c4cccc5oc6ccccc6c45)c4ccccc34)cccc2c1 ; c1ccc2cc(-c3c4ccccc4c(-c4cccc5oc6ccccc6c45)c4ccccc34)ccc2c1 ; c1ccc(-c2ccc(-c3c4ccccc4c(-c4cccc5oc6ccccc6c45)c4ccccc34)cc2)cc1]

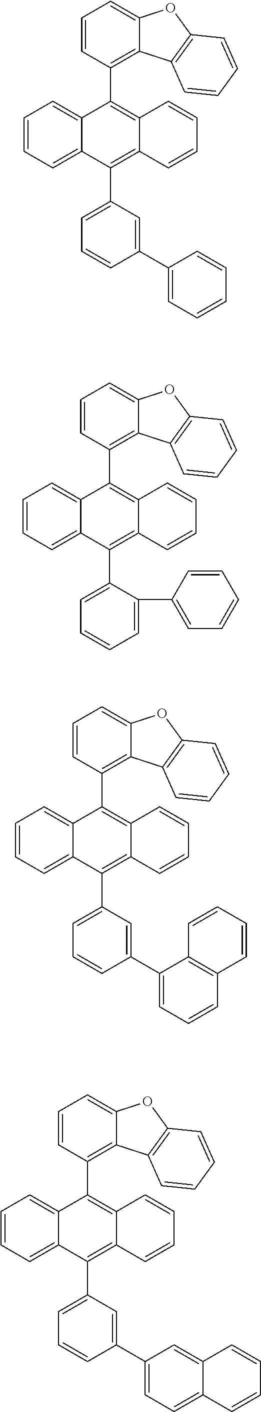 [SMILES: c1ccc(-c2cccc(-c3c4ccccc4c(-c4cccc5oc6ccccc6c45)c4ccccc34)c2)cc1 ; c1ccc(-c2ccccc2-c2c3ccccc3c(-c3cccc4oc5ccccc5c34)c3ccccc23)cc1 ; c1cc(-c2cccc3ccccc23)cc(-c2c3ccccc3c(-c3cccc4oc5ccccc5c34)c3ccccc23)c1 ; c1cc(-c2ccc3ccccc3c2)cc(-c2c3ccccc3c(-c3cccc4oc5ccccc5c34)c3ccccc23)c1]

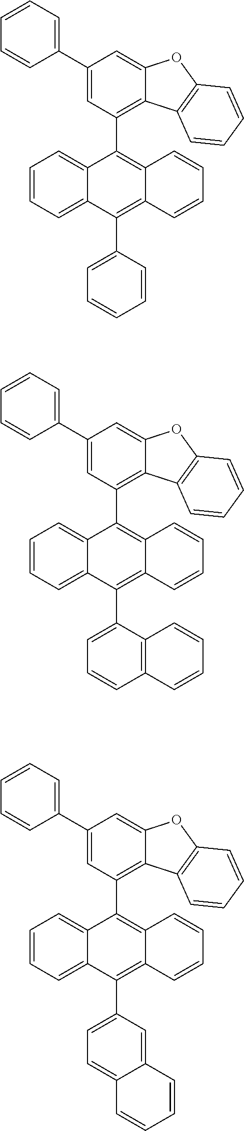 [SMILES: c1ccc(-c2cc(-c3c4ccccc4c(-c4ccccc4)c4ccccc34)c3c(c2)oc2ccccc23)cc1 ; c1ccc(-c2cc(-c3c4ccccc4c(-c4cccc5ccccc45)c4ccccc34)c3c(c2)oc2ccccc23)cc1 ; c1ccc(-c2cc(-c3c4ccccc4c(-c4ccc5ccccc5c4)c4ccccc34)c3c(c2)oc2ccccc23)cc1]

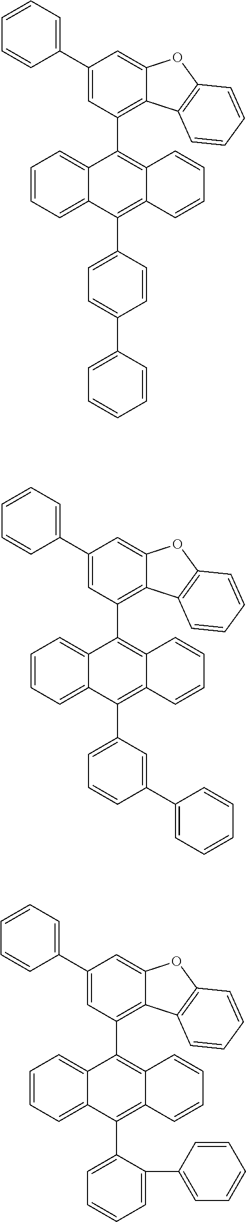 [SMILES: c1ccc(-c2ccc(-c3c4ccccc4c(-c4cc(-c5ccccc5)cc5oc6ccccc6c45)c4ccccc34)cc2)cc1 ; c1ccc(-c2cccc(-c3c4ccccc4c(-c4cc(-c5ccccc5)cc5oc6ccccc6c45)c4ccccc34)c2)cc1 ; c1ccc(-c2cc(-c3c4ccccc4c(-c4ccccc4-c4ccccc4)c4ccccc34)c3c(c2)oc2ccccc23)cc1]

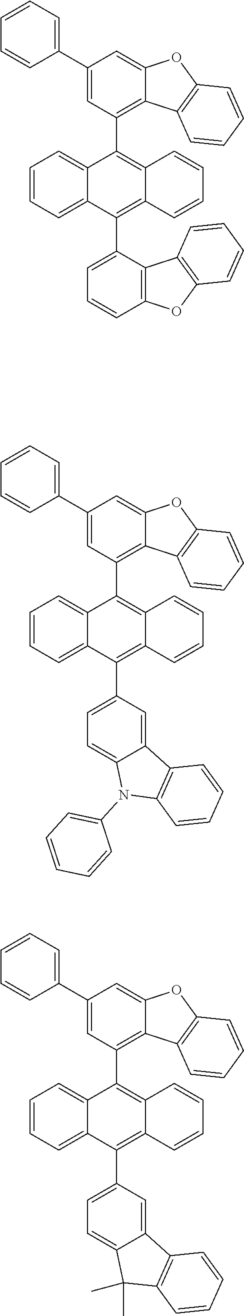 [SMILES: c1ccc(-c2cc(-c3c4ccccc4c(-c4cccc5oc6ccccc6c45)c4ccccc34)c3c(c2)oc2ccccc23)cc1 ; c1ccc(-c2cc(-c3c4ccccc4c(-c4ccc5c(c4)c4ccccc4n5-c4ccccc4)c4ccccc34)c3c(c2)oc2ccccc23)cc1 ; CC1(C)c2ccccc2-c2cc(-c3c4ccccc4c(-c4cc(-c5ccccc5)cc5oc6ccccc6c45)c4ccccc34)ccc21]

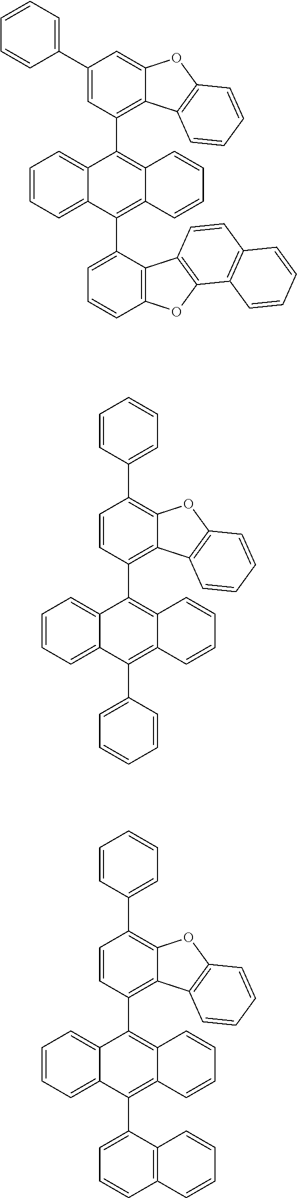 [SMILES: c1ccc(-c2cc(-c3c4ccccc4c(-c4cccc5oc6c7ccccc7ccc6c45)c4ccccc34)c3c(c2)oc2ccccc23)cc1 ; c1ccc(-c2c3ccccc3c(-c3ccc(-c4ccccc4)c4oc5ccccc5c34)c3ccccc23)cc1 ; c1ccc(-c2ccc(-c3c4ccccc4c(-c4cccc5ccccc45)c4ccccc34)c3c2oc2ccccc23)cc1]

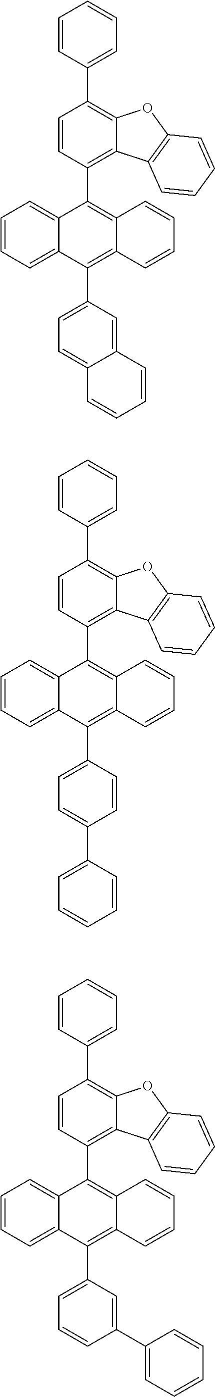 [SMILES: c1ccc(-c2ccc(-c3c4ccccc4c(-c4ccc5ccccc5c4)c4ccccc34)c3c2oc2ccccc23)cc1 ; c1ccc(-c2ccc(-c3c4ccccc4c(-c4ccc(-c5ccccc5)c5oc6ccccc6c45)c4ccccc34)cc2)cc1 ; c1ccc(-c2cccc(-c3c4ccccc4c(-c4ccc(-c5ccccc5)c5oc6ccccc6c45)c4ccccc34)c2)cc1]

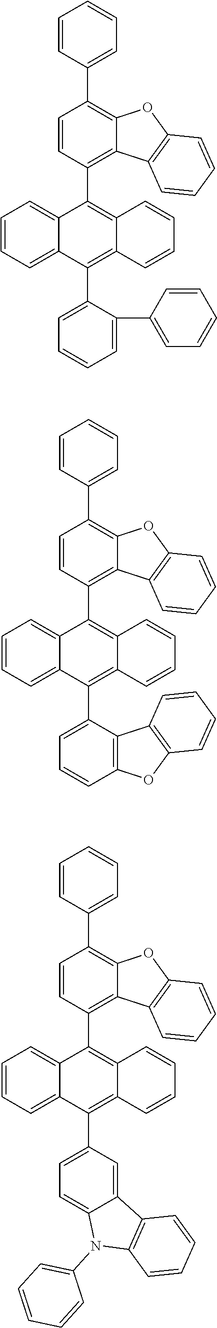 [SMILES: c1ccc(-c2ccccc2-c2c3ccccc3c(-c3ccc(-c4ccccc4)c4oc5ccccc5c34)c3ccccc23)cc1 ; c1ccc(-c2ccc(-c3c4ccccc4c(-c4cccc5oc6ccccc6c45)c4ccccc34)c3c2oc2ccccc23)cc1 ; c1ccc(-c2ccc(-c3c4ccccc4c(-c4ccc5c(c4)c4ccccc4n5-c4ccccc4)c4ccccc34)c3c2oc2ccccc23)cc1]

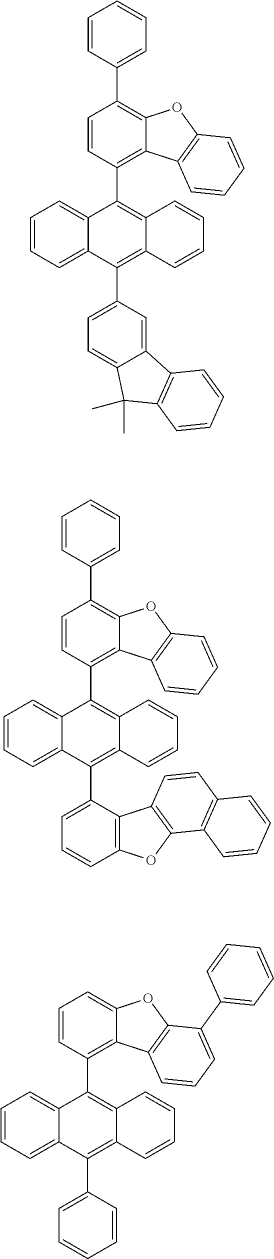 [SMILES: CC1(C)c2ccccc2-c2cc(-c3c4ccccc4c(-c4ccc(-c5ccccc5)c5oc6ccccc6c45)c4ccccc34)ccc21 ; c1ccc(-c2ccc(-c3c4ccccc4c(-c4cccc5oc6c7ccccc7ccc6c45)c4ccccc34)c3c2oc2ccccc23)cc1 ; c1ccc(-c2c3ccccc3c(-c3cccc4oc5c(-c6ccccc6)cccc5c34)c3ccccc23)cc1]

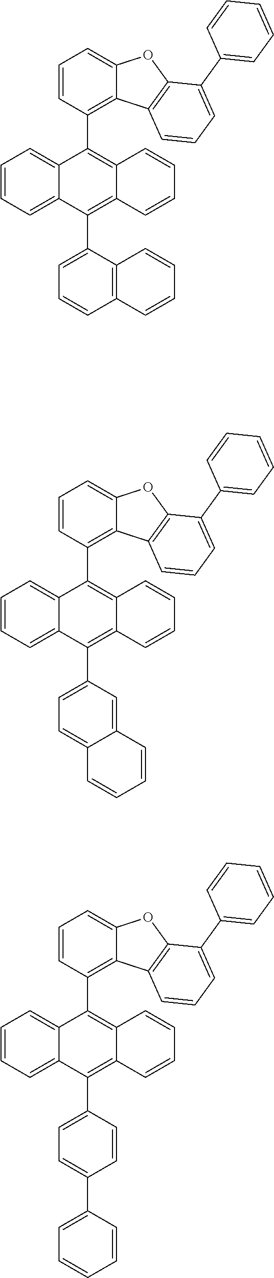 [SMILES: c1ccc(-c2cccc3c2oc2cccc(-c4c5ccccc5c(-c5cccc6ccccc56)c5ccccc45)c23)cc1 ; c1ccc(-c2cccc3c2oc2cccc(-c4c5ccccc5c(-c5ccc6ccccc6c5)c5ccccc45)c23)cc1 ; c1ccc(-c2ccc(-c3c4ccccc4c(-c4cccc5oc6c(-c7ccccc7)cccc6c45)c4ccccc34)cc2)cc1]

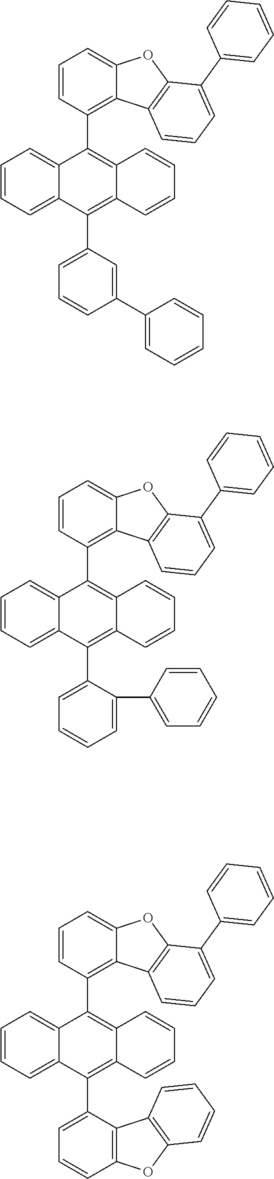 [SMILES: c1ccc(-c2cccc(-c3c4ccccc4c(-c4cccc5oc6c(-c7ccccc7)cccc6c45)c4ccccc34)c2)cc1 ; c1ccc(-c2ccccc2-c2c3ccccc3c(-c3cccc4oc5c(-c6ccccc6)cccc5c34)c3ccccc23)cc1 ; c1ccc(-c2cccc3c2oc2cccc(-c4c5ccccc5c(-c5cccc6oc7ccccc7c56)c5ccccc45)c23)cc1]

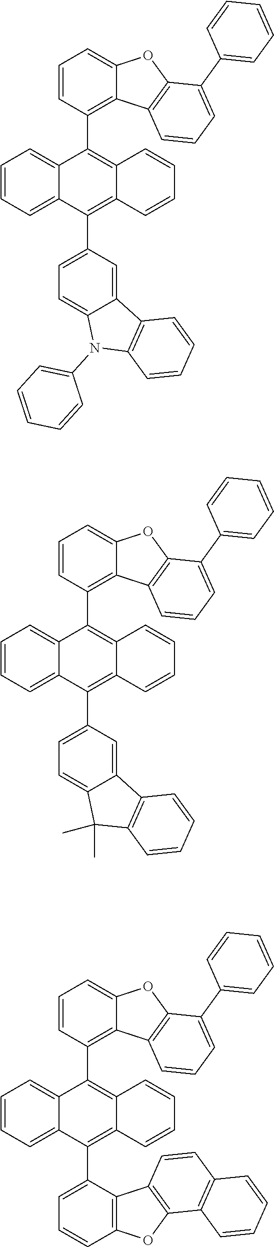 [SMILES: c1ccc(-c2cccc3c2oc2cccc(-c4c5ccccc5c(-c5ccc6c(c5)c5ccccc5n6-c5ccccc5)c5ccccc45)c23)cc1 ; CC1(C)c2ccccc2-c2cc(-c3c4ccccc4c(-c4cccc5oc6c(-c7ccccc7)cccc6c45)c4ccccc34)ccc21 ; c1ccc(-c2cccc3c2oc2cccc(-c4c5ccccc5c(-c5cccc6oc7c8ccccc8ccc7c56)c5ccccc45)c23)cc1]

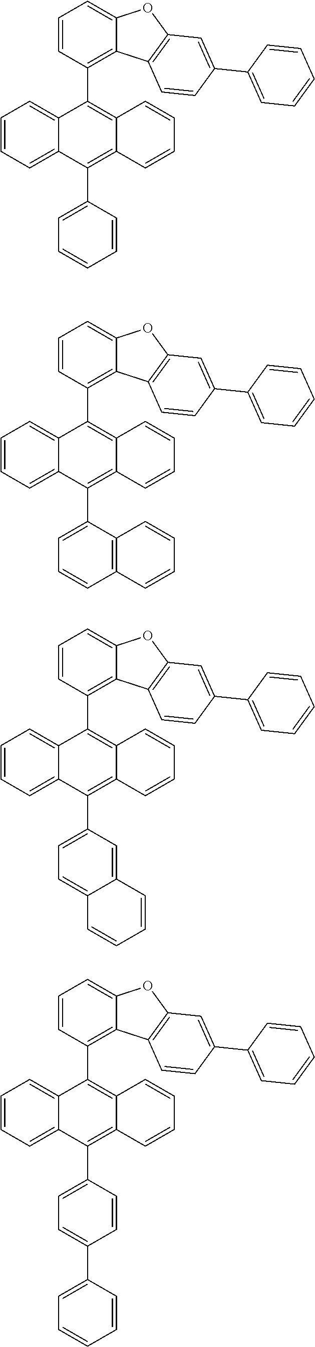

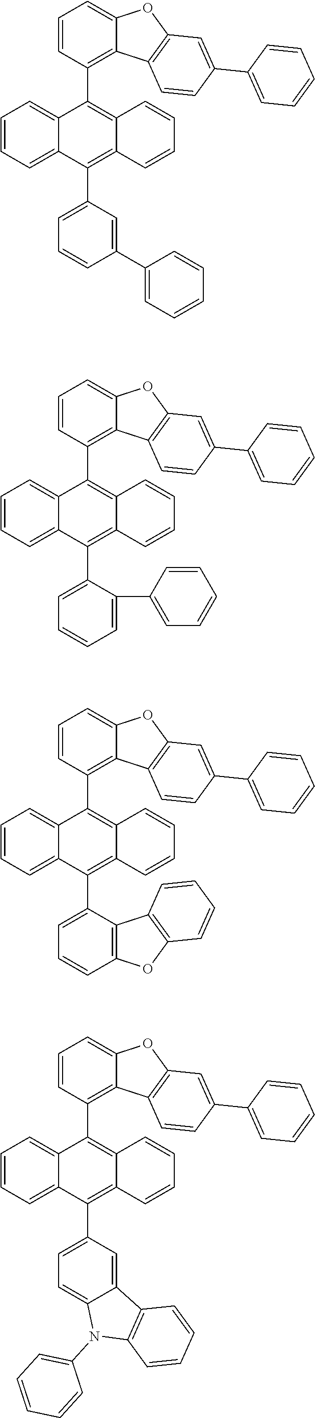 [SMILES: c1ccc(-c2cccc(-c3c4ccccc4c(-c4cccc5oc6cc(-c7ccccc7)ccc6c45)c4ccccc34)c2)cc1 ; c1ccc(-c2ccc3c(c2)oc2cccc(-c4c5ccccc5c(-c5ccccc5-c5ccccc5)c5ccccc45)c23)cc1 ; c1ccc(-c2ccc3c(c2)oc2cccc(-c4c5ccccc5c(-c5cccc6oc7ccccc7c56)c5ccccc45)c23)cc1 ; c1ccc(-c2ccc3c(c2)oc2cccc(-c4c5ccccc5c(-c5ccc6c(c5)c5ccccc5n6-c5ccccc5)c5ccccc45)c23)cc1]

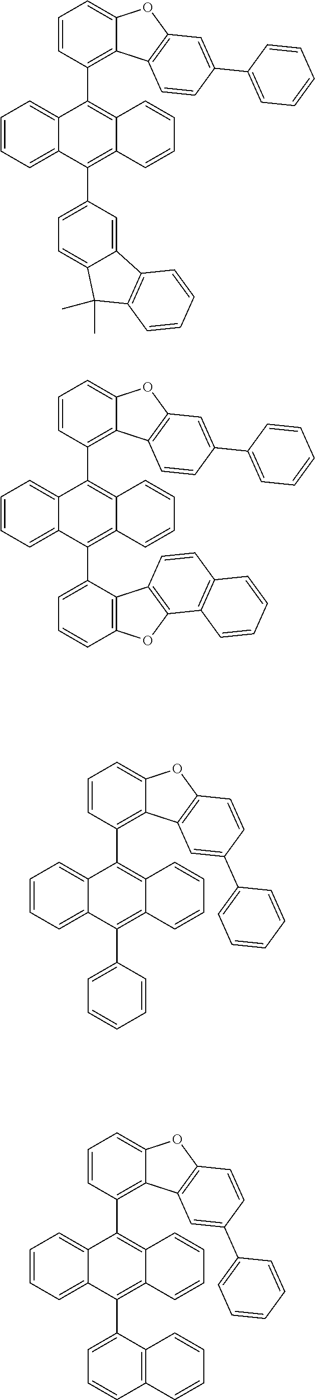 [SMILES: CC1(C)c2ccccc2-c2cc(-c3c4ccccc4c(-c4cccc5oc6cc(-c7ccccc7)ccc6c45)c4ccccc34)ccc21 ; c1ccc(-c2ccc3c(c2)oc2cccc(-c4c5ccccc5c(-c5cccc6oc7c8ccccc8ccc7c56)c5ccccc45)c23)cc1 ; c1ccc(-c2ccc3oc4cccc(-c5c6ccccc6c(-c6ccccc6)c6ccccc56)c4c3c2)cc1 ; c1ccc(-c2ccc3oc4cccc(-c5c6ccccc6c(-c6cccc7ccccc67)c6ccccc56)c4c3c2)cc1]

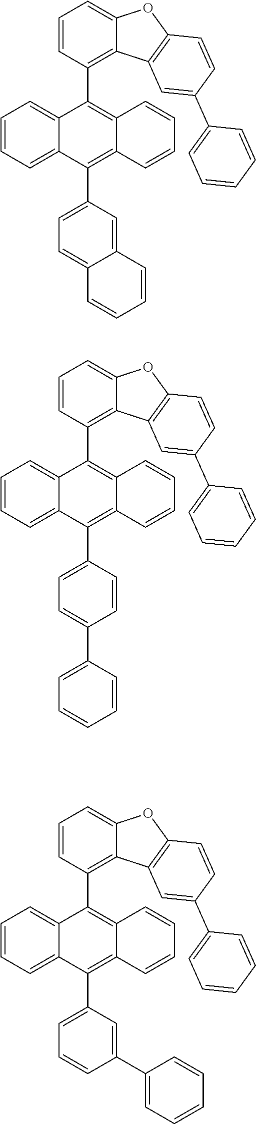 [SMILES: c1ccc(-c2ccc3oc4cccc(-c5c6ccccc6c(-c6ccc7ccccc7c6)c6ccccc56)c4c3c2)cc1 ; c1ccc(-c2ccc(-c3c4ccccc4c(-c4cccc5oc6ccc(-c7ccccc7)cc6c45)c4ccccc34)cc2)cc1 ; c1ccc(-c2cccc(-c3c4ccccc4c(-c4cccc5oc6ccc(-c7ccccc7)cc6c45)c4ccccc34)c2)cc1]

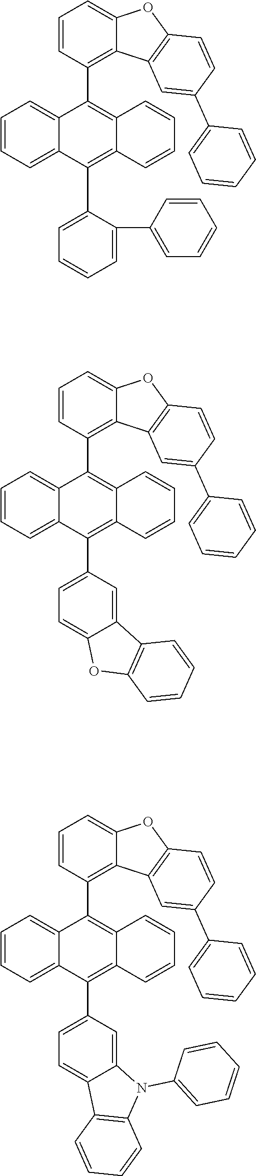 [SMILES: c1ccc(-c2ccc3oc4cccc(-c5c6ccccc6c(-c6ccccc6-c6ccccc6)c6ccccc56)c4c3c2)cc1 ; c1ccc(-c2ccc3oc4cccc(-c5c6ccccc6c(-c6ccc7oc8ccccc8c7c6)c6ccccc56)c4c3c2)cc1 ; c1ccc(-c2ccc3oc4cccc(-c5c6ccccc6c(-c6ccc7c8ccccc8n(-c8ccccc8)c7c6)c6ccccc56)c4c3c2)cc1]

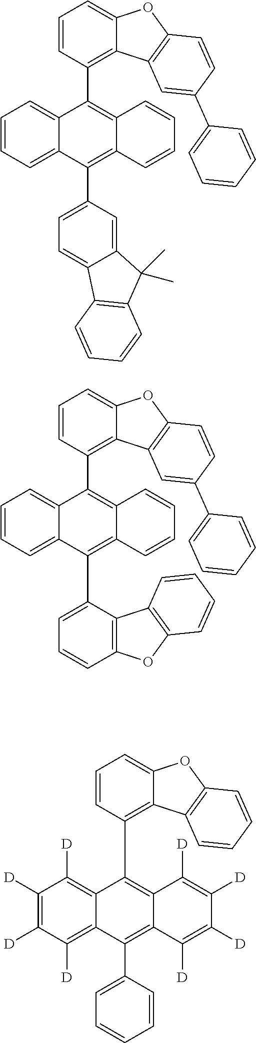

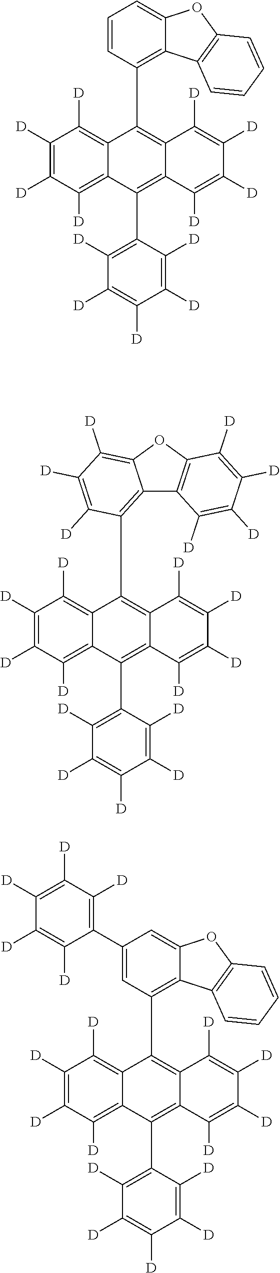 [SMILES: [2H]c1c([2H])c([2H])c(-c2c3c([2H])c([2H])c([2H])c([2H])c3c(-c3cccc4oc5ccccc5c34)c3c([2H])c([2H])c([2H])c([2H])c23)c([2H])c1[2H] ; [2H]c1c([2H])c([2H])c(-c2c3c([2H])c([2H])c([2H])c([2H])c3c(-c3c([2H])c([2H])c([2H])c4oc5c([2H])c([2H])c([2H])c([2H])c5c34)c3c([2H])c([2H])c([2H])c([2H])c23)c([2H])c1[2H] ; [2H]c1c([2H])c([2H])c(-c2cc(-c3c4c([2H])c([2H])c([2H])c([2H])c4c(-c4c([2H])c([2H])c([2H])c([2H])c4[2H])c4c([2H])c([2H])c([2H])c([2H])c34)c3c(c2)oc2ccccc23)c([2H])c1[2H]]

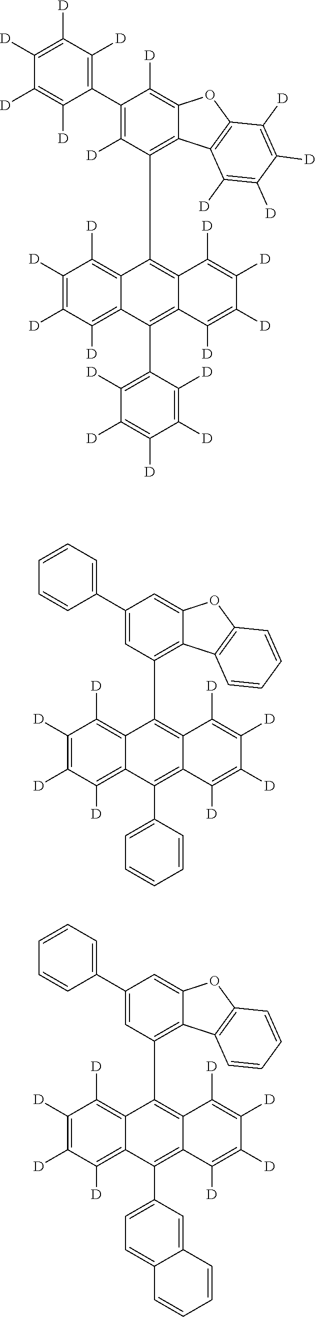 [SMILES: [2H]c1c([2H])c([2H])c(-c2c([2H])c(-c3c4c([2H])c([2H])c([2H])c([2H])c4c(-c4c([2H])c([2H])c([2H])c([2H])c4[2H])c4c([2H])c([2H])c([2H])c([2H])c34)c3c(oc4c([2H])c([2H])c([2H])c([2H])c43)c2[2H])c([2H])c1[2H] ; [2H]c1c([2H])c([2H])c2c(-c3cc(-c4ccccc4)cc4oc5ccccc5c34)c3c([2H])c([2H])c([2H])c([2H])c3c(-c3ccccc3)c2c1[2H] ; [2H]c1c([2H])c([2H])c2c(-c3cc(-c4ccccc4)cc4oc5ccccc5c34)c3c([2H])c([2H])c([2H])c([2H])c3c(-c3ccc4ccccc4c3)c2c1[2H]]

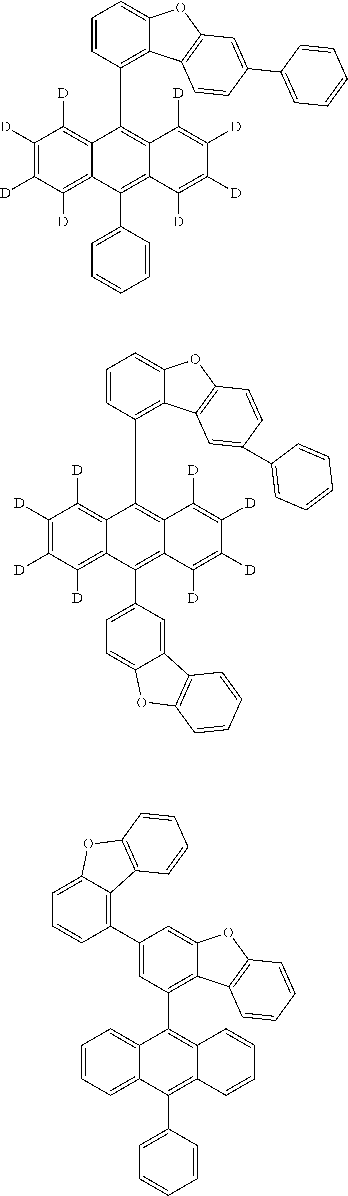 [SMILES: [2H]c1c([2H])c([2H])c2c(-c3cccc4oc5cc(-c6ccccc6)ccc5c34)c3c([2H])c([2H])c([2H])c([2H])c3c(-c3ccccc3)c2c1[2H] ; [2H]c1c([2H])c([2H])c2c(-c3cccc4oc5ccc(-c6ccccc6)cc5c34)c3c([2H])c([2H])c([2H])c([2H])c3c(-c3ccc4oc5ccccc5c4c3)c2c1[2H] ; c1ccc(-c2c3ccccc3c(-c3cc(-c4cccc5oc6ccccc6c45)cc4oc5ccccc5c34)c3ccccc23)cc1]

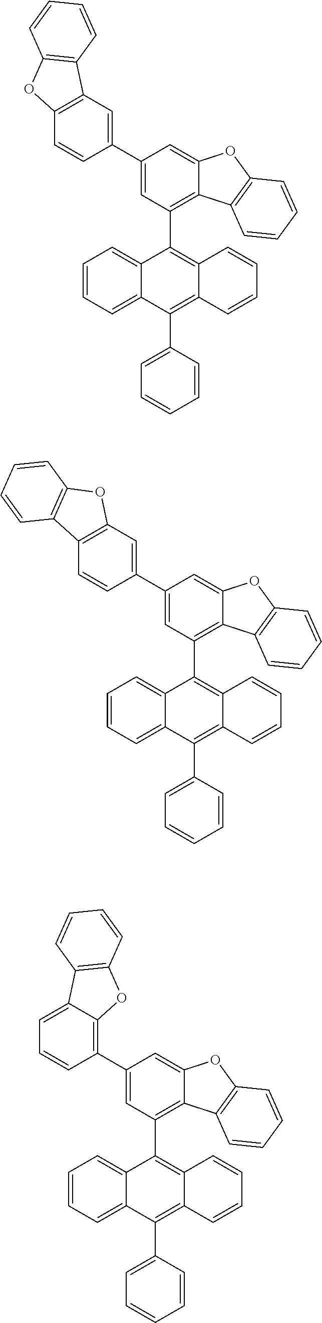 [SMILES: c1ccc(-c2c3ccccc3c(-c3cc(-c4ccc5oc6ccccc6c5c4)cc4oc5ccccc5c34)c3ccccc23)cc1 ; c1ccc(-c2c3ccccc3c(-c3cc(-c4ccc5c(c4)oc4ccccc45)cc4oc5ccccc5c34)c3ccccc23)cc1 ; c1ccc(-c2c3ccccc3c(-c3cc(-c4cccc5c4oc4ccccc45)cc4oc5ccccc5c34)c3ccccc23)cc1]

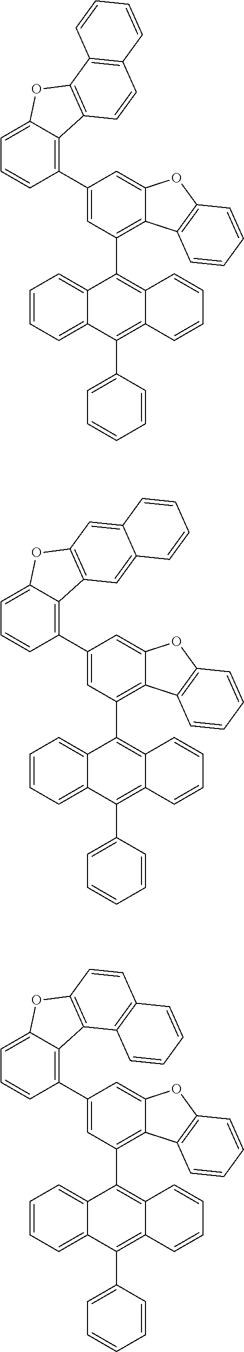 [SMILES: c1ccc(-c2c3ccccc3c(-c3cc(-c4cccc5oc6c7ccccc7ccc6c45)cc4oc5ccccc5c34)c3ccccc23)cc1 ; c1ccc(-c2c3ccccc3c(-c3cc(-c4cccc5oc6cc7ccccc7cc6c45)cc4oc5ccccc5c34)c3ccccc23)cc1 ; c1ccc(-c2c3ccccc3c(-c3cc(-c4cccc5oc6ccc7ccccc7c6c45)cc4oc5ccccc5c34)c3ccccc23)cc1]

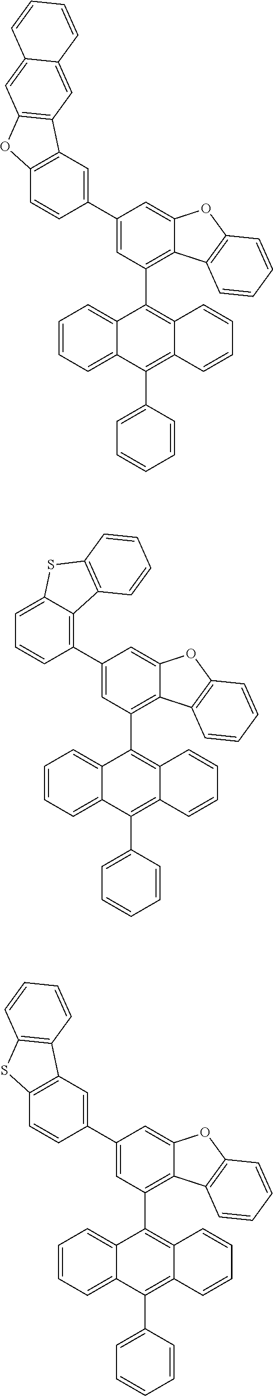 [SMILES: c1ccc(-c2c3ccccc3c(-c3cc(-c4ccc5oc6cc7ccccc7cc6c5c4)cc4oc5ccccc5c34)c3ccccc23)cc1 ; c1ccc(-c2c3ccccc3c(-c3cc(-c4cccc5sc6ccccc6c45)cc4oc5ccccc5c34)c3ccccc23)cc1 ; c1ccc(-c2c3ccccc3c(-c3cc(-c4ccc5sc6ccccc6c5c4)cc4oc5ccccc5c34)c3ccccc23)cc1]

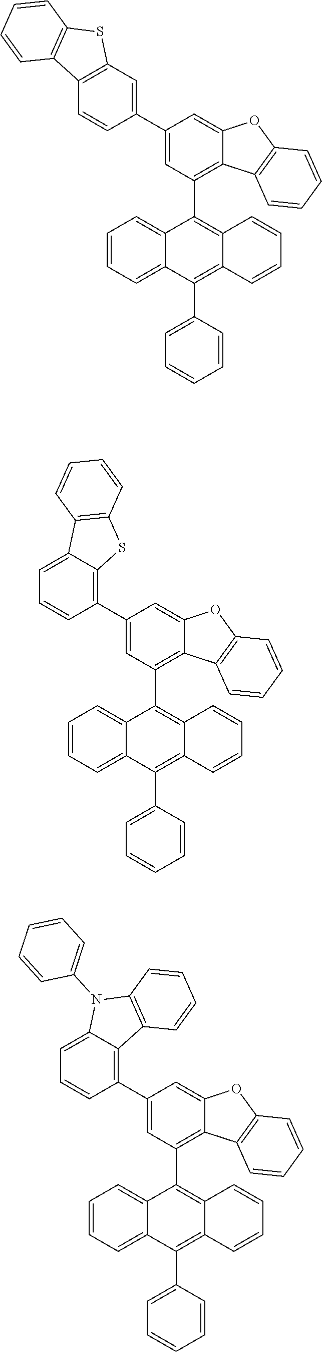 [SMILES: c1ccc(-c2c3ccccc3c(-c3cc(-c4ccc5c(c4)sc4ccccc45)cc4oc5ccccc5c34)c3ccccc23)cc1 ; c1ccc(-c2c3ccccc3c(-c3cc(-c4cccc5c4sc4ccccc45)cc4oc5ccccc5c34)c3ccccc23)cc1 ; c1ccc(-c2c3ccccc3c(-c3cc(-c4cccc5c4c4ccccc4n5-c4ccccc4)cc4oc5ccccc5c34)c3ccccc23)cc1]

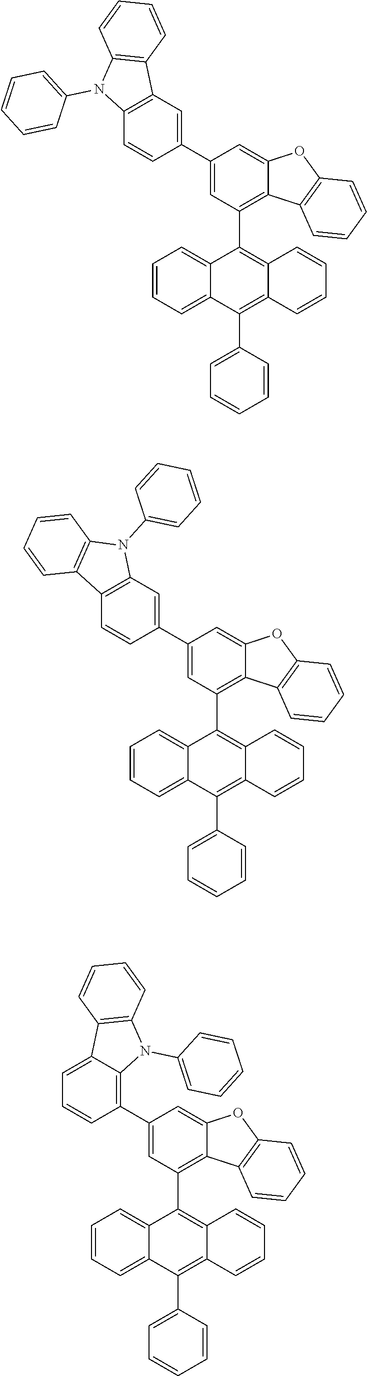 [SMILES: c1ccc(-c2c3ccccc3c(-c3cc(-c4ccc5c(c4)c4ccccc4n5-c4ccccc4)cc4oc5ccccc5c34)c3ccccc23)cc1 ; c1ccc(-c2c3ccccc3c(-c3cc(-c4ccc5c6ccccc6n(-c6ccccc6)c5c4)cc4oc5ccccc5c34)c3ccccc23)cc1 ; c1ccc(-c2c3ccccc3c(-c3cc(-c4cccc5c6ccccc6n(-c6ccccc6)c45)cc4oc5ccccc5c34)c3ccccc23)cc1]

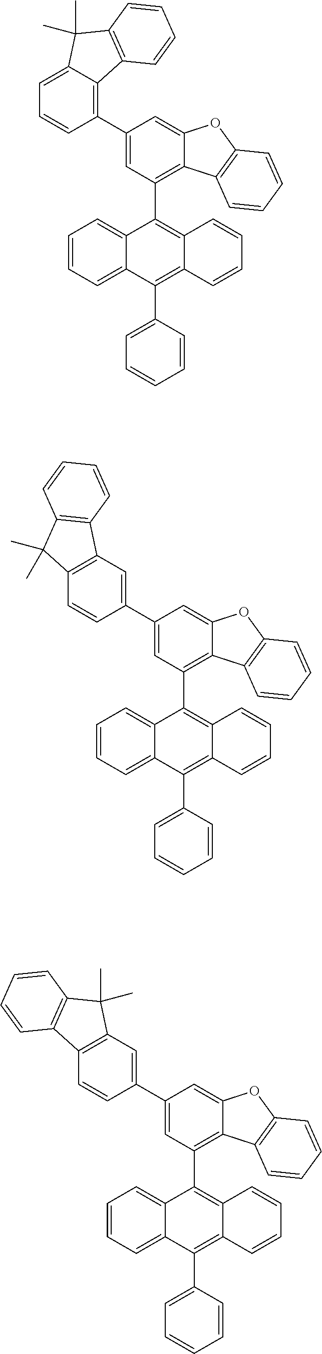 [SMILES: CC1(C)c2ccccc2-c2c(-c3cc(-c4c5ccccc5c(-c5ccccc5)c5ccccc45)c4c(c3)oc3ccccc34)cccc21 ; CC1(C)c2ccccc2-c2cc(-c3cc(-c4c5ccccc5c(-c5ccccc5)c5ccccc45)c4c(c3)oc3ccccc34)ccc21 ; CC1(C)c2ccccc2-c2ccc(-c3cc(-c4c5ccccc5c(-c5ccccc5)c5ccccc45)c4c(c3)oc3ccccc34)cc21]

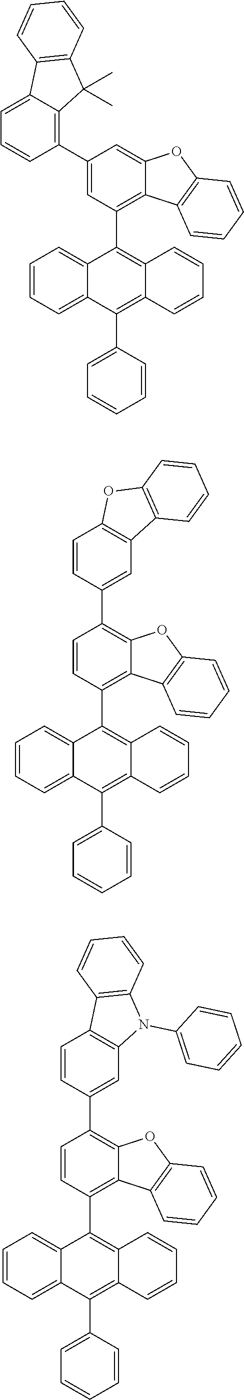 [SMILES: CC1(C)c2ccccc2-c2cccc(-c3cc(-c4c5ccccc5c(-c5ccccc5)c5ccccc45)c4c(c3)oc3ccccc34)c21 ; c1ccc(-c2c3ccccc3c(-c3ccc(-c4ccc5oc6ccccc6c5c4)c4oc5ccccc5c34)c3ccccc23)cc1 ; c1ccc(-c2c3ccccc3c(-c3ccc(-c4ccc5c6ccccc6n(-c6ccccc6)c5c4)c4oc5ccccc5c34)c3ccccc23)cc1]

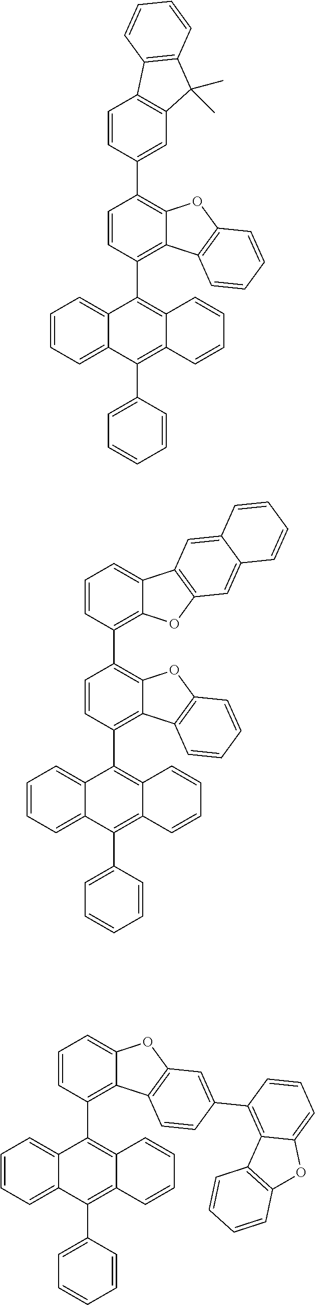 [SMILES: CC1(C)c2ccccc2-c2ccc(-c3ccc(-c4c5ccccc5c(-c5ccccc5)c5ccccc45)c4c3oc3ccccc34)cc21 ; c1ccc(-c2c3ccccc3c(-c3ccc(-c4cccc5c4oc4cc6ccccc6cc45)c4oc5ccccc5c34)c3ccccc23)cc1 ; c1ccc(-c2c3ccccc3c(-c3cccc4oc5cc(-c6cccc7oc8ccccc8c67)ccc5c34)c3ccccc23)cc1]

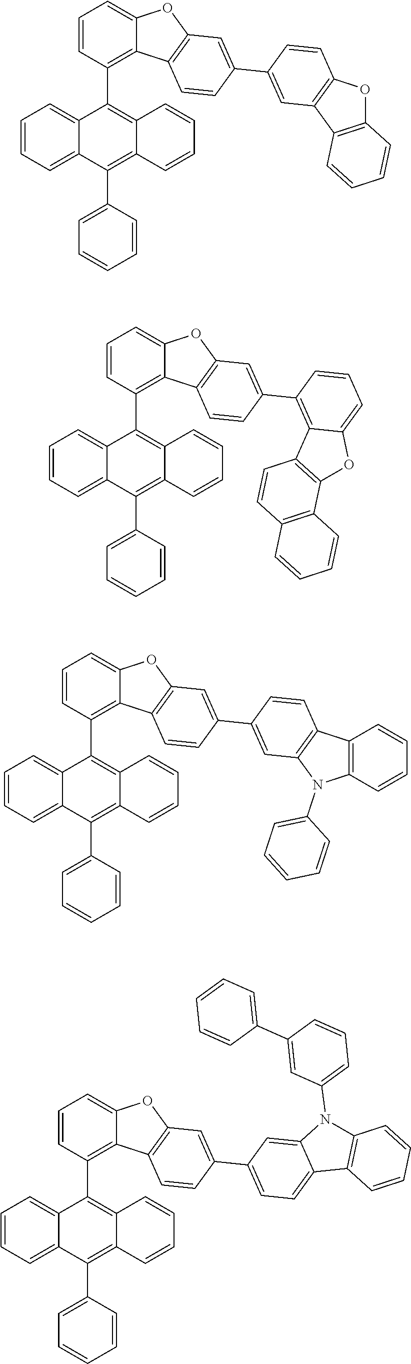 [SMILES: c1ccc(-c2c3ccccc3c(-c3cccc4oc5cc(-c6ccc7oc8ccccc8c7c6)ccc5c34)c3ccccc23)cc1 ; c1ccc(-c2c3ccccc3c(-c3cccc4oc5cc(-c6cccc7oc8c9ccccc9ccc8c67)ccc5c34)c3ccccc23)cc1 ; c1ccc(-c2c3ccccc3c(-c3cccc4oc5cc(-c6ccc7c8ccccc8n(-c8ccccc8)c7c6)ccc5c34)c3ccccc23)cc1 ; c1ccc(-c2cccc(-n3c4ccccc4c4ccc(-c5ccc6c(c5)oc5cccc(-c7c8ccccc8c(-c8ccccc8)c8ccccc78)c56)cc43)c2)cc1]

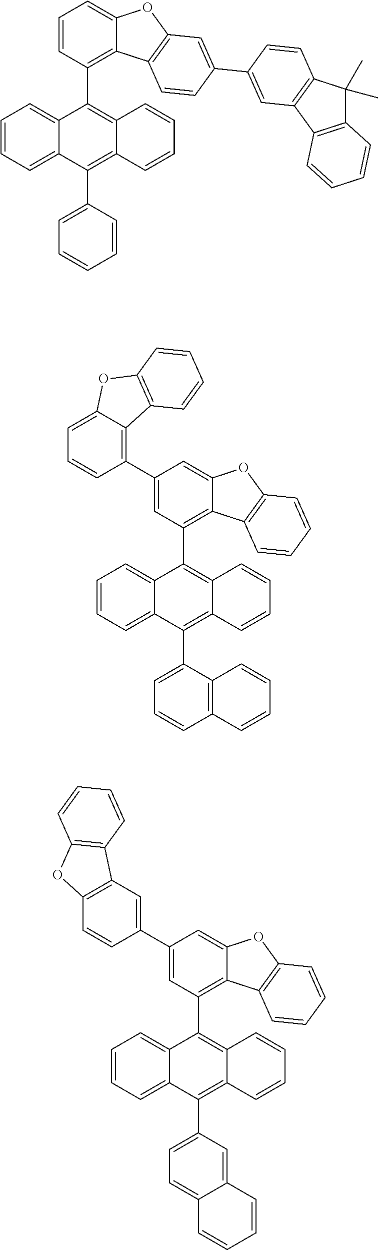 [SMILES: CC1(C)c2ccccc2-c2cc(-c3ccc4c(c3)oc3cccc(-c5c6ccccc6c(-c6ccccc6)c6ccccc56)c34)ccc21 ; c1ccc2c(-c3c4ccccc4c(-c4cc(-c5cccc6oc7ccccc7c56)cc5oc6ccccc6c45)c4ccccc34)cccc2c1 ; c1ccc2cc(-c3c4ccccc4c(-c4cc(-c5ccc6oc7ccccc7c6c5)cc5oc6ccccc6c45)c4ccccc34)ccc2c1]

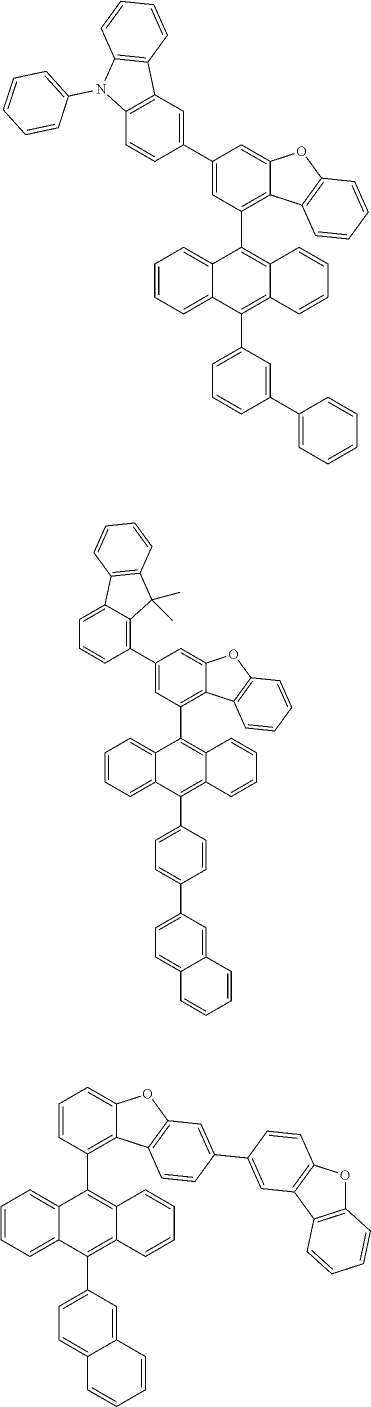 [SMILES: c1ccc(-c2cccc(-c3c4ccccc4c(-c4cc(-c5ccc6c(c5)c5ccccc5n6-c5ccccc5)cc5oc6ccccc6c45)c4ccccc34)c2)cc1 ; CC1(C)c2ccccc2-c2cccc(-c3cc(-c4c5ccccc5c(-c5ccc(-c6ccc7ccccc7c6)cc5)c5ccccc45)c4c(c3)oc3ccccc34)c21 ; c1ccc2cc(-c3c4ccccc4c(-c4cccc5oc6cc(-c7ccc8oc9ccccc9c8c7)ccc6c45)c4ccccc34)ccc2c1]

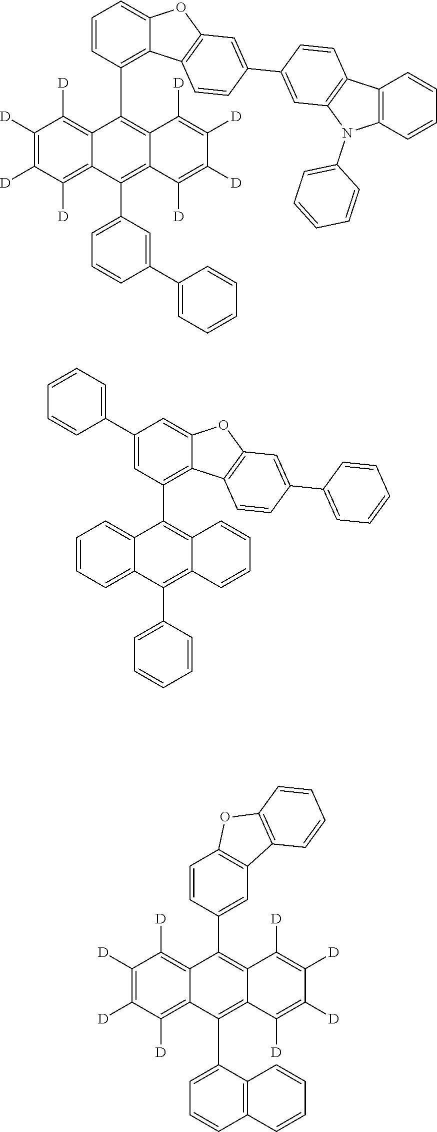 [SMILES: [2H]c1c([2H])c([2H])c2c(-c3cccc4oc5cc(-c6ccc7c8ccccc8n(-c8ccccc8)c7c6)ccc5c34)c3c([2H])c([2H])c([2H])c([2H])c3c(-c3cccc(-c4ccccc4)c3)c2c1[2H] ; c1ccc(-c2ccc3c(c2)oc2cc(-c4ccccc4)cc(-c4c5ccccc5c(-c5ccccc5)c5ccccc45)c23)cc1 ; [2H]c1c([2H])c([2H])c2c(-c3cccc4ccccc34)c3c([2H])c([2H])c([2H])c([2H])c3c(-c3ccc4oc5ccccc5c4c3)c2c1[2H]]

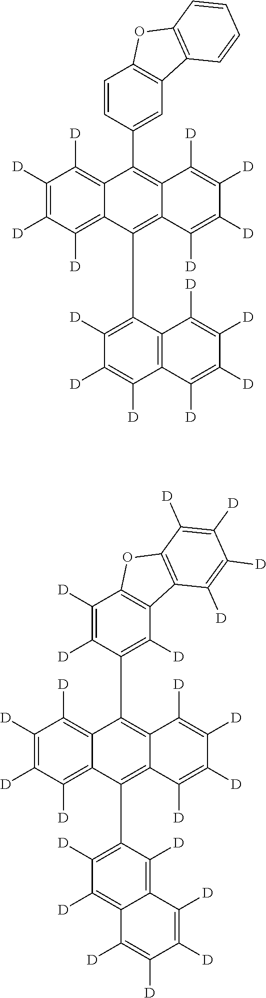 [SMILES: [2H]c1c([2H])c([2H])c2c(-c3c4c([2H])c([2H])c([2H])c([2H])c4c(-c4ccc5oc6ccccc6c5c4)c4c([2H])c([2H])c([2H])c([2H])c34)c([2H])c([2H])c([2H])c2c1[2H] ; [2H]c1c([2H])c([2H])c2c(oc3c([2H])c([2H])c(-c4c5c([2H])c([2H])c([2H])c([2H])c5c(-c5c([2H])c([2H])c6c([2H])c([2H])c([2H])c([2H])c6c5[2H])c5c([2H])c([2H])c([2H])c([2H])c45)c([2H])c32)c1[2H]]

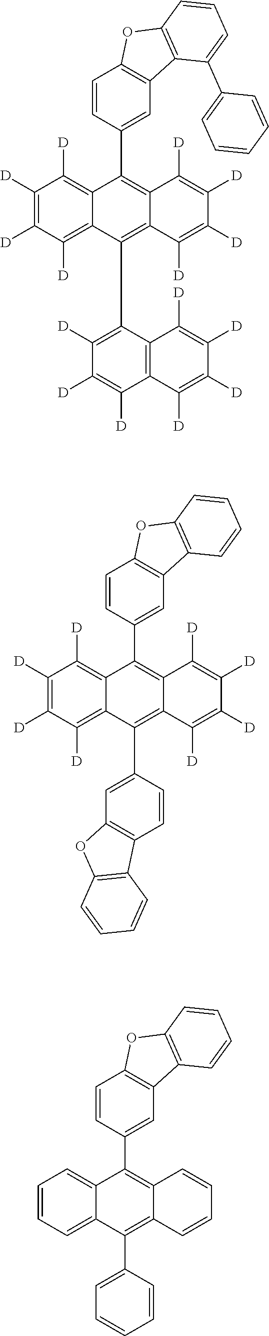 [SMILES: [2H]c1c([2H])c([2H])c2c(-c3c4c([2H])c([2H])c([2H])c([2H])c4c(-c4ccc5oc6cccc(-c7ccccc7)c6c5c4)c4c([2H])c([2H])c([2H])c([2H])c34)c([2H])c([2H])c([2H])c2c1[2H] ; [2H]c1c([2H])c([2H])c2c(-c3ccc4oc5ccccc5c4c3)c3c([2H])c([2H])c([2H])c([2H])c3c(-c3ccc4c(c3)oc3ccccc34)c2c1[2H] ; c1ccc(-c2c3ccccc3c(-c3ccc4oc5ccccc5c4c3)c3ccccc23)cc1]

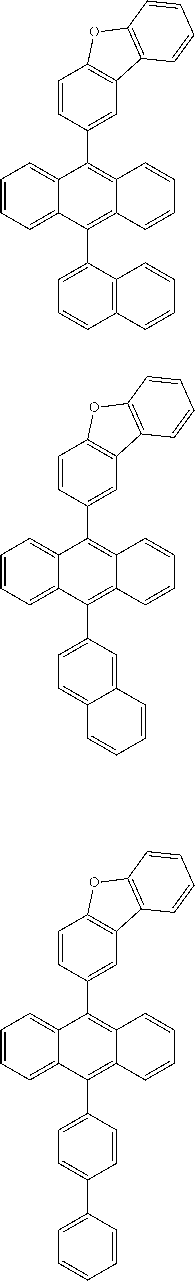 [SMILES: c1ccc2c(-c3c4ccccc4c(-c4ccc5oc6ccccc6c5c4)c4ccccc34)cccc2c1 ; c1ccc2cc(-c3c4ccccc4c(-c4ccc5oc6ccccc6c5c4)c4ccccc34)ccc2c1 ; c1ccc(-c2ccc(-c3c4ccccc4c(-c4ccc5oc6ccccc6c5c4)c4ccccc34)cc2)cc1]

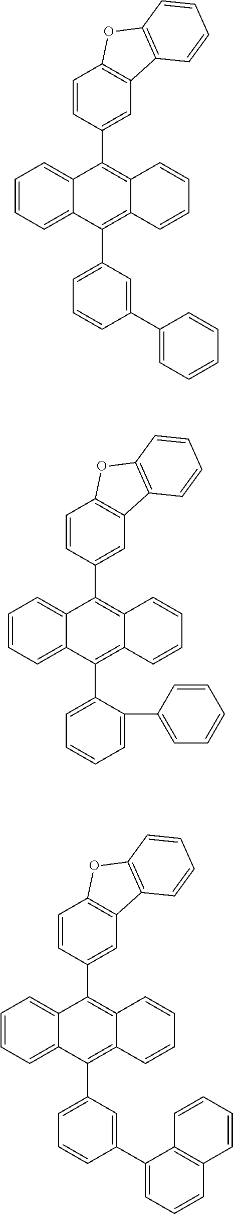 [SMILES: c1ccc(-c2cccc(-c3c4ccccc4c(-c4ccc5oc6ccccc6c5c4)c4ccccc34)c2)cc1 ; c1ccc(-c2ccccc2-c2c3ccccc3c(-c3ccc4oc5ccccc5c4c3)c3ccccc23)cc1 ; c1cc(-c2cccc3ccccc23)cc(-c2c3ccccc3c(-c3ccc4oc5ccccc5c4c3)c3ccccc23)c1]

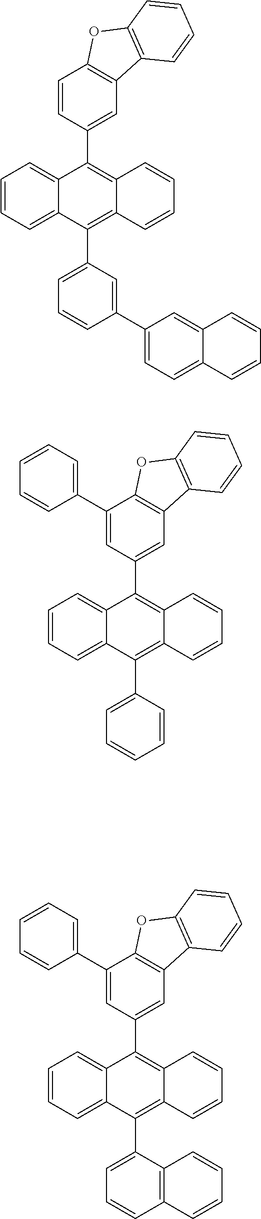 [SMILES: c1cc(-c2ccc3ccccc3c2)cc(-c2c3ccccc3c(-c3ccc4oc5ccccc5c4c3)c3ccccc23)c1 ; c1ccc(-c2c3ccccc3c(-c3cc(-c4ccccc4)c4oc5ccccc5c4c3)c3ccccc23)cc1 ; c1ccc(-c2cc(-c3c4ccccc4c(-c4cccc5ccccc45)c4ccccc34)cc3c2oc2ccccc23)cc1]

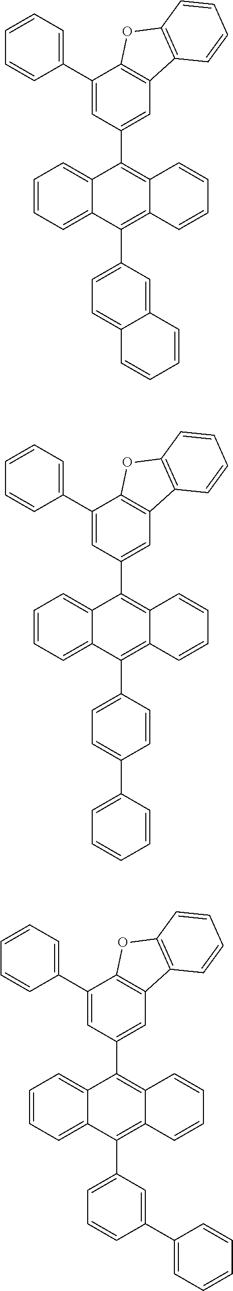 [SMILES: c1ccc(-c2cc(-c3c4ccccc4c(-c4ccc5ccccc5c4)c4ccccc34)cc3c2oc2ccccc23)cc1 ; c1ccc(-c2ccc(-c3c4ccccc4c(-c4cc(-c5ccccc5)c5oc6ccccc6c5c4)c4ccccc34)cc2)cc1 ; c1ccc(-c2cccc(-c3c4ccccc4c(-c4cc(-c5ccccc5)c5oc6ccccc6c5c4)c4ccccc34)c2)cc1]

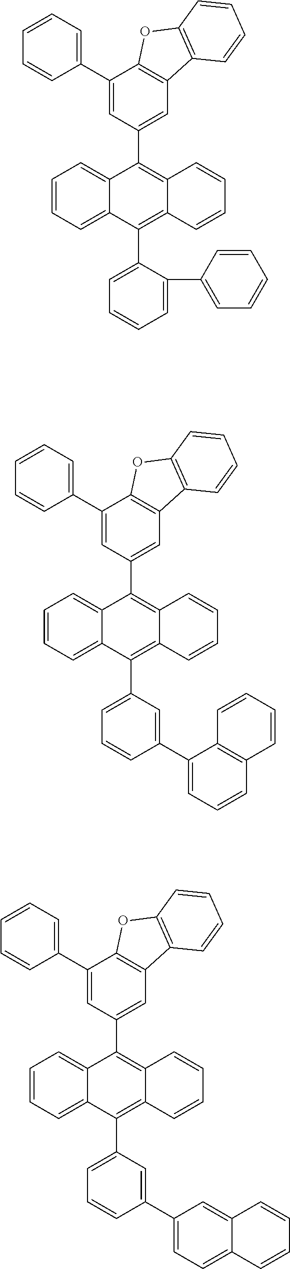 [SMILES: c1ccc(-c2ccccc2-c2c3ccccc3c(-c3cc(-c4ccccc4)c4oc5ccccc5c4c3)c3ccccc23)cc1 ; c1ccc(-c2cc(-c3c4ccccc4c(-c4cccc(-c5cccc6ccccc56)c4)c4ccccc34)cc3c2oc2ccccc23)cc1 ; c1ccc(-c2cc(-c3c4ccccc4c(-c4cccc(-c5ccc6ccccc6c5)c4)c4ccccc34)cc3c2oc2ccccc23)cc1]

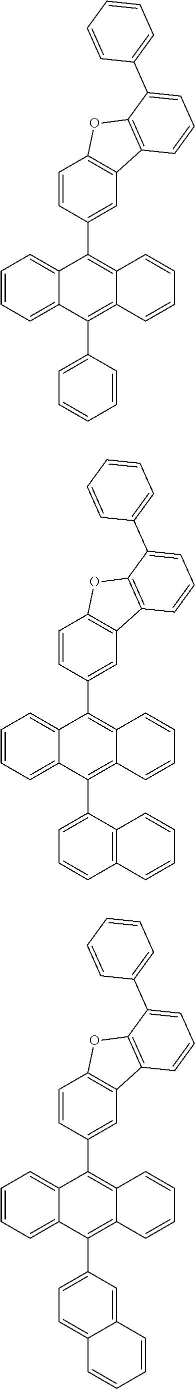

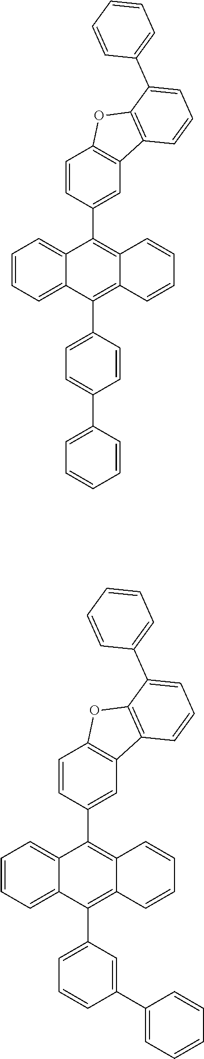 [SMILES: c1ccc(-c2ccc(-c3c4ccccc4c(-c4ccc5oc6c(-c7ccccc7)cccc6c5c4)c4ccccc34)cc2)cc1 ; c1ccc(-c2cccc(-c3c4ccccc4c(-c4ccc5oc6c(-c7ccccc7)cccc6c5c4)c4ccccc34)c2)cc1]

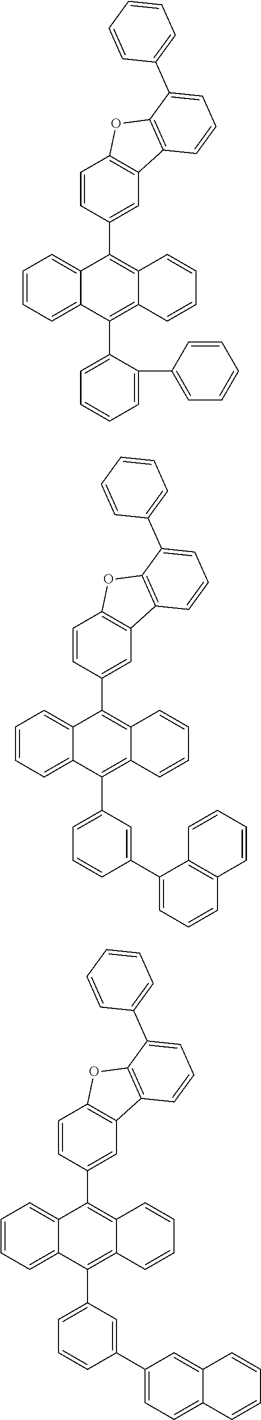

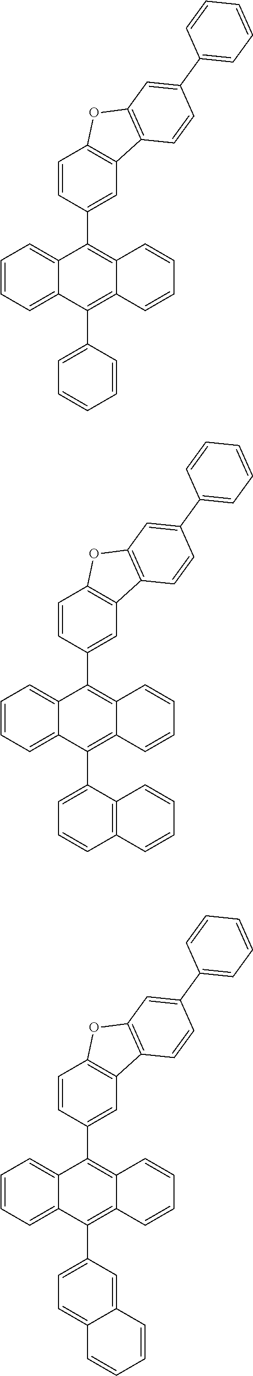 [SMILES: c1ccc(-c2ccc3c(c2)oc2ccc(-c4c5ccccc5c(-c5ccccc5)c5ccccc45)cc23)cc1 ; c1ccc(-c2ccc3c(c2)oc2ccc(-c4c5ccccc5c(-c5cccc6ccccc56)c5ccccc45)cc23)cc1 ; c1ccc(-c2ccc3c(c2)oc2ccc(-c4c5ccccc5c(-c5ccc6ccccc6c5)c5ccccc45)cc23)cc1]

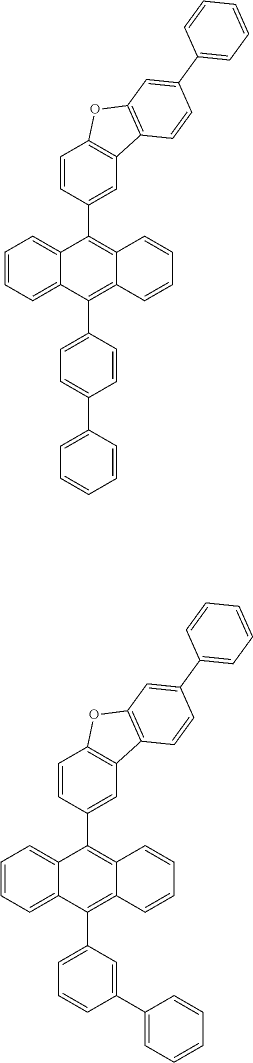 [SMILES: c1ccc(-c2ccc(-c3c4ccccc4c(-c4ccc5oc6cc(-c7ccccc7)ccc6c5c4)c4ccccc34)cc2)cc1 ; c1ccc(-c2cccc(-c3c4ccccc4c(-c4ccc5oc6cc(-c7ccccc7)ccc6c5c4)c4ccccc34)c2)cc1]

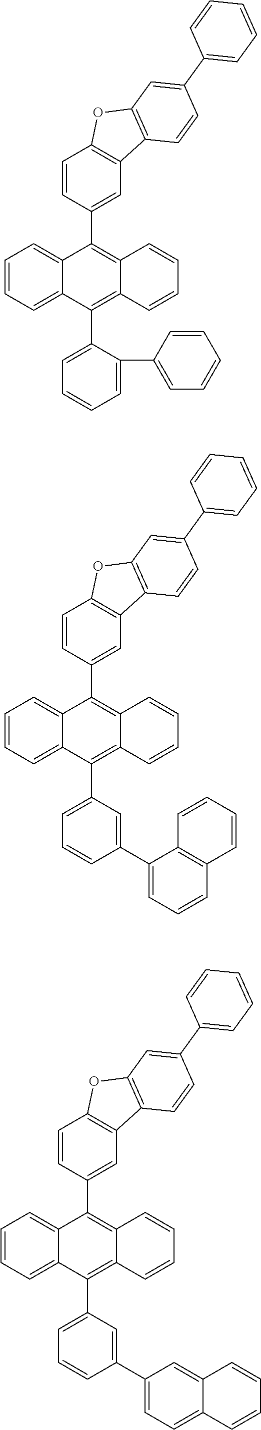 [SMILES: c1ccc(-c2ccc3c(c2)oc2ccc(-c4c5ccccc5c(-c5ccccc5-c5ccccc5)c5ccccc45)cc23)cc1 ; c1ccc(-c2ccc3c(c2)oc2ccc(-c4c5ccccc5c(-c5cccc(-c6cccc7ccccc67)c5)c5ccccc45)cc23)cc1 ; c1ccc(-c2ccc3c(c2)oc2ccc(-c4c5ccccc5c(-c5cccc(-c6ccc7ccccc7c6)c5)c5ccccc45)cc23)cc1]

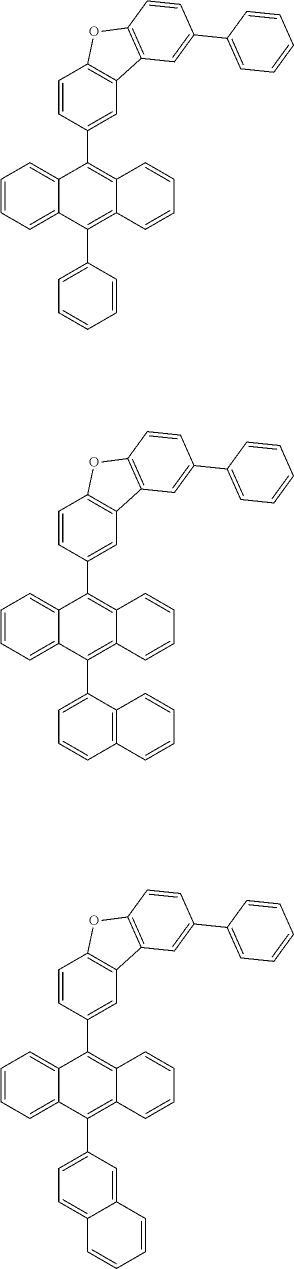 [SMILES: c1ccc(-c2ccc3oc4ccc(-c5c6ccccc6c(-c6ccccc6)c6ccccc56)cc4c3c2)cc1 ; c1ccc(-c2ccc3oc4ccc(-c5c6ccccc6c(-c6cccc7ccccc67)c6ccccc56)cc4c3c2)cc1 ; c1ccc(-c2ccc3oc4ccc(-c5c6ccccc6c(-c6ccc7ccccc7c6)c6ccccc56)cc4c3c2)cc1]

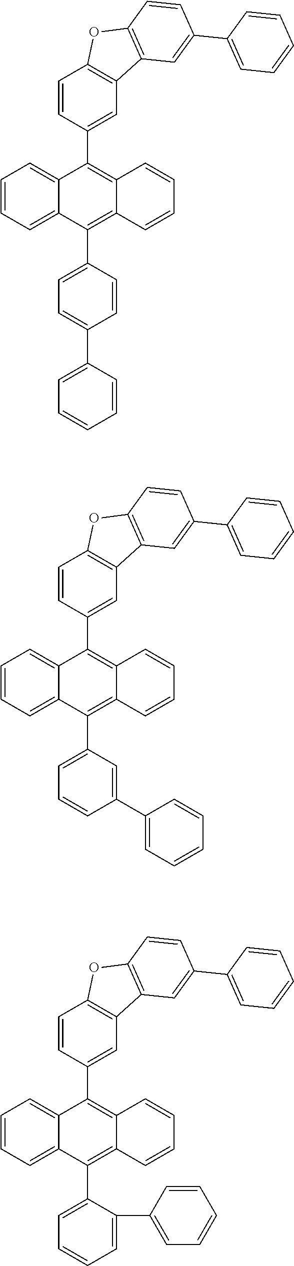 [SMILES: c1ccc(-c2ccc(-c3c4ccccc4c(-c4ccc5oc6ccc(-c7ccccc7)cc6c5c4)c4ccccc34)cc2)cc1 ; c1ccc(-c2cccc(-c3c4ccccc4c(-c4ccc5oc6ccc(-c7ccccc7)cc6c5c4)c4ccccc34)c2)cc1 ; c1ccc(-c2ccc3oc4ccc(-c5c6ccccc6c(-c6ccccc6-c6ccccc6)c6ccccc56)cc4c3c2)cc1]

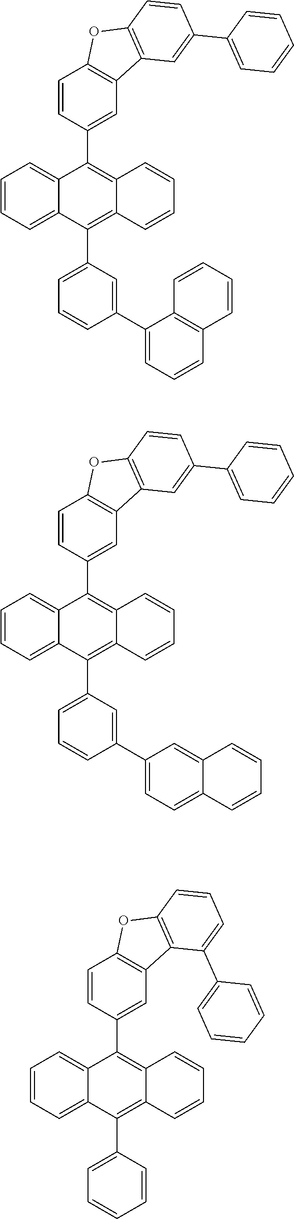 [SMILES: c1ccc(-c2ccc3oc4ccc(-c5c6ccccc6c(-c6cccc(-c7cccc8ccccc78)c6)c6ccccc56)cc4c3c2)cc1 ; c1ccc(-c2ccc3oc4ccc(-c5c6ccccc6c(-c6cccc(-c7ccc8ccccc8c7)c6)c6ccccc56)cc4c3c2)cc1 ; c1ccc(-c2c3ccccc3c(-c3ccc4oc5cccc(-c6ccccc6)c5c4c3)c3ccccc23)cc1]

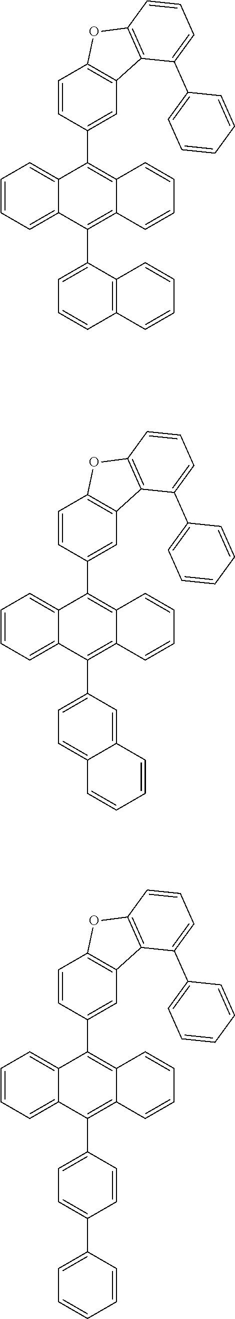 [SMILES: c1ccc(-c2cccc3oc4ccc(-c5c6ccccc6c(-c6cccc7ccccc67)c6ccccc56)cc4c23)cc1 ; c1ccc(-c2cccc3oc4ccc(-c5c6ccccc6c(-c6ccc7ccccc7c6)c6ccccc56)cc4c23)cc1 ; c1ccc(-c2ccc(-c3c4ccccc4c(-c4ccc5oc6cccc(-c7ccccc7)c6c5c4)c4ccccc34)cc2)cc1]

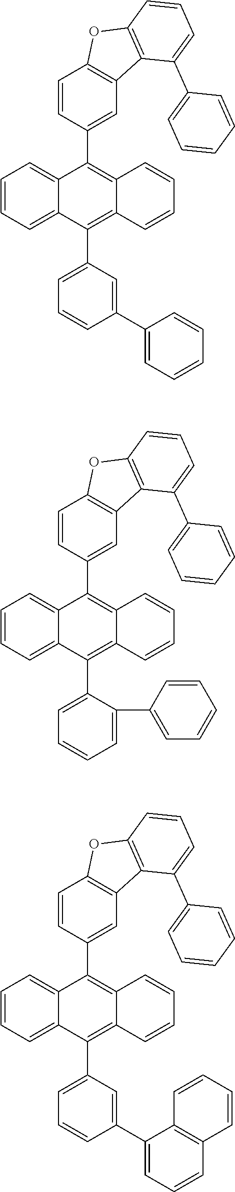 [SMILES: c1ccc(-c2cccc(-c3c4ccccc4c(-c4ccc5oc6cccc(-c7ccccc7)c6c5c4)c4ccccc34)c2)cc1 ; c1ccc(-c2ccccc2-c2c3ccccc3c(-c3ccc4oc5cccc(-c6ccccc6)c5c4c3)c3ccccc23)cc1 ; c1ccc(-c2cccc3oc4ccc(-c5c6ccccc6c(-c6cccc(-c7cccc8ccccc78)c6)c6ccccc56)cc4c23)cc1]

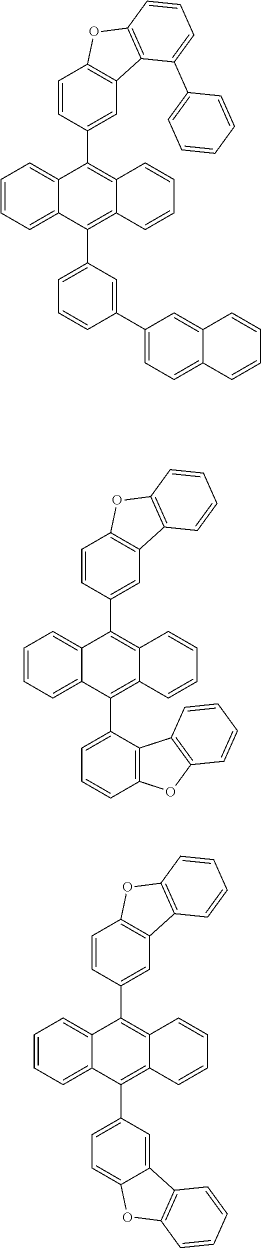 [SMILES: c1ccc(-c2cccc3oc4ccc(-c5c6ccccc6c(-c6cccc(-c7ccc8ccccc8c7)c6)c6ccccc56)cc4c23)cc1 ; c1ccc2c(c1)oc1ccc(-c3c4ccccc4c(-c4cccc5oc6ccccc6c45)c4ccccc34)cc12 ; c1ccc2c(c1)oc1ccc(-c3c4ccccc4c(-c4ccc5oc6ccccc6c5c4)c4ccccc34)cc12]

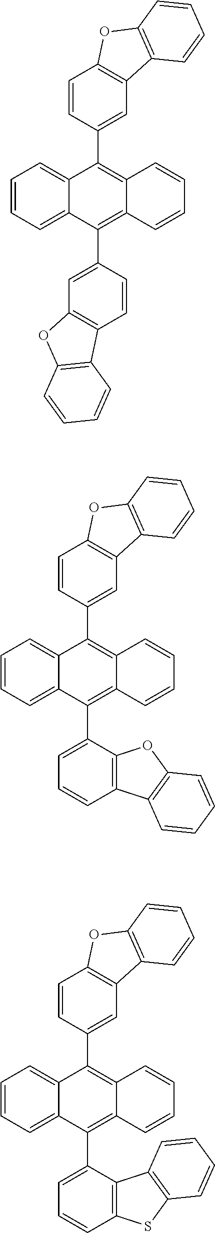 [SMILES: c1ccc2c(c1)oc1cc(-c3c4ccccc4c(-c4ccc5oc6ccccc6c5c4)c4ccccc34)ccc12 ; c1ccc2c(c1)oc1ccc(-c3c4ccccc4c(-c4cccc5c4oc4ccccc45)c4ccccc34)cc12 ; c1ccc2c(c1)oc1ccc(-c3c4ccccc4c(-c4cccc5sc6ccccc6c45)c4ccccc34)cc12]

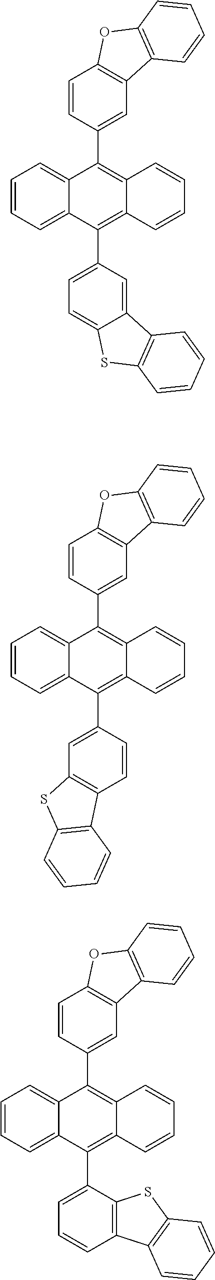 [SMILES: c1ccc2c(c1)oc1ccc(-c3c4ccccc4c(-c4ccc5sc6ccccc6c5c4)c4ccccc34)cc12 ; c1ccc2c(c1)oc1ccc(-c3c4ccccc4c(-c4ccc5c(c4)sc4ccccc45)c4ccccc34)cc12 ; c1ccc2c(c1)oc1ccc(-c3c4ccccc4c(-c4cccc5c4sc4ccccc45)c4ccccc34)cc12]

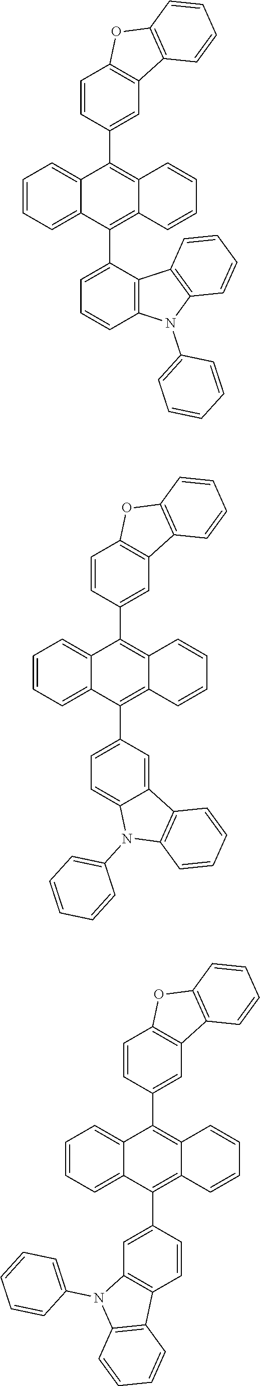 [SMILES: c1ccc(-n2c3ccccc3c3c(-c4c5ccccc5c(-c5ccc6oc7ccccc7c6c5)c5ccccc45)cccc32)cc1 ; c1ccc(-n2c3ccccc3c3cc(-c4c5ccccc5c(-c5ccc6oc7ccccc7c6c5)c5ccccc45)ccc32)cc1 ; c1ccc(-n2c3ccccc3c3ccc(-c4c5ccccc5c(-c5ccc6oc7ccccc7c6c5)c5ccccc45)cc32)cc1]

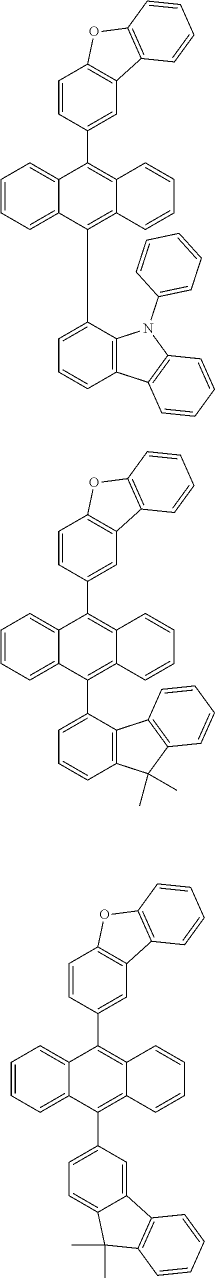

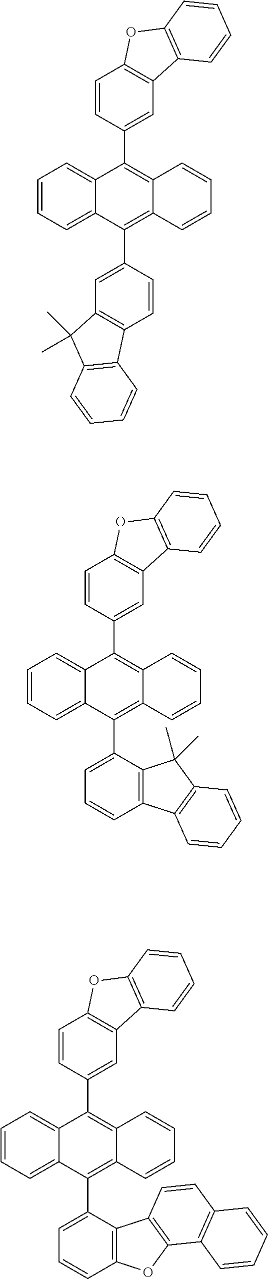 [SMILES: CC1(C)c2ccccc2-c2ccc(-c3c4ccccc4c(-c4ccc5oc6ccccc6c5c4)c4ccccc34)cc21 ; CC1(C)c2ccccc2-c2cccc(-c3c4ccccc4c(-c4ccc5oc6ccccc6c5c4)c4ccccc34)c21 ; c1ccc2c(c1)ccc1c2oc2cccc(-c3c4ccccc4c(-c4ccc5oc6ccccc6c5c4)c4ccccc34)c21]

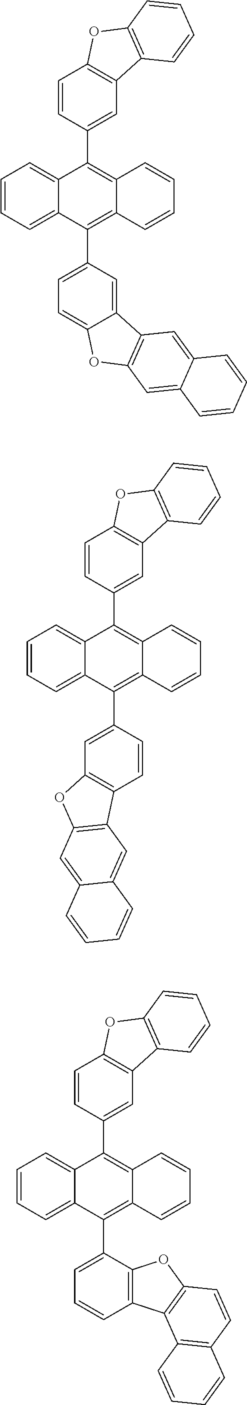 [SMILES: c1ccc2cc3c(cc2c1)oc1ccc(-c2c4ccccc4c(-c4ccc5oc6ccccc6c5c4)c4ccccc24)cc13 ; c1ccc2cc3c(cc2c1)oc1cc(-c2c4ccccc4c(-c4ccc5oc6ccccc6c5c4)c4ccccc24)ccc13 ; c1ccc2c(c1)ccc1oc3c(-c4c5ccccc5c(-c5ccc6oc7ccccc7c6c5)c5ccccc45)cccc3c12]

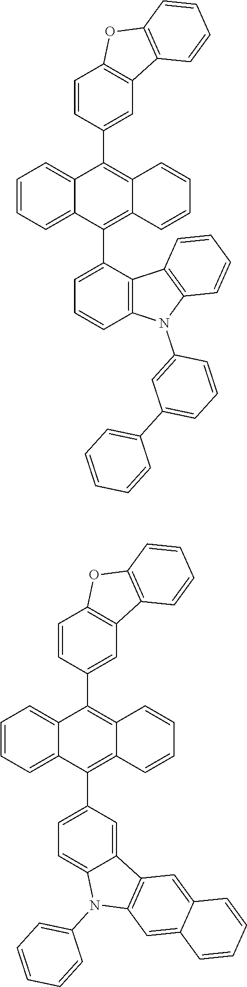 [SMILES: c1ccc(-c2cccc(-n3c4ccccc4c4c(-c5c6ccccc6c(-c6ccc7oc8ccccc8c7c6)c6ccccc56)cccc43)c2)cc1 ; c1ccc(-n2c3ccc(-c4c5ccccc5c(-c5ccc6oc7ccccc7c6c5)c5ccccc45)cc3c3cc4ccccc4cc32)cc1]

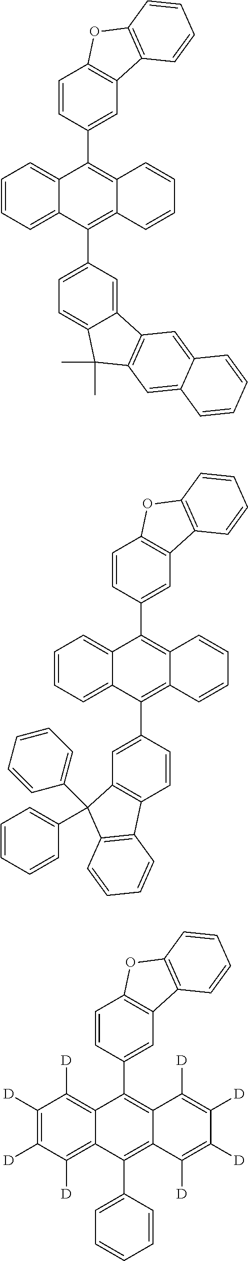 [SMILES: CC1(C)c2ccc(-c3c4ccccc4c(-c4ccc5oc6ccccc6c5c4)c4ccccc34)cc2-c2cc3ccccc3cc21 ; c1ccc(C2(c3ccccc3)c3ccccc3-c3ccc(-c4c5ccccc5c(-c5ccc6oc7ccccc7c6c5)c5ccccc45)cc32)cc1 ; [2H]c1c([2H])c([2H])c2c(-c3ccc4oc5ccccc5c4c3)c3c([2H])c([2H])c([2H])c([2H])c3c(-c3ccccc3)c2c1[2H]]

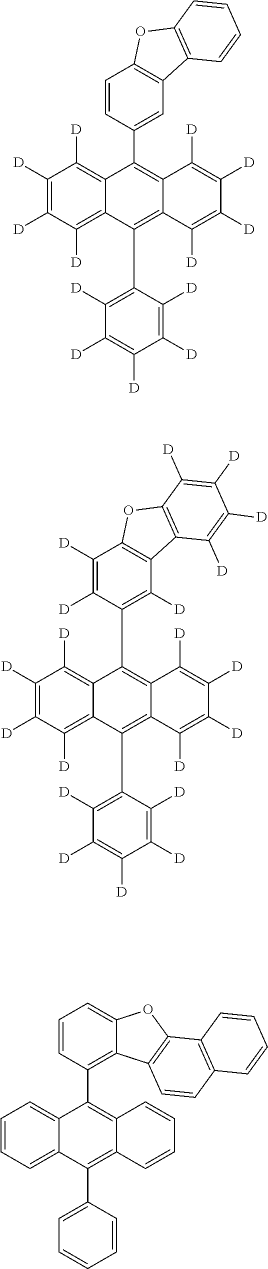 [SMILES: [2H]c1c([2H])c([2H])c(-c2c3c([2H])c([2H])c([2H])c([2H])c3c(-c3ccc4oc5ccccc5c4c3)c3c([2H])c([2H])c([2H])c([2H])c23)c([2H])c1[2H] ; [2H]c1c([2H])c([2H])c(-c2c3c([2H])c([2H])c([2H])c([2H])c3c(-c3c([2H])c([2H])c4oc5c([2H])c([2H])c([2H])c([2H])c5c4c3[2H])c3c([2H])c([2H])c([2H])c([2H])c23)c([2H])c1[2H] ; c1ccc(-c2c3ccccc3c(-c3cccc4oc5c6ccccc6ccc5c34)c3ccccc23)cc1]

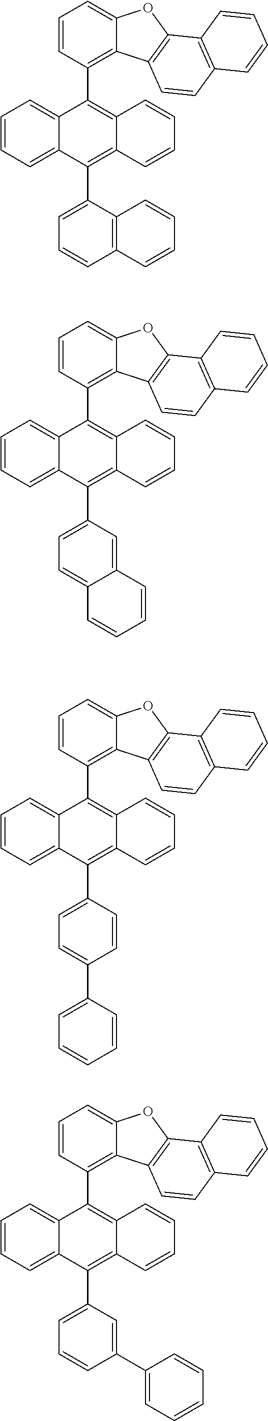

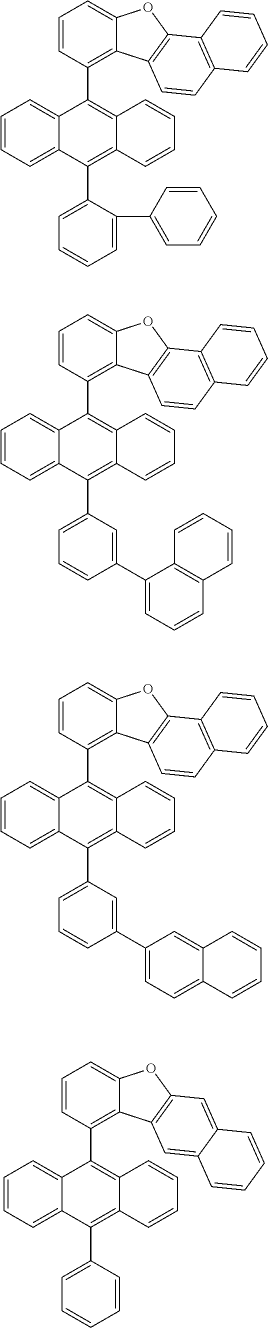 [SMILES: c1ccc(-c2ccccc2-c2c3ccccc3c(-c3cccc4oc5c6ccccc6ccc5c34)c3ccccc23)cc1 ; c1cc(-c2cccc3ccccc23)cc(-c2c3ccccc3c(-c3cccc4oc5c6ccccc6ccc5c34)c3ccccc23)c1 ; c1cc(-c2ccc3ccccc3c2)cc(-c2c3ccccc3c(-c3cccc4oc5c6ccccc6ccc5c34)c3ccccc23)c1 ; c1ccc(-c2c3ccccc3c(-c3cccc4oc5cc6ccccc6cc5c34)c3ccccc23)cc1]

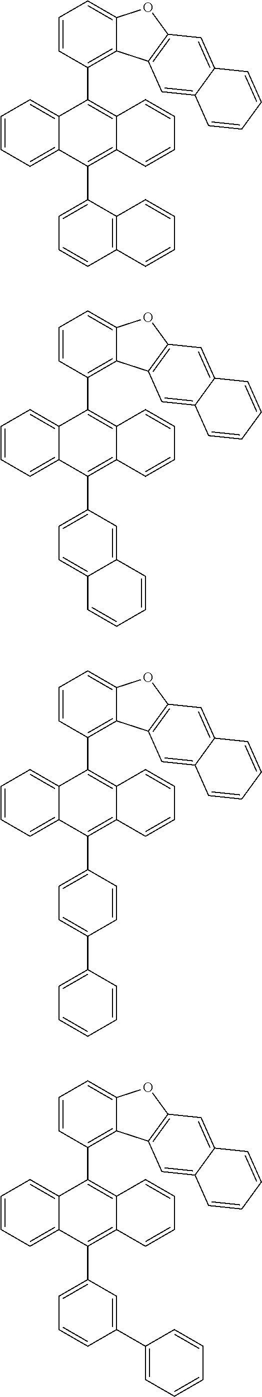

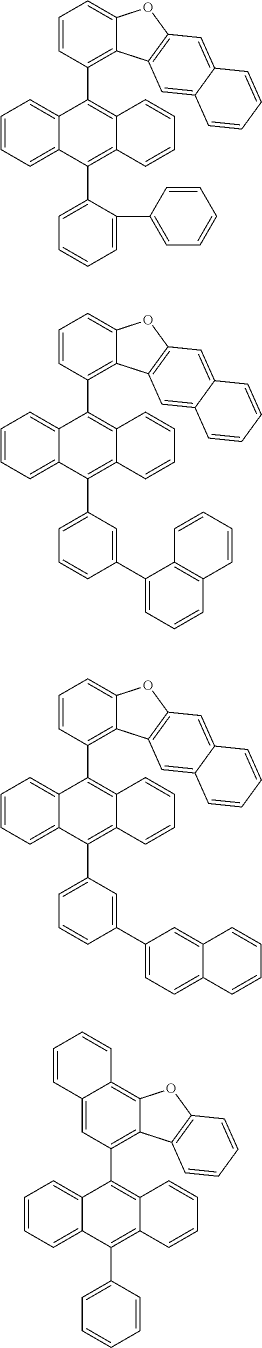 [SMILES: c1ccc(-c2ccccc2-c2c3ccccc3c(-c3cccc4oc5cc6ccccc6cc5c34)c3ccccc23)cc1 ; c1cc(-c2cccc3ccccc23)cc(-c2c3ccccc3c(-c3cccc4oc5cc6ccccc6cc5c34)c3ccccc23)c1 ; c1cc(-c2ccc3ccccc3c2)cc(-c2c3ccccc3c(-c3cccc4oc5cc6ccccc6cc5c34)c3ccccc23)c1 ; c1ccc(-c2c3ccccc3c(-c3cc4ccccc4c4oc5ccccc5c34)c3ccccc23)cc1]

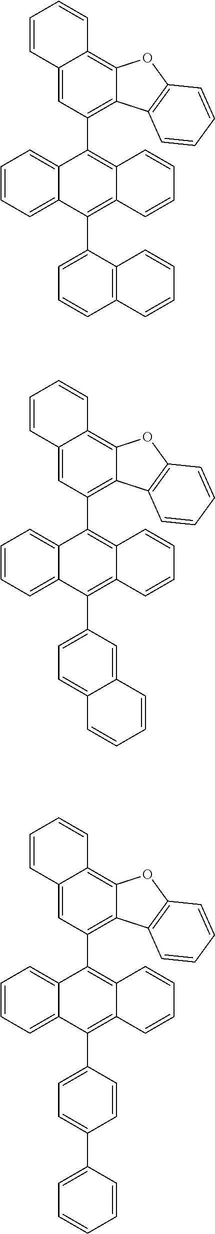 [SMILES: c1ccc2c(-c3c4ccccc4c(-c4cc5ccccc5c5oc6ccccc6c45)c4ccccc34)cccc2c1 ; c1ccc2cc(-c3c4ccccc4c(-c4cc5ccccc5c5oc6ccccc6c45)c4ccccc34)ccc2c1 ; c1ccc(-c2ccc(-c3c4ccccc4c(-c4cc5ccccc5c5oc6ccccc6c45)c4ccccc34)cc2)cc1]

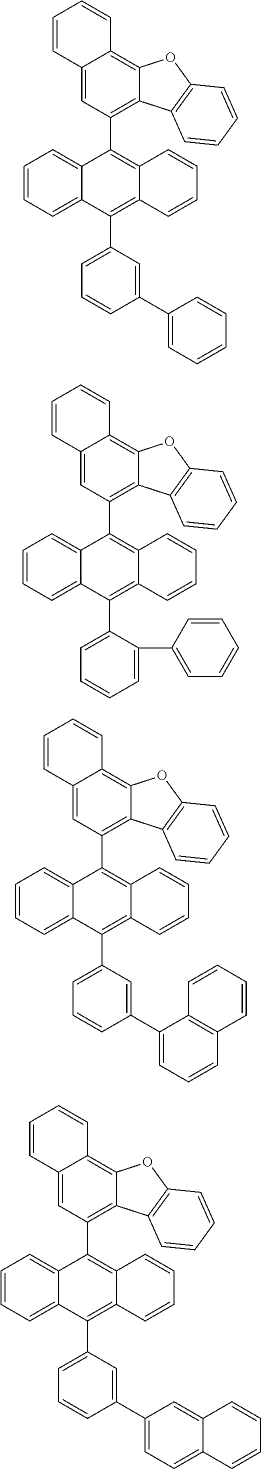

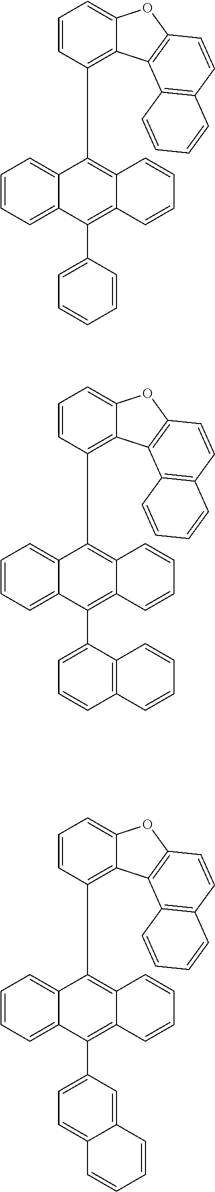 [SMILES: c1ccc(-c2c3ccccc3c(-c3cccc4oc5ccc6ccccc6c5c34)c3ccccc23)cc1 ; c1ccc2c(-c3c4ccccc4c(-c4cccc5oc6ccc7ccccc7c6c45)c4ccccc34)cccc2c1 ; c1ccc2cc(-c3c4ccccc4c(-c4cccc5oc6ccc7ccccc7c6c45)c4ccccc34)ccc2c1]

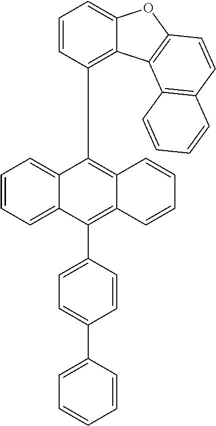 [SMILES: c1ccc(-c2ccc(-c3c4ccccc4c(-c4cccc5oc6ccc7ccccc7c6c45)c4ccccc34)cc2)cc1]

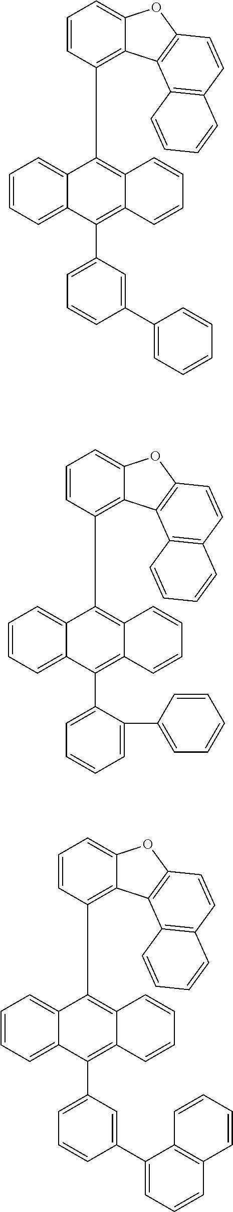 [SMILES: c1ccc(-c2cccc(-c3c4ccccc4c(-c4cccc5oc6ccc7ccccc7c6c45)c4ccccc34)c2)cc1 ; c1ccc(-c2ccccc2-c2c3ccccc3c(-c3cccc4oc5ccc6ccccc6c5c34)c3ccccc23)cc1 ; c1cc(-c2cccc3ccccc23)cc(-c2c3ccccc3c(-c3cccc4oc5ccc6ccccc6c5c34)c3ccccc23)c1]

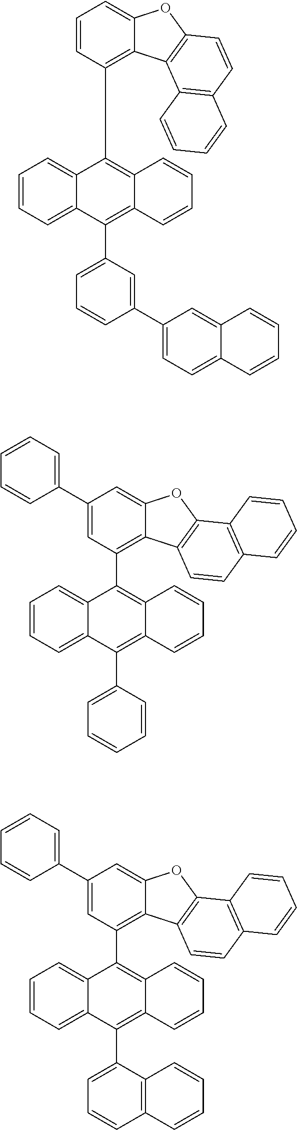 [SMILES: c1cc(-c2ccc3ccccc3c2)cc(-c2c3ccccc3c(-c3cccc4oc5ccc6ccccc6c5c34)c3ccccc23)c1 ; c1ccc(-c2cc(-c3c4ccccc4c(-c4ccccc4)c4ccccc34)c3c(c2)oc2c4ccccc4ccc23)cc1 ; c1ccc(-c2cc(-c3c4ccccc4c(-c4cccc5ccccc45)c4ccccc34)c3c(c2)oc2c4ccccc4ccc23)cc1]

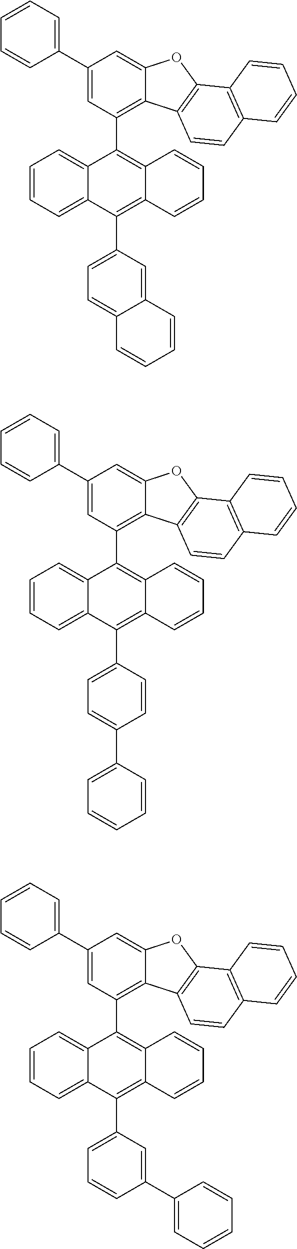 [SMILES: c1ccc(-c2cc(-c3c4ccccc4c(-c4ccc5ccccc5c4)c4ccccc34)c3c(c2)oc2c4ccccc4ccc23)cc1 ; c1ccc(-c2ccc(-c3c4ccccc4c(-c4cc(-c5ccccc5)cc5oc6c7ccccc7ccc6c45)c4ccccc34)cc2)cc1 ; c1ccc(-c2cccc(-c3c4ccccc4c(-c4cc(-c5ccccc5)cc5oc6c7ccccc7ccc6c45)c4ccccc34)c2)cc1]

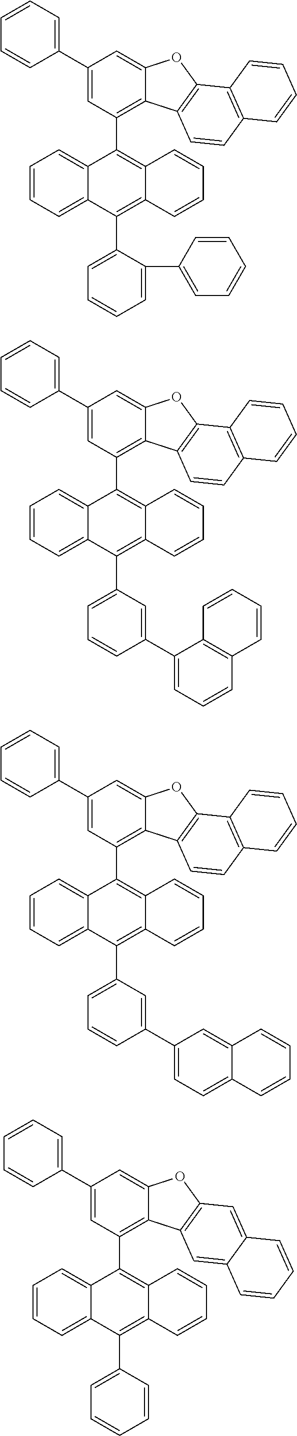 [SMILES: c1ccc(-c2cc(-c3c4ccccc4c(-c4ccccc4-c4ccccc4)c4ccccc34)c3c(c2)oc2c4ccccc4ccc23)cc1 ; c1ccc(-c2cc(-c3c4ccccc4c(-c4cccc(-c5cccc6ccccc56)c4)c4ccccc34)c3c(c2)oc2c4ccccc4ccc23)cc1 ; c1ccc(-c2cc(-c3c4ccccc4c(-c4cccc(-c5ccc6ccccc6c5)c4)c4ccccc34)c3c(c2)oc2c4ccccc4ccc23)cc1 ; c1ccc(-c2cc(-c3c4ccccc4c(-c4ccccc4)c4ccccc34)c3c(c2)oc2cc4ccccc4cc23)cc1]

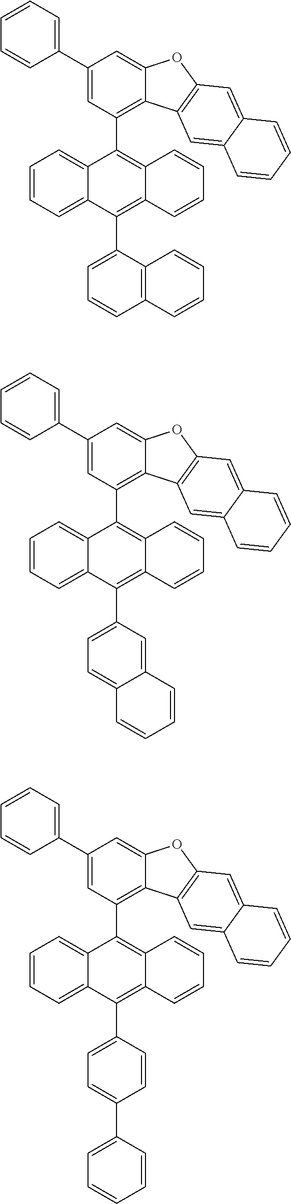 [SMILES: c1ccc(-c2cc(-c3c4ccccc4c(-c4cccc5ccccc45)c4ccccc34)c3c(c2)oc2cc4ccccc4cc23)cc1 ; c1ccc(-c2cc(-c3c4ccccc4c(-c4ccc5ccccc5c4)c4ccccc34)c3c(c2)oc2cc4ccccc4cc23)cc1 ; c1ccc(-c2ccc(-c3c4ccccc4c(-c4cc(-c5ccccc5)cc5oc6cc7ccccc7cc6c45)c4ccccc34)cc2)cc1]

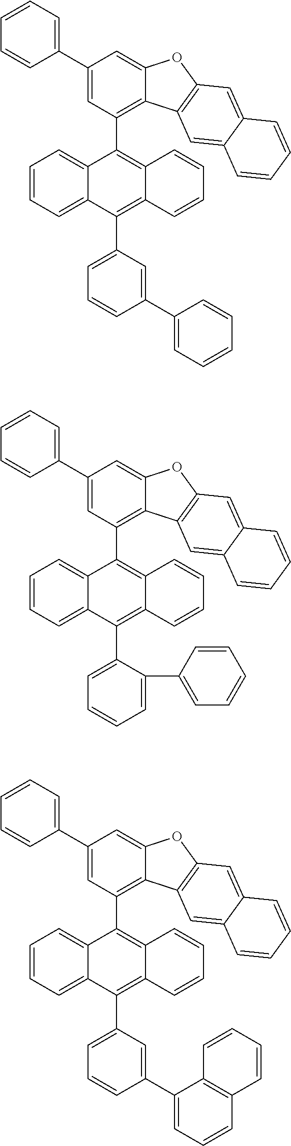 [SMILES: c1ccc(-c2cccc(-c3c4ccccc4c(-c4cc(-c5ccccc5)cc5oc6cc7ccccc7cc6c45)c4ccccc34)c2)cc1 ; c1ccc(-c2cc(-c3c4ccccc4c(-c4ccccc4-c4ccccc4)c4ccccc34)c3c(c2)oc2cc4ccccc4cc23)cc1 ; c1ccc(-c2cc(-c3c4ccccc4c(-c4cccc(-c5cccc6ccccc56)c4)c4ccccc34)c3c(c2)oc2cc4ccccc4cc23)cc1]

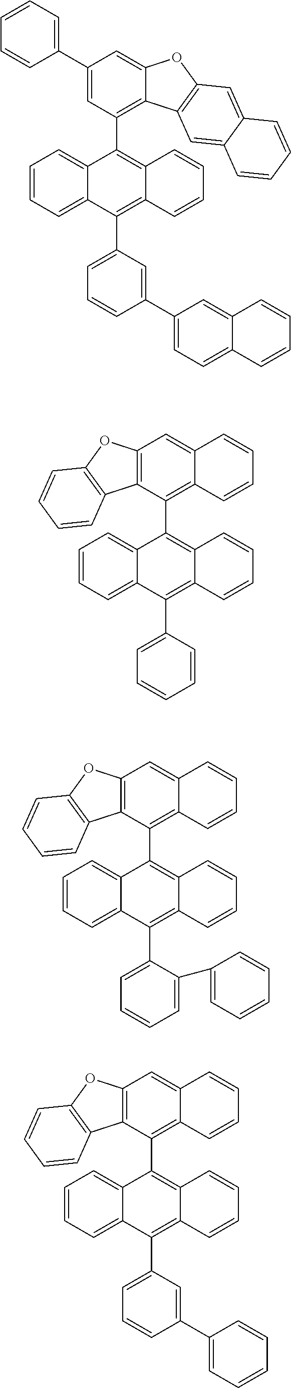

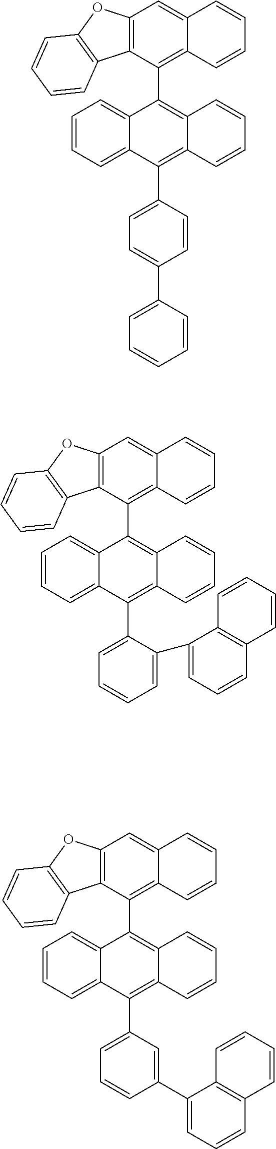 [SMILES: c1ccc(-c2ccc(-c3c4ccccc4c(-c4c5ccccc5cc5oc6ccccc6c45)c4ccccc34)cc2)cc1 ; c1ccc(-c2c3ccccc3c(-c3c4ccccc4cc4oc5ccccc5c34)c3ccccc23)c(-c2cccc3ccccc23)c1 ; c1cc(-c2cccc3ccccc23)cc(-c2c3ccccc3c(-c3c4ccccc4cc4oc5ccccc5c34)c3ccccc23)c1]

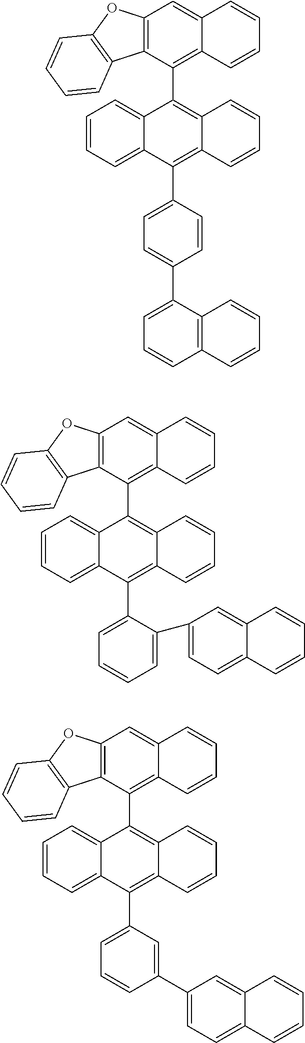

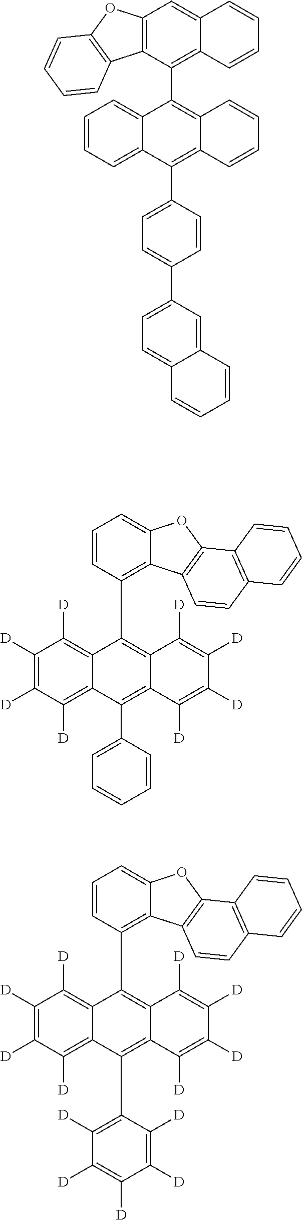 [SMILES: c1ccc2cc(-c3ccc(-c4c5ccccc5c(-c5c6ccccc6cc6oc7ccccc7c56)c5ccccc45)cc3)ccc2c1 ; [2H]c1c([2H])c([2H])c2c(-c3cccc4oc5c6ccccc6ccc5c34)c3c([2H])c([2H])c([2H])c([2H])c3c(-c3ccccc3)c2c1[2H] ; [2H]c1c([2H])c([2H])c(-c2c3c([2H])c([2H])c([2H])c([2H])c3c(-c3cccc4oc5c6ccccc6ccc5c34)c3c([2H])c([2H])c([2H])c([2H])c23)c([2H])c1[2H]]

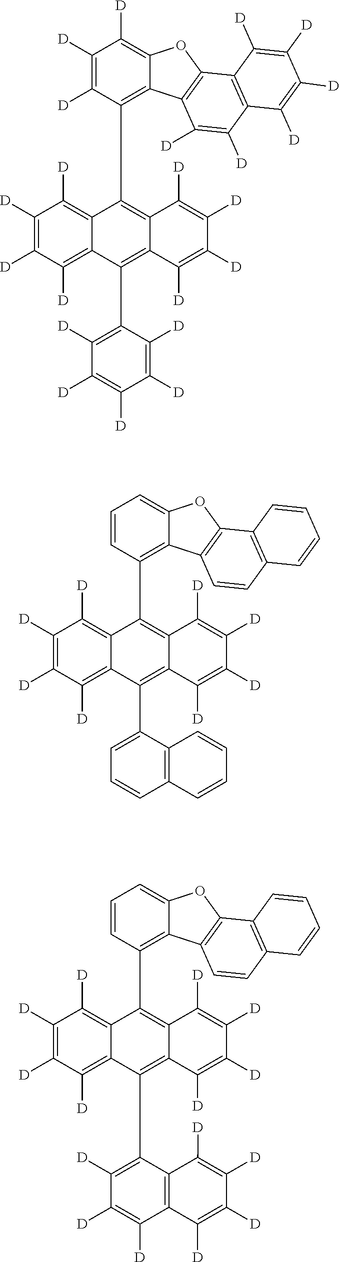 [SMILES: [2H]c1c([2H])c([2H])c(-c2c3c([2H])c([2H])c([2H])c([2H])c3c(-c3c([2H])c([2H])c([2H])c4oc5c6c([2H])c([2H])c([2H])c([2H])c6c([2H])c([2H])c5c34)c3c([2H])c([2H])c([2H])c([2H])c23)c([2H])c1[2H] ; [2H]c1c([2H])c([2H])c2c(-c3cccc4oc5c6ccccc6ccc5c34)c3c([2H])c([2H])c([2H])c([2H])c3c(-c3cccc4ccccc34)c2c1[2H] ; [2H]c1c([2H])c([2H])c2c(-c3c4c([2H])c([2H])c([2H])c([2H])c4c(-c4cccc5oc6c7ccccc7ccc6c45)c4c([2H])c([2H])c([2H])c([2H])c34)c([2H])c([2H])c([2H])c2c1[2H]]

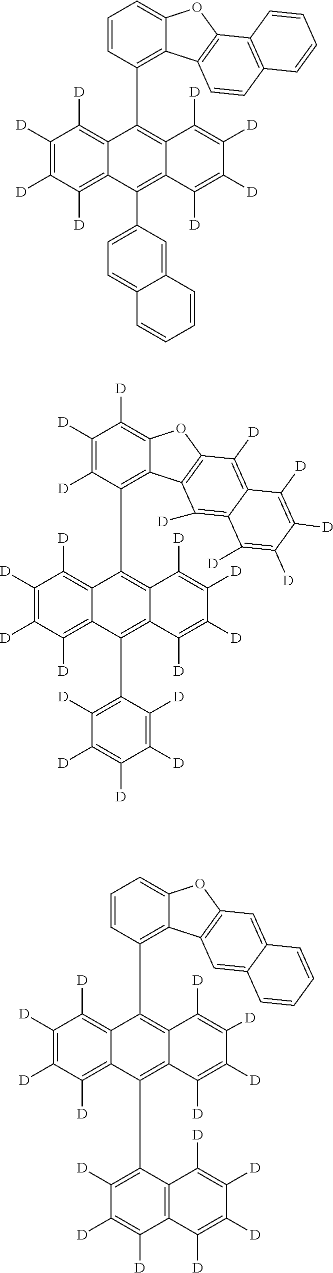 [SMILES: [2H]c1c([2H])c([2H])c2c(-c3cccc4oc5c6ccccc6ccc5c34)c3c([2H])c([2H])c([2H])c([2H])c3c(-c3ccc4ccccc4c3)c2c1[2H] ; [2H]c1c([2H])c([2H])c(-c2c3c([2H])c([2H])c([2H])c([2H])c3c(-c3c([2H])c([2H])c([2H])c4oc5c([2H])c6c([2H])c([2H])c([2H])c([2H])c6c([2H])c5c34)c3c([2H])c([2H])c([2H])c([2H])c23)c([2H])c1[2H] ; [2H]c1c([2H])c([2H])c2c(-c3c4c([2H])c([2H])c([2H])c([2H])c4c(-c4cccc5oc6cc7ccccc7cc6c45)c4c([2H])c([2H])c([2H])c([2H])c34)c([2H])c([2H])c([2H])c2c1[2H]]

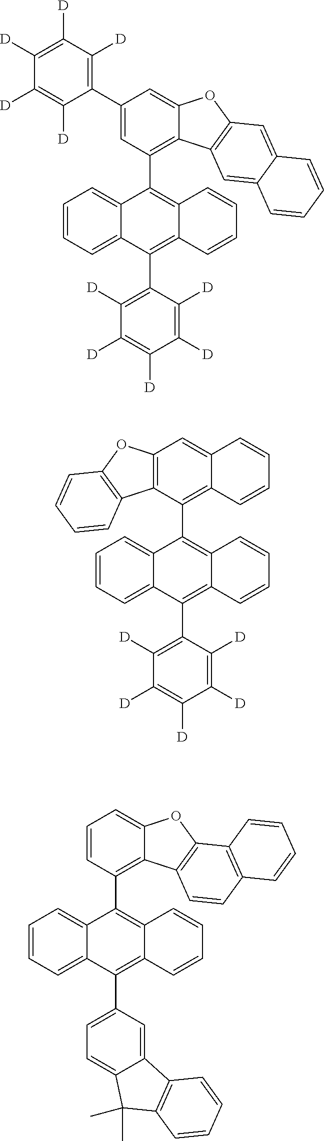 [SMILES: [2H]c1c([2H])c([2H])c(-c2cc(-c3c4ccccc4c(-c4c([2H])c([2H])c([2H])c([2H])c4[2H])c4ccccc34)c3c(c2)oc2cc4ccccc4cc23)c([2H])c1[2H] ; [2H]c1c([2H])c([2H])c(-c2c3ccccc3c(-c3c4ccccc4cc4oc5ccccc5c34)c3ccccc23)c([2H])c1[2H] ; CC1(C)c2ccccc2-c2cc(-c3c4ccccc4c(-c4cccc5oc6c7ccccc7ccc6c45)c4ccccc34)ccc21]

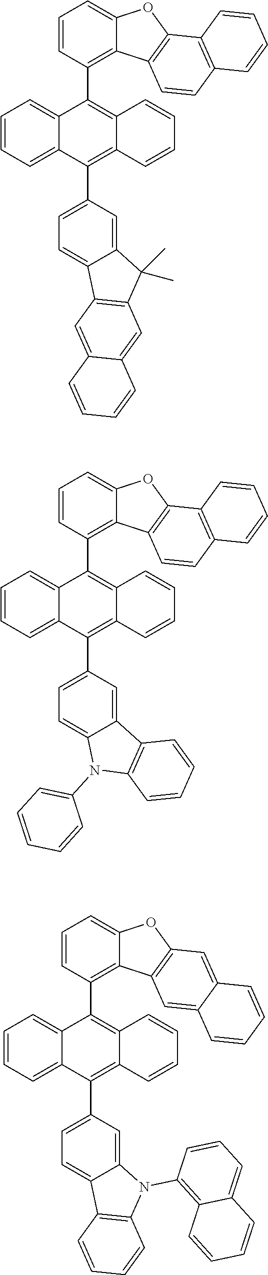 [SMILES: CC1(C)c2cc(-c3c4ccccc4c(-c4cccc5oc6c7ccccc7ccc6c45)c4ccccc34)ccc2-c2cc3ccccc3cc21 ; c1ccc(-n2c3ccccc3c3cc(-c4c5ccccc5c(-c5cccc6oc7c8ccccc8ccc7c56)c5ccccc45)ccc32)cc1 ; c1ccc2cc3c(cc2c1)oc1cccc(-c2c4ccccc4c(-c4ccc5c6ccccc6n(-c6cccc7ccccc67)c5c4)c4ccccc24)c13]

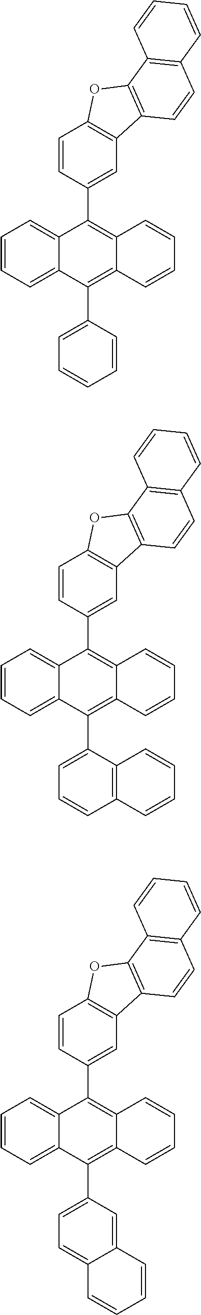 [SMILES: c1ccc(-c2c3ccccc3c(-c3ccc4oc5c6ccccc6ccc5c4c3)c3ccccc23)cc1 ; c1ccc2c(-c3c4ccccc4c(-c4ccc5oc6c7ccccc7ccc6c5c4)c4ccccc34)cccc2c1 ; c1ccc2cc(-c3c4ccccc4c(-c4ccc5oc6c7ccccc7ccc6c5c4)c4ccccc34)ccc2c1]

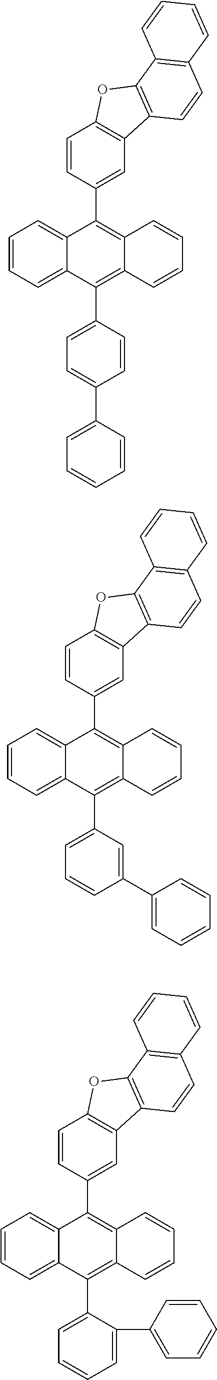 [SMILES: c1ccc(-c2ccc(-c3c4ccccc4c(-c4ccc5oc6c7ccccc7ccc6c5c4)c4ccccc34)cc2)cc1 ; c1ccc(-c2cccc(-c3c4ccccc4c(-c4ccc5oc6c7ccccc7ccc6c5c4)c4ccccc34)c2)cc1 ; c1ccc(-c2ccccc2-c2c3ccccc3c(-c3ccc4oc5c6ccccc6ccc5c4c3)c3ccccc23)cc1]

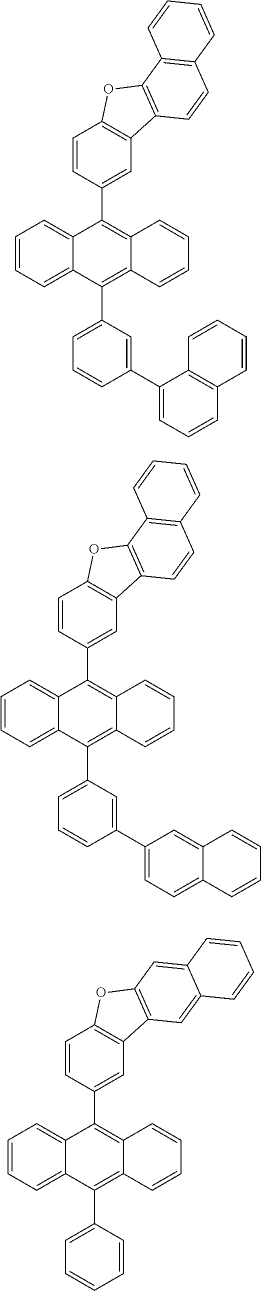

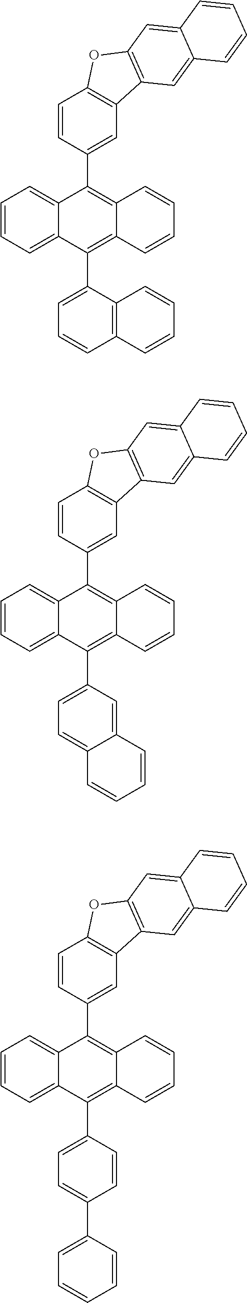 [SMILES: c1ccc2cc3c(cc2c1)oc1ccc(-c2c4ccccc4c(-c4cccc5ccccc45)c4ccccc24)cc13 ; c1ccc2cc(-c3c4ccccc4c(-c4ccc5oc6cc7ccccc7cc6c5c4)c4ccccc34)ccc2c1 ; c1ccc(-c2ccc(-c3c4ccccc4c(-c4ccc5oc6cc7ccccc7cc6c5c4)c4ccccc34)cc2)cc1]

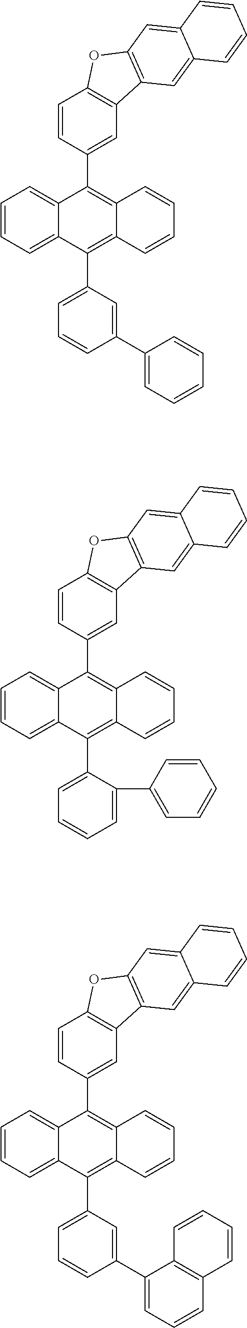 [SMILES: c1ccc(-c2cccc(-c3c4ccccc4c(-c4ccc5oc6cc7ccccc7cc6c5c4)c4ccccc34)c2)cc1 ; c1ccc(-c2ccccc2-c2c3ccccc3c(-c3ccc4oc5cc6ccccc6cc5c4c3)c3ccccc23)cc1 ; c1cc(-c2cccc3ccccc23)cc(-c2c3ccccc3c(-c3ccc4oc5cc6ccccc6cc5c4c3)c3ccccc23)c1]

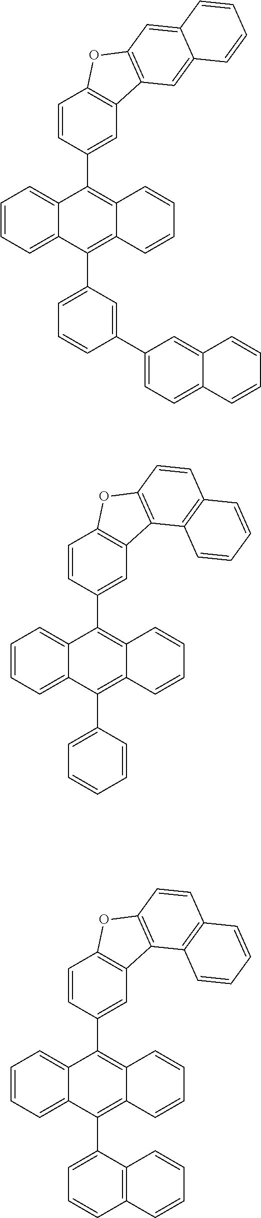 [SMILES: c1cc(-c2ccc3ccccc3c2)cc(-c2c3ccccc3c(-c3ccc4oc5cc6ccccc6cc5c4c3)c3ccccc23)c1 ; c1ccc(-c2c3ccccc3c(-c3ccc4oc5ccc6ccccc6c5c4c3)c3ccccc23)cc1 ; c1ccc2c(-c3c4ccccc4c(-c4ccc5oc6ccc7ccccc7c6c5c4)c4ccccc34)cccc2c1]

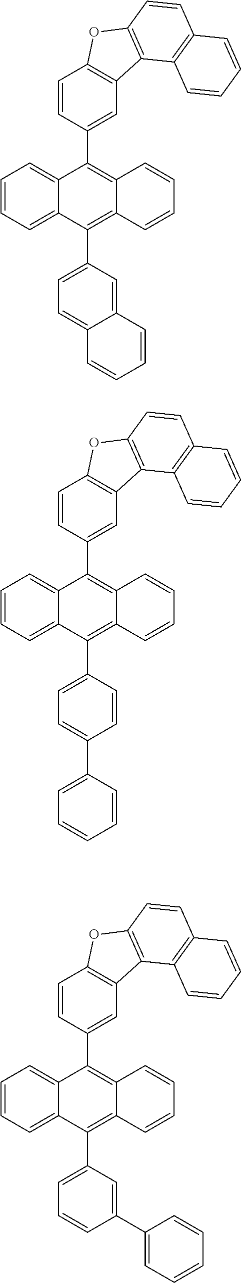

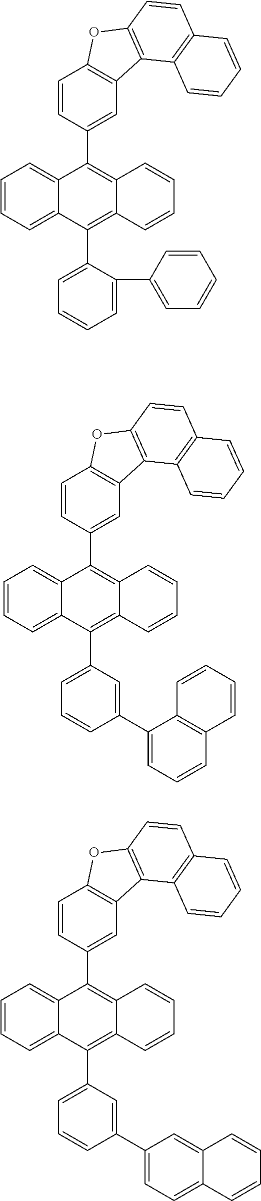

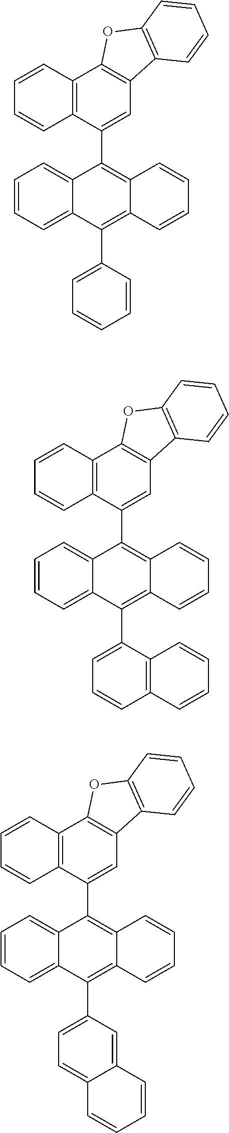 [SMILES: c1ccc(-c2c3ccccc3c(-c3cc4c5ccccc5oc4c4ccccc34)c3ccccc23)cc1 ; c1ccc2c(-c3c4ccccc4c(-c4cc5c6ccccc6oc5c5ccccc45)c4ccccc34)cccc2c1 ; c1ccc2cc(-c3c4ccccc4c(-c4cc5c6ccccc6oc5c5ccccc45)c4ccccc34)ccc2c1]

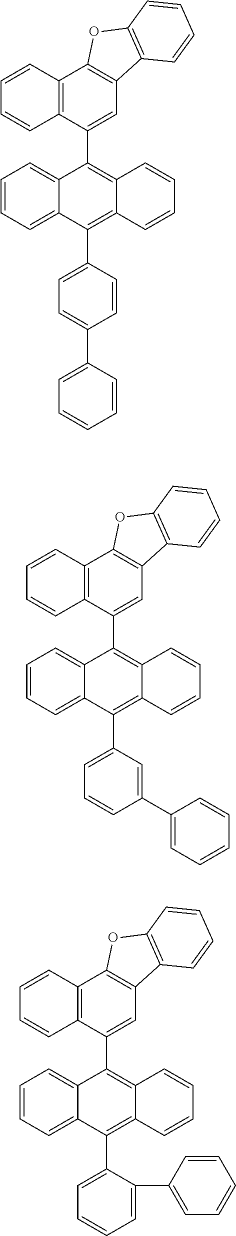

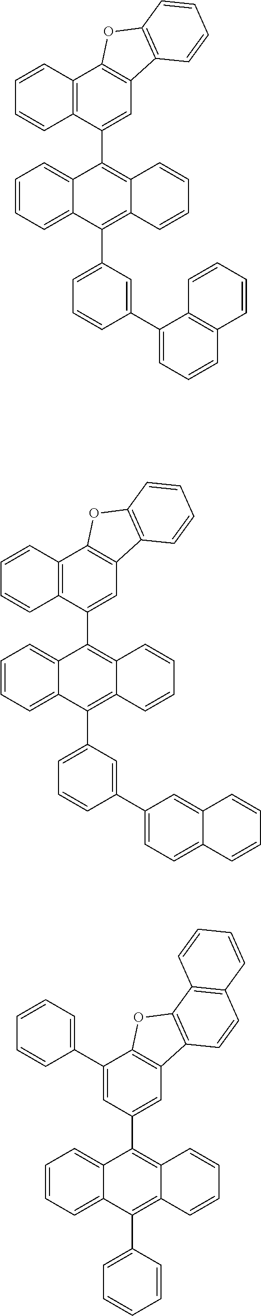 [SMILES: c1cc(-c2cccc3ccccc23)cc(-c2c3ccccc3c(-c3cc4c5ccccc5oc4c4ccccc34)c3ccccc23)c1 ; c1cc(-c2ccc3ccccc3c2)cc(-c2c3ccccc3c(-c3cc4c5ccccc5oc4c4ccccc34)c3ccccc23)c1 ; c1ccc(-c2c3ccccc3c(-c3cc(-c4ccccc4)c4oc5c6ccccc6ccc5c4c3)c3ccccc23)cc1]

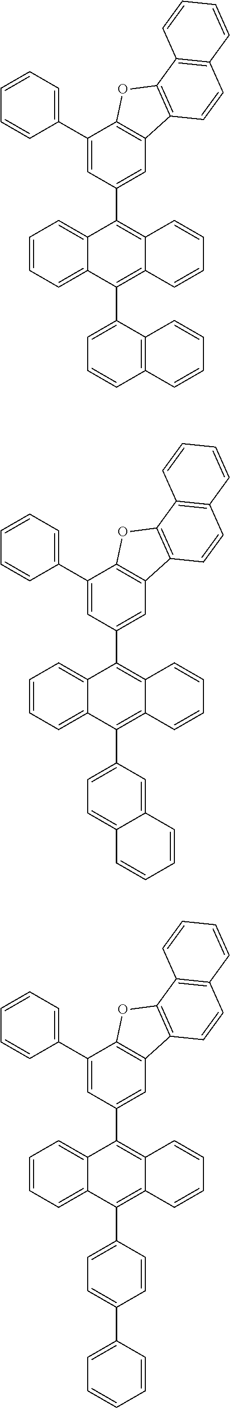 [SMILES: c1ccc(-c2cc(-c3c4ccccc4c(-c4cccc5ccccc45)c4ccccc34)cc3c2oc2c4ccccc4ccc32)cc1 ; c1ccc(-c2cc(-c3c4ccccc4c(-c4ccc5ccccc5c4)c4ccccc34)cc3c2oc2c4ccccc4ccc32)cc1 ; c1ccc(-c2ccc(-c3c4ccccc4c(-c4cc(-c5ccccc5)c5oc6c7ccccc7ccc6c5c4)c4ccccc34)cc2)cc1]

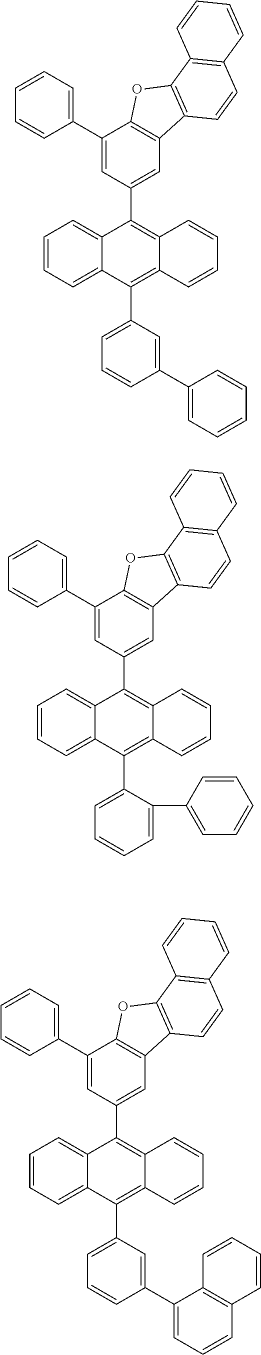

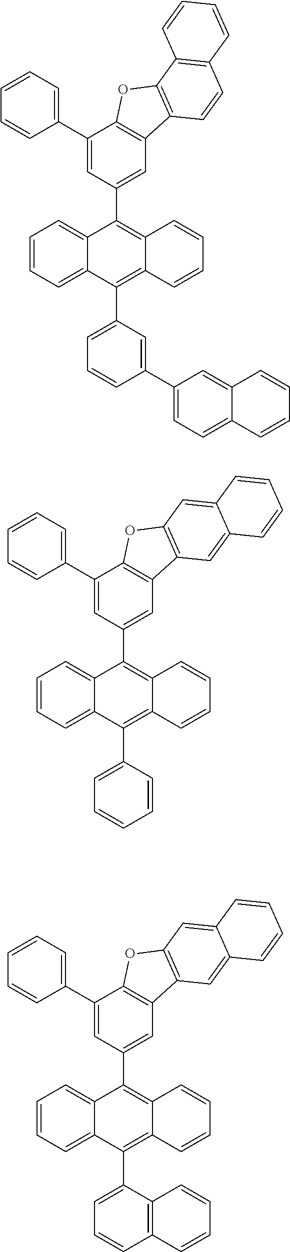

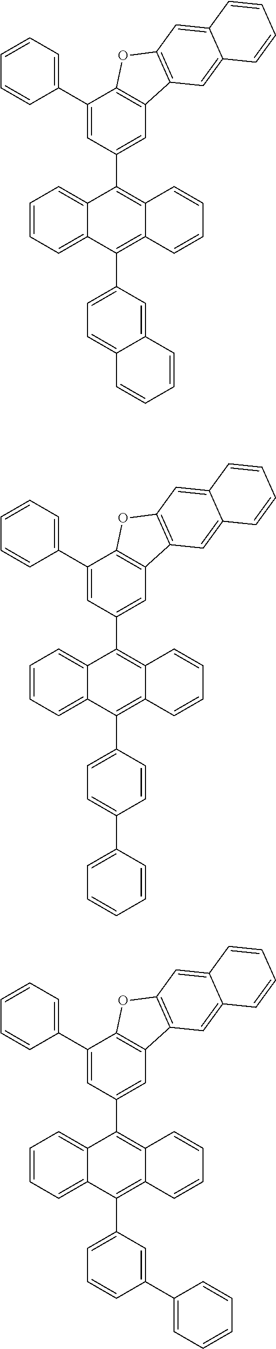 [SMILES: c1ccc(-c2cc(-c3c4ccccc4c(-c4ccc5ccccc5c4)c4ccccc34)cc3c2oc2cc4ccccc4cc23)cc1 ; c1ccc(-c2ccc(-c3c4ccccc4c(-c4cc(-c5ccccc5)c5oc6cc7ccccc7cc6c5c4)c4ccccc34)cc2)cc1 ; c1ccc(-c2cccc(-c3c4ccccc4c(-c4cc(-c5ccccc5)c5oc6cc7ccccc7cc6c5c4)c4ccccc34)c2)cc1]

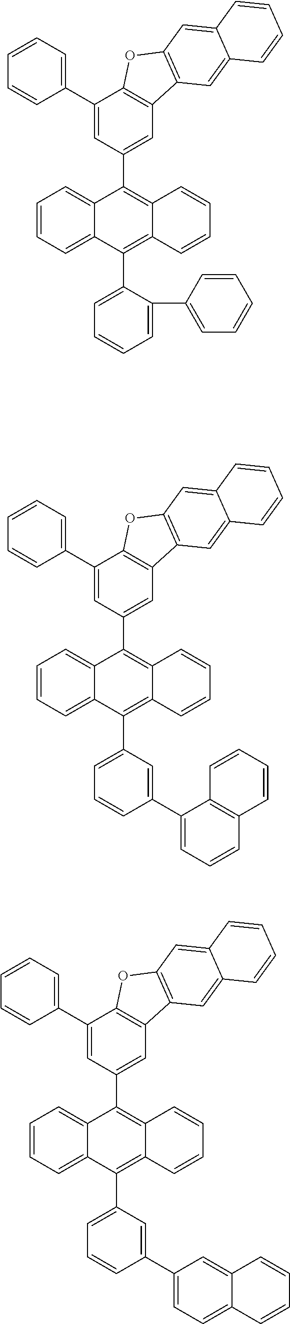 [SMILES: c1ccc(-c2ccccc2-c2c3ccccc3c(-c3cc(-c4ccccc4)c4oc5cc6ccccc6cc5c4c3)c3ccccc23)cc1 ; c1ccc(-c2cc(-c3c4ccccc4c(-c4cccc(-c5cccc6ccccc56)c4)c4ccccc34)cc3c2oc2cc4ccccc4cc23)cc1 ; c1ccc(-c2cc(-c3c4ccccc4c(-c4cccc(-c5ccc6ccccc6c5)c4)c4ccccc34)cc3c2oc2cc4ccccc4cc23)cc1]

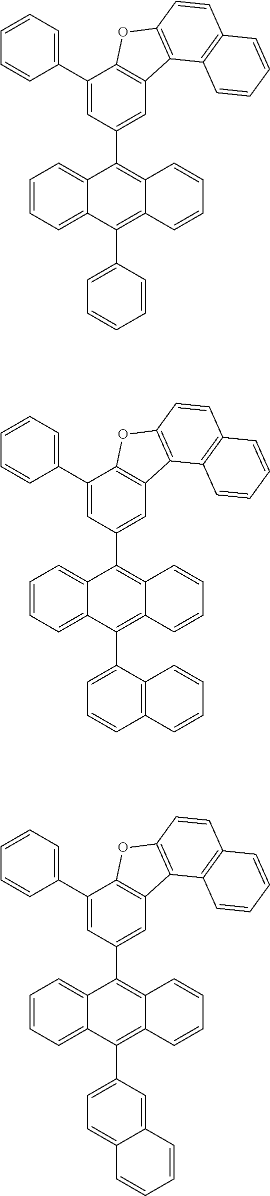 [SMILES: c1ccc(-c2c3ccccc3c(-c3cc(-c4ccccc4)c4oc5ccc6ccccc6c5c4c3)c3ccccc23)cc1 ; c1ccc(-c2cc(-c3c4ccccc4c(-c4cccc5ccccc45)c4ccccc34)cc3c2oc2ccc4ccccc4c23)cc1 ; c1ccc(-c2cc(-c3c4ccccc4c(-c4ccc5ccccc5c4)c4ccccc34)cc3c2oc2ccc4ccccc4c23)cc1]

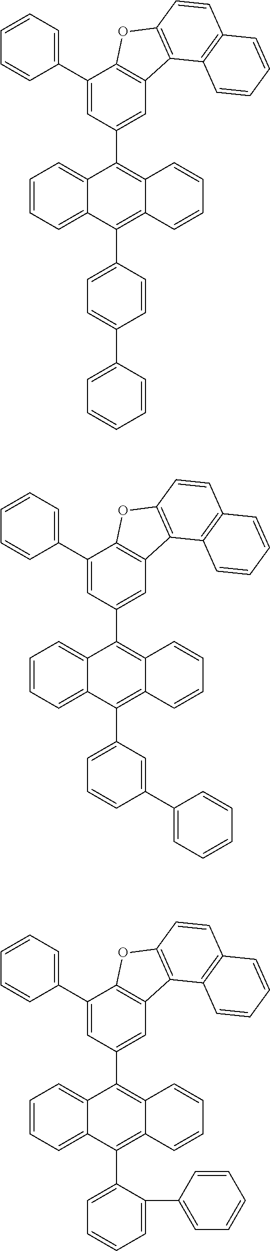 [SMILES: c1ccc(-c2ccc(-c3c4ccccc4c(-c4cc(-c5ccccc5)c5oc6ccc7ccccc7c6c5c4)c4ccccc34)cc2)cc1 ; c1ccc(-c2cccc(-c3c4ccccc4c(-c4cc(-c5ccccc5)c5oc6ccc7ccccc7c6c5c4)c4ccccc34)c2)cc1 ; c1ccc(-c2ccccc2-c2c3ccccc3c(-c3cc(-c4ccccc4)c4oc5ccc6ccccc6c5c4c3)c3ccccc23)cc1]

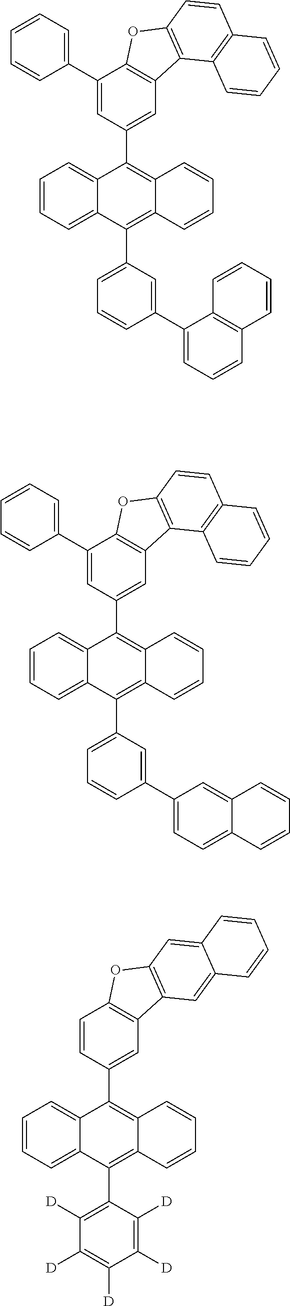 [SMILES: c1ccc(-c2cc(-c3c4ccccc4c(-c4cccc(-c5cccc6ccccc56)c4)c4ccccc34)cc3c2oc2ccc4ccccc4c23)cc1 ; c1ccc(-c2cc(-c3c4ccccc4c(-c4cccc(-c5ccc6ccccc6c5)c4)c4ccccc34)cc3c2oc2ccc4ccccc4c23)cc1 ; [2H]c1c([2H])c([2H])c(-c2c3ccccc3c(-c3ccc4oc5cc6ccccc6cc5c4c3)c3ccccc23)c([2H])c1[2H]]

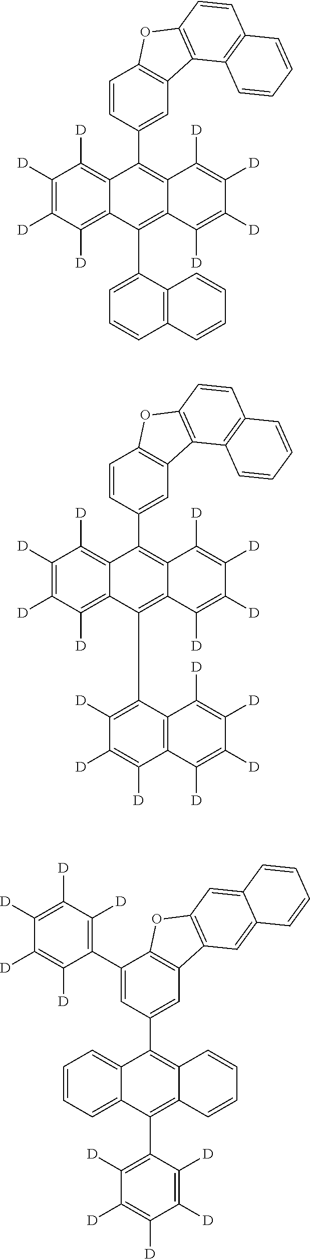

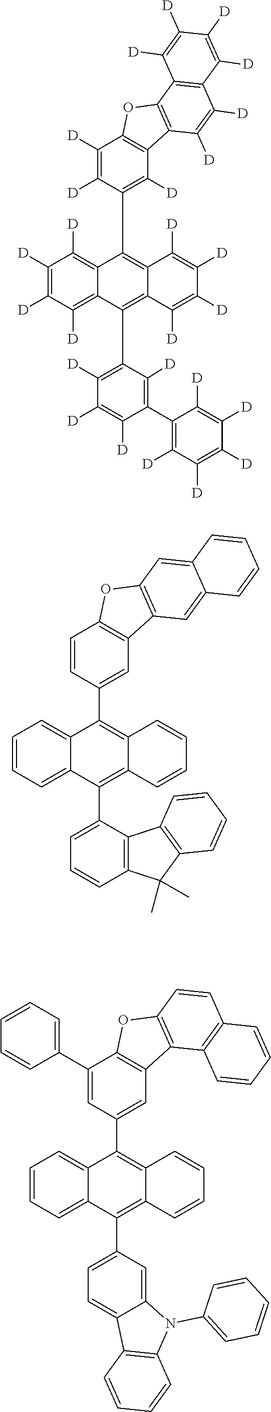

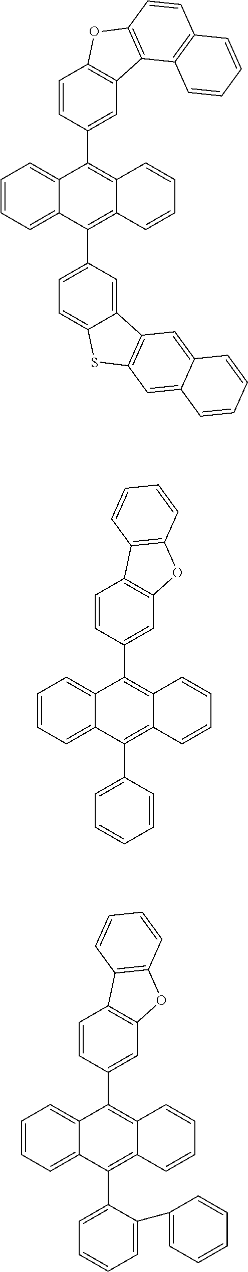 [SMILES: c1ccc2cc3c(cc2c1)sc1ccc(-c2c4ccccc4c(-c4ccc5oc6ccc7ccccc7c6c5c4)c4ccccc24)cc13 ; c1ccc(-c2c3ccccc3c(-c3ccc4c(c3)oc3ccccc34)c3ccccc23)cc1 ; c1ccc(-c2ccccc2-c2c3ccccc3c(-c3ccc4c(c3)oc3ccccc34)c3ccccc23)cc1]

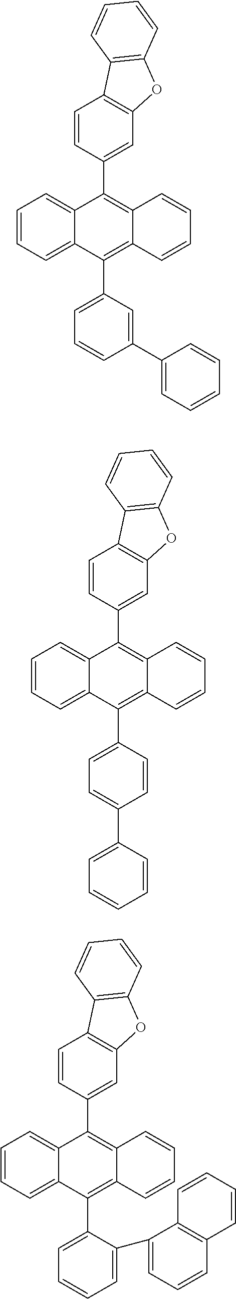

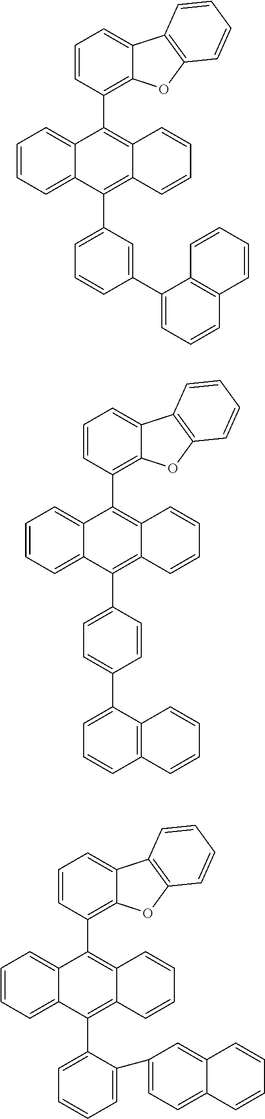

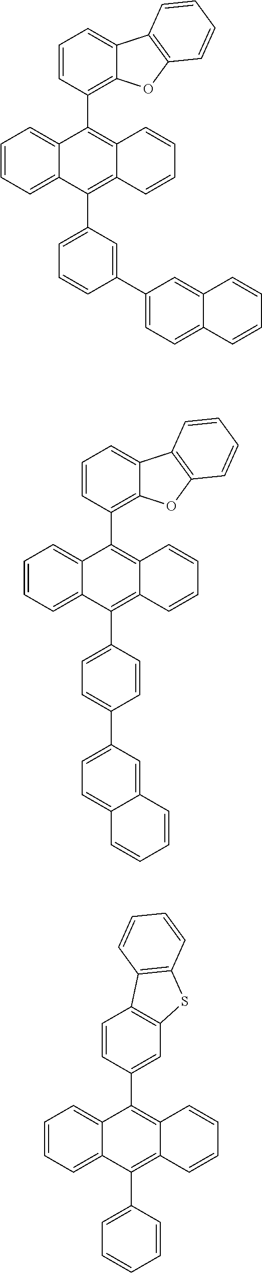 [SMILES: c1cc(-c2ccc3ccccc3c2)cc(-c2c3ccccc3c(-c3cccc4c3oc3ccccc34)c3ccccc23)c1 ; c1ccc2cc(-c3ccc(-c4c5ccccc5c(-c5cccc6c5oc5ccccc56)c5ccccc45)cc3)ccc2c1 ; c1ccc(-c2c3ccccc3c(-c3ccc4c(c3)sc3ccccc34)c3ccccc23)cc1]

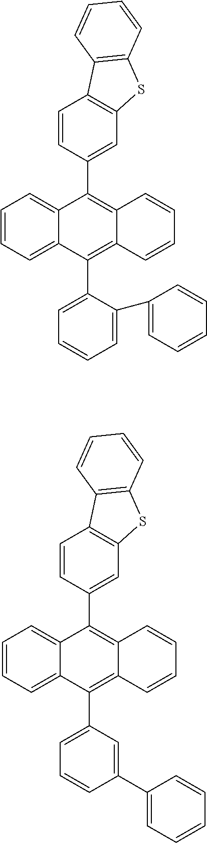 [SMILES: c1ccc(-c2ccccc2-c2c3ccccc3c(-c3ccc4c(c3)sc3ccccc34)c3ccccc23)cc1 ; c1ccc(-c2cccc(-c3c4ccccc4c(-c4ccc5c(c4)sc4ccccc45)c4ccccc34)c2)cc1]

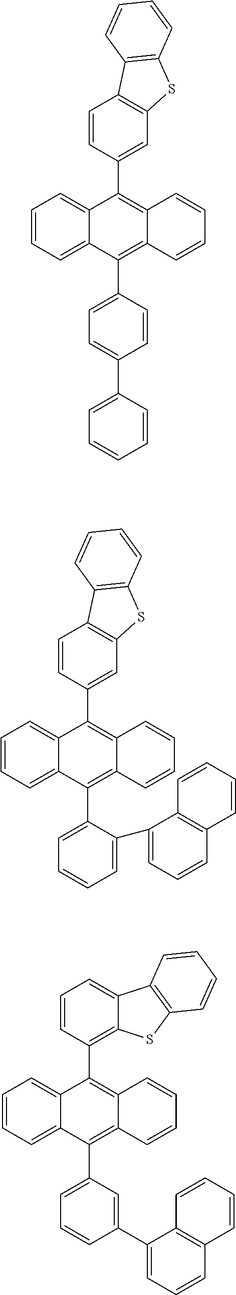 [SMILES: c1ccc(-c2ccc(-c3c4ccccc4c(-c4ccc5c(c4)sc4ccccc45)c4ccccc34)cc2)cc1 ; c1ccc(-c2c3ccccc3c(-c3ccc4c(c3)sc3ccccc34)c3ccccc23)c(-c2cccc3ccccc23)c1 ; c1cc(-c2cccc3ccccc23)cc(-c2c3ccccc3c(-c3cccc4c3sc3ccccc34)c3ccccc23)c1]

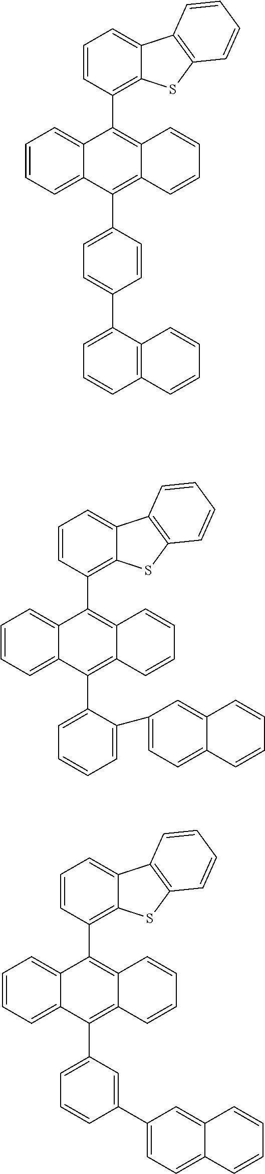 [SMILES: c1ccc2c(-c3ccc(-c4c5ccccc5c(-c5cccc6c5sc5ccccc56)c5ccccc45)cc3)cccc2c1 ; c1ccc(-c2c3ccccc3c(-c3cccc4c3sc3ccccc34)c3ccccc23)c(-c2ccc3ccccc3c2)c1 ; c1cc(-c2ccc3ccccc3c2)cc(-c2c3ccccc3c(-c3cccc4c3sc3ccccc34)c3ccccc23)c1]

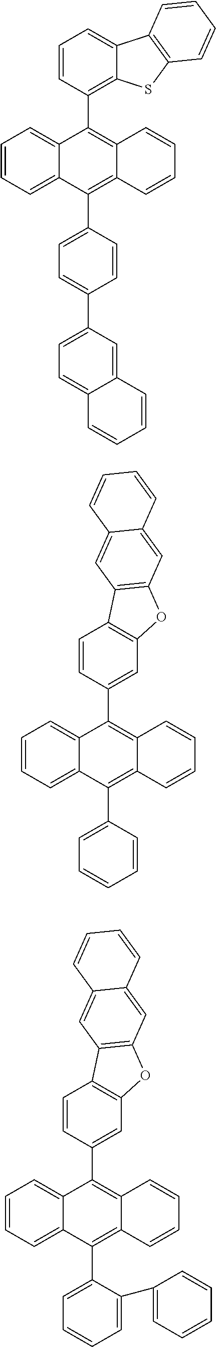

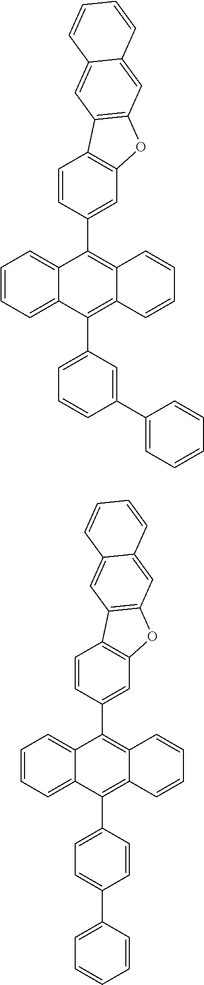 [SMILES: c1ccc(-c2cccc(-c3c4ccccc4c(-c4ccc5c(c4)oc4cc6ccccc6cc45)c4ccccc34)c2)cc1 ; c1ccc(-c2ccc(-c3c4ccccc4c(-c4ccc5c(c4)oc4cc6ccccc6cc45)c4ccccc34)cc2)cc1]

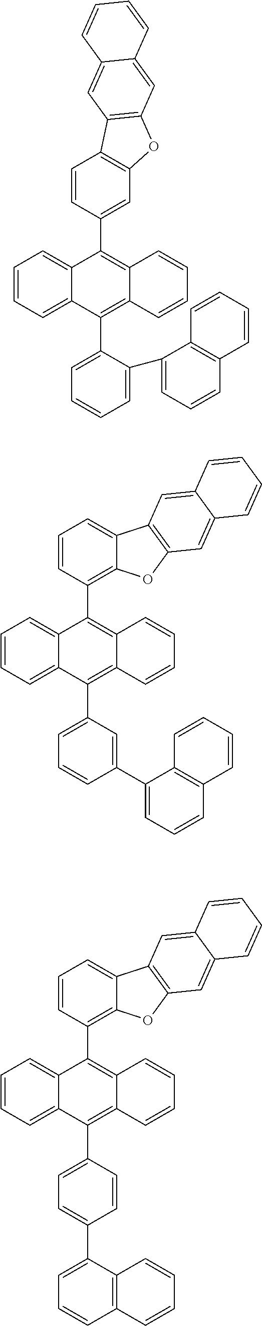 [SMILES: c1ccc(-c2c3ccccc3c(-c3ccc4c(c3)oc3cc5ccccc5cc34)c3ccccc23)c(-c2cccc3ccccc23)c1 ; c1cc(-c2cccc3ccccc23)cc(-c2c3ccccc3c(-c3cccc4c3oc3cc5ccccc5cc34)c3ccccc23)c1 ; c1ccc2cc3c(cc2c1)oc1c(-c2c4ccccc4c(-c4ccc(-c5cccc6ccccc56)cc4)c4ccccc24)cccc13]

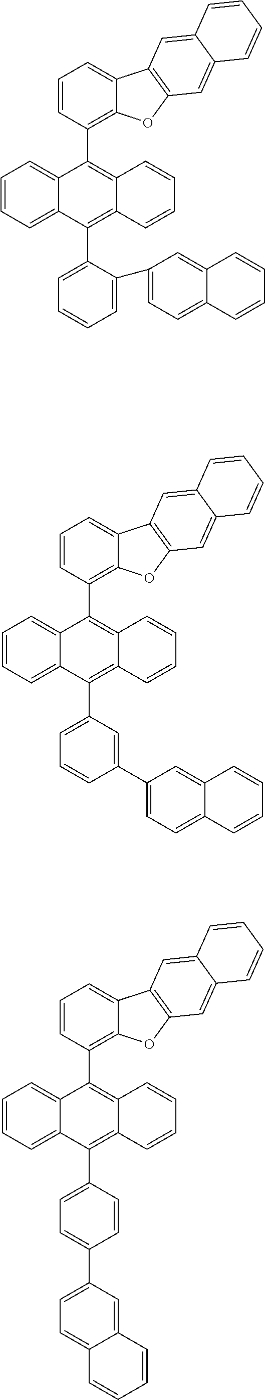 [SMILES: c1ccc(-c2c3ccccc3c(-c3cccc4c3oc3cc5ccccc5cc34)c3ccccc23)c(-c2ccc3ccccc3c2)c1 ; c1cc(-c2ccc3ccccc3c2)cc(-c2c3ccccc3c(-c3cccc4c3oc3cc5ccccc5cc34)c3ccccc23)c1 ; c1ccc2cc(-c3ccc(-c4c5ccccc5c(-c5cccc6c5oc5cc7ccccc7cc56)c5ccccc45)cc3)ccc2c1]

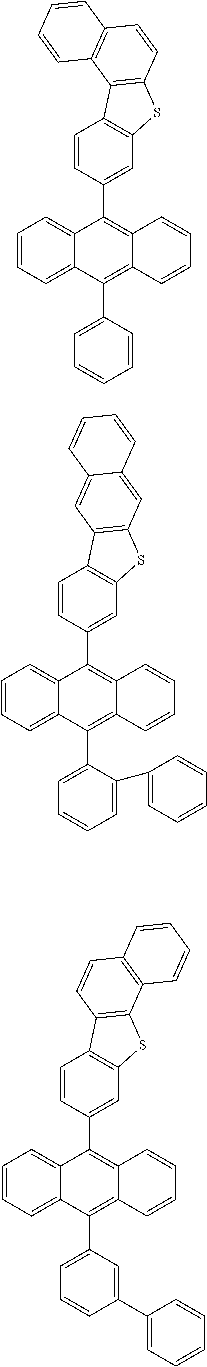

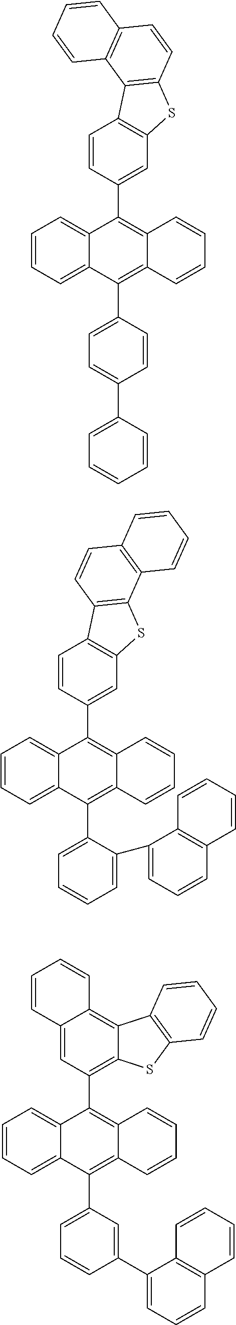

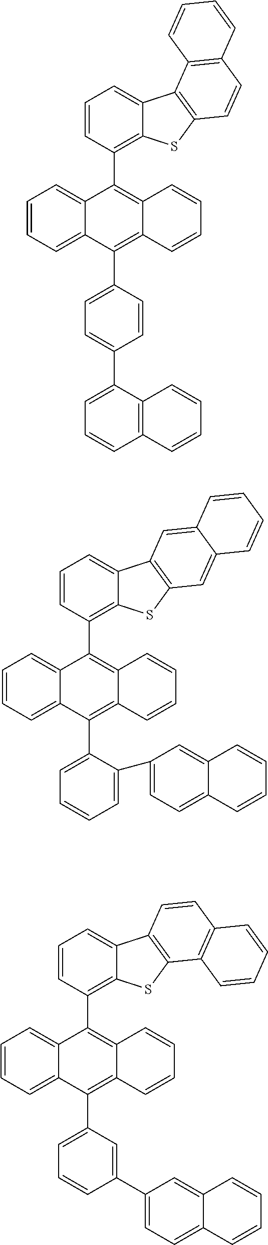 [SMILES: c1ccc2c(-c3ccc(-c4c5ccccc5c(-c5cccc6c5sc5ccc7ccccc7c56)c5ccccc45)cc3)cccc2c1 ; c1ccc(-c2c3ccccc3c(-c3cccc4c3sc3cc5ccccc5cc34)c3ccccc23)c(-c2ccc3ccccc3c2)c1 ; c1cc(-c2ccc3ccccc3c2)cc(-c2c3ccccc3c(-c3cccc4c3sc3c5ccccc5ccc43)c3ccccc23)c1]

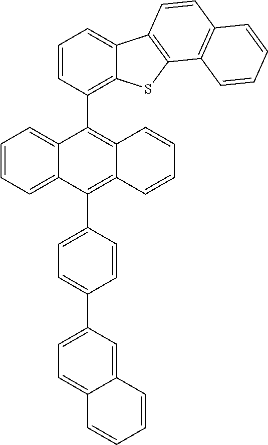 [SMILES: c1ccc2cc(-c3ccc(-c4c5ccccc5c(-c5cccc6c5sc5c7ccccc7ccc65)c5ccccc45)cc3)ccc2c1]

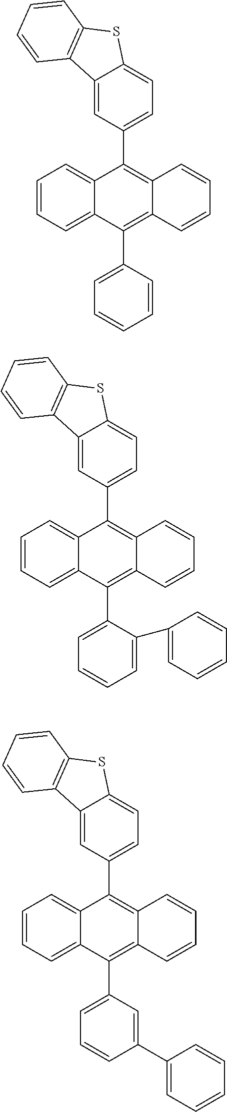 [SMILES: c1ccc(-c2c3ccccc3c(-c3ccc4sc5ccccc5c4c3)c3ccccc23)cc1 ; c1ccc(-c2ccccc2-c2c3ccccc3c(-c3ccc4sc5ccccc5c4c3)c3ccccc23)cc1 ; c1ccc(-c2cccc(-c3c4ccccc4c(-c4ccc5sc6ccccc6c5c4)c4ccccc34)c2)cc1]

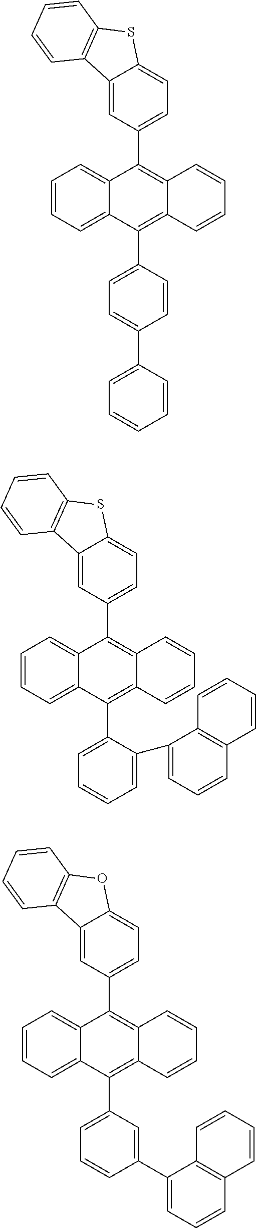 [SMILES: c1ccc(-c2ccc(-c3c4ccccc4c(-c4ccc5sc6ccccc6c5c4)c4ccccc34)cc2)cc1 ; c1ccc(-c2c3ccccc3c(-c3ccc4sc5ccccc5c4c3)c3ccccc23)c(-c2cccc3ccccc23)c1 ; c1cc(-c2cccc3ccccc23)cc(-c2c3ccccc3c(-c3ccc4oc5ccccc5c4c3)c3ccccc23)c1]

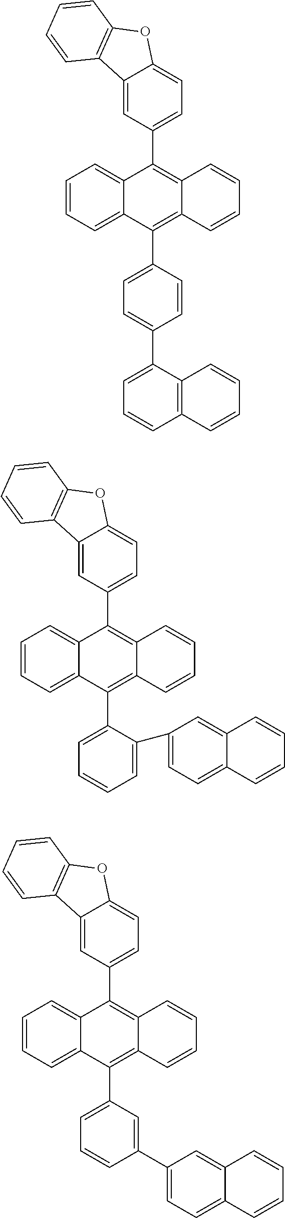 [SMILES: c1ccc2c(-c3ccc(-c4c5ccccc5c(-c5ccc6oc7ccccc7c6c5)c5ccccc45)cc3)cccc2c1 ; c1ccc(-c2c3ccccc3c(-c3ccc4oc5ccccc5c4c3)c3ccccc23)c(-c2ccc3ccccc3c2)c1 ; c1cc(-c2ccc3ccccc3c2)cc(-c2c3ccccc3c(-c3ccc4oc5ccccc5c4c3)c3ccccc23)c1]

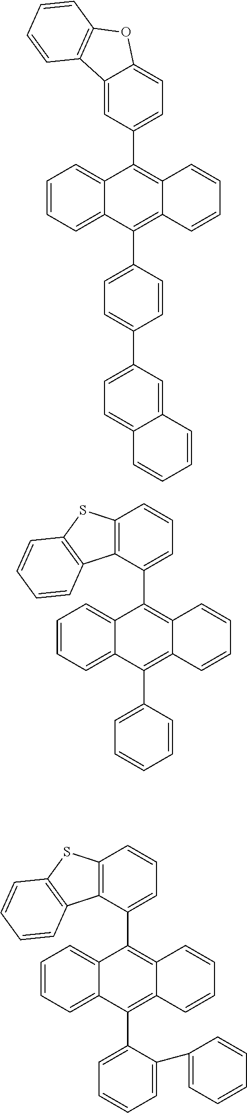

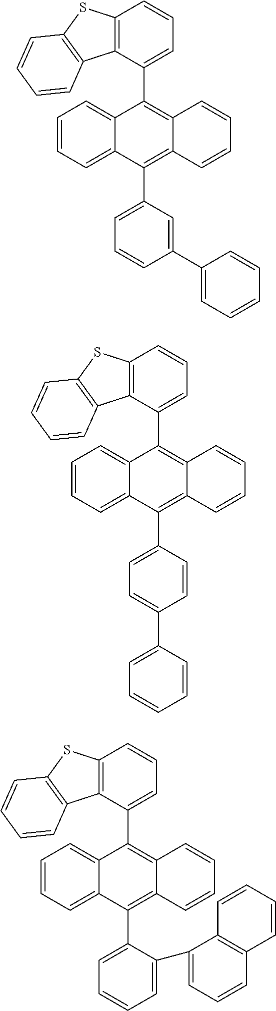

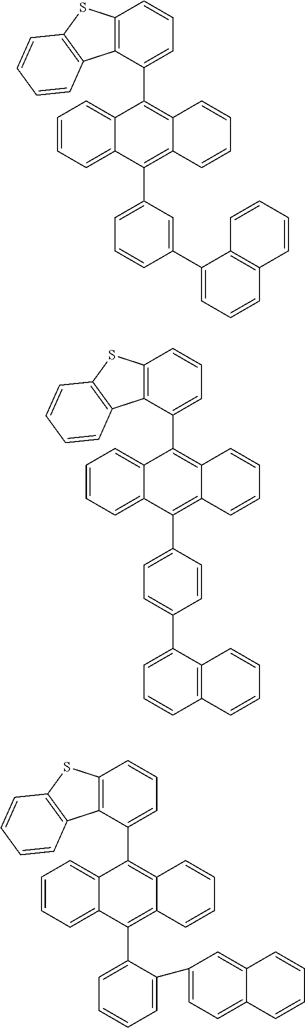 [SMILES: c1cc(-c2cccc3ccccc23)cc(-c2c3ccccc3c(-c3cccc4sc5ccccc5c34)c3ccccc23)c1 ; c1ccc2c(-c3ccc(-c4c5ccccc5c(-c5cccc6sc7ccccc7c56)c5ccccc45)cc3)cccc2c1 ; c1ccc(-c2c3ccccc3c(-c3cccc4sc5ccccc5c34)c3ccccc23)c(-c2ccc3ccccc3c2)c1]

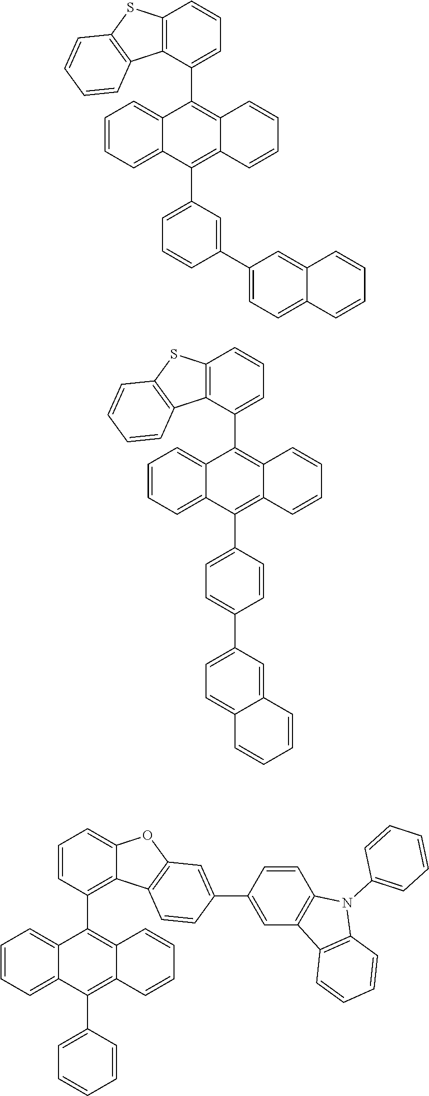 [SMILES: c1cc(-c2ccc3ccccc3c2)cc(-c2c3ccccc3c(-c3cccc4sc5ccccc5c34)c3ccccc23)c1 ; c1ccc2cc(-c3ccc(-c4c5ccccc5c(-c5cccc6sc7ccccc7c56)c5ccccc45)cc3)ccc2c1 ; c1ccc(-c2c3ccccc3c(-c3cccc4oc5cc(-c6ccc7c(c6)c6ccccc6n7-c6ccccc6)ccc5c34)c3ccccc23)cc1]

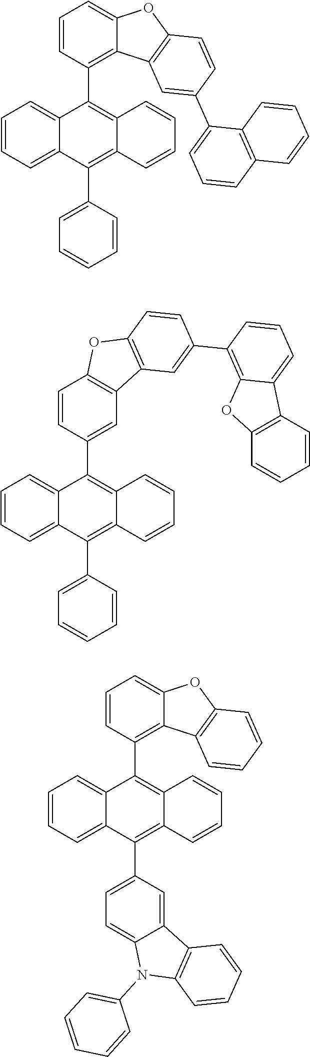 [SMILES: c1ccc(-c2c3ccccc3c(-c3cccc4oc5ccc(-c6cccc7ccccc67)cc5c34)c3ccccc23)cc1 ; c1ccc(-c2c3ccccc3c(-c3ccc4oc5ccc(-c6cccc7c6oc6ccccc67)cc5c4c3)c3ccccc23)cc1 ; c1ccc(-n2c3ccccc3c3cc(-c4c5ccccc5c(-c5cccc6oc7ccccc7c56)c5ccccc45)ccc32)cc1]

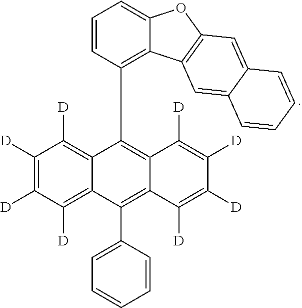 [SMILES: [2H]c1c([2H])c([2H])c2c(-c3cccc4oc5cc6ccccc6cc5c34)c3c([2H])c([2H])c([2H])c([2H])c3c(-c3ccccc3)c2c1[2H]]

The weight ratio of total dopant to total host material is in the range of 1:99 to 70:30; in some embodiments, 5:95 to 70:30; in some embodiments, 10:90 to 20:80.

Given these compositions and the use of one or more host materials that exhibit a net dipole moment, photoactive layers comprising these hosts and one or more dopants may have a non-zero spontaneous orientation polarization (SOP) when they are cast as thin films for use in the devices disclosed herein. The numeric value of the spontaneous orientation polarization in these circumstances is given by SOP-EML.

In some non-limiting embodiments of the organic electronic device disclosed herein, the magnitude of SOP-EML is between 1 and 10 mV/nm, in some non-limiting embodiments between 10 and 20 mV/nm, in some non-limiting embodiments between 20 and 30 mV/nm, in some non-limiting embodiments between 30 and 40 mV/nm, in some non-limiting embodiments between 40 and 50 mV/nm, in some non-limiting embodiments between 50 and 60 mV/nm, in some non-limiting embodiments between 60 and 70 mV/nm, in some non-limiting embodiments between 70 and 80 mV/nm, in some non-limiting embodiments between 80 and 90 mV/nm, and in some non-limiting embodiments between 90 and 100 mV/nm.

While it can be true that the use of such EML with non-zero SOP may benefit from lowered device operating voltage, it can also lead to increased quenching of excitons and lower device efficiency. Generally, a situation arises wherein electron/hole recombination zones in devices such as those disclosed herein are relatively narrow and close to the interface of the emissive layer and the electron blocking layer versus those disclosed by Bangsund et al. (Science Advances, vol. 6 (32), pp 1-10 (2020)). The deleterious effects due to present of SOP in EML may be mitigated by reducing positive charges closer to the interface between the EBL and the EML. This can be accomplished via judicious use of the electron blocking layer compositions disclosed herein with spontaneous orientation polarization (SOP-EBL) tailored to have numerical values close to the corresponding values for SOP-EML. As demonstrated in the Examples herein, device operating voltages can be maintained while overall efficiencies are improved.

b. Electron Blocking Layer

The electron blocking layer is generally a thin film comprising a mixture of a first compound and a second compound; wherein the first compound has a different chemical structure than the second compound; wherein the first compound and the second compound have molecular weights between 300 and 1000; wherein the first compound and the second compound have glass transition temperatures greater than 105° C.; wherein the first compound and the second compound each comprise one or more aryl amine groups; wherein a thin film formed from the first compound has a spontaneous orientation polarization SOP-1; wherein a thin film formed from the second compound has a spontaneous orientation polarization SOP-2; and the absolute value of the difference between SOP-1 and SOP-2 is greater than or equal to 10 mV/nm. Non-limiting embodiments for these compounds and associated properties have been disclosed above herein and also apply to the mixture of the first compound and second compound as used for the electron blocking layer in an organic electronic device.

In some non-limiting embodiments of the organic electronic device disclosed herein, the magnitude of SOP-EBL is between 1 and 10 mV/nm, in some non-limiting embodiments between 10 and 20 mV/nm, in some non-limiting embodiments between 20 and 30 mV/nm, in some non-limiting embodiments between 30 and 40 mV/nm, in some non-limiting embodiments between 40 and 50 mV/nm, in some non-limiting embodiments between 50 and 60 mV/nm, in some non-limiting embodiments between 60 and 70 mV/nm, in some non-limiting embodiments between 70 and 80 mV/nm, in some non-limiting embodiments between 80 and 90 mV/nm, and in some non-limiting embodiments between 90 and 100 mV/nm.

Overall device efficiency is found to improve when electron blocking layers are used having SOP-EBL values proximate to the SOP-EML of the device. In some non-limiting embodiments, the absolute value of the difference between SOP-EML and SOP-EBL is less than or equal to 25 mV/nm, in some non-limiting embodiments less than 20 mV/nm, in some non-limiting embodiments less than 15 mV/nm, in some non-limiting embodiments less than 10 mV/nm, in some non-limiting embodiments less than 5 mV/nm, in some non-limiting embodiments less than 2.5 mV/nm, and in some non-limiting embodiments less than 1 mV/nm.

The concept of using electron blocking layer(s) with spontaneous orientation polarization values close to the corresponding values for device photoactive layers to drive device efficiency improvements can be generalized beyond using electron blocking layers comprising a mixture of a first compound and a second compound as disclosed herein. So long as the absolute value of the difference between SOP-EML and SOP-EBL is less than or equal to 25 mV/nm, in some non-limiting embodiments less than 20 mV/nm, in some non-limiting embodiments less than 15 mV/nm, in some non-limiting embodiments less than 10 mV/nm, in some non-limiting embodiments less than 5 mV/nm, in some non-limiting embodiments less than 2.5 mV/nm, and in some non-limiting embodiments less than 1 mV/nm, efficiency improvement can be expected. In some non-limiting embodiments, electron blocking layers may comprise a mixture of a first compound, a second compound, and a third compound. In some non-limiting embodiments, four or more compounds can be used. Also, a single compound in an electron blocking layer with an appropriate SOP-EBL, can be used. This final approach may have practical limitations as it may be difficult to prepare a single compound with that exhibits the requisite SOP for a specific EML composition.

There is thus further provided herein an organic electronic device comprising an anode; a hole transporting layer; an electron blocking layer; a light emitting layer; an electron transport layer; and a cathode; wherein the light emitting layer comprises a host and a dopant; wherein the light emitting layer has a spontaneous orientation polarization SOP-EML; wherein the electron blocking layer has a spontaneous orientation polarization SOP-EBL; such that the absolute value of the difference between SOP-EML and SOP-EBL is less than or equal to 25 mV/nm.

c. Other Device Layers

The other layers in the organic electronic device can be made of any materials which are known to be useful in such layers.

The anode 110 is an electrode that is particularly efficient for injecting positive charge carriers. It can be made of, for example materials containing a metal, mixed metal, alloy, metal oxide or mixed-metal oxide, or it can be a conducting polymer, and mixtures thereof. Suitable metals include the Group 11 metals, the metals in Groups 4, 5, and 6, and the Group 8-10 transition metals. If the anode is to be light-transmitting, mixed-metal oxides of Groups 12, 13 and 14 metals, such as indium-tin-oxide, are generally used. The anode may also be made of an organic material such as polyaniline as described in “Flexible light-emitting diodes made from soluble conducting polymer,” Nature vol. 357, pp 477 479 (11 Jun. 1992). At least one of the anode and cathode should be at least partially transparent to allow the generated light to be observed.

The hole injection layer 120 includes hole injection material and may have one or more functions in an organic electronic device, including but not limited to, planarization of the underlying layer, charge transport and/or charge injection properties, scavenging of impurities such as oxygen or metal ions, and other aspects to facilitate or to improve the performance of the organic electronic device. The hole injection layer can be formed with polymeric materials, such as polyaniline (PANI) or polyethylenedioxythiophene (PEDOT), which are often doped with protonic acids. The protonic acids can be, for example, poly(styrene-sulfonic acid), poly(2-acrylamido-2-methyl-1-propanesulfonic acid), and the like.

The hole injection layer can include charge transfer compounds, and the like, such as copper phthalocyanine, 1,4,5,8,9,12-hexaaza-triphenylenehexacarbonitrile (HAT-CN), and the tetrathiafulvalene-tetracyanoquinodimethane system (TTF-TCNQ).

In some non-limiting embodiments, the hole injection layer includes at least one electrically conductive polymer and at least one fluorinated acid polymer.

Examples of hole transport materials for layer 130 have been summarized for example, in Kirk-Othmer Encyclopedia of Chemical Technology, Fourth Edition, Vol. 18, p. 837-860, 1996, by Y. Wang. Both hole transporting molecules and polymers can be used. Commonly used hole transporting molecules are: N,N′-diphenyl-N,N′-bis(3-methylphenyl)-[1,1′-biphenyl]-4,4′-diamine (TPD), 1,1-bis[(di-4-tolylamino) phenyl]cyclohexane (TAPC), N,N′-bis(4-methylphenyl)—N,N′-bis(4-ethylphenyl)-[1,1′-(3,3′-dimethyl)biphenyl]-4,4′-diamine (ETPD), tetrakis-(3-methylphenyl)-N,N,N′,N′-2,5-phenylenediamine (PDA), a-phenyl-4-N,N-diphenylaminostyrene (TPS), p-(diethylamino)benzaldehyde diphenylhydrazone (DEH), triphenylamine (TPA), bis[4-(N,N-diethylamino)-2-methylphenyl](4-methylphenyl)methane (MPMP), 1-phenyl-3-[p-(diethylamino)styryl]-5-[p-(diethylamino)phenyl]pyrazoline (PPR or DEASP), 1,2-trans-bis(9H-carbazol-9-yl)cyclobutane (DCZB), N,N,N′,N′-tetrakis(4-methylphenyl)-(1,1′-biphenyl)-4,4′-diamine (TTB), N,N′-bis(naphthalen-1-yl)-N,N′-bis-(phenyl)benzidine (D-NPB), and porphyrinic compounds, such as copper phthalocyanine. In some embodiments, the hole transport layer includes a hole transport polymer.

In some embodiments, the hole transport polymer is a distyrylaryl compound. In some embodiments, the aryl group has two or more fused aromatic rings. In some embodiments, the aryl group is an acene. The term “acene” as used herein refers to a hydrocarbon parent component that contains two or more ortho-fused benzene rings in a straight linear arrangement. Other commonly used hole transporting polymers are polyvinylcarbazole, (phenylmethyl)-polysilane, and polyaniline. It is also possible to obtain hole transporting polymers by doping hole transporting molecules such as those mentioned above into polymers such as polystyrene and polycarbonate. In some cases, triarylamine polymers are used, especially triarylamine-fluorene copolymers. In some cases, the polymers and copolymers are crosslinkable.

In some embodiments, the hole transport layer further includes a p-dopant. In some embodiments, the hole transport layer is doped with a p-dopant. Examples of p-dopants include, but are not limited to, tetrafluorotetracyanoquinodimethane (F4-TCNQ) and perylene-3,4,9,10-tetracarboxylic-3,4,9,10-dianhydride (PTCDA).

In some embodiments, more than one hole transport layer is present (not shown).

Examples of electron transport materials which can be used for layer 160 include, but are not limited to, metal chelated oxinoid compounds, including metal quinolate derivatives such as tris(8-hydroxyquinolato)aluminum (AIQ), bis(2-methyl-8-quinolinolato)(p-phenylphenolato) aluminum (BAIq), tetrakis-(8-hydroxyquinolato)hafnium (HfQ) and tetrakis-(8-hydroxyquinolato)zirconium (ZrQ); and azole compounds such as 2-(4-biphenylyl)-5-(4-t-butylphenyl)-1,3,4-oxadiazole (PBD), 3-(4-biphenylyl)-4-phenyl-5-(4-t-butylphenyl)-1,2,4-triazole (TAZ), and 1,3,5-tri(phenyl-2-benzimidazole)benzene (TPBI); quinoxaline derivatives such as 2,3-bis(4-fluorophenyl)quinoxaline; fluoranthene derivatives, such as 3-(4-(4-methylstyryl)phenyl-p-tolylamino)fluoranthene; phenanthrolines such as 4,7-diphenyl-1,10-phenanthroline (DPA) and 2,9-dimethyl-4,7-diphenyl-1,10-phenanthroline (DDPA); and mixtures thereof. In some embodiments, the electron transport layer further includes an n-dopant. N-dopant materials are well known. The n-dopants include, but are not limited to, Group 1 and 2 metals; Group 1 and 2 metal salts, such as LiF, CsF, and Cs₂CO₃; Group 1 and 2 metal organic compounds, such as L₁ quinolate; and molecular n-dopants, such as leuco dyes, metal complexes, such as W₂(hpp)₄ where hpp=1,3,4,6,7,8-hexahydro-2H-pyrimido-[1,2-a]-pyrimidine and cobaltocene, tetrathianaphthacene, bis(ethylenedithio)tetrathiafulvalene, heterocyclic radicals or diradicals, and the dimers, oligomers, polymers, dispiro compounds and polycycles of heterocyclic radical or diradicals.

In some embodiments, an anti-quenching layer may be present between the photoactive layer and the electron transport layer to prevent quenching of blue luminance by the electron transport layer. To prevent energy transfer quenching, the singlet energy of the anti-quenching material has to be higher than the singlet energy of the blue emitter. To prevent electron transfer quenching, the LUMO level of the anti-quenching material has to be shallow enough (with respect to the vacuum level) such that electron transfer between the emitter exciton and the anti-quenching material is endothermic. Furthermore, the HOMO level of the anti-quenching material has to be deep enough (with respect to the vacuum level) such that electron transfer between the emitter exciton and the anti-quenching material is endothermic. In general, anti-quenching material is a large band-gap material with high singlet and triplet energies.

The cathode 170, is an electrode that is particularly efficient for injecting electrons or negative charge carriers. The cathode can be any metal or nonmetal having a lower work function than the anode. Materials for the cathode can be selected from alkali metals of Group 1 (e.g., Li, Cs), the Group 2 (alkaline earth) metals, the Group 12 metals, including the rare earth elements and lanthanides, and the actinides. Materials such as aluminum, indium, calcium, barium, samarium, and magnesium, as well as combinations, can be used.

Alkali metal-containing inorganic compounds, such as LiF, CsF, Cs₂O and Li₂O, or Li-containing organometallic compounds can also be deposited between the organic layer 160 and the cathode layer 170 to lower the operating voltage. This layer, not shown, may be referred to as an electron injection layer.

It is known to have other layers in organic electronic devices. For example, there can be a layer (not shown) between the anode 110 and hole injection layer 120 to control the amount of positive charge injected and/or to provide band-gap matching of the layers, or to function as a protective layer. Layers that are known in the art can be used, such as copper phthalocyanine, silicon oxy-nitride, fluorocarbons, silanes, or an ultra-thin layer of a metal, such as Pt. Alternatively, some or all of anode layer 110, active layers 120, 130, 140, 150, and 160, or cathode layer 170, can be surface-treated to increase charge carrier transport efficiency. The choice of materials for each of the component layers is preferably determined by balancing the positive and negative charges in the emitter layer to provide a device with high electroluminescence efficiency.

It is understood that each functional layer can be made up of more than one layer.

d. Device Fabrication

The device layers can be formed by any deposition technique, or combinations of techniques, including vapor deposition, liquid deposition, and thermal transfer.

In some embodiments, the device is fabricated by liquid deposition of the hole injection layer, the hole transport layer, the electron blocking layer, and the photoactive layer, and by vapor deposition of the anode, the electron transport layer, an electron injection layer and the cathode. Suitable liquid deposition techniques are well known in the art.

In some embodiments, all the device layers are fabricated by vapor deposition. Such techniques are well known in the art.

### EXAMPLES

The concepts described herein will be further described in the following examples, which do not limit the scope of the invention described in the claims.

### Synthesis Examples

These examples illustrate the preparation of aryl amine compounds for use in the electron blocking layer of an organic electronic device, as described above.

### Synthesis Example 1

### Synthesis of Compound 1-1

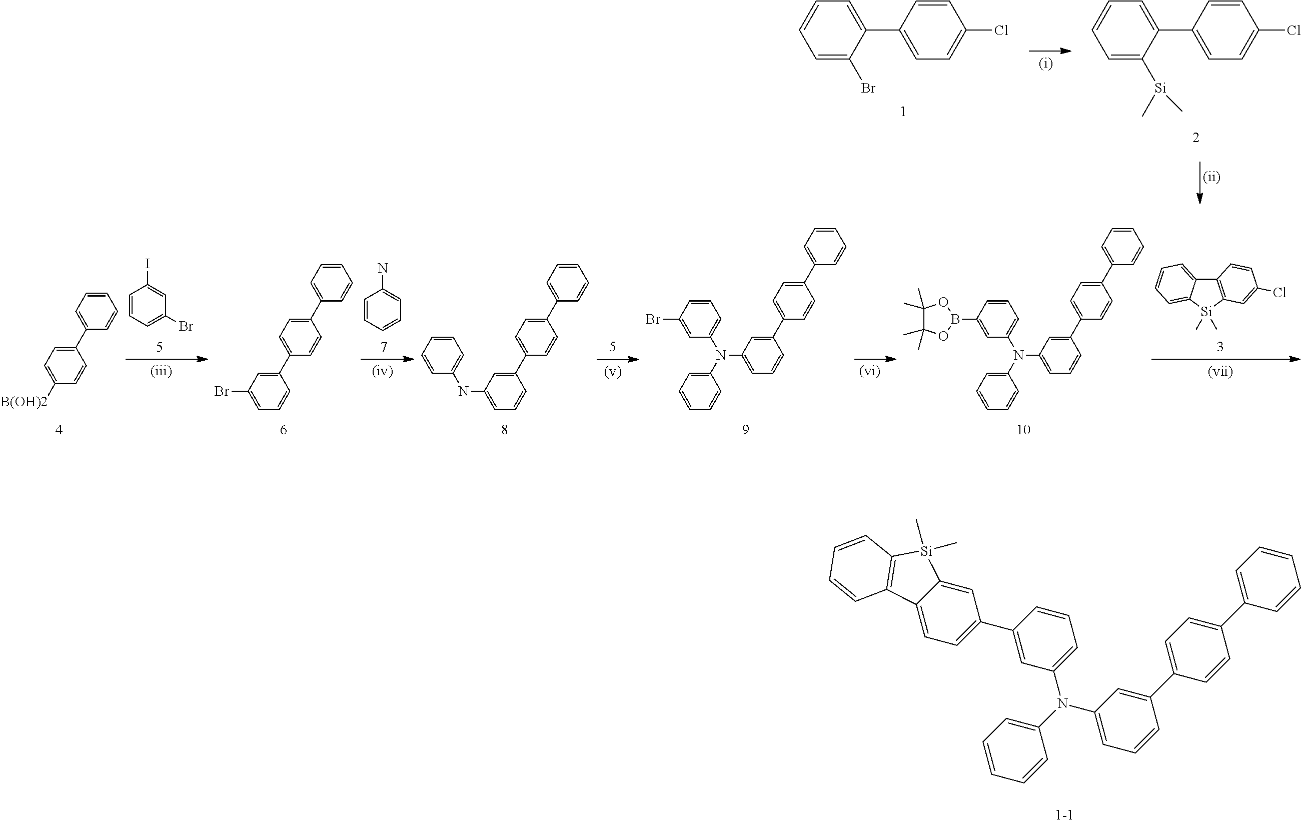

### Synthesis of (4′-chloro-[1,1′-biphenyl]-2-yl) dimethylsilane (2)

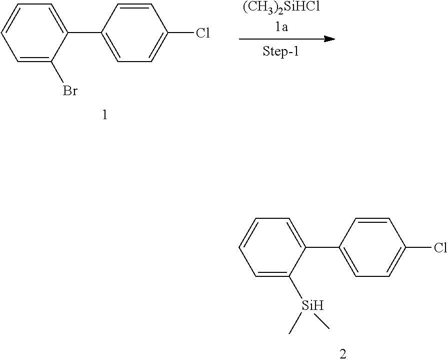

n-BuLi (43.2 mL, 112.35 mmol) was added dropwise to a stirred solution of Comp-1 (20 g, 74.9 mmol) in THE (100 mL), maintained at −78° C., and stirred for 30 mins at same temperature. Comp-1a (13.2 mL, 112.35 mmol) was added to the reaction mixture and continued stirring for 12 h at room temperature. Progress of the reaction was monitored by UPLC and TLC. After 12 h, UPLC showed 65.41% of Comp-2 at 4.70 RT. The reaction mixture was quenched with saturated NH₄Cl solution (200 mL) and extracted with EtOAc (3×100 mL). The combined organics were dried over anhydrous Na₂SO₄ and concentrated to get the crude compound. This was purified by column chromatography using silica (100-200) mesh by eluting with 0-1% EtOAc in petroleum ether to get 12 g of Comp-2 (47%) with 73.14% purity by UPLC. ¹H NMR (CDCl₃, 400 MHz) δ 7.61 (dd, J=4.8, 3.2 Hz, 1H), 7.50-7.56 (m, 1H), 7.40-7.46 (m, 4H), 7.23-7.39 (m, 1H), 0.06 (s, 6H).

### Synthesis of 3-chloro-5,5-dimethyl-5H-dibenzo[b,d]silole (3)

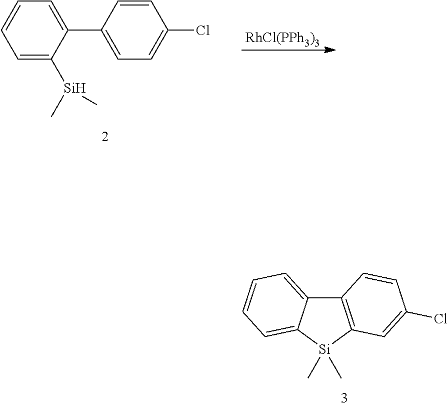

Comp-2 (8 g, 32.52 mmol) was taken in 1,4-dioxane (160 mL) and RhCI(PPh₃)₃(300 mg, 0.32 mmol) was added to it. Then reaction mixture was heated at 120° C. for 30 mins. Progress of the reaction was monitored by TLC and reaction was continued until complete consumption of Comp-2. The reaction mixture was cooled and quenched with water (100 ml) and extracted with ethyl acetate (2×100 ml). The combined organics were dried over anhydrous Na₂SO₄ and concentrated under reduced pressure to get the crude compound. This was purified by column chromatography using silica (100-200) mesh by eluting with 5-10% EtOAc in petroleum ether to get 6.8 g colourless liquid which was further purified by Prep-HPLC to get 3 g of Comp-3 (37%) as colourless liquid with 99.51% purity by LCMS. ¹H NMR (CDCl₃, 400 MHz) δ 7.71-7.78 (m, 2H), 7.61 (dd, J=2 Hz, 1.6 Hz, 1H), 7.56 (d, J=2 Hz, 1H), 7.41-7.45 (m, 1H), 7.38 (dd, J=8.4 Hz, 2.4 Hz, 1H), 7.26-7.36 (m, 1H), 0.42 (s, 6H)

### Synthesis of 3-bromo-1,1′:4′,1″-terphenyl (6)

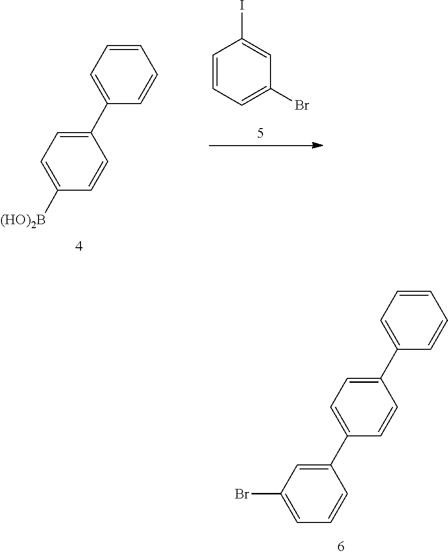 [SMILES: OB(O)c1ccc(-c2ccccc2)cc1 ; Brc1cccc(I)c1 ; Brc1cccc(-c2ccc(-c3ccccc3)cc2)c1]

Comp-4 (10 g, 50.5 mmol) and Comp-5 (7.7 mL, 60.6 mmol) were taken in toluene (100 mL) and water (20 mL), and K₂CO₃ (13.93 g, 101.1 mmol), was added to the mixture. Then the reaction mixture was degassed with argon for 5 min. After adding Pd(PPh₃)₄ (2.9 g, 2.52 mmol) to the reaction mixture, it was again degassed with argon. The reaction was continued for 12 h at 110° C. Progress of the reaction was monitored by UPLC. After 12 h, UPLC showed 94% formation of Comp-6 at 4.96 RT. The reaction was quenched with water (100 ml) and extracted with EtOAc (2×100 mL). The combined organic layers were dried over anhydrous Na₂SO₄ and concentrated under reduced pressure to get the crude compound. This was purified by column chromatography using silica gel by eluting with 5-10% EtOAc in petroleum ether to get 15 g of Comp-6 (90%) as white solid with 95% purity by UPLC. ¹H NMR (CDCl₃, 400 MHz) δ 7.69 (s, J=4.4 Hz, 1H), 7.62-7.67 (m, 6H), 7.55-7.57 (m, 1H), 7.45-7.50 (m, 3H), 7.35-7.39 (m, 1H), 7.30-7.34 (m, 1H).

### Synthesis of N-phenyl-[1,1′:4′,1″-terphenyl]-3-amine (8)

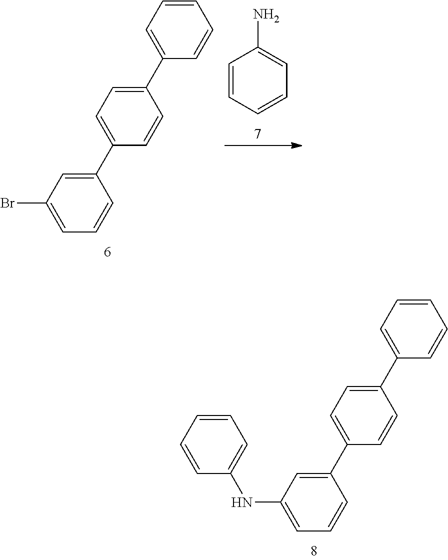

NaOtBu (3.11 g, 32.4 mmol) was added to a stirred solution of Comp-6 (5 g, 16.2 mmol) and Comp-7 (1.78 mL, 19.41 mmol) in toluene (50 mL). The resulting mixture was degassed with argon for 5 min. Pd₂(dba)₃ (740 mg, 0.80 mmol) and dppf (1,1′-ferrocenediyl-bis(diphenylphosphine), 896 mg, 1.6 mmol) were added to the mixture and degassed again. The reaction mixture was heated at 110° C. and the reaction was continued for 12 h. Progress of the reaction was monitored by UPLC. After 12 h, UPLC showed 84% of Comp-8 at 4.68 RT. The Reaction was cooled and filtered through a Celite® pad. Filtrates were concentrated to get crude compound. The obtained crude was purified by column chromatography using silica gel by eluting with 5-10% EtOAc in petroleum ether to get 5 g (90%) of brown solid with 91% purity by UPLC. ¹HNMR (CDCl₃, 400 MHz) δ 7.62-7.65 (m, 6H), 7.43-7.47 (m, 2H), 7.31-7.37 (m, 6H), 7.19-7.29 (m, 1H), 7.13 (dd, J=9.6, 1.2 Hz, 2H), 7.07 (dd, J=8.0, 1.0 Hz, 1H), 6.95-6.97 (m, 1H), 5.80 (s, 1H). (ESI)m/z: [M+H]⁺ calculated for C₂₄H₁₉N 321.42; found 322.39.

### Synthesis of N-(3-bromophenyl)-N-phenyl-[1,1′:4′,1″-terphenyl]-3-amine (9)

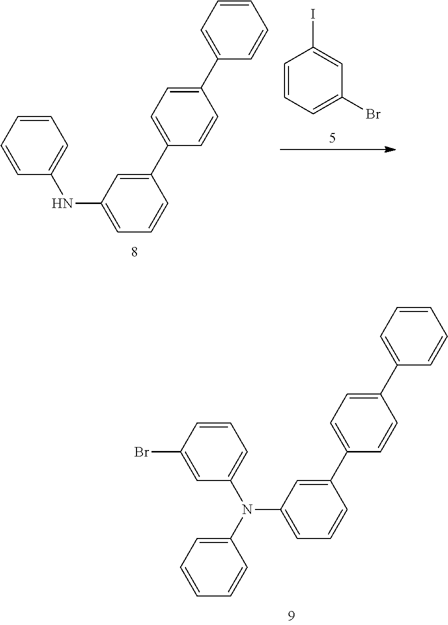

Comp-8 (3.5 g, 10.9 mmol), Comp-5 (2.8 mL, 21.8 mmol), and NaOtBu (2.13 g, 21.8 mmol) were taken in toluene (35 mL) and the mixture was degassed with argon for 5 min. Pd₂(dba)₃ (0.49 g, 0.545 mmol) and dppf (0.6 g, 1.09 mmol) were added to the reaction and stirred for 16 h at 110° C. Progress of the reaction was monitored by UPLC. After 16 h, UPLC showed 76.5% formation of the desired peak at 5.42 RT. The Reaction mixture was cooled and filtered through Celite® pad. Filtrates were concentrated to get crude compound. The obtained crude was purified by column chromatography using silica gel by eluting with 5-10% EtOAc in petroleum ether to get 3.5 g (67%) of brown solid with 90% by UPLC. ¹HNMR (CDCl₃, 400 MHz) δ 7.53-7.64 (m, 6H), 7.42-7.46 (m, 2H), 7.28-7.36 (m, 7H), 7.15 (d, J=1.2 Hz, 2H), 7.02-7.71 (m, 5H). (ESI-MS) m/z: [M+H]⁺ calculated for C₃₀H₂₂BrN 476.42; found 478.23.

### Synthesis of N-phenyl-N-(3-(4,4,5,5-tetramethyl-1,3,2-dioxaborolan-2-yl)phenyl)-[1,1′:4′,1″-terphenyl]-3-amine (10)

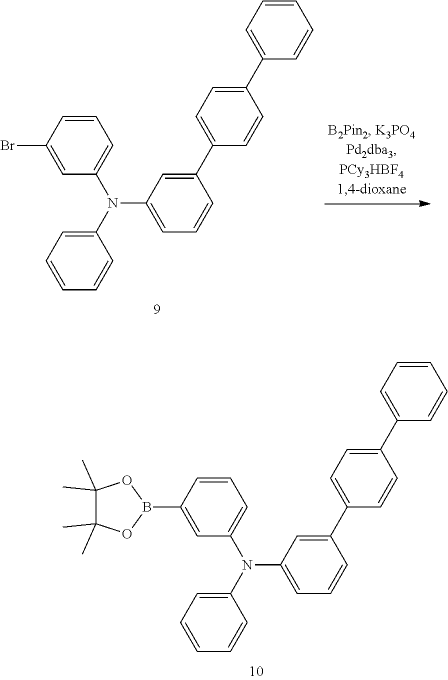 [SMILES: Brc1cccc(N(c2ccccc2)c2cccc(-c3ccc(-c4ccccc4)cc3)c2)c1 ; CC1(C)OB(c2cccc(N(c3ccccc3)c3cccc(-c4ccc(-c5ccccc5)cc4)c3)c2)OC1(C)C]

To a stirred solution of Comp-9 (11 g, 23.1 mmol) in dioxane (110 mL), B₂Pin₂ (8.8 g, 34.6 mmol) and K₃PO₄ (9.79 g, 46.2 mmol) were added at room temperature, and the resulting mixture was purged with argon for 5 min. Pd₂(dba)₃ (1.05 g, 1.15 mmol) and PCy₃.HBF₄ (1.7 g, 4.25 mmol) were added to the reaction mixture and stirred for 16 hrs at 85° C. Progress of the reaction was monitored by UPLC. After 24 h UPLC showed 76% of Comp-10 at 5.42 RT. The reaction was cooled and filtered through a Celite® pad. Filtrates were concentrated to get the crude compound. The obtained crude was purified by column chromatography using silica gel by eluting with 5-10% EtOAc in petroleum ether to get 8 g (66%) of brown solid with 89% purity by LCMS. ¹HNMR (CDCl₃, 400 MHz) δ 7.50-7.65 (m, 8H), 7.43 (t, J=7.6 Hz, 2H), 7.34-7.36 (m, 2H), 7.12-7.34 (m, 8H), 7.10 (d, J=0.8 Hz, 2H), 7.00-7.02 (m, 2H), 1.31 (s, 12H). (ESI-MS) m/z: [M+H]⁺ calculated for C₃₆H₃₄BNO₂ 523.48; found, 524.56.

### Synthesis of N-(3-(5,5-dimethyl-5H-dibenzo[b,d]silol-3-yl)phenyl)-N-phenyl-[1,1′:4′,1″-terphenyl]-3-amine (1-1)

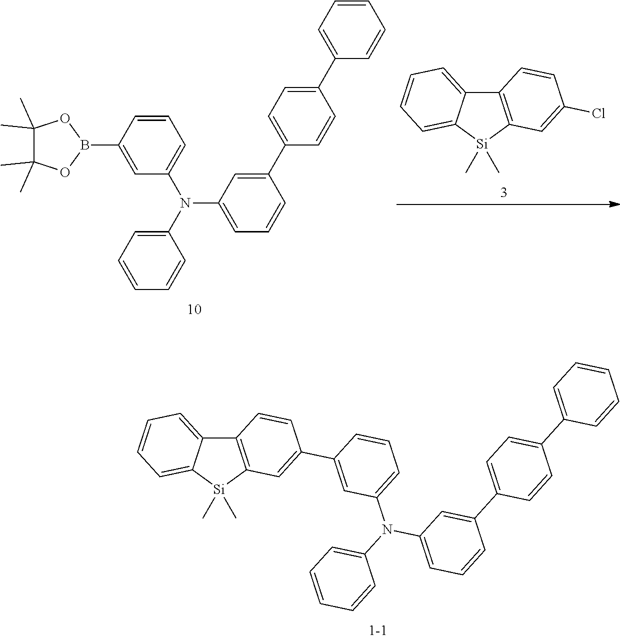

To a stirred solution of Comp-10 (5 g, 9.56 mmol) and Comp-3 (2.8 g, 11.46 mmol) in toluene (75 mL), K₂CO₃(4 g, 28.6 mmol), was added and the resulting mixture was degassed with argon for 5 min. Pd₂(dba)₃ (0.44 g, 0.475 mmol), PCy₃ (0.53 g, 1.91 mmol) was added to the mixture and stirred for 32 h at 100° C. Progress of the reaction was monitored by UPLC. After 32 h, UPLC showed 66% formation of the desired peak at 5.82 RT. The reaction was cooled and filtered through a Celite® pad. Filtrates were concentrated to get the crude compound. The obtained crude was purified by column chromatography using silica gel by eluting with 5-10% EtOAc in pet ether to get 4 g of white solid. This was further purified by dissolving in 5 volumes of CHCl₃ and co-precipitation using 10 volumes of acetonitrile to get 2.3 g (40%) of white solid with 99.3% purity by UPLC. ¹H NMR (CDCl₃₆, 400 MHz) δ 7.80-7.82 (m, 2H), 7.77 (d, J=1.6 Hz, 1H), 7.55-7.66 (m, 9H), 7.44-7.45 (m, 5H), 7.25-7.36 (m, 8H), 7.19-7.22 (m, J=8.8 Hz, 2H), 7.10-7.17 (m, 2H), 7.04 (s, 1H), 0.42 (s, 6H). (ESI-MS) m/z: [M+H]⁺ calculated for C₄₄H₃₅NSi 605.86; found, 606.47.

### Synthesis Example 2

### Synthesis of Compound 1-71

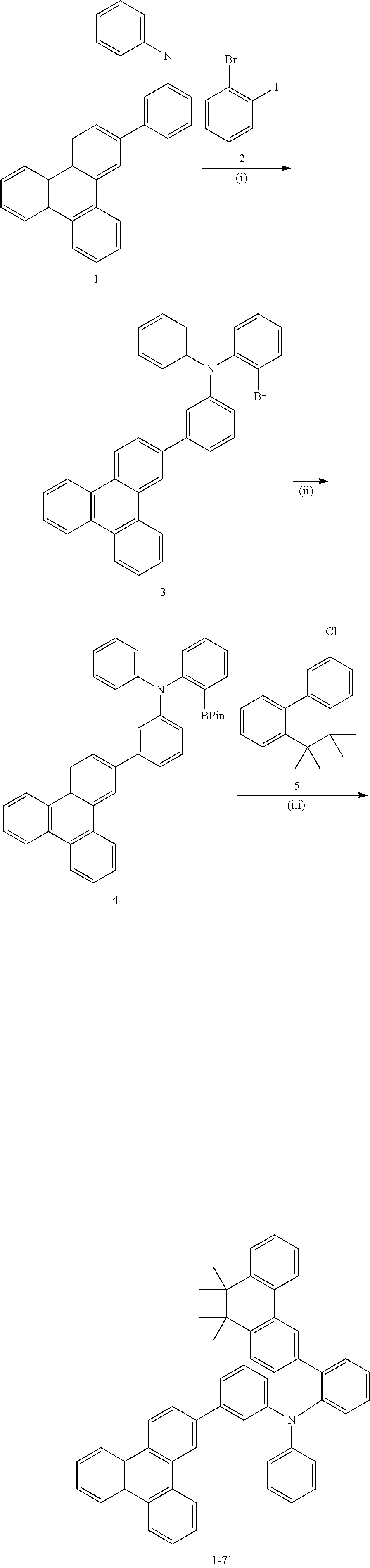

### Synthesis of 2-bromo-N-phenyl-N-(3-(triphenylen-2-yl)phenyl)aniline (3)

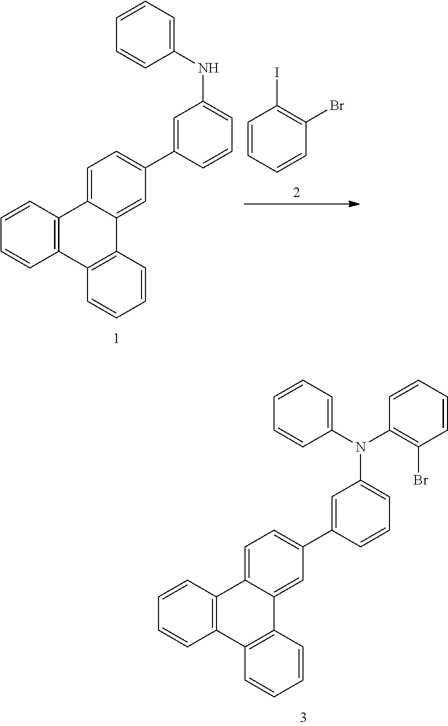

Comp-2 (3.9 mL, 0.030 mmol) and NaOtBu (4.86 g, 0.05 mmol) were added to a stirred solution of Comp-1 (10 g, 0.025 mmol) taken in toluene (100 mL). The resulting mixture was degassed with argon for 5 mins. Pd₂(dba)₃ (1.15 g, 0.0012 mmol)S-Phos (2.07 g, 0.005 mmol) were added and again degassed for 5 min. The resulting reaction mixture was heated to 100° C. for 2 h. Progress of the reaction was monitored by TLC and UPLC. After 2 h, UPLC showed 72% formation of the desired peak at 6.03 RT. The reaction was cooled to room temperature, passed through a Celite® pad, and washed with an excess of EtOAc (200 mL). The resulting filtrates were concentrated to get a crude compound. The obtained crude was purified by column chromatography using 100-200 silica gel by eluting with petroleum ether to get an off-white solid (12 g, 86%). ¹H NMR (CDCl₃, 400 MHz) δ8.75 (d, J=1.6 Hz, 1H), 8.64-8.68 (m, 5H), 7.78 (dd, J=1.6 Hz, 1.4 Hz, 1H), 7.64-7.70 (m, 5H), 7.42-7.73 (m, 4H), 7.35-7.37 (m, 2H), 7.08-7.15 (m, 3H), 6.99-7.07 (m, 2H). (ESI-MS) m/z: [M]⁺ calculated for C₃₆H₂₄BrN 550.50; found 550.42.

### Synthesis of N-phenyl-2-(4,4,5,5-tetramethyl-1,3,2-dioxaborolan-2-yl)-N-(3-(triphenylen-2-yl)phenyl)aniline (4)

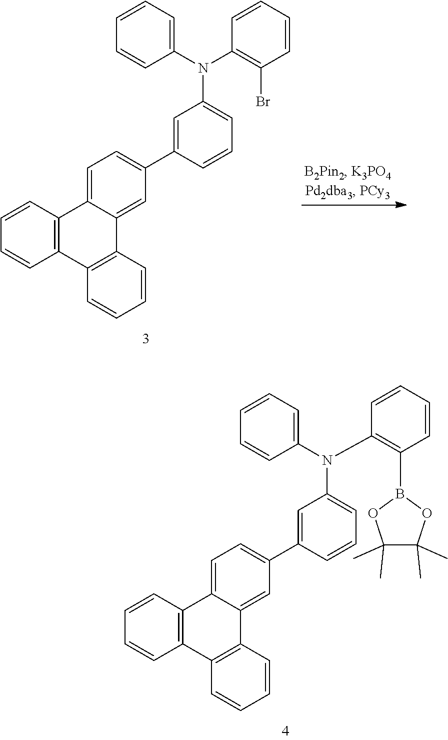 [SMILES: Brc1ccccc1N(c1ccccc1)c1cccc(-c2ccc3c4ccccc4c4ccccc4c3c2)c1 ; CC1(C)OB(c2ccccc2N(c2ccccc2)c2cccc(-c3ccc4c5ccccc5c5ccccc5c4c3)c2)OC1(C)C]

B₂Pin₂ (3.09 g, 12.16 mmol) and K₃PO₄ (2.58 g, 12.16 mmol) were added to a stirred solution of Comp-3 (3.35 g, 6.08 mmol) in dioxane (33.5 mL) and the resulting reaction mixture was purged with argon for 5 mins. Pd₂(dba)₃ (0.278 g, 0.304 mmol), and PCy₃ (0.34 g, 1.21 mmol) were added to the reaction mixture and heated at 70° C. for 16 h. Progress of the reaction was monitored by TLC and UPLC. After 16 h, UPLC showed 91% formation of the desired mass peak at 6.09 RT. The reaction was cooled to RT, passed through a Celite® pad and washed with an excess of EtOAc (200 mL). The resulting filtrates were concentrated to get a crude compound. The obtained crude was purified by column chromatography using 100-200 silica gel by eluting with 5-10% EtOAc in petroleum ether to get 2.5 g (yield: 74%) of Comp-4 as a brown solid with 94% purity. ¹H NMR (CDCl₃, 400 MHz) δ 8.76 (s, 1H), 8.65-8.71 (m, 5H), 7.79 (dd, J=5.6, 1.6 Hz, 2H), 7.64-7.76 (m, 4H), 7.46 (s, 1H), 7.39-7.42 (m, 1H), 7.31 (d, J=1.2 Hz, 2H), 7.23-7.25 (m, 3H), 7.21-7.22 (m, 3H), 7.18-7.19 (m, 1H), 7.12-7.15 (m, 1H), 6.96-7.10 (m, 1H), 1.03 (s, 12H). (ESI-MS) m/z: [M+]⁺ calculated for C₄₂H₃₆BNO₂ 597.57; found 597.67.

### Synthesis of N-phenyl-2-(9,9,10,10-tetramethyl-9,10-dihydrophenanthren-3-yl)-N-(3-(triphenylen-2-yl)phenyl)aniline (1-71)

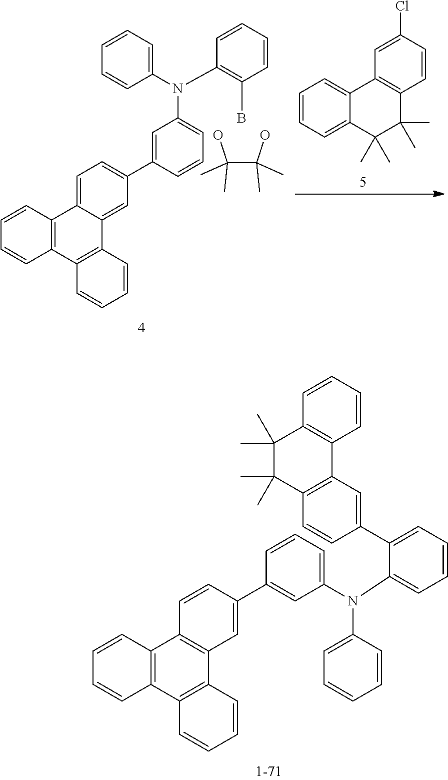

To a stirred solution of Comp-4 (2.5 g, 4.18 mmol) in dioxane (25 mL), Comp-5 (1.35 g, 5.01 mmol) and K₂CO₃ (3.09 g, 12.54 mmol) were added. The resulting reaction mixture was degassed for 5 mins. Pd₂(dba)₃ (0.19 g, 0.209 mmol) and PCy₃ (0.23 g, 0.84 mmol) were added and degassed for another 5 mins. The reaction was continued for 48 h at 90° C. Progress of the reaction was monitored by TLC and UPLC. After 48 h, UPLC showed 56% of 1-71 at 6.80 RT. The reaction was cooled to room temperature, passed through a Celite® pad and washed with an excess of EtOAc (200 mL). The resulting filtrates were concentrated to get crude compound. The obtained crude was purified by column chromatography using 100-200 silica gel by eluting with 5-10% EtOAc in petroleum ether to get 2.5 g (yield: 84%) of 1-71. Compound was further purified by re crystallization in toluene to get 1.8 g of 1-71 as an Off white solid. ¹H NMR (CDCl₃, 400 MHz) δ 8.66-8.61 (m, 6H), 7.66-7.61 (m, 5H), 7.58 (s, 1H), 7.40-7.33 (m, 4H), 7.31-7.33 (m, 3H), 7.29, 7.11 (m, 8H), 7.05 (dd, J=1.2 Hz, 0.8 Hz, 2H), 7.07-6.99 (m, 1H), 6.82 (s, 1H), 1.36 (d, J=12.4, 6H), 0.77 (s, 6H). (ESI-MS) m/z: [M+H]⁺ calculated for C₅₄H₄₃N 705.95; found 706.71.

### Synthesis Example 3

### Synthesis of Compound 1-78

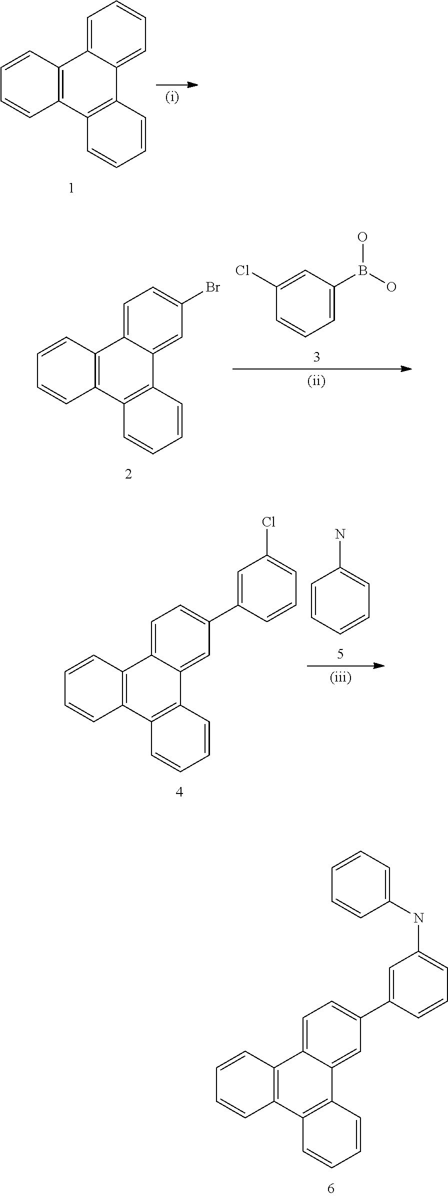

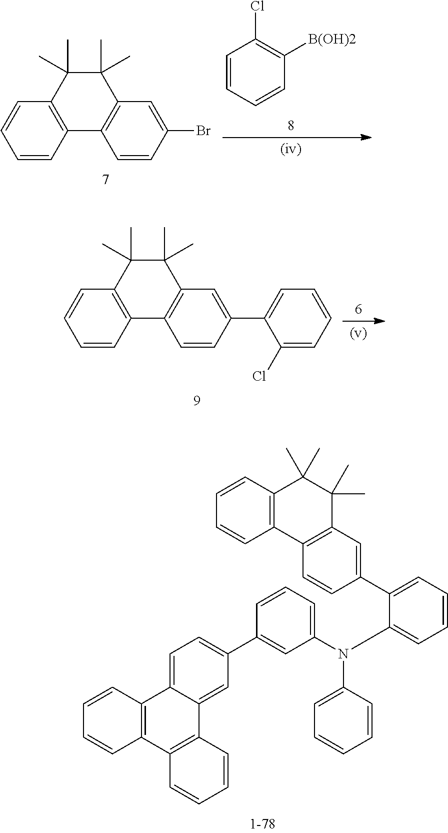 [SMILES: CC1(C)c2ccccc2-c2ccc(Br)cc2C1(C)C ; OB(O)c1ccccc1Cl ; CC1(C)c2ccccc2-c2ccc(-c3ccccc3Cl)cc2C1(C)C ; CC1(C)c2ccccc2-c2ccc(-c3ccccc3N(c3ccccc3)c3cccc(-c4ccc5c6ccccc6c6ccccc6c5c4)c3)cc2C1(C)C]

### Synthesis of 2-bromotriphenylene (2)

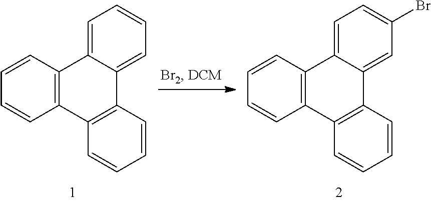

Bromine (104 g, 657.8 mmol) was added to a stirred solution of Comp-1 (100 g, 438.5 mmol) in DCM (3000 mL), kept at 0° C., and stirred at room temperature for 16 h. Progress of the reaction was monitored by TLC and LCMS of the reaction mass and after 16 h LCMS showed 68.3% formation of new peak at 4.58 RT. The reaction mixture was quenched with sodium thiosulfate pentahydrate solution (400 mL) and extracted with DCM (3×500 mL). Combined organics were dried over anhydrous Na₂SO₄ and concentrated under reduced pressure to get crude compound. The obtained crude was purified by column chromatography using 100-200 silicagel by eluting with pet ether to get 105 g of Comp-2 as an off-white solid (105 g; crude 50%). (ESI-MS) m/z: [M+H]⁺ calculated for C₁₈H₁₁Br 307.19; found 308.17.

### Synthesis of 2-(3-chlorophenyl)triphenylene (4)

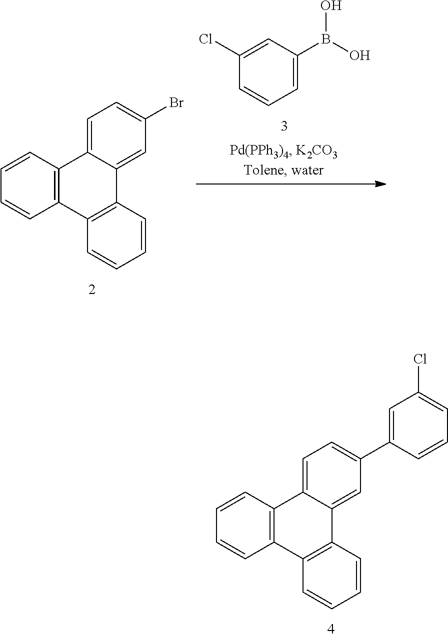 [SMILES: Brc1ccc2c3ccccc3c3ccccc3c2c1 ; OB(O)c1cccc(Cl)c1 ; Clc1cccc(-c2ccc3c4ccccc4c4ccccc4c3c2)c1]

K₂CO₃ (15.1 g, 97.4 mmol) was added to a stirred solution of Comp-2 (10.0 g, 32.43 mmol) and Comp-3 (6.1 g, 38.96 mmol) taken in toluene (110 mL) and water (30 mL). The reaction mixture was purged with argon for 5 mins and Pd(PPh₃)₄ (1.9 g, 1.6 mmol) was added to the reaction mixture and again purged with argon for 5 mins. The resulting reaction was heated to 110° C. for 16 h. Progress of the reaction was monitored by LCMS. After 16 h LCMS showed 65.9% formation of Comp-5 at 4.86 RT. The resulting reaction mixture was diluted with water (300 mL) and extracted with ethyl acetate (2×300 mL), then the combined organic layers were dried over anhydrous Na₂SO₄ and concentrated under reduced pressure to get crude compound. The obtained crude was purified by column chromatography using 100-200 silicagel by eluting with pet ether to get an Off white solid (6.6 g, 60%). ¹H NMR (CDCl₃, 400 MHz) δ 8.82 (d, J=1.6 Hz, 1H), 8.67-8.76 (m, 5H), 7.86 (dd, J=8.4 Hz, 2 Hz, 1H), 7.79 (t, J=3.6 Hz, 1H), 7.68-7.71 (m, 5H), 7.26-7.48 (m, 2H). (ESI-MS) m/z: [M+2H]⁺ calculated for C₂₄H₁₅Cl 338.8; found 341.

### Synthesis of N-phenyl-3-(triphenylen-2-yl)aniline (6)

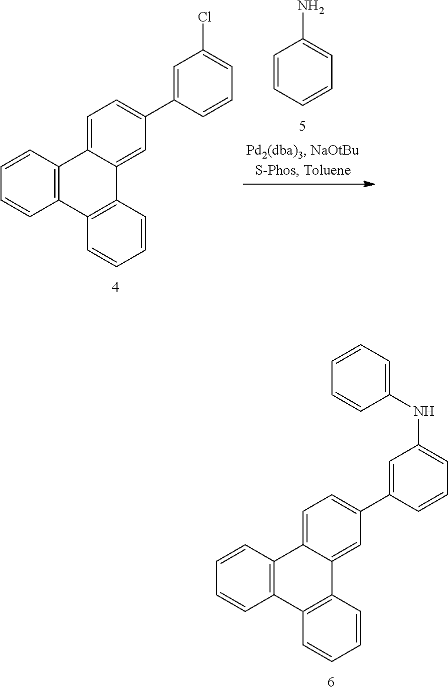

To a stirred solution of Comp-4 (7.0 g, 20.7 mmol) and Comp-5 (2.31 g, 24.85 mmol) in toluene (70 mL), NaOtBu (4.0 g, 41.42 mmol) was added and the reaction mixture was purged with argon for five minutes. S-Phos (1.7 g, 4.14 mmol) and Pd₂(dba)₃ (0.94 g, 1.03 mmol) were added and the reaction mixture was purged again with argon for five minutes. The resulting reaction mixture was stirred at 100° C. for 16 h. Progress of the reaction was monitored by LCMS. After 16 h LCMS showed 79.48% formation of Comp-6. The reaction was cooled and filtered through a Celite® pad and washed with excess EtOAc (200 mL). The resulting filtrates were concentrated under reduced pressure to get the crude compound. The obtained crude was purified by column chromatography using 100-200 silica gel to get white solid (6.2 g, 76%). ¹H NMR (CDCl₃, 400 MHz) δ 8.83 (d, J=2 Hz, 1H), 8.65-8.73 (m, 5H), 7.86 (dd, J=8.4, 8.8 Hz, 1H), 7.65-7.68 (m, 4H), 7.49 (t, J=3.6 Hz, 1H), 7.41 (d, J=8 Hz, 1H), 7.37 (t, J=2.8 Hz, 1H), 7.25-7.33 (m, 2H), 7.13-7.18 (m, 3H), 6.98 (m, 1H), 5.87 (bs, 1H). (ESI-MS) m/z: [M+H]⁺ calculated for C₃₀H₂₁N 395.51; found 396.3.

### Synthesis of 2-(2-chlorophenyl)-9,9,10,10-tetramethyl-9,10-dihydrophenanthrene (8)

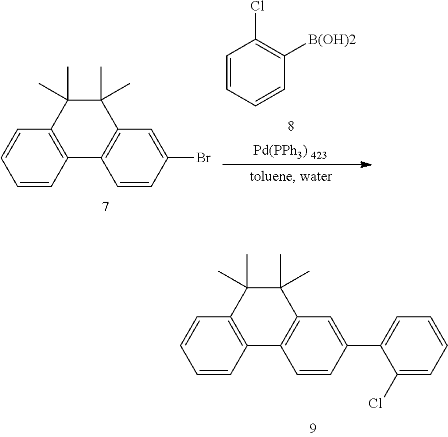 [SMILES: CC1(C)c2ccccc2-c2ccc(Br)cc2C1(C)C ; OB(O)c1ccccc1Cl ; CC1(C)c2ccccc2-c2ccc(-c3ccccc3Cl)cc2C1(C)C]

To a stirred solution of Comp-7 (1.0 g, 3.17 mmol) and Comp-8 (0.67 g, 3.81 mmol) in toluene (10 mL) and water (2 mL) was added K₂CO₃ (0.85 g, 6.35 mmol) followed by purging with argon for 5 mins. Pd(PPh₃)₄ (180 mg, 0.16 mmol) was added to the reaction and purged again with argon for 5 mins. The resulting reaction was heated to 110° C. for 16 h. Progress of the reaction was monitored by LCMS. After 16 h LCMS showed 68.3% formation of Comp-9 at 4.83 RT. The reaction was cooled and diluted with water and extracted with ethyl acetate. The organic layer was washed with water and concentrated under reduced pressure to get the crude compound. The crude compound was purified by column chromatography using 100-200 silica gel and isolated major compound eluted with petroleum ether to get 2-(2-chlorophenyl)-9,9,10,10-tetramethyl-9,10-dihydrophenanthrene (0.92 g, 55%). 1H NMR (CDCl₃, 400 MHz) δ, 7.78-7.82 (m, 2H), 7.52 (d, J=2 Hz, 1H), 7.49 (dd, J=9.2 Hz, 6.4 Hz, 1H), 7.25-7.45 (m, 7H). (ESI) m/z: [M]⁺ calculated for C₂₄H₂₃Cl 346.9; found 346.4.

### Synthesis of N-phenyl-2-(9,9,10,10-tetramethyl-9,10-dihydrophenanthren-2-yl)-N-(3-(triphenylen-2-yl)phenyl)aniline (1-78)

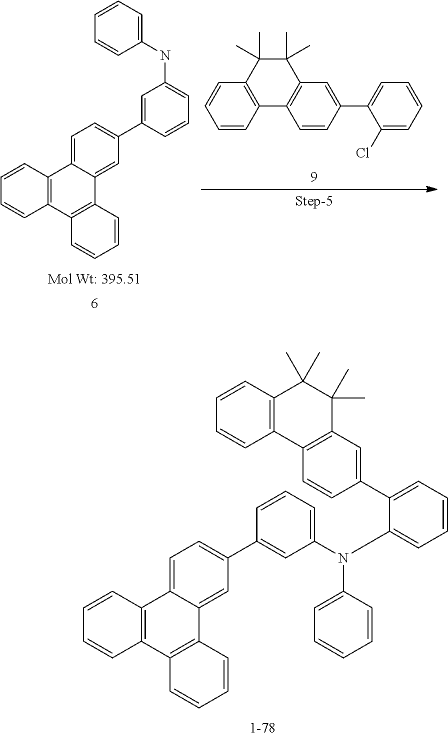

To a stirred solution of Comp-6 (2.5 g, 6.33 mmol) and Comp-9 (2.6 g, 7.60 mmol) in toluene (25 mL), NaOtBu (1.21 g, 12.66 mmol) was added and purged with argon for 5 mins. S-Phos (518 mg, 1.27 mmol) and Pd₂(dba)₃ (0.29 g, 0.32 mmol) were added to the reaction mixture which was then purged again for 5 mins with argon. The resulting reaction was heated to 110° C. for 16 h. Progress of the reaction was monitored by LCMS. After 16 h LCMS showed 70% formation of 1-78. The reaction was cooled and filtered through a Celite® pad, washed with excess EtOAc (200 mL), and concentrated under reduced pressure to get the crude compound. The obtained crude was purified by column chromatography using 100-200 silica gel to afford 3.3 g of 1-78 (74%) as an off white solid. Further purified by Prep HPLC to get 2.7 g of 1-78. (MS: 705.9, M+H), 1H NMR (CDCl₃, 400 MHz) δ 8.70-8.81 (m, 6H), 7.68-7.72 (m, 6H), 7.62 (d, J=8 Hz, 1H), 7.37-7.51 (m, 6H), 7.16-7.37 (m, 11H), 6.95 (d, J=8 Hz, 2H), 6.86-6.88 (m, 2H), 1.14-1.29 (m, 6H), 0.64-0.67 (m, 6H). ESI m/z: [M+H]⁺ calculated for C₅₄H₄₃N 705.3; found 705.7.

### Synthesis Example 4 Synthesis of Compound 2-24

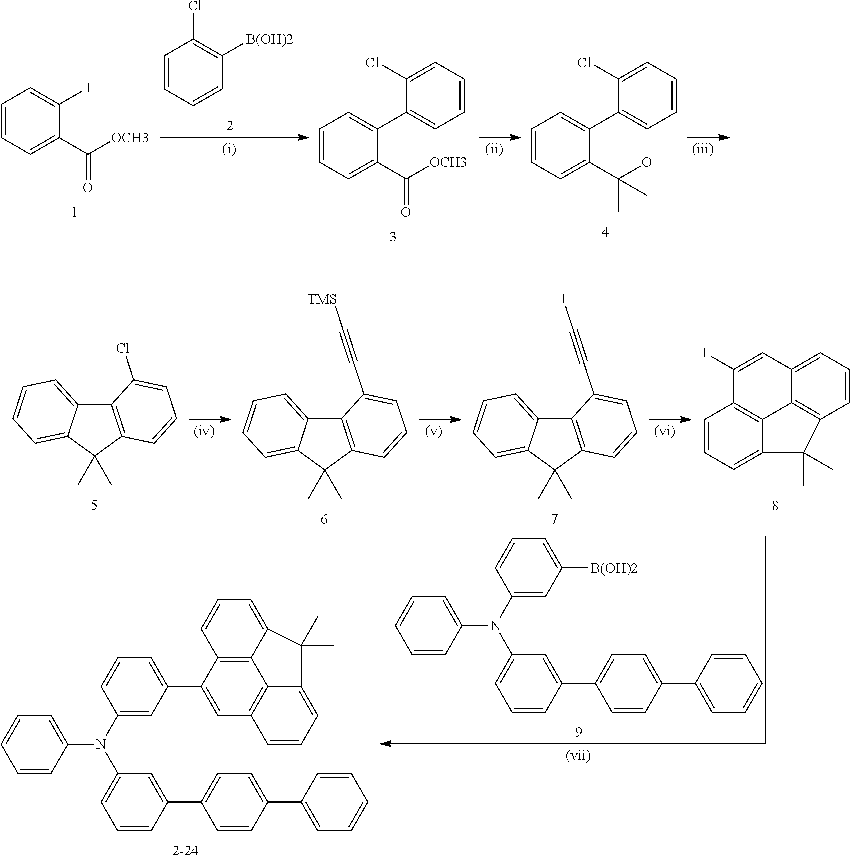

### Synthesis of methyl 2′-chloro-[1,1′-biphenyl]-2-carboxylate (3)

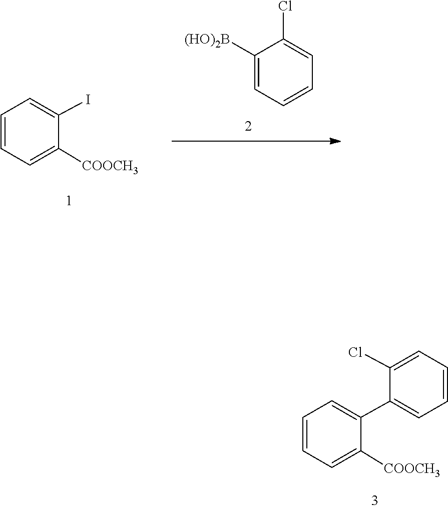 [SMILES: COC(=O)c1ccccc1I ; OB(O)c1ccccc1Cl ; COC(=O)c1ccccc1-c1ccccc1Cl]

Comp-2 (44.7 g, 286 mmol) and K₂CO₃ (79.1 g, 572 mmol) were added to a stirred solution of Comp-1 (50 g, 190.8 mmol) in dioxane (500 mL) and water (200 mL). The resulting mixture was purged with argon for 10 mins. Then, Pd(PPh₃)₄ (11 g, 9.54 mmol) was added and the reactor was heated to 85° C. for 16 h. Progress of the reaction was monitored by TLC and LCMS. After 16 h TLC showed complete consumption of Comp-1 and LCMS showed 76.4% formation of desired mass peak at 2.47 RT. The reaction mixture was cooled to room temperature, diluted with water (500 mL), and extracted with EtOAc (3×300 mL). The combined organic layers were dried over anhydrous Na₂SO₄ and concentrated to get the crude compound. The obtained crude was purified by column chromatography using (100-200 mesh silica) by eluting with petroleum ether to get 40.8 g (87%) of Comp-3 as a gummy liquid with 97.8% purity by UPLC. ¹H NMR (DMSO-d6, 400 MHz) δ 7.93 (dd, J=11 Hz, 1.5 Hz, 1H), 7.65-7.70 (m, 1H), 7.54-7.58 (m, 1H), 7.47-7.51 (m, 1H), 7.37-7.41 (m, 2H), 7.26-7.32 (m, 2H), 3.58 (s, 3H). (ESI-MS) m/z: [M+H]⁺ calculated for C₁₄H₁₁ClO₂ 246.69; found 247.24.

### Synthesis of 2-(2′-chloro-[1,1′-biphenyl]-2-yl)propan-2-ol (4)

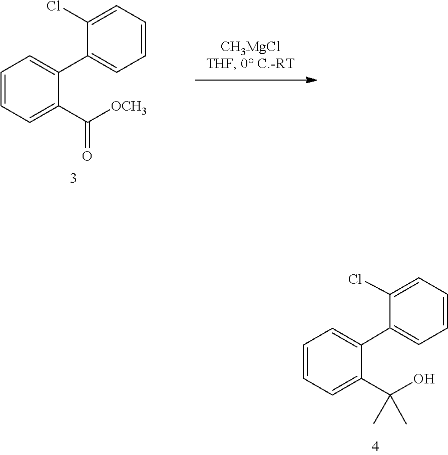 [SMILES: COC(=O)c1ccccc1-c1ccccc1Cl ; CC(C)(O)c1ccccc1-c1ccccc1Cl]

To a stirred solution of Comp-3 (40 g, 162.15 mmol) in THF (600 mL) kept at 0° C., CH₃MgCl (3M in THF) (324 mL, 972.8 mmol) was added dropwise. The reaction mixture was stirred at room temperature for 16 h. After 16 h, progress of the reaction was monitored by TLC and LCMS. TLC showed the complete consumption of Comp-3. LCMS showed 84% formation of desired mass peak at 2.37 RT. The reaction mixture was cooled to 0° C., quenched with saturated NH₄Cl solution slowly and extracted with EtOAc (3×200 mL). The combined organic layers were dried over anhydrous Na₂SO₄ and concentrated to get the crude compound. The obtained crude was purified through column chromatography (100-200 mesh silica) by eluting with petroleum ether to afford 27.8 g of Comp-4 (70%) as white solid with 95.2% purity by UPLC. ¹H NMR (DMSO-d₆, 400 MHz) δ 7.82 (dd, J=11.5 Hz, 1.5 Hz, 1H), 7.49 (dd, J=11.5 Hz, 1.5 Hz, 1H), 7.29-7.39 (m, 4H), 7.22-7.26 (m, 1H), 6.89 (dd, J=11 Hz, 1.5 Hz, 1H), 4.87 (s, 1H), 1.25 (s, 3H), 1.17 (s, 3H). (ESI-MS) m/z: [M+H]⁺ calculated for C₁₅H₁₅ClO 246.69; found 229.36.

### Synthesis of 4-chloro-9,9-dimethyl-9H-fluorene (5)

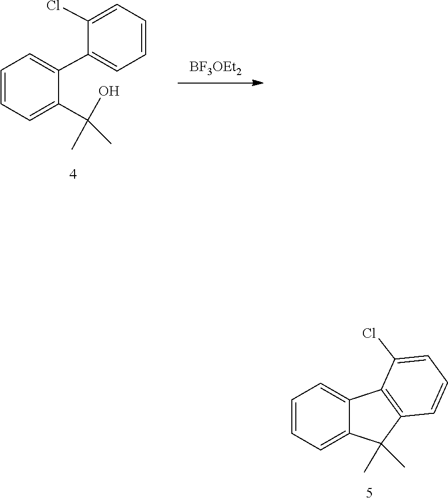

To a stirred solution of Comp-4 (22.7 g, 92.49 mmol) in DCM (455 mL), BF₃.OEt₂ (17.4 mL, 138.7 mmol) was added dropwise while maintaining bath temp at 0° C. The resulting reaction mixture was stirred at room temperature for 16 h. Progress of the reaction was monitored by TLC and UPLC. After 16 h, TLC showed complete conversion of Comp-4 and UPLC showed 87.3% formation of desired peak at 4.68 RT. The reaction mixture was cooled to 0° C., quenched with water (200 mL), and extracted with DCM (3×200 mL). The combined organic layers were dried over anhydrous Na₂SO₄ and concentrated to get the crude compound. The resulting crude was purified by column chromatography (100-200 mesh silica) by eluting with 0-5% EtOAc in petroleum ether to get 20.5 g of Comp-5 (86%) as a gummy liquid with 89% purity by UPLC. ¹H NMR (CDCl₃, 400 MHz) δ8.38-8.40 (m, 1H), 7.42-7.45 (m, 1H), 7.30-7.39 (m, 4H), 7.20-7.27 (m, 1H), 1.48 (s, 6H). (ESI-MS) m/z: [M+H]⁺ calculated for C₁₅H₁₃Cl 228.72; found 229.36.

### Synthesis of ((9,9-dimethyl-9H-fluoren-4-yl)ethynyl)triisopropylsilane (6)

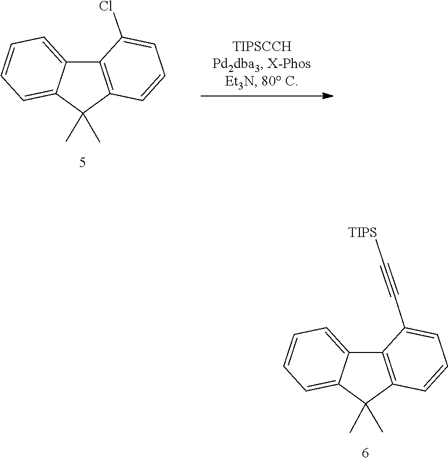

In a 500 mL steel bomb, Comp-5 (18 g, 78.6 mmol) and Et₃N (180 mL) were taken, then the mixture was purged with Argon for 5 mins. Pd₂dba₃ (3.6 g, 3.93 mmol) and X-Phos (7.5 g, 15.7 mmol) were added to the mixture followed by TIPS acetylene (52.8 mL, 235.8 mmol). The resulting mixture was heated to 80° C. and heating was continued for 16 h. Progress of the reaction was monitored by TLC and UPLC. After 16 h, TLC showed the complete conversion of Comp-5 and UPLC showed 70.8% formation of desired peak at 5.81 RT. The reaction mixture was cooled to room temperature, passed through a Celite® pad and washed with excess EtOAc (500 mL). The combined filtrates were concentrated to get the crude compound. The resulting crude was purified by column chromatography (230-400 mesh silica) by eluting with petroleum ether to get 28 g of Comp-6 as gummy liquid (80%) with 93.3% purity by UPLC. ¹H NMR (CDCl₃, 400 MHz) δ 8.67-8.69 (m, 1H), 7.32-7.46 (m, 5H), 7.22-7.25 (m, 1H), 1.46 (s, 6H), 1.18-1.22 (m, 22H). (ESI-MS) m/z: [M+H]⁺ calculated for C₂₆H₃₄Si 374.24; found 375.3.

### Synthesis of 4-(iodoethynyl)-9,9-dimethyl-9H-fluorene (7)

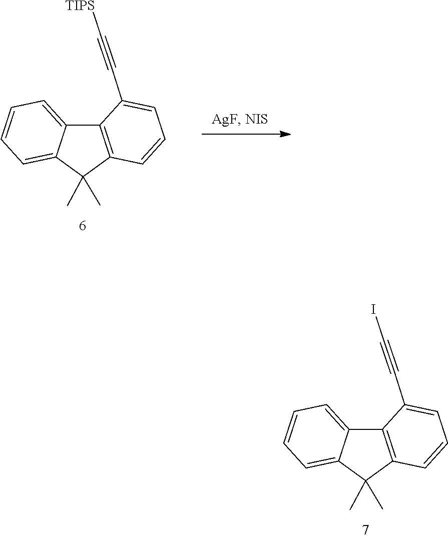

To a stirred solution of Comp-6 (28 g, 74.8 mmol) in acetonitrile (280 mL), NIS (25.2 g, 112.29 mmol) and AgF (14.2 g, 112.29 mmol) were added. The reaction mixture was stirred for 16 h at room temperature. Progress of the reaction was monitored by TLC and UPLC. After 16 h, TLC showed complete conversion of Comp-6 and UPLC showed 93% formation of desired peak at 4.69 RT. The reaction mixture was passed through Celite®, washed with excess EtOAc (500 mL), and concentrated to get the crude compound. The resulting crude was purified by column chromatography (100-200 mesh silica) by eluting with 0-5% EtOAc in petroleum ether to obtain 22.5 g of Comp-7 (87%) as pale-yellow solid with 97.8% purity by UPLC. ¹H NMR (CDCl₃, 400 MHz) δ 8.31-8.34 (m, 1H), 7.35-7.46 (m, 5H), 7.26-7.26 (m, 1H), 1.46 (s, 6H). (ESI-MS) m/z: [M+H]⁺ calculated for C₁₇H₁₃I 344.20; found 345.23.

### Synthesis of 8-bromo-4,4-dimethyl-4H-cyclopenta[def]phenanthrene (8a)

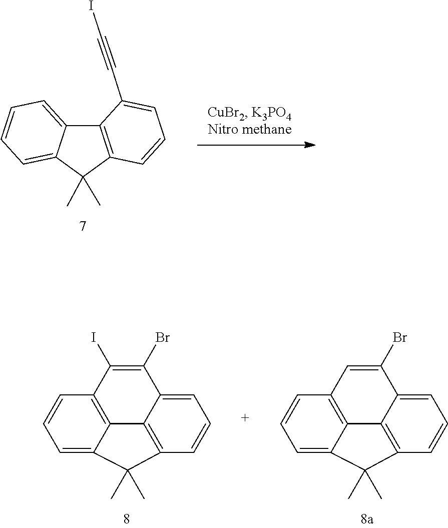 [SMILES: CC1(C)c2ccccc2-c2c(C#CI)cccc21 ; CC1(C)c2cccc3c(Br)c(I)c4cccc1c4c23 ; CC1(C)c2cccc3cc(Br)c4cccc1c4c23]

To a stirred solution of Comp-7 (7 g, 20.34 mmol) in nitromethane (70 mL), CuBr₂ (13.6 g, 61.04 mmol) and K₃PO₄ (2.16 g, 10.18 mmol) were added at room temperature and stirred for 16 h. Progress of the reaction was monitored by TLC and UPLC. After 16 h, TLC showed complete conversion of comp-7 and UPLC showed 67% formation of Comp-8a at 4.49 RT. The reaction mixture was passed through a Celite® pad and washed with excess EtOAc (300 mL). Filtrates were concentrated to get the crude compound. The resulting crude was purified by column chromatography (100-200 mesh silica) by eluting with 0-5% EtOAc in petroleum ether to get 6 g of Comp-8a (84%) as an off-white solid with 84.34% purity by UPLC. ¹H NMR (CDCl₃₆, 400 MHz) δ 7.68-7.71 (m, 1H), 7.44-7.47 (m, 2H), 7.32-7.40 (m, 3H), 7.15 (dd, J=11 Hz, 1.5 Hz, 1H), 1.49 (s, 3H), 1.48 (s, 3H). (ESI-MS) m/z: [M+H]⁺ calculated for C₁₇H₁₃Br 297.20.

### Synthesis of N-(3-(4,4-dimethyl-4H-cyclopenta[def]phenanthren-8-yl) phenyl)-N-phenyl-[1,1′:4′,1″-terphenyl]-3-amine (2-24)

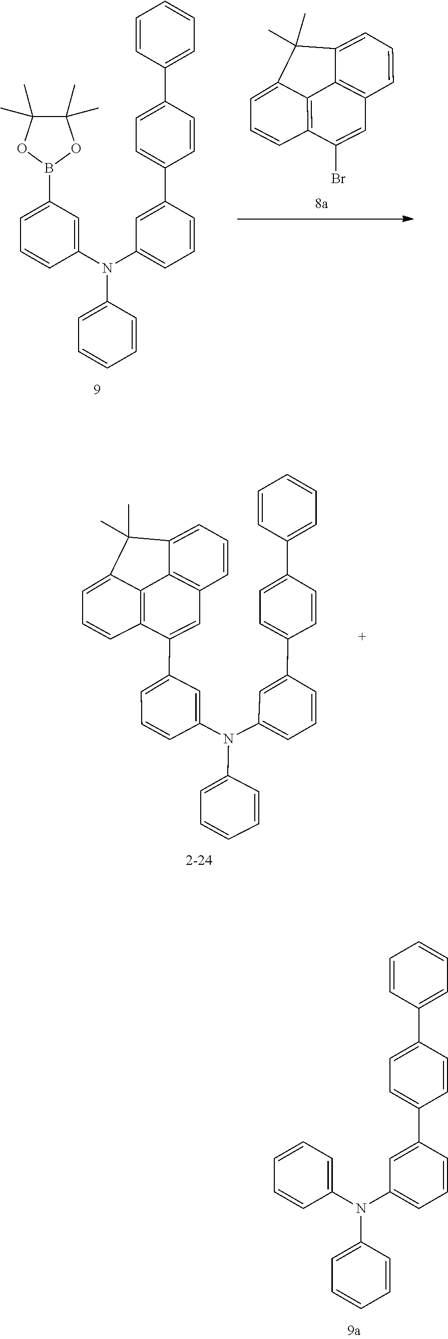 [SMILES: CC1(C)OB(c2cccc(N(c3ccccc3)c3cccc(-c4ccc(-c5ccccc5)cc4)c3)c2)OC1(C)C ; CC1(C)c2cccc3cc(Br)c4cccc1c4c23 ; CC1(C)c2cccc3cc(-c4cccc(N(c5ccccc5)c5cccc(-c6ccc(-c7ccccc7)cc6)c5)c4)c4cccc1c4c23 ; c1ccc(-c2ccc(-c3cccc(N(c4ccccc4)c4ccccc4)c3)cc2)cc1]

To a stirred solution of Comp-8a (5 g, 16.83 mmol) taken in dioxane (100 mL) and water (20 mL), Comp-9 (8.8 g, 16.8 mmol) and NaOH (2.02 g, 50.5 mmol) were added. The resulting mixture was purged with argon for 5 mins. Pd(PPh₃)₄ (0.97 g, 0.841 mmol) was added and the mixture was heated to 80° C. where the reaction continued for 2 h. Progress of the reaction was monitored by TLC and UPLC. After 2 h, TLC showed complete conversion of comp-8a and UPLC showed 42.5% formation of desired peak at 6.07 RT & 32.2% formation of Comp-9a at 6.22 RT. The reaction mixture was passed through a Celite® pad and washed with excess EtOAc (300 mL). Filtrates were concentrated to get the crude compound. The resulting crude was purified by column chromatography (100-200 mesh silica) by eluting with 0-2% EtOAc in petroleum ether to get 7 g of 2-24 as white solid. The resulting solid was co-precipitated using chloroform and acetonitrile several times to get 1.74 g of 2-24 (17%) as an off-white solid with 99.3% purity by UPLC. ¹H NMR (CDCl₃, 400 MHz) δ 8.47 (d, J=9.5 Hz, 1H), 7.58-7.64 (m, 6H), 7.38-7.46 (m, 7H), 7.28-7.37 (m, 8H), 7.19-7.24 (m, 3H), 7.08-7.19 (m, 3H), 1.46 (s, 6H). (ESI-MS) m/z: [M+H]⁺ calculated for C₄₇H₃₅N 613.80; found 614.6

### Synthesis Example 5

### Synthesis of Compound 2-32

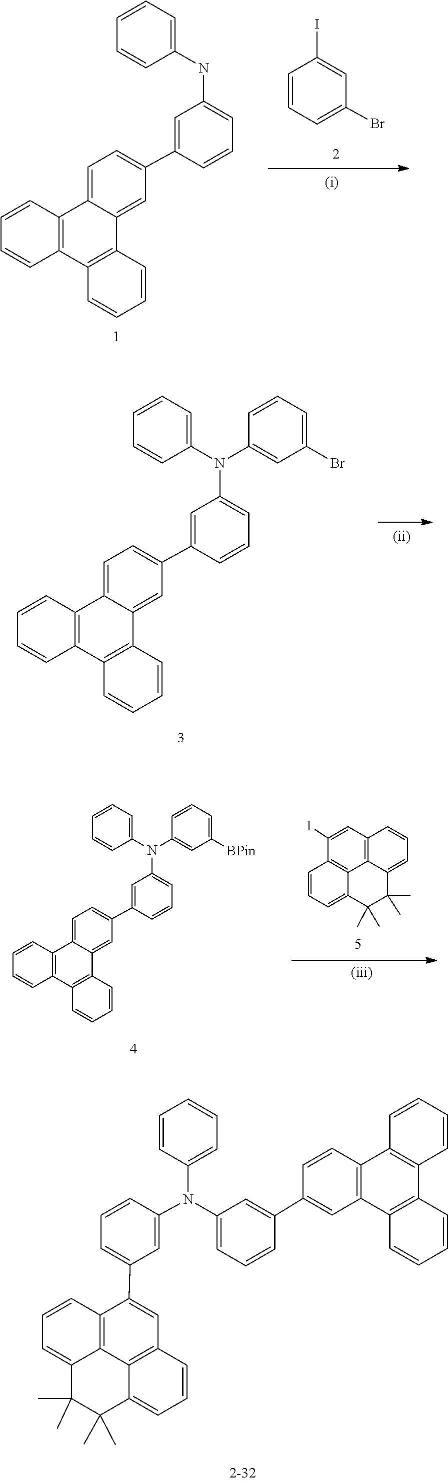

### Synthesis of 3-bromo-N-phenyl-N-(3-(triphenylen-2-yl)phenyl)aniline (3)

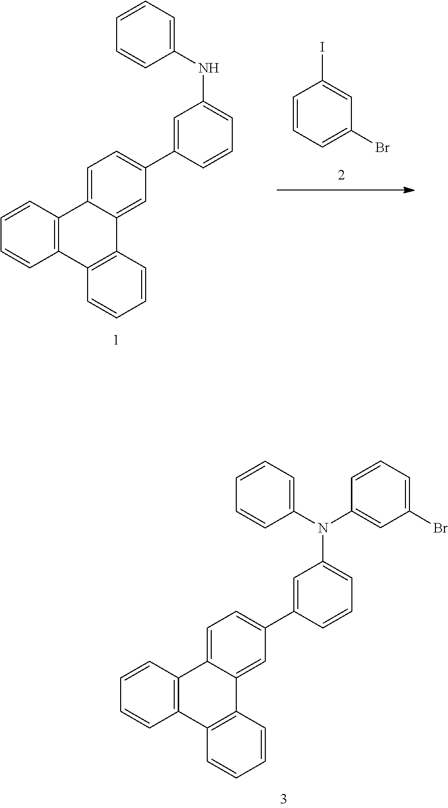 [SMILES: c1ccc(Nc2cccc(-c3ccc4c5ccccc5c5ccccc5c4c3)c2)cc1 ; Brc1cccc(I)c1 ; Brc1cccc(N(c2ccccc2)c2cccc(-c3ccc4c5ccccc5c5ccccc5c4c3)c2)c1]

Comp-2 (3.9 mL, 30.3 mmol) and NaOtBu (4.86 g, 50.6 mmol) were added to a stirred solution of Comp-1 (10 g, 25.3 mmol) taken in toluene (100 mL). The reactor was purged with argon for five minutes. Pd₂(dba)₃ (1.15 g, 1.26 mmol) and S-Phos (2.07 g, 5.06 mmol) were then added and the resulting mixture was heated at 100° C. for 16 h. Progress of the reaction was monitored by UPLC, after 16 h UPLC showed 43% of desired peak at 6.20 RT. The reaction was cooled and filtered through a Celite® pad and washed with excess of EtOAc (300 mL). Filtrates were concentrated to get the crude compound. The obtained crude was purified by column chromatography using 100-200 mesh silica gel by eluting with 15-20% EtOAc in petroleum ether to get 7.1 g Comp-3 (51%) as an off-white solid with 94.7% purity by UPLC. ¹H NMR (CDCl₃, 400 MHz) 8.75 (d, J=2 Hz, 1H), 8.64-8.67 (m, 5H), 7.78-7.80 (m, 1H), 7.65-7.68 (m, 4H), 7.53 (t, J=3.6 Hz, 1H), 7.48 (s, 1H), 7.43 (m, 1H), 7.30-7.34 (m, 3H), 7.20 (dd, J=8.8 Hz, 1.2 Hz, 2H), 7.10-7.13 (m, 5H). (ESI-MS) m/z: [M+H]⁺ calculated for C₃₆H₂₄BrN 550.50; found 551.46.

### Synthesis of N-phenyl-3-(4,4,5,5-tetramethyl-1,3,2-dioxaborolan-2-yl)-N-(3-(triphenylen-2-yl)phenyl)aniline (4)

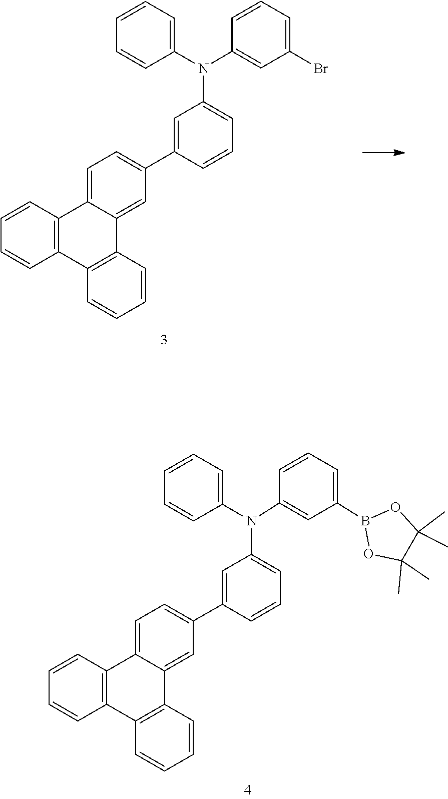 [SMILES: Brc1cccc(N(c2ccccc2)c2cccc(-c3ccc4c5ccccc5c5ccccc5c4c3)c2)c1 ; CC1(C)OB(c2cccc(N(c3ccccc3)c3cccc(-c4ccc5c6ccccc6c6ccccc6c5c4)c3)c2)OC1(C)C]

To a stirred solution of Comp-3 (7 g, 12.72 mmol) in dioxane (70 mL), B₂Pin₂ (6.43 g, 25.45 mmol) and KOAc (2.5 g, 25.45 mmol) were added. The reactor was purged with argon for five minutes. PdCl₂dppf.DCM (0.91 g, 1.27 mmol) was added to the reaction mixture which was heated at 85° C. for 16 h. Progress of the reaction was monitored by UPLC. After 16 h, UPLC showed 81.2% of desired mass peak. The reaction was cooled and filtered through a Celite® pad and washed with excess of EtOAc (300 mL). Filtrates were concentrated to get the crude compound. The obtained crude was purified by column chromatography using 100-200 mesh silica gel by eluting with 30-40% EtOAc in petroleum ether to get 5.7 g of Comp-4 (75%) as an off-white solid with 99% purity by UPLC. ¹H NMR (CDCl₃, 400 MHz) δ 8.75 (d, J=1.2 Hz, 1H), 8.62-8.68 (m, 5H), 7.78 (dd, J=6.8 Hz, 1.6 Hz, 1H), 7.64-7.70 (m, 5H), 7.49-7.55 (m, 2H), 7.37-7.42 (m, 2H), 7.27-7.30 (m, 3H), 7.16-7.17 (m, 2H), 7.02-7.09 (m 2H), 1.32 (s, 12H). (ESI-MS) m/z: [M+H]⁺ calculated for C₄₂H₃₆BNO₂ 597.57; found 598.58.

### Synthesis of N-phenyl-3-(9,9,10,10-tetramethyl-9,10-dihydropyren-4-yl)-N-(3-(triphenylen-2-yl)phenyl)aniline (2-32)

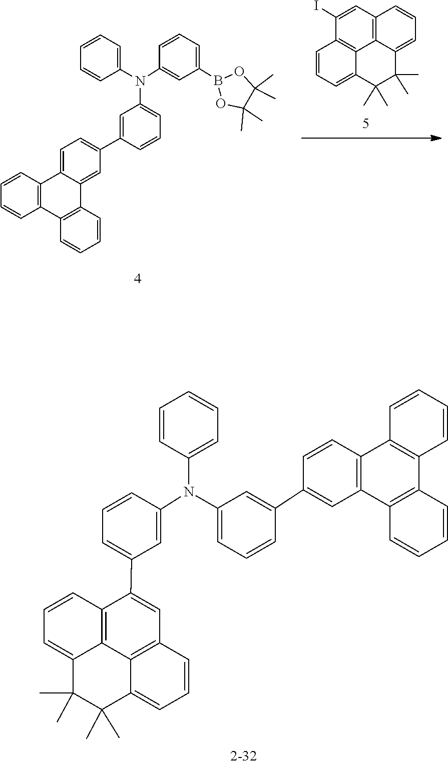

To a stirred solution of Comp-5 (2 g, 5.18 mmol) in 1,2-DME (16 mL) and water (4 mL), Comp-4 (3.71 g, 6.21 mmol) and Ba(OH)₂ (3.26 g, 10.36 mmol), were added. The resulting mixture was purged with argon for 5 min. Pd(PPh₃)₄ (0.3 g, 0.259 mmol) was added to the reaction mixture and heated for 16 h at 100° C. Progress of the reaction was monitored by LCMS. After 16 h, LCMS showed 60.4% of 2-32 at 4.82 RT. The reaction mixture was diluted with DCM and dried over anhydrous Na₂SO₄ and concentrated to get the crude compound. The obtained crude was purified by column chromatography using 100-200 silica gel to get 1.4 g (yield: 57%) of 2-32 as an off-white solid with >99% purity by UPLC. ¹H NMR (CDCl₃, 400 MHz) δ 8.95-8.87 (m, 2H), 8.80-8.85 (m, 4H), 7.78-7.82 (m, 1H), 7.73-7.74 (m, 2H), 7.70-7.72 (m, 4H), 7.64-7.69 (m, 4H), 7.54-7.60 (m, 2H), 7.50-7.52 (m, 2H), 7.36-7.40 (m, 3H), 7.09-7.27 (m, 7H), 1.58-1.60 (m, 6H), 0.95-0.83 (s, 6H). (ESI-MS) m/z: [M+H]⁺ calculated for C₅₆H₄₃N, 729.97; found 730.82.

### Synthesis Example 6

### Synthesis of Compound 3-60

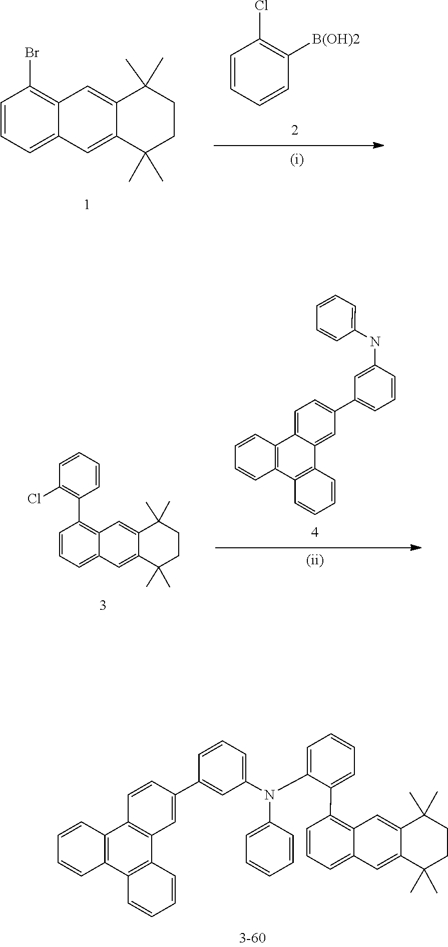 [SMILES: CC1(C)CCC(C)(C)c2cc3c(Br)cccc3cc21 ; OB(O)c1ccccc1Cl ; CC1(C)CCC(C)(C)c2cc3c(-c4ccccc4Cl)cccc3cc21 ; c1ccc(Nc2cccc(-c3ccc4c5ccccc5c5ccccc5c4c3)c2)cc1 ; CC1(C)CCC(C)(C)c2cc3c(-c4ccccc4N(c4ccccc4)c4cccc(-c5ccc6c7ccccc7c7ccccc7c6c5)c4)cccc3cc21]

### Synthesis of 5-(2-chlorophenyl)-1,1,4,4-tetramethyl-1,2,3,4-tetrahydroanthracene (3)

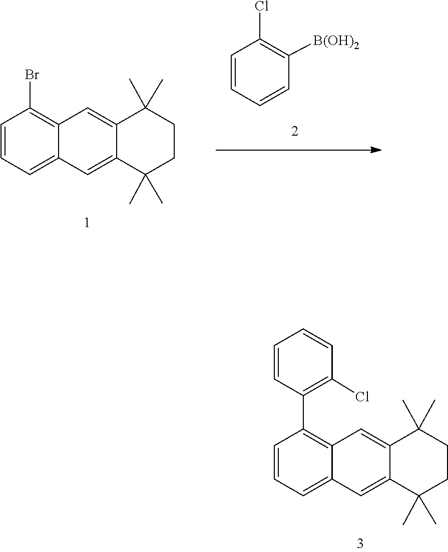 [SMILES: CC1(C)CCC(C)(C)c2cc3c(Br)cccc3cc21 ; OB(O)c1ccccc1Cl ; CC1(C)CCC(C)(C)c2cc3c(-c4ccccc4Cl)cccc3cc21]

Comp-1 (18 g, 56.73 mmol), Comp-2 (11.53 g, 73.75 mmol), and K₂CO₃ (15.6 g, 113.47 mmol) were taken in toluene (180 mL) and water (36 mL). The reaction mixture was purged with argon for 5 mins. Then, Pd(PPh₃)₄ (3.3 g, 2.83 mmol) was added and the mixture was purged again for 5 mins before the resulting solution was refluxed for 5 h. Progress of the reaction was monitored by UPLC. After 5 h UPLC showed 62.71% formation of Comp-3 at 5.07 RT. The reaction mixture was cooled and filtered through a Celite® pad and washed with an excess of EtOAc. The combined organics were washed with water and dried over anhydrous Na₂SO₄ and concentrated under reduced pressure to get the crude compound. The obtained crude was purified by column chromatography by eluting with petroleum ether and subsequently further purified by trituration with ethanol to get a white solid (15 g, 74%). 1H NMR (CDCl₃, 400 MHz) δ 7.82 (s, 1H), 7.79 (d, J=8 Hz, 1H), 7.53-7.55 (m, 1H), 7.43 (s, 1H), 7.35-7.41 (m, 4H), 7.24-7.27 (m, 1H), 1.70-1.78 (m, 4H), 1.42 (s, 3H), 1.38 (s, 3H), 1.24 (s, 3H), 1.19 (s, 3H).

### Synthesis of N-phenyl-2-(5,5,8,8-tetramethyl-5,6,7,8-tetrahydroanthracen-1-yl)-N-(3-(triphenylen-2-yl)phenyl)aniline (3-60)

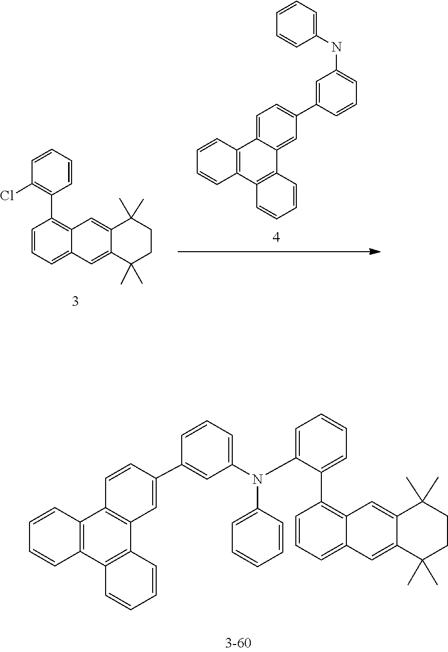 [SMILES: CC1(C)CCC(C)(C)c2cc3c(-c4ccccc4Cl)cccc3cc21 ; c1ccc(Nc2cccc(-c3ccc4c5ccccc5c5ccccc5c4c3)c2)cc1 ; CC1(C)CCC(C)(C)c2cc3c(-c4ccccc4N(c4ccccc4)c4cccc(-c5ccc6c7ccccc7c7ccccc7c6c5)c4)cccc3cc21]

To a stirred solution of Comp-3 (9.2 g, 26.30 mmol) and Comp-4 (8 g, 20.23 mmol) in toluene, (80 mL) NaOtBu was added. The resulting reaction mixture was de-gassed for 5 mins. Pd₂(dba)₃ (0.96 g, 1.01 mmol) and t-Bu₃P.HBF₄ (1.66 g, 4.05 mmol) were added and the reactor was purged with argon for 5 mins. The resulting solution was refluxed for 3 h. Progress of the reaction was monitored by UPLC, after 3 h UPLC showed 83% of 3-60 formed at 6.83 RT. (ESI-MS) m/z: [M+H]⁺ 707.6. The reaction mixture was cooled and filtered through a Celite® pad and washed with excess of EtOAc. The combined filtrates were concentrated under reduced pressure to get the crude compound. The obtained crude was purified by column chromatography by eluting with 0-2% EtOAc in petroleum ether to get 5.6 g of 3-60. The resulting compound was co-precipitated using THE (3 V) and acetonitrile (10 V) to get a white solid of compound 3-60 (5.1 g, 36%). 1H NMR (CDCl₃, 400 MHz) δ; 8.58-8.68 (m, 5H), 8.59 (d, J=8.4 Hz, 1H), 7.60-7.69 (m, 7H), 7.35-7.57 (m, 5H), 6.94-7.03 (m, 7H), 6.68-6.84 (m, 4H); 1.53-1.69 (m, 4H), 1.32-1.33 (m, 6H), 1.20 (s, 3H), 1.10 (s, 3H).

### Synthesis Example 7

### Synthesis of Compound 3-68

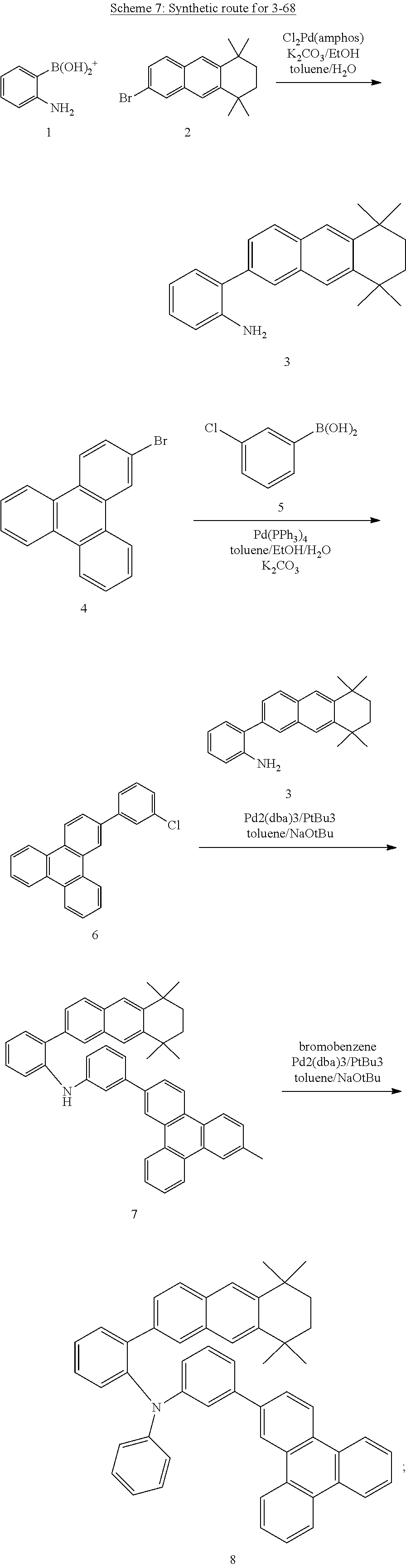

Synthesis of (5,6,7,8-tetrahydro-5,5,8,8-tetramethyl-2-anthracen-2-yl)benzeneamine 3. A mixture of (2-aminophenyl) boronic acid 1 (4.36 g, 31.84 mmole), 6-bromo-1,2,3,4-tetrahydro-1,1,4,4-tetramethyl-anthracene 2 (10 g, 31.52 mmole), Cl₂Pd(amphos) (223 mg, 0.315 mmole), K₂CO₃ (13.07 g, 94.56 mmole), ethanol (40 ml), water (20 ml) and toluene (100 ml) was degassed and stirred under nitrogen atmosphere at 90° C. for 80 min. After that the mixture cooled down, the toluene layer was separated, washed with water, and passed through silica gel. The toluene was distilled off to minimal amount, the residue triturated with hexanes, passed through a filter filled with silica gel using gradient eluation with hexanes, then mixtures of hexanes and dichloromethane and pure dichloromethane. Fractions containing the product were combined, the eluent was evaporated and dried in vacuum to give 9.84 g (95%) of (5,6,7,8-tetrahydro-5,5,8,8-tetramethyl-2-anthracen-2-yl)benzeneamine 3 as an oil with purity 99.67% by UPLC. (ESI-MS) m/z: [M+H]⁺=330. ¹H-NMR (CD₂Cl₂): 1.395 (s, 6H), 1.405 (s, 6H), 1.79 (s, 4H), 3.83 (br. S, 2H), 6.78 (dd, 1H, J1=1 Hz, J2=10 Hz), 6.81 (dt, 1H, J1=1.5 Hz, J2=10 Hz), 7.14 (dt, 1H, J1=2 Hz, J2=10 Hz), 7.18 (dd, 1H, J1=2.5 Hz, J2=9 Hz), 7.44 (dd, 1H, J1=2 Hz, J2=11 Hz), 7.79-7.82 (m, 4H).

Synthesis of 2-(3-Chlorophenyl)triphenylene 6. A mixture of 2-bromotriphenylene 4 (5.5059 g, 16.47 mmole), 3-chlorobenzene boronic acid 5 (3.68 g, 24.705 mmole), Pd(PPhs)₄ (1.91 g, 1.653 mmole), K₂CO₃ (6.83 g, 49.41 mmole), ethanol (80 ml), water (40 ml) and toluene (200 ml) was degassed and stirred under nitrogen atmosphere at 95° C. for 18 hours. After that, reaction the mixture was cooled, diluted with water, the toluene layer was separated and passed through a filter filled with silica gel and florisil eluating with toluene. The residue after evaporation of toluene was triturated with ethanol, and the initial precipitate was collected by filtration. The above crude product was dissolved in dichloromethane, absorbed onto Celite®, and subjected to chromatography purification on silica gel column using gradient elution with hexanes to mixtures of hexanes and dichloromethane. Fractions containing high purity portions of the product were combined, the eluent was evaporated to a minimal amount, precipitate filtered, washed with hexanes, and dried in vacuum to give 1.92 g of 2-(3-chlorophenyl)triphenylene 6 as white powder with purity>99.95% by UPLC. Lesser purity material were also obtained from tail fractions(ESI-MS) m/z: [M+H]⁺=338. ¹H-NMR (CDCls): 7.40-7.42 (m, 1H), 7.47 (t, 1H, J=8 Hz), 7.69-7.73 (m, 5H), 7.80 (t, 1H, J=2 Hz), 7.87 (dd, 1H, J1=2 Hz, J2=9 Hz), 8.67-8.77 (m, 5 Hz), 8.83 (d, 1H, J=2 Hz).

Synthesis of N-((5,6,7,8-tetrahydro-5,5,8,8-tetramethyl-2-anthracen-2-yl)-phenyl)-3-(triphenylen-2-yl)benzeneamine 7. A mixture of (5,6,7,8-tetrahydro-5,5,8,8-tetramethyl-2-anthracen-2-yl)benzeneamine 3 (1.867 g, 5.67 mmole), 2-(3-chlorophenyl) triphenylene 6 (1.92 g, 5.67 mmole), Pd₂(dba)₃ (104 mg, 0.113 mmole), tri-tert-butylphosphine (80 mg, 0.395 mmole), sodium tert-butoxide (0.654 g, 6.804 mmole) and toluene (100 ml) was stirred under nitrogen atmosphere at 85° C. for 21 hours. After the reaction mixture cooled down, it was passed through a filter filled with florisil and silica gel eluting with dichloromethane. The residue after evaporation of solvents was dissolved in dichloromethane, absorbed onto Celite®, and subjected to chromatography purification on silica gel column using gradient elution with hexanes to mixtures of hexanes and dichloromethane. Fractions containing high purity material were combined, the eluent was evaporated to a volume of approximately 15 ml and decanted hot. The residue was dried in vacuum to give 2.08 g of N-((5,6,7,8-tetrahydro-5,5,8,8-tetramethyl-2-anthracen-2-yl)-phenyl)-3-(triphenylen-2-yl)benzeneamine 7 as white amorphous solids with purity 99.99% by UPLC. Lesser purity material (0.94 g) was also obtained after evaporation of the filtrate. (ESI-MS) m/z: [M+H]⁺=632. ¹H-NMR (CDCl₃): 1.42 (s, 6H), 1.43 (s, 6H), 1.56 (br. S, 1H), 1.80 (s, 4H), 7.07 (t, 1H, J=7 Hz), 7.16 (d, 1H, J=7 Hz), 7.34 (t, 1H, J=10 Hz), 7.38 (dd, 2H, J1=2 Hz, J2=10 Hz), 7.42 (d, 1H, J=8 Hz), 7.45-7.46 (m, 1H), 7.51 (dd, 1H, J1=2 Hz, J2=10 Hz), 7.57 (d, 1H, J=8 Hz), 7.67-7.70 (m, 4H), 7.83-7.89 (m, 5H), 8.67-8.75 (m, 5H), 8.83 (d, 1H, J=2 Hz).

Synthesis of Compound 3-68. N-Phenyl,N-((5,6,7,8-tetrahydro-5,5,8,8-tetramethyl-2-anthracen-2-yl)-phenyl)-3-(triphenylen-2-yl)benzeneamine 8. A mixture of N-((5,6,7,8-tetrahydro-5,5,8,8-tetramethyl-2-anthracen-2-yl)-phenyl)-3-(triphenylen-2-yl)benzeneamine 7 (2.08 g, 3.3 mmole), bromobenzene (2.58 g, 16.45 mmole), Pd₂(dba)₃ (60 mg, 0.066 mmole), tri-tert-butylphosphine (70 mg, 0.347 mmole), sodium tert-butoxide (0.95 g, 9.9 mmole) and toluene (100 ml) was stirred under nitrogen atmosphere at 110° C. for 3 hours. After that reaction mixture cooled down, it was passed through a filter filled with florisil and silica gel eluting with toluene. The residue after evaporation of the toluene was dissolved in dichloromethane, absorbed onto Celite®, and subjected to chromatography purification on silica gel column using gradient elution with hexanes to mixtures of hexanes and dichloromethane. Fractions containing high purity material were combined, the eluent was evaporated, and the residue was dissolved in approximately 150 ml of hot hexanes. The precipitate was collected by filtration, dried in vacuum to give 1.708 g of N-phenyl,N-((5,6,7,8-tetrahydro-5,5,8,8-tetramethyl-2-anthracen-2-yl)-phenyl)-3-(triphenylen-2-yl)benzeneamine (Compound 3-68) 8 as white powder with purity 99.99% by UPLC. (ESI-MS) m/z: [M+H]⁺=708. ¹H-NMR (CDCls): 1.26 (s, 6H), 1.28 (s, 6H), 1.67 (s, 4H), 6.83-6.90 (m, 2H), 7.02 (d, 2H, J=11 Hz), 7.10-7.18 (m, 5H), 7.32-7.46 (m, 7H), 7.52-7.67 (m, 7H), 8.51-8.66 (m, 6H).

### Device Examples

These examples illustrate the fabrication and testing of organic electronic device, as described above.

### Device Fabrication

Bottom-emission devices were fabricated on patterned indium tin oxide (ITO) coated glass substrates. Cleaned substrates were loaded into a vacuum chamber. Once pressure reached 5×10-7 Torr or below, they sequentially received thermal evaporations of 10 nm NDP-9: HT1 (37:937) as the hole injection layer, 160 nm HT1 as the hole transport layer, 10 nm electron blocking layer, 30 nm BD1:BH1 or BD2:BH1 (3:97) as the emissive layer, 30 nm ET1:LiQ (1:1) as the electron transport layer.

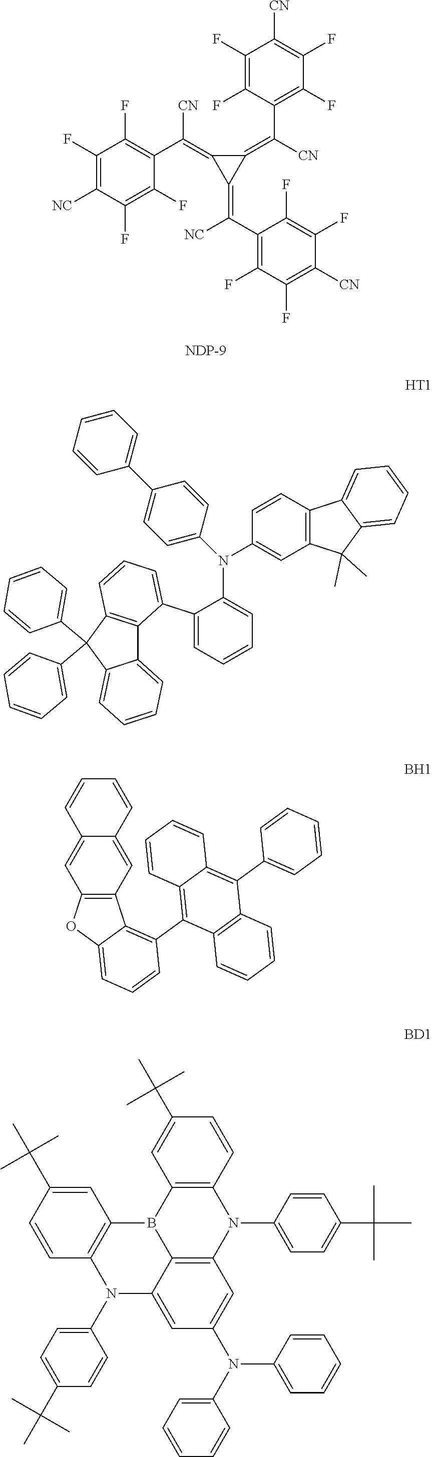 [SMILES: N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F ; "NDP-9" ; CC1(C)c2ccccc2-c2ccc(N(c3ccc(-c4ccccc4)cc3)c3ccccc3-c3cccc4c3-c3ccccc3C4(c3ccccc3)c3ccccc3)cc21 ; c1ccc(-c2c3ccccc3c(-c3cccc4oc5cc6ccccc6cc5c34)c3ccccc23)cc1 ; CC(C)(C)c1ccc(N2c3ccc(C(C)(C)C)cc3B3c4cc(C(C)(C)C)ccc4N(c4ccc(C(C)(C)C)cc4)c4cc(N(c5ccccc5)c5ccccc5)cc2c43)cc1]

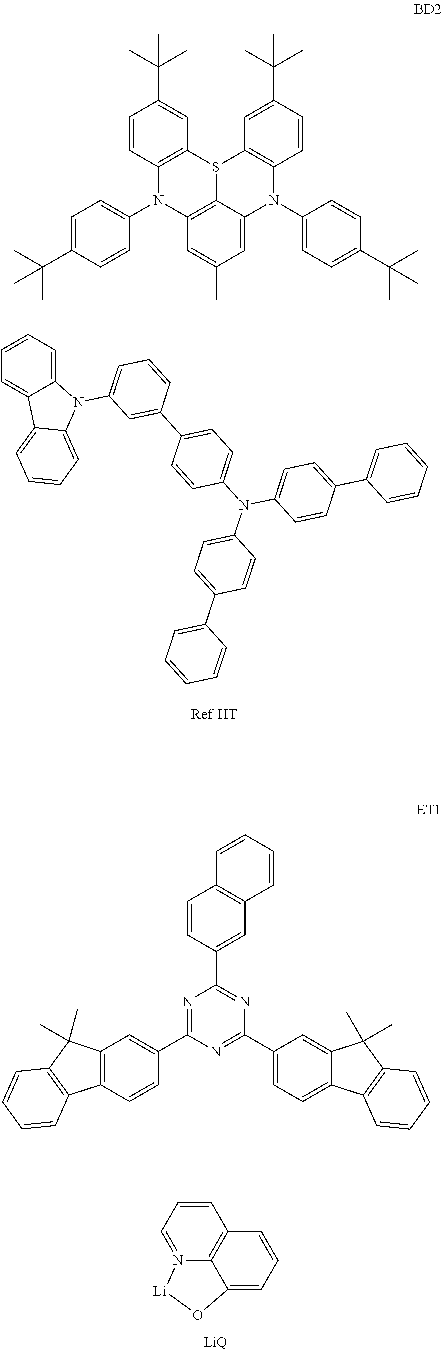

The bottom-emission devices were thermally evaporated with AI cathode material. The chamber was then vented, and the devices were encapsulated using a glass lid, desiccant, and UV curable epoxy. Device electroluminescence was measured using PR750 spectrometer and quantum efficiency was calculated assuming a Lambertian distribution of light output.

SOP values were measured in devices using the cyclic voltammetry method. The OLED driving voltage was ramped up from −10 V until the device just turned on and back to −10 V repeatedly, and a displacement current was recorded during the process. The onset of injection current is observed to shift due to SOP in the layer of interest. The amount of shift relative to a material with known SOP is used to determine the SOP of layer of interest. In the end, all SOP values are referenced to N,N′-di(1-naphthyl)-N,N′-diphenyl-(1,1′-biphenyl)-4,4′-diamine, which is assumed to have an SOP of 0 V/nm.

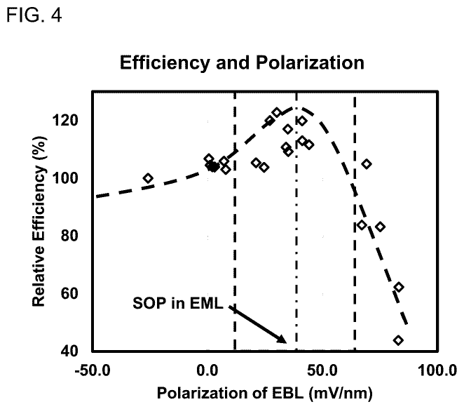

Device efficiency and polarization of the EBL is listed in Tables 1a and 1b. Data in Table 1a is plotted in FIG. 4.

TABLE 1a

| | | | Relative | Voltage | |
|---|---|---|---|---|---|
| | mixed | | Efficiency | Reduction | SOP |
| EBL | with* | Emitter | (%) | (V) | (mV/nm) |
| Ref HT | | BD1 | 100 | | −26 |
| 3-69 | | BD1 | 44 | 0.04 | 83 |
| 3-42 | | BD1 | 62 | −0.18 | 83 |
| 3-30 | | BD1 | 84 | −0.14 | 67 |
| 1-52 | Ref HT | BD1 | 107 | −0.24 | 1 |
| 1-52 | | BD1 | 120 | −0.23 | 27 |
| 3-44 | Ref HT | BD1 | 104 | −0.36 | 25 |
| 3-44 | | BD1 | 83 | −0.28 | 75 |
| 1-62 | Ref HT | BD1 | 104 | −0.26 | 2 |
| 1-62 | | BD1 | 111 | −0.14 | 34 |
| 2-20 | Ref HT | BD1 | 105 | −0.35 | 21 |
| 2-20 | | BD1 | 105 | −0.29 | 69 |
| 1-65 | Ref HT | BD1 | 104 | −0.27 | 1 |
| 1-65 | | BD1 | 113 | −0.2 | 41 |
| 1-78 | Ref HT | BD1 | 104 | −0.29 | 3 |
| 1-78 | | BD1 | 120 | −0.19 | 41 |
| 1-71 | Ref HT | BD1 | 106 | −0.3 | 7 |
| 1-71 | | BD1 | 112 | −0.23 | 44 |
| 2-32 | Ref HT | BD1 | 104 | −0.25 | 2 |
| 2-32 | | BD1 | 123 | −0.19 | 30 |
| 2-30 | Ref HT | BD1 | 104 | −0.25 | 3 |
| 2-30 | | BD1 | 109 | −0.13 | 35 |

*1:1 mixing ratio by weight

TABLE 1b

| | | Mixing | | Relative | Voltage | |
|---|---|---|---|---|---|---|
| | Mixed | ratio by | | Efficiency | Reduction | SOP |
| EBL | with | weight | Emitter | (%) | (V) | (mV/nm) |
| Ref HT | | | BD2 | 100 | | −26 |
| 1-1 | | | BD2 | 117 | −0.11 | 35 |
| 2-24 | | | BD2 | 103 | −0.04 | 8 |
| 3-60 | Ref HT | 1:3 | BD2 | 106 | −0.39 | 5 |
| 3-60 | Ref HT | 1:1 | BD2 | 117 | −0.34 | 58 |
| 3-60 | Ref HT | 3:1 | BD2 | 78 | −0.34 | 94 |
| 3-60 | | | BD2 | 62 | −0.18 | 131 |

The data show that when the polarization of the EBL is within ±25 mV/nm of the EML polarization, device efficiency is improved over the reference EBL. In most cases, a reduction in operating voltage is also observed. By reducing the difference in polarization between the EML and the adjacent layer (EBL in this case), device efficiency is improved while low operating voltage is maintained.

Further, the polarization can be fine-tuned by co-depositing two materials with different polarizations, as data suggested in Table 1 b. This result provides a simple solution to optimize polarization of the EBL layer to work with a variety of different blue host materials to achieve the benefits as disclosed herein.

Note that not all of the activities described above in the general description, or the examples are required, that a portion of a specific activity may not be required, and that one or more further activities may be performed in addition to those described. Still further, the order in which activities are listed are not necessarily the order in which they are performed.

In the foregoing specification, the concepts have been described with reference to specific embodiments. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of invention.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

It is to be appreciated that certain features are, for clarity, described herein in the context of separate embodiments, may also be provided in combination in a single embodiment. Conversely, various features that are, for brevity, described in the context of a single embodiment, may also be provided separately or in any subcombination. The use of numerical values in the various ranges specified herein is stated as approximations as though the minimum and maximum values within the stated ranges were both being preceded by the word “about.” In this manner, slight variations above and below the stated ranges can be used to achieve substantially the same results as values within the ranges. Also, the disclosure of these ranges is intended as a continuous range including every value between the minimum and maximum average values including fractional values that can result when some of components of one value are mixed with those of different value. Moreover, when broader and narrower ranges are disclosed, it is within the contemplation of this invention to match a minimum value from one range with a maximum value from another range and vice versa.

What is claimed is:

1. A composition comprising:
a mixture of a first compound and a second compound; wherein
the first compound has a different chemical structure than the second compound; wherein
the first compound and the second compound have molecular weights between 300 and 1000; wherein
the first compound and the second compound have glass transition temperatures (T_{g}'s) greater than 105° C.; wherein
the first compound and the second compound each comprise one or more aryl amine groups; wherein
the first compound has a concentration C₁ in the mixture;
wherein
the second compound has a concentration C₂ in the mixture;
wherein
C₁ is between 1 wt. % and 99 wt. %; and
C₂ is between 1 wt. % and 99 wt. %; wherein
a thin film formed from the first compound has a spontaneous orientation polarization SOP-1; wherein
a thin film formed from the second compound has a spontaneous orientation polarization SOP-2; and
the absolute value of the difference between SOP-1 and SOP-2 is greater than or equal to 10 mV/nm.

2. The composition of claim 1; wherein
the first compound and the second compound each comprise one aryl amine group.

3. The composition of claim 1; wherein
the first compound and/or the second compound have a chemical structure given by Formula 1: 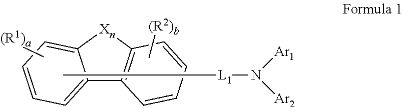
wherein
X represents —O—, —S—, —Si(R′)(R″)—, —N(R)—, —C(R′)(R″)—, —Se—, or (R′)(R″)C-C(R′″)(R″″);
R, R′, and R″ each independently represent a substituted or unsubstituted (C1-C30)alkyl, a substituted or unsubstituted (C6-C30)aryl, or a substituted or unsubstituted (3- to 30-membered)heteroaryl, -L₂-N-(Ar₃)(Ar₄) or -L₃-N(Ar₅)-L₄-N-(Ar₆)(Ar₇); or R′ and R″ may be linked to each other to form a ring(s), and R′ and R″ may be the same or different;
Ar₁-Ar₇ each independently represent hydrogen, deuterium, a substituted or unsubstituted (C1-C30)alkyl, a substituted or unsubstituted (C6-C30)aryl, a substituted or unsubstituted (3- to 30-membered) heteroaryl, a substituted or unsubstituted mono- or di-(C1-C30) alkylamino, a substituted or unsubstituted mono- or di-(C6-C30)arylamino, or a substituted or unsubstituted (C1-C30)alkyl(C6-C30)arylamino, where if a plurality of Ar₁-Ar₇ is present, each of adjacent Ar₁-Ar₇ may be the same or different; wherein if Ar₁-Ar₇ each independently represent a substituted or unsubstituted (C6-C30)aryl, or a substituted or unsubstituted (3- to 30-membered)heteroaryl, adjacent Ar₁-Ar₇ may be linked to each other via a single bond to form a ring(s);
L₁-L₄ represent a single bond, a substituted or unsubstituted (C6-C30)arylene, or a substituted or unsubstituted (3- to 30-membered)heteroarylene;
R¹ and R² each independently represent hydrogen, deuterium, a halogen, a cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted mono- or di-(C1-C30)alkylamino, a substituted or unsubstituted mono- or di-(C6-C30)arylamino, or a substituted or unsubstituted (C1-C30)alkyl(C6-C30)arylamino, where if a plurality of R¹ and/or R² is present, each may be the same or different at each occurrence, and where adjacent R¹ and/or R² groups or R¹ and/or R² groups on adjacent rings can be joined together to form a 5- or 6-membered cycloaliphatic ring, carbocyclic aromatic ring, heteroaromatic ring, or a substituted derivative thereof;
a and b each independently represent an integer between 0 and 4, with the proviso that the maximum value for a or b is 3 when the bond to L₁ attaches to the ring bearing R¹ or R², respectively; and
n represents 1 or 2.

4. The composition of claim 3; wherein
the first compound and/or the second compound are selected from the group consisting of Formula 1-1 through Formula 1-79.

5. The composition of claim 1; wherein
the first compound and/or the second compound have a chemical structure given by Formula 2: 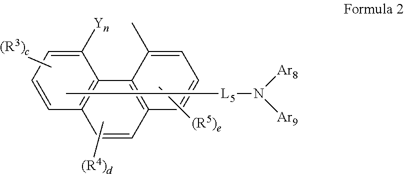
wherein
Y is the same or different at each occurrence and represents —O—, —S—, —Si(R′)(R″)—, —N(R)—, C(R′)(R″)—, —Se—, or (R′)(R″)C-C(R′″)(R″″);
R, R′, and R″ each independently represent a substituted or unsubstituted (C₁-C₃₀)alkyl, a substituted or unsubstituted (C₆-C₃₀)aryl, or a substituted or unsubstituted (3- to 30-membered)heteroaryl, -L₂-N—(Ar₃)(Ar₄) or -L₃-N(Ar₅)-L₄-N—(Ar₆)(Ar₇); or R′ and R″ may be linked to each other to form a ring(s), and R′ and R″ may be the same or different;
Ar₃-Ar₉ each independently represent hydrogen, deuterium, a substituted or unsubstituted (C1-C30)alkyl, a substituted or unsubstituted (C6-C30)aryl, a substituted or unsubstituted (3- to 30-membered) heteroaryl, a substituted or unsubstituted mono- or di-(C1-C30) alkylamino, a substituted or unsubstituted mono- or di-(C6-C30)arylamino, or a substituted or unsubstituted (C1-C30)alkyl(C6-C30)arylamino, where if a plurality of Ar₃-Ar₉ is present, each of Ar₃-Ar₉ may be the same or different; wherein
if Ar₃-Ar₉ each independently represent a substituted or unsubstituted (C6-C30)aryl, or a substituted or unsubstituted (3- to 30-membered)heteroaryl, adjacent Ar₃-Ar₉ may be linked to each other via a single bond to form a ring(s);
L₂-L₅ represent a single bond, a substituted or unsubstituted (C6-C30)arylene, or a substituted or unsubstituted (3- to 30-membered)heteroarylene;
R³-R⁵ each independently represent hydrogen, deuterium, a halogen, a cyano, a substituted or unsubstituted (C1-C30)alkyl, a substituted or unsubstituted (C6-C30)aryl, a substituted or unsubstituted (3 to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted mono- or di-(C1-C30)alkylamino, a substituted or unsubstituted mono- or di-(C6-C30)arylamino, or a substituted or unsubstituted (C1-C30)alkyl(C6-C30)arylamino, where if a plurality of R³-R⁵ is present, each may be the same or different at each occurrence; and where adjacent R³ and/or R⁴ and/or R⁵ groups or R³ and/or R⁴ and/or R⁵ groups on adjacent rings can be joined together to form a 5- or 6-membered cycloaliphatic ring, carbocyclic aromatic ring, heteroaromatic ring, or a substituted derivative thereof;
c and e each independently represent an integer between 0 and 3, with the proviso that the maximum value for c or e is 2 when the bond to L₅ attaches to the ring bearing R³ or R⁵, respectively. d represents an integer between 0 and 2, with the proviso that the maximum value for d is 1 when the bond to L₅ attaches to the ring bearing R⁴; and
n represents 1 or 2.

6. The composition of claim 5; wherein
the first compound and/or the second compound are selected from the group consisting of Formula 2-1 through Formula 2-65.

7. The composition of claim 1; wherein
the first compound and/or the second compound have a chemical structure given by Formula 3: 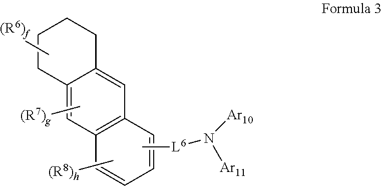
wherein
Ar₁₀-Ar₁₁ each independently represent hydrogen, deuterium, a substituted or unsubstituted (C1-C30)alkyl, a substituted or unsubstituted (C6-C30)aryl, a substituted or unsubstituted (3- to 30-membered) heteroaryl, a substituted or unsubstituted mono- or di-(C1-C30) alkylamino, a substituted or unsubstituted mono- or di-(C6-C30)arylamino, or a substituted or unsubstituted (C1-C30)alkyl(C6-C30)arylamino, where if a plurality of Ar₃-Ar₉ is present, each of Ar₁₀-Ar₁₁ may be the same or different; wherein
if Ar₁₀-Ar₁₁ each independently represent a substituted or unsubstituted (C6-C30)aryl, or a substituted or unsubstituted (3- to 30-membered)heteroaryl, adjacent Ar₃-Ar₉ may be linked to each other via a single bond to form a ring(s);
L₆ represent a single bond, a substituted or unsubstituted (C6-C30)arylene, or a substituted or unsubstituted (3- to 30-membered)heteroarylene; R⁶, R⁷ and R⁸ each independently represent hydrogen, deuterium, a halogen, a cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted mono- or di-(C1-C30)alkylamino, a substituted or unsubstituted mono- or di-(C6-C30)arylamino, or a substituted or unsubstituted (C1-C30)alkyl(C6-C30)arylamino, where if a plurality of R⁶,R⁷ and/or R⁸ is present, each may be the same or different at each occurrence; and where adjacent R⁶ and/or R⁷ and/or R⁸ groups or R⁶ and/or R⁷ and/or R⁸ groups on adjacent rings can be joined together to form a 5- or 6-membered cycloaliphatic ring, carbocyclic aromatic ring, heteroaromatic ring, or a substituted derivative thereof;
f represents an integer between 0 and 8, g represents an integer between 0 and 2, and h represents an integer between 0 and 4 with the proviso that the maximum value for g is 1 and the maximum value for h is 3 when the bond to L₆ attaches to the ring bearing R⁷ or R⁸, respectively.

8. The composition of claim 7; wherein
the first compound and/or the second compound are selected from the group consisting of Formula 3-1 through Formula 3-79.

9. The composition of claim 1; wherein
the first compound and/or the second compound comprise one or more deuterium atoms.

10. A thin film comprising:
a mixture of a first compound and a second compound; wherein
the first compound has a different chemical structure than the second compound; wherein
the first compound and the second compound have molecular weights between 300 and 1000; wherein
the first compound and the second compound have glass transition temperatures greater than 105° C.; wherein
the first compound and the second compound each comprise one or more aryl amine groups; wherein
a thin film formed from the first compound has a spontaneous orientation polarization SOP-1; wherein
a thin film formed from the second compound has a spontaneous orientation polarization SOP-2; and
the absolute value of the difference between SOP-1 and SOP-2 is greater than or equal to 10 mV/nm.

11. The thin film of claim 10; wherein
the thin film has a thickness between 1 nm and 200 nm.

12. An organic electronic device comprising:
an anode;
a hole transporting layer;
a electron blocking layer;
a light emitting layer;
an electron transport layer; and
a cathode; wherein
the light emitting layer comprises a host and a dopant; wherein
the light emitting layer has a spontaneous orientation polarization SOP-EML; wherein
the electron blocking layer has a spontaneous orientation polarization SOP-EBL; such that
the absolute value of the difference between SOP-EML and SOP-EBL is less than or equal to 25 mV/nm.

13. The organic light emitting device of claim 12; wherein:
10 mV/nm<SOP-EML<100 mV/nm; and
10 mV/nm<SOP-EBL<100 mV/nm.
